(19) United States
(12) Patent Application Publication
(10) Pub. No.: US 2025/0048676 A1
(43) Pub. Date: Feb. 6, 2025

(54) SEMICONDUCTOR DEVICE, METHOD FOR MANUFACTURING SEMICONDUCTOR DEVICE

(71) Applicant: SEMICONDUCTOR ENERGY LABORATORY CO., LTD., Atsugi-shi, Kanagawa-ken (JP)

(72) Inventors: Ryota HODO, Atsugi, Kanagawa (JP); Satoru SAITO, Yamato, Kanagawa (JP); Hitoshi KUNITAKE, Machida, Tokyo (JP); Shunpei YAMAZAKI, Setagaya, Tokyo (JP); Masahiro WAKUDA, Isehara, Kanagawa (JP); Toshiki HAMADA, Isehara, Kanagawa (JP)

(21) Appl. No.: 18/713,288

(22) PCT Filed: Nov. 17, 2022
(86) PCT No.: PCT/IB2022/061054

§ 371 Date: May 24, 2024

(30) Foreign Application Priority Data
Nov. 30, 2021 (JP) 2021-194809
Feb. 28, 2022 (JP) 2022-030009
May 16, 2022 (JP) 2022-080079

(51) Int. Cl. H01L 29/423; H01L 29/66; H01L 29/786

(52) U.S. Cl. CPC H01L 29/42384; H01L 29/66969; H01L 29/78648; H01L 29/7869

(57) ABSTRACT

A semiconductor device that can be miniaturized or highly integrated and a manufacturing method thereof are provided. A semiconductor device includes a metal oxide, a first conductor and a second conductor over the metal oxide, a first insulator positioned over the metal oxide and between the first conductor and the second conductor, a second insulator over the first insulator, a third insulator over the second insulator, a third conductor over the third insulator, a fourth insulator positioned between the first conductor and the first insulator, and a fifth insulator positioned between the second conductor and the first insulator. The first insulator is in contact with the top surface and the side surface of the metal oxide, and oxygen is less likely to pass through the first insulator than the second insulator. The first conductor, the second conductor, the fourth insulator, and the fifth insulator contain the same metal element. In a cross-sectional view in a channel length direction, a distance from the first conductor to the first insulator is greater than or equal to a thickness of the first insulator and less than or equal to a distance from the third conductor to the metal oxide.

### TECHNICAL FIELD

One embodiment of the present invention relates to a transistor, a semiconductor device, a display device, and an electronic device. Another embodiment of the present invention relates to a method for manufacturing a semiconductor device and a method for manufacturing a display device. Another embodiment of the present invention relates to a semiconductor wafer and a module.

Note that in this specification and the like, a semiconductor device generally means a device that can function by utilizing semiconductor characteristics. A semiconductor element such as a transistor, a semiconductor circuit, an arithmetic device, and a storage device are each an embodiment of a semiconductor device. It can be sometimes said that a display device (a liquid crystal display device, a light-emitting display device, and the like), a projection device, a lighting device, an electro-optical device, a power storage device, a storage device, a semiconductor circuit, an image capturing device, an electronic device, and the like include a semiconductor device.

Note that one embodiment of the present invention is not limited to the above technical field. One embodiment of the invention disclosed in this specification and the like relates to an object, a method, or a manufacturing method. One embodiment of the present invention relates to a process, a machine, manufacture, or a composition of matter.

### BACKGROUND ART

In recent years, semiconductor devices have been developed, and LSIs, CPUs, memories, and the like are mainly used as the semiconductor devices. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of an LSI, a CPU, a memory, or the like is mounted on a circuit board, for example, a printed wiring board, to be used as one of components of a variety of electronic devices.

A technique by which a transistor is formed using a semiconductor thin film formed over a substrate having an insulating surface has been attracting attention. The transistor is used in a wide range of electronic devices such as an integrated circuit (IC) and an image display device (also simply referred to as a display device). A silicon-based semiconductor material is widely known as a semiconductor thin film applicable to the transistor and further, an oxide semiconductor has been attracting attention as another material.

It is known that a transistor using an oxide semiconductor has an extremely low leakage current in a non-conduction state. For example, Patent Document 1 discloses a low-power-consumption CPU utilizing a feature of a low leakage current of the transistor using an oxide semiconductor. Furthermore, for example, Patent Document 2 discloses a storage device that can retain stored contents for a long time by utilizing a feature of a low leakage current of the transistor using an oxide semiconductor.

In recent years, demand for an integrated circuit with higher density has risen with reductions in size and weight of electronic devices. Therefore, a technique for miniaturizing transistors has been required. Non-Patent Document 1 and Non-Patent Document 2 disclose a transistor using silicon for a channel with a channel length of 3 nm and without p/n junction (Junctionless-FET). Non-Patent Document 3 discloses a transistor using an oxide semiconductor for a channel with a gate length of less than or equal to 12 nm.

### REFERENCES

### Patent Documents

[Patent Document 1] Japanese Published Patent Application No. 2012-257187
[Patent Document 2] Japanese Published Patent Application No. 2011-151383

### Non-Patent Documents

[Non-Patent Document 1] S. Migita, et al, “Electrical Performances of Junctionless-FETs at the Scaling Limit (L_{CH}=3 nm)”, IEDM Tech. Dig., pp. 191-194, 2012.
[Non-Patent Document 2] S. Migita, et al, “Experimental Demonstration of Ultrashort-Channel (3 nm) Junctionless FETs Utilizing Atomically Sharp V-Grooves on SOI”, IEEE Trans. Nanotechnol., 13, pp. 208-215, 2014.
[Non-Patent Document 3] S. Subhechha, et al, “First demonstration of sub-12 nm L_{g} gate last IGZO-TFTs with oxygen tunnel architecture for front gate devices”, Symposium on VLSI Technology Digest of Technical Papers, T10-5, 2021.

### SUMMARY OF THE INVENTION

### Problems to be Solved by the Invention

An object of one embodiment of the present invention is to provide a semiconductor device that can be miniaturized or highly integrated. Another object is to provide a semiconductor device having favorable electrical characteristics. Another object is to provide a semiconductor device with a small variation in electrical characteristics of transistors. Another object is to provide a semiconductor device having favorable reliability. Another object is to provide a semiconductor device with a high on-state current. Another object is to provide a semiconductor device with low power consumption.

Note that the description of these objects does not preclude the existence of other objects. Note that one embodiment of the present invention does not need to achieve all of these objects. Note that other objects will be apparent from the description of the specification, the drawings, the claims, and the like, and other objects can be derived from the description of the specification, the drawings, the claims, and the like.

### Means for Solving the Problems

One embodiment of the present invention is a semiconductor device including a metal oxide including a channel formation region of a transistor, a first conductor and a second conductor over the metal oxide, a first insulator positioned over the metal oxide and between the first conductor and the second conductor, a second insulator over the first insulator, a third insulator over the second insulator, a third conductor over the third insulator, a fourth insulator positioned between the first conductor and the first insulator, a fifth insulator positioned between the second conductor and the first insulator, and a sixth insulator positioned above the first conductor and the second conductor. The sixth insulator has an opening. The opening includes a region that is between the first conductor and the second conductor and that overlaps with the metal oxide. The first insulator, the second insulator, the third insulator, and the third conductor are placed in the opening. The first insulator includes a region in contact with a top surface of the metal oxide, a region in contact with a side surface of the metal oxide, and a region in contact with a sidewall of the opening. The first insulator is a material through which oxygen is less likely to pass than the second insulator. The first insulator includes a region having a thickness of greater than or equal to 1.0 nm and less than 3.0 nm. The first conductor and the second conductor each contain a metal element. The fourth insulator and the fifth insulator contain the metal element. In a cross-sectional view of the transistor in a channel length direction, a distance from the first conductor to the first insulator is greater than or equal to a thickness of the first insulator and is less than or equal to a distance from the third conductor to the metal oxide.

In the above semiconductor device, it is preferable that the first insulator be a material through which oxygen and hydrogen are less likely to pass than the second insulator, the third insulator be a material through which hydrogen is less likely to pass than the second insulator, the first insulator and the second insulator each contain oxygen, the second insulator and the third insulator each contain silicon, and the third insulator and the third conductor each contain nitrogen.

In the above semiconductor device, the first insulator preferably contains aluminum.

In the above semiconductor device, the metal oxide preferably has a concentration gradient with an increasing concentration of aluminum from a bottom surface of the metal oxide toward the top surface of the metal oxide.

In the above semiconductor device, the metal oxide preferably contains at least indium, aluminum, and zinc.

In the above semiconductor device, the metal element is preferably tantalum or titanium.

One embodiment of the present invention is a method for manufacturing a semiconductor device including a metal oxide, a first conductor to a third conductor, a first insulator to a fourth insulator, a fifth insulator positioned between the first conductor and the second insulator, and a sixth insulator positioned between the second conductor and the second insulator. The method for manufacturing a semiconductor device includes a first step of sequentially forming a metal oxide film and a conductive film, a second step of processing the metal oxide film and the conductive film into an island shape to form the metal oxide and a conductive layer, a third step of forming the first insulator, a fourth step of processing part of the first insulator and part of the conductive layer to form the first conductor, the second conductor, and an opening reaching the metal oxide, a fifth step of forming a first insulating film in the opening, a sixth step of forming a second insulating film over the first insulating film, a seventh step of performing microwave treatment in an atmosphere containing oxygen, an eighth step of sequentially forming a third insulating film and a second conductive film, and a ninth step of forming the second insulator, the third insulator, the fourth insulator, and the third conductor by CMP treatment. The fifth insulator and the sixth insulator are formed when any one of the fourth step, the fifth step, the sixth step, and the seventh step is performed.

### Effect of the Invention

According to one embodiment of the present invention, a semiconductor device that can be miniaturized or highly integrated can be provided. Alternatively, a semiconductor device with favorable reliability can be provided. Alternatively, a semiconductor device with a small variation in electrical characteristics of transistors can be provided. Alternatively, a semiconductor device having favorable electrical characteristics can be provided. Alternatively, a semiconductor device with a high on-state current can be provided. Alternatively, a semiconductor device with low power consumption can be provided.

Note that the description of these effects does not preclude the existence of other effects. Note that one embodiment of the present invention does not need to have all of these effects. Note that other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1A is a top view of a semiconductor device of one embodiment of the present invention.

FIG. 1B to FIG. 1D are cross-sectional views of the semiconductor device of one embodiment of the present invention.

FIG. 2 is a cross-sectional view of a semiconductor device of one embodiment of the present invention.

FIG. 3A to FIG. 3E are cross-sectional views of semiconductor devices of one embodiment of the present invention.

FIG. 4A to FIG. 4D are schematic diagrams of aluminum concentration profiles in a metal oxide.

FIG. 5A and FIG. 5B are cross-sectional views of semiconductor devices of one embodiment of the present invention.

FIG. 6A and FIG. 6B are cross-sectional views of semiconductor devices of one embodiment of the present invention.

FIG. 7A is a top view illustrating a method for manufacturing a semiconductor device of one embodiment of the present invention. FIG. 7B to FIG. 7D are cross-sectional views illustrating the method for manufacturing a semiconductor device of one embodiment of the present invention.

FIG. 8A is a top view illustrating the method for manufacturing a semiconductor device of one embodiment of the present invention. FIG. 8B to FIG. 8D are cross-sectional views illustrating the method for manufacturing a semiconductor device of one embodiment of the present invention.

FIG. 9A is a top view illustrating the method for manufacturing a semiconductor device of one embodiment of the present invention. FIG. 9B to FIG. 9D are cross-sectional views illustrating the method for manufacturing a semiconductor device of one embodiment of the present invention.

FIG. 10A is a top view illustrating the method for manufacturing a semiconductor device of one embodiment of the present invention. FIG. 10B to FIG. 10D are cross-sectional views illustrating the method for manufacturing a semiconductor device of one embodiment of the present invention.

FIG. 11A is a top view illustrating the method for manufacturing a semiconductor device of one embodiment of the present invention. FIG. 11B to FIG. 11D are cross-sectional views illustrating the method for manufacturing a semiconductor device of one embodiment of the present invention.

FIG. 12A is a top view illustrating the method for manufacturing a semiconductor device of one embodiment of the present invention. FIG. 12B to FIG. 12D are cross-sectional views illustrating the method for manufacturing a semiconductor device of one embodiment of the present invention.

FIG. 13A is a top view illustrating the method for manufacturing a semiconductor device of one embodiment of the present invention. FIG. 13B to FIG. 13D are cross-sectional views illustrating the method for manufacturing a semiconductor device of one embodiment of the present invention.

FIG. 14A is a top view illustrating the method for manufacturing a semiconductor device of one embodiment of the present invention. FIG. 14B to FIG. 14D are cross-sectional views illustrating the method for manufacturing a semiconductor device of one embodiment of the present invention.

FIG. 15A is a top view illustrating the method for manufacturing a semiconductor device of one embodiment of the present invention. FIG. 15B to FIG. 15D are cross-sectional views illustrating the method for manufacturing a semiconductor device of one embodiment of the present invention.

FIG. 16A is a top view illustrating the method for manufacturing a semiconductor device of one embodiment of the present invention. FIG. 16B to FIG. 16D are cross-sectional views illustrating the method for manufacturing a semiconductor device of one embodiment of the present invention.

FIG. 17A is a top view illustrating the method for manufacturing a semiconductor device of one embodiment of the present invention. FIG. 17B to FIG. 17D are cross-sectional views illustrating the method for manufacturing a semiconductor device of one embodiment of the present invention.

FIG. 18 is a top view illustrating a microwave treatment apparatus according to one embodiment of the present invention.

FIG. 19 is a cross-sectional schematic view illustrating a microwave treatment apparatus according to one embodiment of the present invention.

FIG. 20 is a schematic cross-sectional view illustrating a microwave treatment apparatus according to one embodiment of the present invention.

FIG. 21 is a schematic view illustrating a microwave treatment apparatus according to one embodiment of the present invention.

FIG. 22A is a top view of a semiconductor device of one embodiment of the present invention.

FIG. 22B to FIG. 22D are cross-sectional views of the semiconductor device of one embodiment of the present invention.

FIG. 23A is a top view of a semiconductor device of one embodiment of the present invention.

FIG. 23B to FIG. 23D are cross-sectional views of the semiconductor device of one embodiment of the present invention.

FIG. 24A is a top view of a semiconductor device of one embodiment of the present invention.

FIG. 24B to FIG. 24D are cross-sectional views of the semiconductor device of one embodiment of the present invention.

FIG. 25A is a top view of a semiconductor device of one embodiment of the present invention.

FIG. 25B to FIG. 25D are cross-sectional views of the semiconductor device of one embodiment of the present invention.

FIG. 26A is a plan view of a semiconductor device according to one embodiment of the present invention. FIG. 26B and FIG. 26C are cross-sectional views of the semiconductor device of one embodiment of the present invention.

FIG. 27A and FIG. 27B are diagrams illustrating a structure example of a display device.

FIG. 28A to FIG. 28D are circuit diagrams illustrating structure examples of a display device.

FIG. 29A to FIG. 29D are circuit diagrams illustrating structure examples of a display device.

FIG. 30 is a circuit diagram illustrating a structure example of a display device.

FIG. 31A to FIG. 31C are diagrams illustrating a structure example of a display device.

FIG. 32A to FIG. 32F are diagrams illustrating pixel structure examples.

FIG. 33 is a diagram illustrating a structure example of a display device.

FIG. 34 is a diagram illustrating a structure example of a display device.

FIG. 35 is a diagram illustrating a structure example of a display device.

FIG. 36 is a diagram illustrating a structure example of a display device.

FIG. 37A to FIG. 37F are diagrams illustrating structure examples of light-emitting elements.

FIG. 38A to FIG. 38C are diagrams illustrating structure examples of light-emitting elements.

FIG. 39A to FIG. 39D are diagrams illustrating examples of electronic devices.

FIG. 40A to FIG. 40F are diagrams illustrating examples of electronic devices.

FIG. 41A to FIG. 41G are diagrams illustrating examples of electronic devices.

FIG. 42A is a block diagram illustrating a structure example of a storage device according to one embodiment of the present invention. FIG. 42B is a perspective view illustrating a structure example of the storage device according to one embodiment of the present invention.

FIG. 43A to FIG. 43H are circuit diagrams illustrating structure examples of storage devices according to one embodiment of the present invention.

FIG. 44 is a diagram illustrating the etching rate of a metal oxide.

FIG. 45A to FIG. 45C are diagrams illustrating methods for fabricating samples.

FIG. 46 is a cross-sectional STEM image of a transistor included in a fabricated sample.

FIG. 47A and FIG. 47B are schematic cross-sectional views of a transistor used for device simulation.

FIG. 48A is a diagram showing Cg-Vg characteristics obtained by device simulation. FIG. 48B is a diagram showing Id-Vg characteristics obtained by device simulation.

FIG. 49A is a diagram showing Id-Vg characteristics obtained by device simulation. FIG. 49B shows the results of Vth estimated from Id-Vg characteristics. FIG. 49C shows the results of drain current estimated from Id-Vg characteristics.

FIG. 50A and FIG. 50B are cross-sectional STEM images of a fabricated sample.

FIG. 51 is the Id-Vg characteristics of transistors.

FIG. 52 is a diagram showing the normal probability plot of Vth.

FIG. 53 is a diagram showing the measurement result of cutoff frequency of a transistor.

FIG. 54A is a diagram illustrating the stacked-layer structure of a stacked-layer film. FIG. 54B and FIG. 54C are the results of SIMS analysis of fabricated samples.

FIG. 55 is a diagram showing the sheet resistances of fabricated samples.

FIG. 56A and FIG. 56B are the Id-Vg characteristics of transistors.

FIG. 57A to FIG. 57C are cross-sectional STEM images of a transistor included in a fabricated sample.

FIG. 58A is the Id-Vg characteristics of transistors. FIG. 58B is a diagram showing the normal probability plot of Vth.

FIG. 59 is a diagram showing the relationship between the Hall mobility and the carrier concentration of a metal oxide.

FIG. 60A to FIG. 60D are the Id-Vg characteristics of transistors.

FIG. 61 is a diagram showing the relationship between threshold voltage and field-effect mobility in a linear region.

FIG. 62A is a diagram showing the temperature dependence of the carrier concentration of a metal oxide. FIG. 62B is a diagram showing the temperature dependence of the Hall mobility of a metal oxide.

### MODE FOR CARRYING OUT THE INVENTION

Embodiments are described below with reference to the drawings. Note that the embodiments can be implemented with many different modes, and it is readily understood by those skilled in the art that modes and details thereof can be changed in various ways without departing from the spirit and scope thereof. Thus, the present invention should not be interpreted as being limited to the description of the embodiments below.

In the drawings, the size, the layer thickness, or the region is exaggerated for clarity in some cases. Therefore, the size, the layer thickness, or the region is not limited to the illustrated scale. Note that the drawings schematically show ideal examples, and embodiments of the present invention are not limited to shapes or values shown in the drawings. For example, in the actual manufacturing process, a layer, a resist mask, or the like might be unintentionally reduced in size by treatment such as etching, which might not be reflected in the drawings for easy understanding. Furthermore, in the drawings, the same reference numerals are used in common for the same portions or portions having similar functions in different drawings, and repeated description thereof is omitted in some cases. The same hatching pattern is applied to portions having similar functions, and the portions are not especially denoted by reference numerals in some cases.

Furthermore, especially in a top view (also referred to as a “plan view”), a perspective view, or the like, the description of some components might be omitted for easy understanding of the invention. The description of some hidden lines and the like might also be omitted.

The ordinal numbers such as “first” and “second” in this specification and the like are used for convenience and do not denote the order of steps or the stacking order of layers. Therefore, for example, the term “first” can be replaced with the term “second”, “third”, or the like as appropriate. In addition, the ordinal numbers in this specification and the like do not sometimes correspond to the ordinal numbers that are used to specify one embodiment of the present invention.

Moreover, in this specification and the like, terms for describing arrangement, such as “over” and “under”, are used for convenience for describing the positional relationship between components with reference to drawings. The positional relationship between components is changed as appropriate in accordance with the direction in which the components are described. Thus, without limitation to terms described in this specification, the description can be changed appropriately depending on the situation.

When this specification and the like explicitly state that X and Y are connected, for example, the case where X and Y are electrically connected, the case where X and Y are functionally connected, and the case where X and Y are directly connected are regarded as being disclosed in this specification and the like. Accordingly, without being limited to a predetermined connection relationship, e.g., a connection relationship shown in drawings or texts, a connection relationship other than one shown in drawings or texts is regarded as being disclosed in the drawings or the texts. Here, X and Y each denote an object (e.g., a device, an element, a circuit, a wiring, an electrode, a terminal, a conductive film, or a layer).

In this specification and the like, a transistor is an element having at least three terminals including a gate, a drain, and a source. In addition, the transistor includes a region where a channel is formed (hereinafter also referred to as a channel formation region) between the drain (a drain terminal, a drain region, or a drain electrode) and the source (a source terminal, a source region, or a source electrode), and current can flow between the source and the drain through the channel formation region. Note that in this specification and the like, a channel formation region refers to a region through which a current mainly flows.

Furthermore, functions of a source and a drain are sometimes interchanged with each other when transistors having different polarities are used or when the direction of a current is changed in a circuit operation, for example. Therefore, the terms “source” and “drain” can sometimes be interchanged with each other in this specification and the like.

Note that a channel length refers to, for example, a distance between a source (a source region or a source electrode) and a drain (a drain region or a drain electrode) in a region where a semiconductor (or a portion where a current flows in a semiconductor when a transistor is in an on state) and a gate electrode overlap with each other or a channel formation region in a top view of the transistor. Note that in one transistor, channel lengths in all regions do not necessarily have the same value. In other words, the channel length of one transistor is not fixed to one value in some cases. Thus, in this specification, the channel length is any one of the values, the maximum value, the minimum value, or the average value in a channel formation region.

A channel width refers to, for example, the length of a channel formation region in a direction perpendicular to a channel length direction in a region where a semiconductor (or a portion where a current flows in a semiconductor when a transistor is in an on state) and a gate electrode overlap with each other, or a channel formation region in a top view of the transistor. Note that in one transistor, channel widths in all regions do not necessarily have the same value. In other words, the channel width of one transistor is not fixed to one value in some cases. Thus, in this specification, the channel width is any one of the values, the maximum value, the minimum value, or the average value in a channel formation region.

Note that in this specification and the like, depending on the transistor structure, a channel width in a region where a channel is actually formed (hereinafter also referred to as an “effective channel width”) is different from a channel width shown in a top view of a transistor (hereinafter also referred to as an “apparent channel width”) in some cases. For example, when a gate electrode covers a side surface of a semiconductor, the effective channel width is larger than the apparent channel width, and its influence cannot be ignored in some cases. For example, in a miniaturized transistor whose gate electrode covers a side surface of a semiconductor, the proportion of a channel formation region formed in the side surface of the semiconductor is increased in some cases. In that case, the effective channel width is larger than the apparent channel width.

In such a case, the effective channel width is sometimes difficult to estimate by actual measurement. For example, estimation of an effective channel width from a design value requires assumption that the shape of a semiconductor is known. Accordingly, in the case where the shape of a semiconductor is not known accurately, it is difficult to measure the effective channel width accurately.

In this specification, the simple term “channel width” refers to an apparent channel width in some cases. Alternatively, in this specification, the simple term “channel width” refers to an effective channel width in some cases. Note that the value of a channel length, a channel width, an effective channel width, an apparent channel width, or the like can be determined, for example, by analyzing a cross-sectional TEM image.

Note that impurities in a semiconductor refer to, for example, elements other than the main components of a semiconductor. For example, an element with a concentration lower than 0.1 atomic % can be regarded as an impurity. When an impurity is contained, for example, the density of defect states in a semiconductor increases and the crystallinity decreases in some cases. In the case where the semiconductor is an oxide semiconductor, examples of an impurity which changes the characteristics of the semiconductor include Group 1 elements, Group 2 elements, Group 13 elements, Group 14 elements, Group 15 elements, and transition metals other than the main components of the oxide semiconductor; hydrogen, lithium, sodium, silicon, boron, phosphorus, carbon, and nitrogen are given as examples. Note that water also serves as an impurity in some cases. In addition, oxygen vacancies (also referred to as V_{O}) are formed in an oxide semiconductor in some cases by entry of impurities, for example.

Note that in this specification and the like, silicon oxynitride is a material that contains more oxygen than nitrogen in its composition. Moreover, silicon nitride oxide is a material that contains more nitrogen than oxygen in its composition.

In this specification and the like, the term “insulator” can be replaced with an insulating film or an insulating layer. Furthermore, the term “conductor” can be replaced with a conductive film or a conductive layer. Moreover, the term “semiconductor” can be replaced with a semiconductor film or a semiconductor layer.

In this specification and the like, “parallel” indicates a state where two straight lines are placed at an angle greater than or equal to −10° and less than or equal to 10°. Accordingly, the case where the angle is greater than or equal to −5° and less than or equal to 5° is also included. Furthermore, “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Accordingly, the case where the angle is greater than or equal to 85° and less than or equal to 95° is also included. Furthermore, “substantially perpendicular” indicates a state where two straight lines are placed at an angle greater than or equal to 60° and less than or equal to 120°.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is used in a semiconductor layer of a transistor, the metal oxide is referred to as an oxide semiconductor in some cases. That is, an OS transistor can also be referred to as a transistor including a metal oxide or an oxide semiconductor.

In this specification and the like, “normally off” means that a drain current per micrometer of channel width flowing through a transistor when no potential is applied to a gate or the gate is supplied with a ground potential is 1×10⁻²⁰ A or lower at room temperature, 1×10⁻¹⁸ A or lower at 85° C., or 1×10⁻¹⁶ A or lower at 125° C.

In this specification and the like, “voltage” and “potential” can be replaced with each other as appropriate. “VOltage” refers to a potential difference from a reference potential, and when the reference potential is a ground potential, for example, “voltage” can be replaced with “potential”. Note that the ground potential does not necessarily mean 0 V. Moreover, potentials are relative values, and a potential supplied to a wiring, a potential applied to a circuit or the like, and a potential output from a circuit or the like, for example, change with a change of the reference potential.

In this specification and the like, when a plurality of components are denoted with the same reference numerals, and in particular need to be distinguished from each other, an identification sign such as “_1”, “[n]”, or “[m,n]” is sometimes added to the reference numerals.

In this specification, in the case where the maximum value and the minimum value are specified, a structure in which the maximum value and the minimum value are freely combined is also disclosed.

Note that in this specification and the like, the expression “level or substantially level” indicates a structure having the same level from a reference surface (e.g., a flat surface such as a substrate surface) in a cross-sectional view. For example, in a manufacturing process of a semiconductor device, planarization treatment (typically, CMP treatment) is performed, whereby the surface(s) of a single layer or a plurality of layers are exposed in some cases. In this case, the surfaces on which the CMP treatment is performed are at the same level from a reference surface. Note that a plurality of layers are not level with each other in some cases, depending on a treatment apparatus, a treatment method, or a material of the treated surfaces on which the CMP treatment is performed. This case is also regarded as being “level or substantially level” in this specification and the like. For example, the expression “level or substantially level” also includes the case where layers having two levels with respect to the reference surface (here, given as a first layer and a second layer) are provided to have a difference of less than or equal to 20 nm between the top-surface level of the first layer and the top-surface level of the second layer.

Note that in this specification and the like, the expression “end portions are aligned or substantially aligned” means that at least outlines of stacked layers partly overlap with each other in a top view. For example, the case of processing an upper layer and a lower layer with the use of the same mask pattern or mask patterns that are partly the same is included. Note that, in some cases, the outlines do not exactly overlap with each other and the outline of the upper layer is positioned inward from the outline of the lower layer or the outline of the upper layer is positioned outward from the outline of the lower layer; such a case is also represented by the expression “end portions are aligned or substantially aligned”.

### Embodiment 1

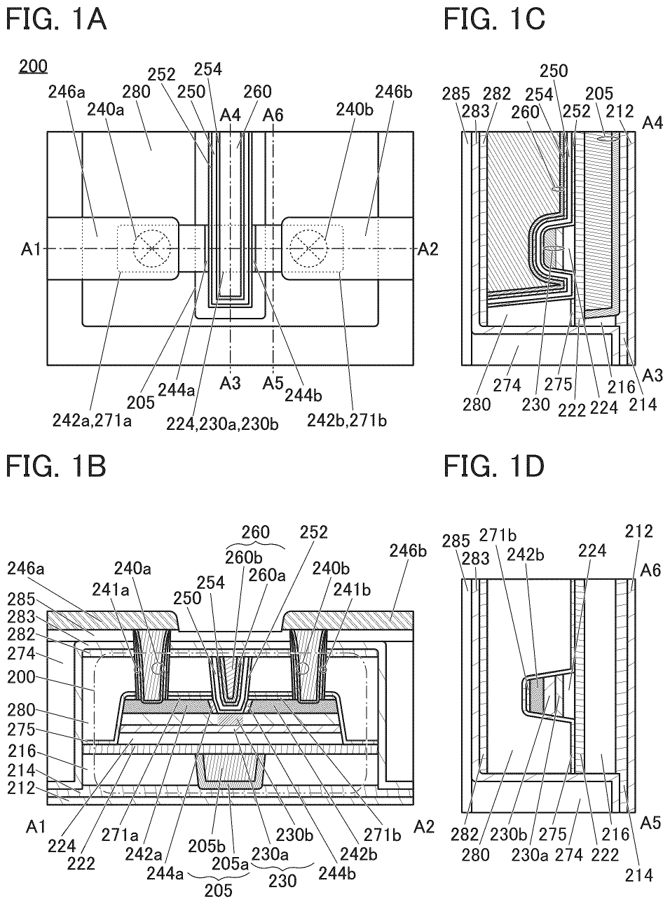

In this embodiment, an example of a semiconductor device of one embodiment of the present invention and a manufacturing method thereof are described with reference to FIG. 1A to FIG. 26C. The semiconductor device of one embodiment of the present invention includes a transistor.

### <Structure Example of Semiconductor Device>

A structure of a semiconductor device including a transistor 200 is described with reference to FIG. 1. FIG. 1A to FIG. 1D are a top view and cross-sectional views of the semiconductor device including the transistor 200. FIG. 1A is a top view of the semiconductor device. FIG. 1B to FIG. 1D are cross-sectional views of the semiconductor device. Here, FIG. 1B is a cross-sectional view of a portion indicated by dashed-dotted line A1-A2 in FIG. 1A, and is a cross-sectional view of the transistor 200 in the channel length direction. FIG. 1C is a cross-sectional view of a portion indicated by dashed-dotted line A3-A4 in FIG. 1A, and is a cross-sectional view of the transistor 200 in a channel width direction. FIG. 1D is a cross-sectional view of a portion indicated by dashed-dotted line A5-A6 in FIG. 1A. Note that for clarity of the drawing, some components are omitted in the top view of FIG. 1A.

The semiconductor device of one embodiment of the present invention includes an insulator 212 over a substrate (not illustrated), an insulator 214 over the insulator 212, the transistor 200 over the insulator 214, an insulator 280 over the transistor 200, an insulator 282 over the insulator 280, an insulator 283 over the insulator 282, an insulator 274 over the insulator 283, and an insulator 285 over the insulator 283 and the insulator 274. The insulator 212, the insulator 214, the insulator 280, the insulator 282, the insulator 283, the insulator 285, the insulator 274, and the insulator 285 each function as an interlayer film. In addition, the semiconductor device also includes a conductor 240a and a conductor 240b that are electrically connected to the transistor 200 and function as plugs. Note that an insulator 241a is provided in contact with the side surface of the conductor 240a, and an insulator 241b is provided in contact with the side surface of the insulator 240b. A conductor 246a that is electrically connected to the conductor 240a is provided over the insulator 285 and the conductor 240a, and a conductor 246b that is electrically connected to the conductor 240b is provided over the insulator 285 and the conductor 240b. The insulator 283 is in contact with part of the top surface of the insulator 214, the side surface of the insulator 280, and the side surface and the top surface of the insulator 282.

The insulator 241a is provided in contact with the inner wall of an opening formed in the insulator 280, the insulator 282, the insulator 283, and the insulator 285, and the conductor 240a is provided in contact with the side surface of the insulator 241a. The insulator 241b is provided in contact with the inner wall of an opening formed in the insulator 280, the insulator 282, the insulator 283, and the insulator 285, and the conductor 240b is provided in contact with the side surface of the insulator 241b. Note that the insulator 241a and the insulator 241b each have a structure in which a first insulator is provided in contact with the inner wall of the opening and a second insulator is provided inward from the first insulator. The conductor 240a has a structure in which a first conductor is provided in contact with the side surface of the insulator 241a and a second conductor is provided inward from the first conductor. The conductor 240b has a structure in which a first conductor is provided in contact with the side surface of the insulator 241b and a second conductor is provided inward from the first conductor. Here, the top surface of the conductor 240a can be substantially level with the top surface of the insulator 285 in a region overlapping with the conductor 246a. Moreover, the top surface of the conductor 240b can be substantially level with the top surface of the insulator 285 in a region overlapping with the conductor 246b.

Although the insulator 241a and the insulator 241b in the transistor 200 each have a structure in which the first insulator and the second insulator are stacked, the present invention is not limited thereto. For example, the insulator 241a and the insulator 241b may each have a single-layer structure or a stacked-layer structure of three or more layers. Although the conductor 240a and the conductor 240b in the transistor 200 each have a structure in which the first conductor and the second conductor are stacked, the present invention is not limited thereto. For example, the conductor 240a and the conductor 240b may each have a single-layer structure or a stacked-layer structure of three or more layers. In the case where a component has a stacked-layer structure, layers may be distinguished by ordinal numbers corresponding to the formation order.

### [Transistor 200]

As illustrated in FIG. 1A to FIG. 1D, the transistor 200 includes an insulator 216 over the insulator 214, a conductor 205 (a conductor 205a and a conductor 205b) placed to be embedded in the insulator 216, an insulator 222 over the insulator 216 and the conductor 205, an insulator 224 over the insulator 222, an oxide 230a over the insulator 224, an oxide 230b over the oxide 230a, a conductor 242a and a conductor 242b over the oxide 230b, an insulator 271a over the conductor 242a, an insulator 271b over the conductor 242b, an insulator 252 positioned over the oxide 230b and between the conductor 242a and the conductor 242b, an insulator 250 over the insulator 252, an insulator 254 over the insulator 250, a conductor 260 (a conductor 260a and a conductor 260b) positioned over the insulator 254 and overlapping with part of the oxide 230b, and an insulator 275 placed over the insulator 222, the insulator 224, the oxide 230a, the oxide 230b, the conductor 242a, the conductor 242b, the insulator 271a, and the insulator 271b. The transistor 200 also includes an insulator 244a positioned between the conductor 242a and the insulator 252 and an insulator 244b positioned between the conductor 242b and the insulator 252.

Hereinafter, the oxide 230a and the oxide 230b are collectively referred to as an oxide 230 in some cases. The conductor 242a and the conductor 242b are collectively referred to as a conductor 242 in some cases. The insulator 271a and the insulator 271b are collectively referred to as an insulator 271 in some cases.

The insulator 280 is positioned over the insulator 275. Thus, it can be said that the insulator 280 is positioned above the conductor 242a and the conductor 242b. An opening reaching the oxide 230b is provided in the insulator 280 and the insulator 275. That is, it can be said that the opening includes a region that is between the conductor 242a and the conductor 242b and overlaps with the oxide 230b. It can also be said that the insulator 275 includes an opening overlapping with the opening included in the insulator 280. The insulator 252, the insulator 250, the insulator 254, and the conductor 260 are placed in the opening. That is, the conductor 260 includes a region overlapping with the oxide 230b with the insulator 252, the insulator 250, and the insulator 254 therebetween. The conductor 260, the insulator 252, the insulator 250, and the insulator 254 are provided between the insulator 271a and the conductor 242a, and the insulator 271b and the conductor 242b in the channel length direction of the transistor 200. The insulator 254 includes a region in contact with the side surface of the conductor 260 and a region in contact with the bottom surface of the conductor 260.

The conductor 260 functions as a first gate (also referred to as a top gate) electrode, and the conductor 205 functions as a second gate (also referred to as a back gate) electrode. The insulator 252, the insulator 250, and the insulator 254 function as a first gate insulator, and the insulator 222 and the insulator 224 function as a second gate insulator. Note that the gate insulator is also referred to as a gate insulating layer or a gate insulating film in some cases. The conductor 242a functions as one of a source electrode and a drain electrode, and the conductor 242b functions as the other of the source electrode and the drain electrode. At least part of a region of the oxide 230 overlapping with the conductor 260 functions as a channel formation region.

To miniaturize or highly integrate transistors, a thinner gate insulator is needed. However, as the gate insulator becomes thinner, a problem such as increases in parasitic capacitance between the source electrode and the gate electrode and parasitic capacitance between the drain electrode and the gate electrode or increases in leakage current between the source electrode and the gate electrode and leakage current between the drain electrode and the gate electrode may arise.

Thus, in this embodiment, the insulator 244a is provided between the conductor 242a functioning as one of the source electrode and the drain electrode and the conductor 260 functioning as the top gate electrode, and the insulator 244b is provided between the conductor 242b functioning as the other of the source electrode and the drain electrode and the conductor 260. Since the insulator 244a and the insulator 244b are provided, a distance between the conductor 242a and the conductor 260 and a distance between the conductor 242b and the conductor 260 can be increased, so that parasitic capacitance between the conductor 242a and the conductor 260 and parasitic capacitance between the conductor 242b and the conductor 260 can be reduced. Thus, the switching speed of the transistor 200 can be improved, and the transistor can have high frequency characteristics.

In the transistor 200, a metal oxide functioning as a semiconductor (hereinafter also referred to as an oxide semiconductor) is preferably used for the oxide 230 including the channel formation region.

The metal oxide functioning as a semiconductor preferably has a band gap of 2 eV or higher, further preferably 2.5 eV or higher. With use of a metal oxide having a wide bandgap, the off-state current of the transistor can be reduced.

In the oxide 230, the channel formation region is preferably an i-type or substantially i-type region with a reduced carrier concentration, whereas the source region and the drain region are preferably n-type regions with high carrier concentrations. With such a structure, a semiconductor device having favorable electrical characteristics can be provided. Note that at least part of the channel formation region in the oxide 230 overlaps with the conductor 260. In other words, the channel formation region is provided in a region between the conductor 242a and the conductor 242b. One of the source region and the drain region is provided to overlap with the conductor 242a, and the other of the source region and the drain region is provided to overlap with the conductor 242b.

A transistor using an oxide semiconductor is likely to have its electrical characteristics changed by impurities and oxygen vacancies in a channel formation region in the oxide semiconductor, which might affect the reliability. In some cases, a defect that is an oxygen vacancy into which hydrogen enters (hereinafter sometimes referred to as V_{O}H) is formed, which generates an electron serving as a carrier. Therefore, when the channel formation region in the oxide semiconductor includes oxygen vacancies, the transistor is likely to have normally-on characteristics (characteristics with which, even when no voltage is applied to the gate electrode, the channel exists and current flows through the transistor). Therefore, impurities, oxygen vacancies, and V_{O}H are preferably reduced as much as possible in the channel formation region in the oxide semiconductor.

As a countermeasure against the above, an insulator containing oxygen that is released by heating (hereinafter sometimes referred to as excess oxygen) is provided in the vicinity of the oxide semiconductor and heat treatment is performed, so that oxygen can be supplied from the insulator to the oxide semiconductor to reduce oxygen vacancies and V_{O}H. However, supply of an excess amount of oxygen to the source region or the drain region might cause a decrease in the on-state current or field-effect mobility of the transistor. Furthermore, a variation of the amount of oxygen supplied to the source region or the drain region in the substrate plane leads to a variation in characteristics of the semiconductor device including the transistor. When oxygen supplied from the insulator to the oxide semiconductor diffuses into conductors such as the gate electrode, the source electrode, and the drain electrode, the conductors might be oxidized and the conductivity might be impaired, for example, so that the electrical characteristics and reliability of the transistor might be adversely affected.

Accordingly, oxygen vacancies and V_{O}H are preferably reduced in the channel formation region. Thus, it is preferable that oxygen be supplied to the channel formation region and an excess amount of oxygen not be supplied to the source region or the drain region. Furthermore, it is preferable to inhibit diffusion of hydrogen into the channel formation region.

An insulator through which oxygen is likely to pass is preferably used as the insulator 250 to supply oxygen to the channel formation region. An insulator containing excess oxygen is preferably used as the insulator 280. With such a structure, oxygen contained in the insulator 280 can be supplied to the channel formation region of the oxide 230 through the insulator 250. Thus, the channel formation region of the oxide 230 can be an i-type or substantially i-type region.

As the insulator 250, for example, silicon oxide, silicon oxynitride, silicon oxide to which fluorine is added, silicon oxide to which carbon is added, silicon oxide to which carbon and nitrogen are added, porous silicon oxide, or the like can be used. In particular, silicon oxide and silicon oxynitride, which are thermally stable, are preferable. In this case, the insulator 250 contains at least oxygen and silicon.

The concentration of impurities such as water and hydrogen in the insulator 250 is preferably reduced.

The thickness of the insulator 250 is preferably greater than or equal to 0.5 nm and less than or equal to 20 nm, further preferably greater than or equal to 1 nm and less than or equal to nm. In particular, in order to manufacture a minute transistor (e.g., a transistor with a gate length of less than or equal to 10 nm), the thickness of the insulator 250 is preferably greater than or equal to 0.5 nm and less than or equal to 10 nm, further preferably greater than or equal to 0.5 nm and less than or equal to 5 nm. In the above case, at least part of the insulator 250 includes a region having a thickness like the above-described thickness.

The insulator 250 is provided in contact with the top surface of the insulator 252.

An insulator containing excess oxygen is preferably used as the insulator 280. For the insulator 280, for example, an oxide containing silicon such as silicon oxide, silicon oxynitride, silicon oxide to which fluorine is added, silicon oxide to which carbon is added, silicon oxide to which carbon and nitrogen are added, or porous silicon oxide is preferably used. In particular, silicon oxide and silicon oxynitride, which are thermally stable, are preferable. A material such as silicon oxide, silicon oxynitride, or porous silicon oxide is preferably used, in which case a region including oxygen that is released by heating can be easily formed.

The insulator 280 functions as an interlayer film and preferably has a low permittivity. When a material with a low permittivity is used for an interlayer film, parasitic capacitance generated between wirings can be reduced. The above-described oxide containing silicon is preferable because it is a material with a low permittivity.

The concentration of impurities such as water and hydrogen in the insulator 280 is preferably reduced.

The insulator 280 is provided over the insulator 275 and has an opening in a region where the insulator 252, the insulator 250, the insulator 254, and the conductor 260 are provided. The top surface of the insulator 280 may be planarized.

Supply of an excess amount of oxygen to the channel formation region in the oxide 230 might cause excessive oxidation of the source region and the drain region through the channel formation region and cause a decrease in the on-state current or field-effect mobility of the transistor 200.

Thus, the insulator 252 having a barrier property against oxygen is preferably provided between the insulator 250 and the oxide 230b. The insulator 252 is provided in contact with the bottom surface of the insulator 250, the top surface of the oxide 230b, and the side surface of the oxide 230b. Since the insulator 252 has a barrier property against oxygen, oxygen contained in the insulator 250 can be supplied to the channel formation region, while oxygen contained in the insulator 250 can be inhibited from being excessively supplied to the channel formation region. Thus, it is possible to inhibit supply of excess oxygen to the source region and the drain region through the channel formation region and decrease in the on-state current or field-effect mobility of the transistor 200. In addition, it is possible to inhibit release of oxygen from the oxide 230 when heat treatment or the like is performed and inhibit formation of oxygen vacancies in the oxide 230. Accordingly, the transistor 200 can have favorable electrical characteristics and higher reliability.

The insulator 252 is provided between the insulator 280 and the insulator 250 and includes a region in contact with the sidewall of the opening included in the insulator 280. With such a structure, oxygen contained in the insulator 280 can be supplied to the insulator 250, while oxygen contained in the insulator 280 can be inhibited from being excessively supplied to the insulator 250.

An insulator containing an oxide of one or both of aluminum and hafnium is preferably used as the insulator 252. As the insulator, aluminum oxide, hafnium oxide, an oxide containing aluminum and hafnium (hafnium aluminate), an oxide containing hafnium and silicon (hafnium silicate), or the like can be used. In this embodiment, aluminum oxide is used as the insulator 252. In this case, the insulator 252 contains at least oxygen and aluminum. Note that oxygen is less likely to pass through the insulator 252 than the insulator 250, for example. For the insulator 252, a material through which oxygen is less likely to pass than the insulator 250 is used, for example. As the insulator 252, magnesium oxide, gallium oxide, gallium zinc oxide, indium gallium zinc oxide, or the like may be used, for example.

Note that the thickness of the insulator 252 is preferably small. This is because the amount of oxygen supplied to the oxide 230 through the insulator 250 is reduced when the thickness of the insulator 252 is too large. The thickness of the insulator 252 is specifically greater than or equal to 0.1 nm and less than or equal to 5.0 nm, preferably greater than or equal to 0.5 nm and less than or equal to 3.0 nm, further preferably greater than or equal to 1.0 nm and less than 3.0 nm. In this case, at least part of the insulator 252 includes a region having a thickness like the above-described thickness. For example, the insulator 252 preferably includes a region having a thickness smaller than the thickness of the insulator 250. In this case, at least part of the insulator 252 includes a region having a thickness smaller than that of the insulator 250.

To form the insulator 252 having a small thickness as described above, an atomic layer deposition (ALD) method is preferably used for deposition. Examples of an ALD method include a thermal ALD method, in which a precursor and a reactant react with each other only by a thermal energy, and a PEALD (Plasma Enhanced ALD) method, in which a reactant excited by plasma is used. The use of plasma in a PEALD method is sometimes preferable because deposition at a lower temperature is possible.

An ALD method, which enables an atomic layer to be deposited one by one, has advantages such as deposition of an extremely thin film, deposition on a component with a high aspect ratio, deposition of a film with a small number of defects such as pinholes, deposition with excellent coverage, and low-temperature deposition. Therefore, the insulator 252 can be deposited on the side surface of the opening formed in the insulator 280 and the like, with a small thickness like the above-described thickness and favorable coverage.

Note that some of precursors usable in an ALD method contain carbon or the like. Thus, in some cases, a film provided by an ALD method contains impurities such as carbon in a larger amount than a film provided by another deposition method. Note that impurities can be quantified by secondary ion mass spectrometry (SIMS), X-ray photoelectron spectroscopy (XPS), or auger electron spectroscopy (AES).

When the thickness of the insulator 252 is reduced, the transistor 200 can be miniaturized. This is because the insulator 252 is provided in the opening formed in the insulator 280 and the like, together with the insulator 254, the insulator 250, and the conductor 260. With such a structure, a semiconductor device that can be miniaturized or highly integrated can be provided.

The insulator 252 is provided between the insulator 250 and the conductor 242a and between the insulator 250 and the conductor 242b. When the thickness of the insulator 252 is reduced, the side surface of the conductor 242a is oxidized to form the insulator 244a. Similarly, the side surface of the conductor 242b is oxidized to form the insulator 244b. In other words, the transistor 200 includes the insulator 244a positioned between the conductor 242a and the insulator 252 and the insulator 244b positioned between the conductor 242b and the insulator 252.

Note that the lengths of the insulator 244a and the insulator 244b in the channel length direction can be controlled by adjusting the thickness of the insulator 252. For example, when the thickness of the insulator 252 is increased, the amount of oxygen contained in the insulator 250 and diffused into the conductor 242a and the conductor 242b is reduced, so that the side surfaces of the conductor 242a and the conductor 242b can be inhibited from being oxidized and the lengths of the insulator 244a and the insulator 244b in the channel length direction can be reduced. Accordingly, a decrease in the on-state current or field-effect mobility of the transistor 200 can be inhibited.

As will be described in detail later, the insulator 244a and the insulator 244b are formed in a self-aligned manner in a step of forming the conductor 242a and the conductor 242b or after forming the conductor 242a and the conductor 242b. Thus, parasitic capacitance between the conductor 242a and the conductor 260 and parasitic capacitance between the conductor 242b and the conductor 260 can be reduced in a self-aligned manner.

The insulator 244a contains an element contained in the conductor 242a and oxygen. Similarly, the insulator 244b contains an element contained in the conductor 242b and oxygen. For example, in the case where a material containing a metal element is used for the conductor 242a and the conductor 242b, the insulator 244a and the insulator 244b each contain the metal element and oxygen. As another example, in the case where a conductive material containing a metal element and nitrogen is used for the conductor 242a and the conductor 242b, the insulator 244a and the insulator 244b each contain the metal element, oxygen, and nitrogen.

In order to inhibit diffusion of hydrogen into the channel formation region, an insulator having a function of inhibiting hydrogen diffusion is preferably provided in the vicinity of the oxide 230. In the semiconductor device described in this embodiment, the insulator corresponds to the insulator 252 and the insulator 254, for example.

Aluminum oxide, which can be suitably used for the insulator 252, has a function of inhibiting diffusion of hydrogen (e.g., at least one of a hydrogen atom, a hydrogen molecule, and the like). Thus, diffusion of impurities contained in the insulator 250, such as hydrogen, into the oxide 230 can be prevented. Note that hydrogen is less likely to pass through the insulator 252 than the insulator 250, for example. The insulator 252 is a material through which hydrogen is less likely to pass than the insulator 250, for example.

The insulator 254 preferably has a barrier property against hydrogen. Accordingly, diffusion of impurities contained in the conductor 260, such as hydrogen, into the insulator 250 and the oxide 230 can be prevented. As the insulator 254, silicon nitride deposited by a PEALD method is used, for example. In this case, the insulator 254 contains at least nitrogen and silicon. As the insulator 254, aluminum oxide, magnesium oxide, hafnium oxide, gallium oxide, indium gallium zinc oxide, silicon nitride oxide, or the like may be used, for example. Note that hydrogen is less likely to pass through the insulator 254 than the insulator 250, for example. For the insulator 254, a material through which hydrogen is less likely to pass than the insulator 250 is used, for example.

The insulator 254 may further have a barrier property against oxygen. The insulator 254 is provided between the insulator 250 and the conductor 260. Thus, diffusion of oxygen contained in the insulator 250 into the conductor 260 can be prevented, so that oxidation of the conductor 260 can be inhibited. A reduction in the amount of oxygen supplied to the oxide 230 can be inhibited. Note that oxygen is less likely to pass through the insulator 254 than the insulator 250, for example. For the insulator 254, a material through which oxygen is less likely to pass than the insulator 250 is used, for example.

The insulator 254 needs to be provided in the opening formed in the insulator 280 and the like, together with the insulator 252, the insulator 250, and the conductor 260. The thickness of the insulator 254 is preferably small for miniaturization of the transistor 200. The thickness of the insulator 254 is greater than or equal to 0.1 nm and less than or equal to 5.0 nm, preferably greater than or equal to 0.5 nm and less than or equal to 3.0 nm, further preferably greater than or equal to 1.0 nm and less than or equal to 3.0 nm. In this case, at least part of the insulator 254 includes a region having a thickness like the above-described thickness. The thickness of the insulator 254 is preferably smaller than the thickness of the insulator 250. In this case, at least part of the insulator 254 includes a region having a thickness smaller than that of the insulator 250.

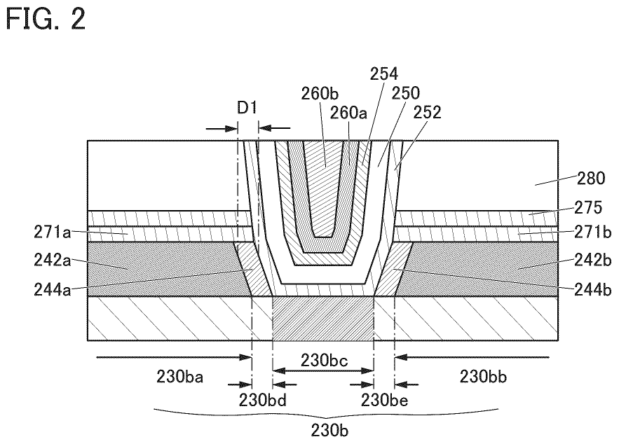

Here, FIG. 2 illustrates an enlarged view of the vicinity of the channel formation region in FIG. 1B. As illustrated in FIG. 2, the length of the insulator 244a in the channel length direction is referred to as a length D1. Note that the length D1 is also a distance from the conductor 242a to the insulator 252 in a cross-sectional view in the channel length direction. The length D1 is also a distance from the side surface of the conductor 242a to a surface of the insulator 252 in contact with the insulator 244a. For example, the length D1 refers to a difference of the position of the interface between the insulator 244a and the insulator 252 from the position of the interface between the conductor 242a and the insulator 244a. The length of the insulator 244b in the channel length direction is equal to or substantially equal to the length D1.

The length D1 is preferably greater than or equal to 1 nm, greater than or equal to 3 nm, or greater than or equal to 5 nm and less than or equal to 20 nm, less than or equal to 15 nm, or less than or equal to 10 nm. Alternatively, the length D1 is preferably greater than or equal to the thickness of the insulator 252 and less than or equal to a distance from the conductor 260 to the oxide 230. Here, the distance from the conductor 260 to the oxide 230b refers to, for example, a distance from the bottom surface of the conductor 260a to the top surface of the oxide 230b in the cross-sectional view in the channel length direction. Note that the distance from the conductor 260 to the oxide 230b is also the sum of the thickness of the insulator 252, the thickness of the insulator 250, and the thickness of the insulator 254. That is, it can also be said that the distance from the conductor 260 to the oxide 230b is the physical thickness of the first gate insulator. With such a structure, the transistor 200 can have favorable electrical characteristics.

Note that the length D1 can be measured by observing a cross-sectional shape of the insulator 244a and its vicinity with a transmission electron microscope (TEM) or the like in some cases.

Furthermore, the length D1 can sometimes be calculated by composition line analysis of the insulator 244a and its vicinity with energy dispersive X-ray spectroscopy (EDX). For example, as a method for calculating the length D1, first, EDX line analysis is performed with the channel length direction regarded as a depth direction. Next, in the profile of quantitative values of elements in the depth direction, which is obtained from the analysis, the depth (position) of the interface between the insulator 244a and the insulator 252 is regarded as a depth at which the quantitative value of an element that is the main component of the insulator 252 but is not the main component of the conductor 242a becomes half. Moreover, the depth (position) of the interface between the conductor 242a and the insulator 244a is regarded as a depth at which the quantitative value of oxygen becomes half. In this manner, the length D1 can be calculated.

As illustrated in FIG. 2, the oxide 230b includes a region 230bc functioning as the channel formation region of the transistor 200 and a region 230ba and a region 230bb that are provided to sandwich the region 230bc and function as a source region and a drain region. At least part of the region 230bc overlaps with the conductor 260. In other words, the region 230bc is provided in a region between the conductor 242a and the conductor 242b. The region 230ba is provided to overlap with the conductor 242a, and the region 230bb is provided to overlap with the conductor 242b.

The region 230bc has a smaller amount of oxygen vacancies or a lower impurity concentration than those of the region 230ba and the region 230bb, and thus is a high-resistance region with a low carrier concentration. Thus, the region 230bc can be regarded as being i-type (intrinsic) or substantially i-type.

The region 230ba and the region 230bb have a large amount of oxygen vacancies or a high concentration of an impurity such as hydrogen, nitrogen, or a metal element, and thus are each a low-resistance region with an increased carrier concentration. In other words, the region 230ba and the region 230bb are each an n-type region having a higher carrier concentration and a lower resistance than those of the region 230bc.

Here, the carrier concentration of the region 230bc is preferably lower than or equal to 1×10¹⁸ cm³, further preferably lower than 1×10¹⁷ cm³, still further preferably lower than 1×10¹⁶ cm³, yet further preferably lower than 1×10¹³ cm³, and yet still further preferably lower than 1×10¹² cm³. Note that the lower limit of the carrier concentration of the region 230bc functioning as the channel formation region is not particularly limited and can be, for example, 1×10⁹ cm³.

Since the transistor 200 includes the insulator 244a, a region 230bd is formed in the oxide 230b below the insulator 244a. The region 230bd is a region having a carrier concentration lower than or substantially equal to the carrier concentration of the region 230ba and higher than or substantially equal to the carrier concentration of the region 230bc. The region 230bd is positioned between the region 230bc and the region 230ba and thus functions as a junction region or an offset region between the region 230bc and the region 230ba. The region 230bd has a hydrogen concentration lower than or substantially equal to the hydrogen concentrations of the region 230ba and higher than or substantially equal to the hydrogen concentration of the region 230bc in some cases. Similarly, since the transistor 200 includes the insulator 244b, a region 230be is formed in the oxide 230b below the insulator 244b. Like the region 230bd, the region 230be functions as a junction region or an offset region between the region 230bc and the region 230bb.

Since the region 230bd is positioned below the insulator 244a, oxygen contained in the insulator 250 or the like is sometimes supplied to the region 230bd through the insulator 244a. Thus, the amount of oxygen vacancies in the region 230bd is smaller than or substantially equal to the amount of oxygen vacancies in the region 230ba and larger than or substantially equal to the amount of oxygen vacancies in the region 230bc in some cases. Similarly, the amount of oxygen vacancies in the region 230be is smaller than or substantially equal to the amount of oxygen vacancies in the region 230bb and larger than or substantially equal to the amount of oxygen vacancies in the region 230bc in some cases.

Although FIG. 2 illustrates an example where the region 230ba, the region 230bb, the region 230bc, the region 230bd, and the region 230be are formed in the oxide 230b, the present invention is not limited thereto. For example, the above regions may be formed not only in the oxide 230b but also in the oxide 230a.

In the oxide 230, the range of each region is difficult to detect clearly in some cases. The concentrations of a metal element and impurity elements such as hydrogen and nitrogen, which are detected in each region, may be not only gradually changed between the regions but also continuously changed in each region. That is, the region closer to the channel formation region has lower concentrations of impurity elements such as hydrogen and nitrogen.

As illustrated in FIG. 1C, the insulator 252 is provided in contact with the top surface and the side surface of the oxide 230b, the side surface of the oxide 230a, the side surface of the insulator 224, and the top surface of the insulator 222. That is, the regions of the oxide 230a, the oxide 230b, and the insulator 224 that overlap with the conductor 260 are covered with the insulator 252 in the cross section in the channel width direction. The insulator 252 includes a region in contact with the side surface of the insulator 271a, a region in contact with the side surface of the insulator 271b, and a region in contact with the sidewall of the opening included in the insulator 275.

With the above structure, the region 230bc functioning as the channel formation region can be an i-type or substantially i-type region, and the region 230ba and the region 230bb functioning as the source region and the drain region can be n-type regions. Parasitic capacitance between the conductor 260 and the conductor 242a and parasitic capacitance between the conductor 260 and the conductor 242b can be reduced in a self-aligned manner. Thus, a semiconductor device with favorable electrical characteristics can be provided. The semiconductor device with the above structure can have favorable electrical characteristics even when miniaturized or highly integrated. For example, the semiconductor device can have favorable electrical characteristics even when a gate length is less than or equal to 20 nm, less than or equal to 15 nm, less than or equal to 10 nm, or less than or equal to 7 nm and greater than or equal to 1 nm, greater than or equal to 3 nm, or greater than or equal to 5 nm. Note that the gate length will be described later.

Miniaturization of the transistor 200 can improve the high frequency characteristics. Specifically, the cutoff frequency can be improved. When the gate length is within any of the above ranges, the cutoff frequency of the transistor can be greater than or equal to 50 GHz or greater than or equal to 100 GHz at room temperature, for example.

In the case where aluminum oxide is used for the insulator 252, silicon oxide or silicon oxynitride is used for the insulator 250, and silicon nitride is used for the insulator 254, the insulator 252 and the insulator 250 each contain oxygen, and the insulator 250 and the insulator 254 each contain silicon. When layers in contact with each other contain a common element as a main component, the density of defect states at the interface between the layers can be decreased. Thus, carrier traps or the like due to the defect states are reduced, so that the transistor 200 and the semiconductor device which have favorable characteristics and high reliability can be manufactured.

Furthermore, in the case where titanium nitride or tantalum nitride is used for the conductor 260a, the insulator 254 and the conductor 260a each contain nitrogen. With such a structure, the transistor 200 and the semiconductor device which have favorable characteristics and high reliability can be manufactured as described above.

Note that since the oxide 230b contains oxygen as a main component, the density of defect states at the interface between the oxide 230b and the insulator 252 can be decreased. Thus, carrier traps or the like due to the defect states are reduced, so that the transistor 200 and the semiconductor device which have favorable characteristics and high reliability can be manufactured.

In the cross-sectional view in the channel length direction, the bottom surface of the conductor 260a is preferably positioned between the bottom surface and the top surface of the conductor 242a. With such a structure, the electric field of the conductor 260 is likely to act on the channel formation region of the oxide 230b. Thus, the on-state current of the transistor 200 can be increased, and the frequency characteristics of the transistor 200 can be improved. Note that the bottom surface of the conductor 260a is sometimes positioned below the bottom surface of the conductor 242a or positioned above the top surface of the conductor 242a in the cross-sectional view in the channel length direction, depending on the thickness of the gate insulator, the amount of removal of the upper portion of the oxide 230b, or the like.

Here, the above-described gate length is described.

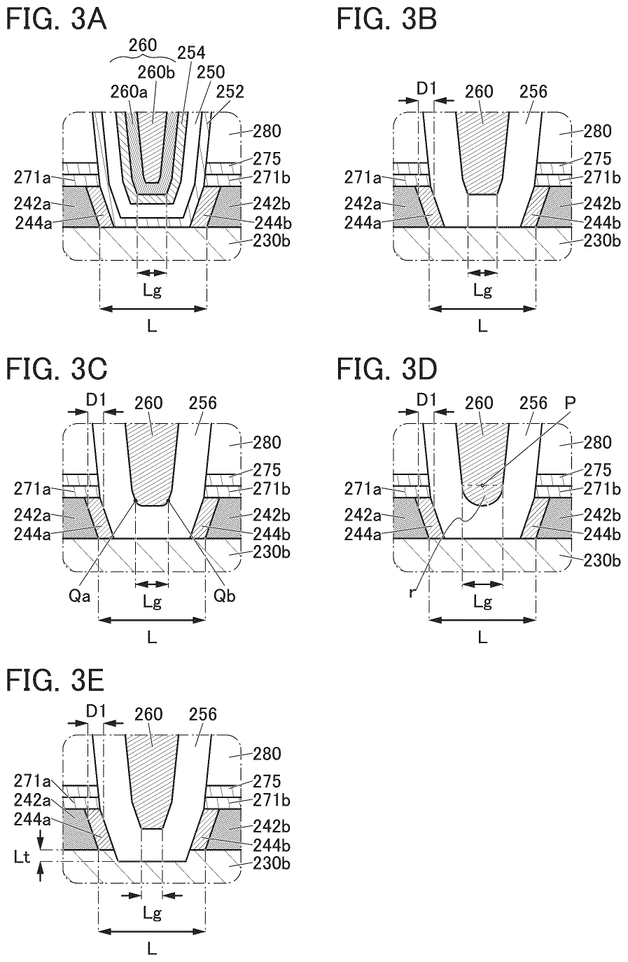

FIG. 3A illustrates an enlarged view of the vicinity of the channel formation region in FIG. 1B. FIG. 3A is a cross-sectional view of the transistor 200 in the channel length direction. As described above, the insulator 252, the insulator 250, and the insulator 254 function as the first gate insulator.

Hereinafter, the insulator 252, the insulator 250, and the insulator 254 are collectively referred to as an insulator 256 in some cases. In this case, the insulator 256 includes the insulator 252, the insulator 250 over the insulator 252, and the insulator 254 over the insulator 250. In addition, the insulator 256 functions as the first gate insulator.

FIG. 3B illustrates a cross-sectional view in which the insulator 252, the insulator 250, and the insulator 254 included in FIG. 3A are replaced with the insulator 256. In FIG. 3B, the conductor 260 is illustrated as a single layer for simplification of the drawing. Note that the conductor 260 may have a stacked-layer structure of the conductor 260a and the conductor 260b as described above or a stacked-layer structure of three or more layers.

A width Lg illustrated in FIG. 3A and FIG. 3B is the width of the bottom surface of the conductor 260 in a region overlapping with the oxide 230b in a cross-sectional view in the channel length direction. Hereinafter, the bottom surface of the conductor 260 in the region overlapping with the oxide 230b in a cross-sectional view in the channel length direction is simply referred to as the bottom surface of the conductor 260 in the region overlapping with the oxide 230b in some cases. That is, the bottom surface of the conductor 260 in the region overlapping with the oxide 230b in the following description can be rephrased as the bottom surface of the conductor 260 in the region overlapping with the oxide 230b in a cross-sectional view in the channel length direction in some cases.

The gate length refers to the length of a gate electrode in a direction in which carriers move inside a channel formation region during operation of the transistor and to the width of the bottom surface of the gate electrode in a top view of the transistor. In this specification and the like, the gate length is the width of the bottom surface of the conductor 260 in the region overlapping with the oxide 230b in a cross-sectional view in the channel length direction. That is, the gate length is the width Lg illustrated in FIG. 3A and FIG. 3B. Note that the conductor 260 is provided in the opening included in the insulator 275 and the insulator 280. The sidewall of the opening is perpendicular to a substrate surface or inclined to the substrate surface. In particular, in the case where the angle formed between the sidewall of the opening and the substrate surface is less than or equal to 90°, the minimum width of the conductor 260 in the region overlapping with the oxide 230b is the width Lg. Thus, the conductor 260 can be regarded as having a region with the width Lg in a cross-sectional view in the channel length direction.

The bottom surface of the conductor 260 in the region overlapping with the oxide 230b preferably includes a flat region. As illustrated in FIG. 3A and FIG. 3B, in the case where the bottom surface of the conductor 260 in the region overlapping with the oxide 230b includes a flat region, the width Lg is the width of the flat region. When the bottom surface of the conductor 260 in the region overlapping with the oxide 230b includes the flat region, an electric field can be uniformly generated in the channel formation region of the oxide 230.

Although FIG. 3A and FIG. 3B each illustrate a structure in which the bottom surface of the conductor 260 in the region overlapping with the oxide 230b includes the flat region, the present invention is not limited thereto. In a cross-sectional view in the channel length direction, the bottom surface of the conductor 260 in the region overlapping with the oxide 230b may have a curve.

FIG. 3C illustrates a modification example of the transistor 200 in FIG. 3B. FIG. 3C is a cross-sectional view of the transistor 200 in the channel length direction. For example, as illustrated in FIG. 3C, the bottom surface of the conductor 260 in the region overlapping with the oxide 230b may include a flat region and a region having a curve. Note that the region having a curve is positioned at an end portion on each side of the bottom surface. Here, a point where the curve of the bottom surface on the conductor 242a side is in contact with the side surface of the conductor 260 on the conductor 242a side is referred to as a point Qa. A point where the curve of the bottom surface on the conductor 242b side is in contact with the side surface of the conductor 260 on the conductor 242b side is referred to as a point Qb. In this structure, the width Lg is the length of a line segment connecting the point Qa and the point Qb.

FIG. 3D illustrates a modification example of the transistor 200 in FIG. 3B. FIG. 3D is a cross-sectional view of the transistor 200 in the channel length direction. For example, as illustrated in FIG. 3D, the bottom surface of the conductor 260 may have an arc shape. Note that the arc has a radius r and a curvature center P positioned in the conductor 260. In such a structure, the width Lg is the width of a region where a straight line that includes the curvature center P and is parallel to the bottom surface of the oxide 230b overlaps with the conductor 260 in a cross-sectional view in the channel length direction. In other words, the width Lg is twice as long as the radius r. Note that the straight line indicated by a dashed line in FIG. 3D is the straight line that includes the curvature center P and is parallel to the bottom surface of the oxide 230b.

Note that in the case where the radius r is large (e.g., the case where the radius r is larger than the channel length) in the shape of the bottom surface of the conductor 260 illustrated in FIG. 3D, the distance is large from the curvature center P to the channel formation region of the oxide 230b. At this time, the width Lg illustrated in FIG. 3C may be used as the gate length of the shape. That is, the width Lg may be calculated by determining the point Qa and the point Qb in the shape of the bottom surface of the conductor 260 illustrated in FIG. 3D.

It is sometimes difficult to determine the point Qa and the point Qb in the shape of the bottom surface of the conductor 260 illustrated in FIG. 3C. At this time, the width Lg illustrated in FIG. 3D may be used as the gate length of the shape. That is, the width Lg may be calculated by determining the curvature center P in the shape of the bottom surface of the conductor 260 illustrated in FIG. 3C.

The above is the description of the gate length. Next, the channel length is described.

The insulator 244a has a lower conductivity than the conductor 242a, and the insulator 244b has a lower conductivity than the conductor 242b. Accordingly, in the case where the transistor 200 includes the insulator 244a and the insulator 244b, the distance between the lower end portion of the conductor 242a and the lower end portion of the conductor 242b can be regarded as the channel length as illustrated in FIG. 3A to FIG. 3D. That is, when the insulator 244a and the insulator 244b are formed, the channel length can be increased. Thus, the source-drain withstand voltage of the transistor 200 can be improved, so that the transistor can be highly reliable. Therefore, the transistor can have favorable electrical characteristics even when miniaturized. Note that the distance between the lower end portion of the conductor 242a and the lower end portion of the conductor 242b is a distance L.

The channel length is set in accordance with a material used for the conductor 260, the gate length, a material used for the first gate insulator, the thickness thereof, and the like. In the case where the gate length is within any of the above ranges, the channel length is less than or equal to 60 nm, less than or equal to 50 nm, less than or equal to 40 nm, or less than or equal to 30 nm and greater than or equal to 5 nm, greater than or equal to 10 nm, greater than or equal to 15 nm, or greater than or equal to 20 nm, for example.

The length D1 of the insulator 244a in the channel length direction is preferably smaller than the width Lg and is preferably within any of the above ranges. With such a structure, even when the gate length is within any of the above ranges, the transistor 200 can have favorable electrical characteristics. Note that in the case where the width Lg is significantly small (e.g., the case where the width Lg is less than 5 nm), the length D1 is larger than the width Lg in some cases.

When the opening is formed in the insulator 280 and the insulator 275, an upper portion of the oxide 230b in a region overlapping with the opening is removed in some cases. At this time, as illustrated in FIG. 3E, the thickness of the oxide 230b in a region overlapping with the conductor 260 is smaller than the thickness of the oxide 230b in a region overlapping with the conductor 242a. Note that the transistor 200 illustrated in FIG. 3E is a modification example of the transistor 200 illustrated in FIG. 3B. FIG. 3E is a cross-sectional view of the transistor 200 in the channel length direction.

As illustrated in FIG. 3E, a difference between the thickness of the oxide 230b in the region overlapping with the conductor 260 and the thickness of the oxide 230b in the region overlapping with the conductor 242a is referred to as difference Lt. When the difference Lt is small, the distance L may be regarded as the channel length.

Accordingly, a semiconductor device having favorable reliability can be provided. A semiconductor device having favorable electrical characteristics can be provided. A semiconductor device that can be miniaturized or highly integrated can be provided. A semiconductor device that has favorable electrical characteristics and can be miniaturized or highly integrated can be provided.

In this embodiment, microwave treatment is performed in an atmosphere containing oxygen in a state where the conductor 242a and the conductor 242b are provided over the oxide 230b so that oxygen vacancies and V_{O}H in the region 230bc can be reduced. Note that the microwave treatment will be described in detail later in <Method for manufacturing semiconductor device>.

At least one of the insulator 212, the insulator 214, the insulator 271, the insulator 275, the insulator 282, the insulator 283, and the insulator 285 preferably functions as a barrier insulating film, which inhibits diffusion of impurities such as water and hydrogen into the transistor 200 from the substrate side or from above the transistor 200. Thus, for at least one of the insulator 212, the insulator 214, the insulator 271, the insulator 275, the insulator 282, the insulator 283, and the insulator 285, it is preferable to use an insulating material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), or a copper atom (an insulating material through which the impurities are less likely to pass). Alternatively, it is preferable to use an insulating material having a function of inhibiting diffusion of oxygen (e.g., at least one of an oxygen atom, an oxygen molecule, and the like) (an insulating material through which the oxygen is less likely to pass).

Note that in this specification, a barrier insulating film refers to an insulating film having a barrier property. A barrier property in this specification means a function of inhibiting diffusion of a targeted substance (also referred to as having low permeability). Alternatively, the barrier property means a function of capturing and fixing (also referred to as gettering) a targeted substance.

An insulator having a function of inhibiting diffusion of oxygen and impurities such as water and hydrogen is preferably used for the insulator 212, the insulator 214, the insulator 271, the insulator 275, the insulator 282, the insulator 283, and the insulator 285; for example, aluminum oxide, magnesium oxide, hafnium oxide, gallium oxide, indium gallium zinc oxide, silicon nitride, silicon nitride oxide, or the like can be used. For example, silicon nitride or the like, which has a higher hydrogen barrier property, is preferably used for the insulator 212, the insulator 275, and the insulator 283. For example, aluminum oxide, magnesium oxide, or the like, which has a function of capturing and fixing hydrogen well, is preferably used for the insulator 214, the insulator 271, the insulator 282, and the insulator 285. In this case, impurities such as water and hydrogen can be inhibited from diffusing to the transistor 200 side from the substrate side through the insulator 212 and the insulator 214. Alternatively, impurities such as water and hydrogen can be inhibited from diffusing to the transistor 200 side from an interlayer insulating film and the like which are placed outside the insulator 285 through the insulator 283 and the insulator 282. Alternatively, oxygen contained in the insulator 224 and the like can be inhibited from diffusing to the substrate side through the insulator 212 and the insulator 214. Alternatively, oxygen contained in the insulator 280 and the like can be inhibited from diffusing to above the transistor 200 through the insulator 282 and the like. In this manner, it is preferable that the transistor 200 be surrounded by the insulator 212, the insulator 214, the insulator 271, the insulator 275, the insulator 282, the insulator 283, and the insulator 285, which have a function of inhibiting diffusion of oxygen and impurities such as water and hydrogen.

Here, an oxide having an amorphous structure is preferably used for the insulator 212, the insulator 214, the insulator 271, the insulator 275, the insulator 282, the insulator 283, and the insulator 285. For example, a metal oxide such as AlOₓ (x is a given number greater than 0) or MgO_{y} (y is a given number greater than 0) is preferably used. In such a metal oxide having an amorphous structure, an oxygen atom has a dangling bond and sometimes has a property of capturing or fixing hydrogen with the dangling bond. When such a metal oxide having an amorphous structure is used as the component of the transistor 200 or provided around the transistor 200, hydrogen contained in the transistor 200 or hydrogen around the transistor 200 can be captured or fixed. In particular, hydrogen contained in the channel formation region of the transistor 200 is preferably captured or fixed. The metal oxide having an amorphous structure is used as the component of the transistor 200 or provided around the transistor 200, whereby the transistor 200 and the semiconductor device which have favorable characteristics and high reliability can be manufactured.

Although the insulator 212, the insulator 214, the insulator 271, the insulator 275, the insulator 282, the insulator 283, and the insulator 285 preferably have an amorphous structure, a region having a polycrystalline structure may be partly formed. The insulator 212, the insulator 214, the insulator 271, the insulator 275, the insulator 282, the insulator 283, and the insulator 285 may have a multilayer structure in which a layer having an amorphous structure and a layer having a polycrystalline structure are stacked. For example, a stacked-layer structure in which a layer having a polycrystalline structure is formed over a layer having an amorphous structure may be employed.

The insulator 212, the insulator 214, the insulator 271, the insulator 275, the insulator 282, the insulator 283, and the insulator 285 are deposited by a sputtering method, for example. Since a sputtering method does not need to use a molecule containing hydrogen as a deposition gas, the hydrogen concentrations in the insulator 212, the insulator 214, the insulator 271, the insulator 275, the insulator 282, the insulator 283, and the insulator 285 can be reduced. Note that the deposition method is not limited to a sputtering method, and a chemical vapor deposition (CVD) method, a molecular beam epitaxy (MBE) method, a pulsed laser deposition (PLD) method, an ALD method, or the like can be used as appropriate.

The resistivities of the insulator 212, the insulator 275, and the insulator 283 are preferably low in some cases. For example, by setting the resistivities of the insulator 212, the insulator 275, and the insulator 283 to approximately 1×10¹³ Ωcm, the insulator 212, the insulator 275, and the insulator 283 can sometimes reduce charge up of the conductor 205, the conductor 242, the conductor 260, the conductor 246a, or the conductor 246b in treatment using plasma or the like in the manufacturing process of a semiconductor device. The resistivities of the insulator 212, the insulator 275, and the insulator 283 are preferably higher than or equal to 1×10¹⁰ Ωcm and lower than or equal to 1×10¹⁵ ωcm.

The insulator 216, the insulator 274, the insulator 280, and the insulator 285 each preferably have a lower permittivity than the insulator 214. When a material with a low permittivity is used for an interlayer film, parasitic capacitance generated between wirings can be reduced. For the insulator 216, the insulator 274, the insulator 280, and the insulator 285, silicon oxide, silicon oxynitride, silicon oxide to which fluorine is added, silicon oxide to which carbon is added, silicon oxide to which carbon and nitrogen are added, porous silicon oxide, or the like is used as appropriate, for example.

The conductor 205 is placed to overlap with the oxide 230 and the conductor 260. Here, the conductor 205 is preferably provided to be embedded in an opening formed in the insulator 216. Part of the conductor 205 is embedded in the insulator 214 in some cases.

The conductor 205 includes the conductor 205a and the conductor 205b. The conductor 205a is provided in contact with the bottom surface and the sidewall of the above opening. The conductor 205b is provided to be embedded in a depressed portion formed in the conductor 205a. Here, the top surface of the conductor 205b is level or substantially level with the top surface of the conductor 205a and the top surface of the insulator 216.

Here, for the conductor 205a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom. Alternatively, it is preferable to use a conductive material having a function of inhibiting diffusion of oxygen (e.g., at least one of an oxygen atom, an oxygen molecule, and the like).

When a conductive material having a function of inhibiting diffusion of hydrogen is used for the conductor 205a, impurities such as hydrogen contained in the conductor 205b can be prevented from diffusing into the oxide 230 through the insulator 216, the insulator 224, and the like. When a conductive material having a function of inhibiting diffusion of oxygen is used for the conductor 205a, the conductivity of the conductor 205b can be inhibited from being lowered because of oxidation. Examples of the conductive material having a function of inhibiting diffusion of oxygen include titanium, titanium nitride, tantalum, tantalum nitride, ruthenium, and ruthenium oxide. Thus, a single layer or a stacked layer of the above conductive materials is preferably used for the conductor 205a. For example, titanium nitride is used for the conductor 205a.

A conductive material containing tungsten, copper, or aluminum as its main component is preferably used for the conductor 205b. For example, tungsten is used for the conductor 205b.

The conductor 205 sometimes functions as a second gate electrode. In that case, by changing a potential applied to the conductor 205 not in conjunction with but independently of a potential applied to the conductor 260, the threshold voltage (Vth) of the transistor 200 can be controlled. In particular, by applying a negative potential to the conductor 205, Vth of the transistor 200 can be higher, and its off-state current can be reduced. Thus, a drain current at the time when a potential applied to the conductor 260 is 0 V can be lower in the case where a negative potential is applied to the conductor 205 than in the case where the negative potential is not applied to the conductor 205.

The resistivity of the conductor 205 is designed in consideration of the potential applied to the conductor 205, and the thickness of the conductor 205 is set in accordance with the resistivity. The thickness of the insulator 216 is substantially equal to that of the conductor 205. Here, the conductor 205 and the insulator 216 are preferably as thin as possible in the allowable range of the design of the conductor 205. When the thickness of the insulator 216 is reduced, the absolute amount of impurities such as hydrogen contained in the insulator 216 can be reduced, thereby reducing the amount of the impurities to be diffused into the oxide 230.

As illustrated in FIG. 1A, the conductor 205 is preferably provided to be larger than a region of the oxide 230 that does not overlap with the conductor 242a or the conductor 242b. As illustrated in FIG. 1C, it is particularly preferable that the conductor 205 extend to a region outside an end portion of the oxide 230 in the channel width direction. That is, the conductor 205 and the conductor 260 preferably overlap with each other with the insulators therebetween on the outer side of the side surface of the oxide 230 in the channel width direction. With such a structure, the channel formation region of the oxide 230 can be electrically surrounded by the electric field of the conductor 260 functioning as a first gate electrode and the electric field of the conductor 205 functioning as the second gate electrode. In this specification, a transistor structure in which a channel formation region is electrically surrounded by electric fields of a first gate and a second gate is referred to as a surrounded channel (S-channel) structure.

In this specification and the like, a transistor having the S-channel structure refers to a transistor having a structure in which a channel formation region is electrically surrounded by the electric fields of a pair of gate electrodes. The S-channel structure disclosed in this specification and the like has a structure different from a Fin-type structure and a planar structure. Meanwhile, the S-channel structure disclosed in this specification and the like can also be regarded as a kind of the Fin-type structure. In this specification and the like, the Fin-type structure refers to a structure where at least two surfaces (specifically, two surfaces, three surfaces, four surfaces, or the like) of a channel are covered with a gate electrode. With the Fin-type structure and the S-channel structure, resistance to a short-channel effect can be enhanced; that is, a transistor in which a short-channel effect is less likely to occur can be provided.

When the transistor 200 becomes normally-off and has the above-described S-channel structure, the channel formation region can be electrically surrounded. Accordingly, the density of current flowing in the transistor can be improved, which can be expected to improve the on-state current of the transistor or increase the field-effect mobility of the transistor.

Although FIG. 1B illustrates a transistor with an S-channel structure as the transistor 200, the semiconductor device of one embodiment of the present invention is not limited thereto. For example, a transistor structure that can be used in one embodiment of the present invention may be one or more selected from a planar structure, a Fin-type structure, and a GAA (Gate All Around) structure.

Furthermore, as illustrated in FIG. 1C, the conductor 205 is extended to function as a wiring as well. However, without limitation to this structure, a structure in which a conductor functioning as a wiring is provided below the conductor 205 may be employed. In addition, the conductor 205 is not necessarily provided in each transistor. For example, the conductor 205 may be shared by a plurality of transistors.

Although the transistor 200 having a structure in which the conductor 205 is a stack of the conductor 205a and the conductor 205b is illustrated, the present invention is not limited thereto. For example, the conductor 205 may be provided to have a single-layer structure or a stacked-layer structure of three or more layers.

It is preferable that the insulator 222 have a function of inhibiting diffusion of hydrogen (e.g., at least one of a hydrogen atom, a hydrogen molecule, and the like). In addition, it is preferable that the insulator 222 have a function of inhibiting diffusion of oxygen (e.g., at least one of an oxygen atom, an oxygen molecule, and the like). For example, the insulator 222 preferably has a function of inhibiting diffusion of one or both of hydrogen and oxygen more than the insulator 224.

As the insulator 222, an insulator containing an oxide of one or both of aluminum and hafnium, which is an insulating material, is preferably used. For the insulator, aluminum oxide, hafnium oxide, an oxide containing aluminum and hafnium (hafnium aluminate), or the like is preferably used. Alternatively, an oxide containing hafnium and zirconium, e.g., a hafnium zirconium oxide, is preferably used. In the case where the insulator 222 is formed using such a material, the insulator 222 functions as a layer that inhibits release of oxygen from the oxide 230 to the substrate side and diffusion of impurities such as hydrogen from the periphery of the transistor 200 into the oxide 230. Thus, providing the insulator 222 can inhibit diffusion of impurities such as hydrogen into the oxide 230 and inhibit generation of oxygen vacancies in the oxide 230. Moreover, the conductor 205 can be inhibited from reacting with oxygen contained in the insulator 224 and the oxide 230.

Alternatively, aluminum oxide, bismuth oxide, germanium oxide, niobium oxide, silicon oxide, titanium oxide, tungsten oxide, yttrium oxide, or zirconium oxide may be added to the above insulator, for example. Alternatively, these insulators may be subjected to nitriding treatment. A stack of silicon oxide, silicon oxynitride, or silicon nitride over these insulators may be used for the insulator 222.

For example, a single layer or stacked layers of an insulator(s) containing what is called a high-k material such as aluminum oxide, hafnium oxide, tantalum oxide, zirconium oxide, or hafnium zirconium oxide may be used for the insulator 222. As miniaturization and high integration of transistors progress, a problem such as a leakage current may arise because of a thinner gate insulator. When a high-k material is used for the insulator functioning as a gate insulator, a gate potential at the time of the operation of the transistor can be reduced while the physical thickness is maintained. Furthermore, a substance with a high permittivity such as lead zirconate titanate (PZT), strontium titanate (SrTiO₃), or (Ba,Sr)TiO₃ (BST) can be used for the insulator 222 in some cases.

Silicon oxide or silicon oxynitride, for example, is used as appropriate for the insulator 224 that is in contact with the oxide 230.

Note that one or both of the insulator 222 and the insulator 224 may have a stacked-layer structure of two or more layers. In that case, without limitation to a stacked-layer structure formed of the same material, a stacked-layer structure formed of different materials may be employed. The insulator 224 may be formed into an island shape so as to overlap with the oxide 230a. In this case, the insulator 275 is in contact with the side surface of the insulator 224 and the top surface of the insulator 222.

For example, as the oxide 230, a metal oxide such as an In-M-Zn oxide containing indium, an element M, and zinc (the element M is one or more kinds selected from aluminum, gallium, yttrium, tin, boron, silicon, vanadium, beryllium, copper, titanium, iron, nickel, germanium, zirconium, molybdenum, lanthanum, cerium, neodymium, hafnium, tantalum, tungsten, magnesium, cobalt, and the like) can be used. Specifically, a metal oxide containing indium, zinc, and one or more selected from gallium, aluminum, and tin is preferably used. Note that an In—Ga oxide, an In—Zn oxide, an indium oxide, or the like may be used as the oxide 230.

The oxide 230 preferably has a stacked-layer structure of a plurality of oxide layers with different chemical compositions. For example, the atomic ratio of the element M to a metal element that is a main component in the metal oxide used as the oxide 230a is preferably greater than the atomic ratio of the element M to a metal element that is a main component in the metal oxide used as the oxide 230b. Moreover, the atomic ratio of the element M to In in the metal oxide used as the oxide 230a is preferably greater than the atomic ratio of the element M to In in the metal oxide used as the oxide 230b. With such a structure, impurities and oxygen can be inhibited from diffusing into the oxide 230b from the components formed below the oxide 230a.

Furthermore, the atomic ratio of In to the element M in the metal oxide used as the oxide 230b is preferably greater than the atomic ratio of In to the element M in the metal oxide used as the oxide 230a. With this structure, the transistor 200 can have a high on-state current and high frequency characteristics.

When the oxide 230a and the oxide 230b contain a common element as the main component besides oxygen, the density of defect states at an interface between the oxide 230a and the oxide 230b can be decreased. Thus, the influence of interface scattering on carrier conduction is small, and the transistor 200 can have a high on-state current and high frequency characteristics.

Specifically, as the oxide 230a, a metal oxide with a composition of In:M:Zn=1:3:4 [atomic ratio] or in the neighborhood thereof, a composition of In:M:Zn=1:3:2 [atomic ratio] or in the neighborhood thereof, or a composition of In:M:Zn=1:1:0.5 [atomic ratio] or in the neighborhood thereof is used. As the oxide 230b, a metal oxide with a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, a composition of In:M:Zn=1:1:5 [atomic ratio] or in the neighborhood thereof, a composition of In:M:Zn=1:1:8 [atomic ratio] or in the neighborhood thereof, a composition of In:M:Zn=4:2:3 [atomic ratio] or in the neighborhood thereof, or a composition of In:M:Zn=5:1:3 [atomic ratio] or in the neighborhood thereof is used. Note that a composition in the neighborhood includes the range of +30% of an intended atomic ratio. Gallium or aluminum is preferably used as the element M.

When the metal oxide is deposited by a sputtering method, the above atomic ratio is not limited to the atomic ratio of the deposited metal oxide and may be the atomic ratio of a sputtering target used for depositing the metal oxide.

In the case where the transistor 200 is used in, for example, a pixel circuit of a display device, part of light (stray light) emitted by a light-emitting element in the display device might enter the transistor 200. In that case, the stray light sometimes causes a degradation in transistor characteristics and adversely affects pixel operation.

Note that the stray-light-induced degradation amount of transistor characteristics can be evaluated using the amount of change in the threshold voltage or the amount of change in the shift voltage (Vsh) of the transistor measured in an NBTIS (Negative Bias Temperature Illumination Stress) test of the transistor, for example. Note that the shift voltage (Vsh) is defined as Vg at which, in a drain current (Id)-gate voltage (Vg) curve of a transistor, the tangent at a point where the slope of the curve is the steepest intersects the straight line of Id=1 pA. Here, the degradation of change in the threshold voltage or degradation of change in Vsh of the transistor in the NBTIS test is referred to as negative-bias photodegradation in some cases.

Accordingly, in the case where the transistor 200 is used in, for example, a pixel circuit of a display device, it is preferable to reduce the influence of stray light on the transistor 200. For example, it is preferable to reduce the stray-light-induced degradation of transistor characteristics for the transistor 200. Specifically, the transistor 200 preferably has high resistance to the NBTIS test (reduces negative-bias photodegradation).

Thus, in the case where the transistor 200 is used in, for example, a pixel circuit of a display device, a metal oxide having a bandgap greater than or equal to 3.1 eV is preferably used, and a metal oxide having a bandgap greater than or equal to 3.3 eV is further preferably used as the metal oxide functioning as a semiconductor of the transistor 200. The energy of light having a wavelength greater than or equal to 400 nm is less than or equal to 3.1 eV. That is, even when light having a wavelength greater than or equal to 400 nm enters the metal oxide, electrons in the valence band are less likely to be excited into the conduction band. Thus, when a metal oxide having a wider bandgap is used in a channel formation region of the transistor, the resistance to the NBTIS test can be increased. That is, with use of a metal oxide having a wider bandgap in the channel formation region of the transistor, the influence of stray light can be reduced even when a light-blocking layer or the like is not provided, so that degradation of the transistor characteristics can be suppressed.

Specifically, as the oxide 230, a metal oxide with a composition of In:M:Zn=2:6:5 [atomic ratio] or in the neighborhood thereof, a metal oxide with a composition of In:M:Zn=1:3:4 [atomic ratio] or in the neighborhood thereof, a metal oxide with a composition of In:M:Zn=1:1:1 [atomic ratio] or in the neighborhood thereof, or a metal oxide with a composition of In:M:Zn=1:4:5 [atomic ratio] or in the neighborhood thereof is used.

For example, when the atomic ratio is described as In:M:Zn=2:6:5 or a composition in the neighborhood thereof, the case is included where M is greater than or equal to 4 and less than or equal to 8 and Zn is greater than or equal to 3 and less than or equal to 7.5 with In being 2. When the atomic ratio is described as In:M:Zn=1:1:1 or a composition in the neighborhood thereof, the case is included where M is greater than 0.1 and less than or equal to 2 and Zn is greater than 0.1 and less than or equal to 2 with In being 1.

The bandgap of the metal oxide can be evaluated using one or a plurality of optical evaluation with a spectrophotometer, spectroscopic ellipsometry, a photoluminescence method, X-ray photoelectron spectroscopy (XPS or ESCA: Electron Spectroscopy for Chemical Analysis), an X-ray absorption fine structure (XAFS), and the like.

The composition of the metal oxide can be evaluated using an inductively coupled plasma-mass spectrometry (ICP-MS), XPS, SEM (Scanning Electron Microscopy)-EDX (Energy Dispersive X-ray Spectroscopy), SIMS, or the like.

The oxide 230b preferably has crystallinity. It is particularly preferable to use a CAAC-OS (c-axis aligned crystalline oxide semiconductor) as the oxide 230b.

The CAAC-OS is a metal oxide having a dense structure with high crystallinity and small amounts of impurities and defects (for example, oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including the CAAC-OS is physically stable. Therefore, the metal oxide including the CAAC-OS is resistant to heat and has high reliability.

When an oxide having crystallinity, such as CAAC-OS, is used as the oxide 230b, oxygen extraction from the oxide 230b by the conductor 242a or the conductor 242b can be inhibited. This can reduce oxygen extraction from the oxide 230b even when heat treatment is performed; thus, the transistor 200 is stable with respect to high temperatures in a manufacturing process (what is called thermal budget). Furthermore, it is possible to inhibit a reduction in the conductivity of the conductor 242a and the conductor 242b.

As illustrated in FIG. 1C, a curved surface may be provided between the side surface of the oxide 230b and the top surface of the oxide 230b in a cross-sectional view of the transistor 200 in the channel width direction. That is, an end portion of the side surface and an end portion of the top surface may be curved (hereinafter also referred to as rounded).

The radius of curvature of the curved surface is preferably greater than 0 nm and less than the thickness of the oxide 230b in a region overlapping with the conductor 242, or less than half of the length of a region that does not have the curved surface. Specifically, the radius of curvature of the curved surface is greater than 0 nm and less than or equal to 20 nm, preferably greater than or equal to 1 nm and less than or equal to 15 nm, further preferably greater than or equal to 2 nm and less than or equal to 10 nm. Such a shape can improve the coverage of the oxide 230b with the insulator 252, the insulator 250, the insulator 254, and the conductor 260.

When aluminum oxide is used as the insulator 252, aluminum is added to a region of the oxide 230b in contact with the insulator 252 and to the vicinity thereof in some cases. Note that addition of aluminum to the region of the oxide 230b in contact with the insulator 252 and to the vicinity thereof is caused by a step of the formation of an insulating film to be the insulator 252 or a later step, such as the formation of the insulating film, the formation of a film over the insulating film, or heat treatment in or after the formation of the insulating film.

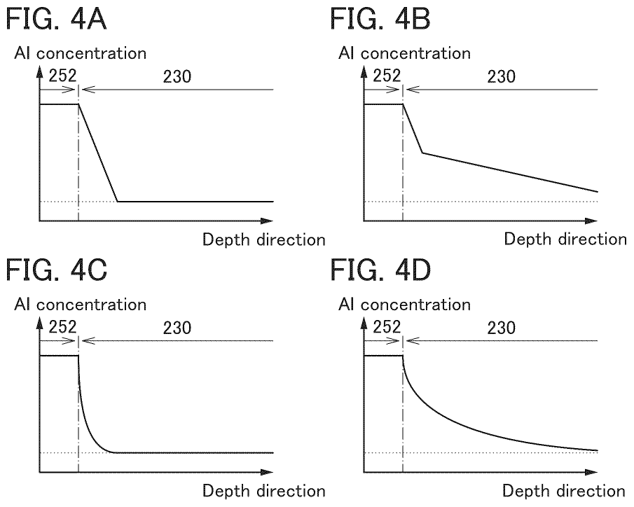

FIG. 4A to FIG. 4D schematically show aluminum concentration profiles in depth direction in the insulator 252 and the oxide 230. In FIG. 4A to FIG. 4D, the vertical axis represents the aluminum (Al) concentration and the horizontal axis represents the depth. Note that the depth can be rephrased as a film thickness.

Note that in the case where a metal oxide not containing aluminum is used as the oxide 230 before addition of aluminum, dotted lines shown in FIG. 4A to FIG. 4D represent the lower detection limit of the aluminum concentration. In the case where a metal oxide containing aluminum is used as the oxide 230 before addition of aluminum, the dotted lines shown in FIG. 4A to FIG. 4D represent the aluminum concentration of the oxide 230 in the vicinity of the insulator 224.

As shown in FIG. 4A to FIG. 4D, the oxide 230 has a concentration gradient in which the aluminum concentration increases from the bottom surface of the oxide 230 to the top surface of the oxide 230. In other words, the oxide 230 has a concentration gradient in which the aluminum concentration increases toward the insulator 252 in the film thickness direction.

In some cases, as shown in FIG. 4A, the oxide 230 includes a region in which the aluminum concentration decreases monotonously from the peak at the interface between the insulator 252 and the oxide 230 and a region in which the aluminum concentration is constant. In that case, the region in which the aluminum concentration decreases monotonously is located close to the insulator 252, compared with the region in which the aluminum concentration is constant.

As shown in FIG. 4B, the oxide 230 includes a first region in which the aluminum concentration decreases monotonously from the peak at the interface between the insulator 252 and the oxide 230 and a second region in which the aluminum concentration decreases monotonously, in some cases. In that case, the first region is located close to the insulator 252, compared with the second region.

As shown in FIG. 4C, the oxide 230 includes a region in which the aluminum concentration decreases exponentially from the peak at the interface between the insulator 252 and the oxide 230 and a region in which the aluminum concentration is constant, in some cases. In that case, the region in which the aluminum concentration decreases exponentially is located close to the insulator 252, compared with the region in which the aluminum concentration is constant.

As shown in FIG. 4D, the aluminum concentration of the oxide 230 decreases exponentially from the peak at the interface between the insulator 252 and the oxide 230 in some cases.

The addition of aluminum to the region of the oxide 230b in contact with the insulator 252 and to the vicinity thereof can inhibit the formation of oxygen vacancies in the region and in the vicinity thereof. Since a channel is easily formed in the region of the oxide 230b and the vicinity thereof, oxygen vacancies in the channel formation region can be reduced with such a structure. Accordingly, a change in the electrical characteristics of the transistor 200 can be inhibited, and thus a variation in the electrical characteristics of the transistors 200 in the substrate plane can be inhibited. In the case where an In-M-Zn oxide is used as the oxide 230b before addition of aluminum, the oxide 230b contains at least indium (In), aluminum (Al), and zinc (Zn). Furthermore, the oxide 230b contains indium (In), the element M, aluminum (Al), and zinc (Zn).

The insulator 252 containing aluminum oxide or the like is provided in contact with the top surface and the side surface of the oxide 230, whereby indium contained in the oxide 230 is unevenly distributed, in some cases, at the interface between the oxide 230 and the insulator 252 and in its vicinity. Accordingly, the vicinity of the surface of the oxide 230 has an atomic ratio close to that of an indium oxide or that of an In—Zn oxide. Such an increase in the atomic ratio of indium in the vicinity of the surface of the oxide 230, especially the oxide 230b, can increase the field-effect mobility of the transistor 200.

Although a structure in which two layers, the oxide 230a and the oxide 230b, are stacked as the oxide 230 in the transistor 200 is described, the present invention is not limited thereto. For example, the oxide 230 may be provided as a single layer of the oxide 230a, a single layer of the oxide 230b, or a stacked-layer structure of three or more layers, or the oxide 230a and the oxide 230b may each have a stacked-layer structure.

The conductor 242a and the conductor 242b are provided in contact with the top surface of the oxide 230b.

A conductive material that is less likely to be oxidized, a conductive material having a function of inhibiting diffusion of oxygen, or the like is preferably used for the conductor 242a and the conductor 242b. Examples of the conductive material include a conductive material containing nitrogen, a conductive material containing oxygen, and the like. This can inhibit a reduction in the conductivity of the conductor 242a and the conductor 242b. In the case where a conductive material containing a metal element and nitrogen is used for the conductor 242a and the conductor 242b, the conductor 242a and the conductor 242b contain at least the metal element and nitrogen.

As the conductor 242a and the conductor 242b, for example, a nitride containing tantalum, a nitride containing titanium, a nitride containing molybdenum, a nitride containing tungsten, a nitride containing tantalum and aluminum, or a nitride containing titanium and aluminum is preferably used. As another example, ruthenium, ruthenium oxide, ruthenium nitride, an oxide containing strontium and ruthenium, or an oxide containing lanthanum and nickel may be used. These materials are preferable because they are each a conductive material that is less likely to be oxidized or a material that maintains the conductivity even after absorbing oxygen.

Note that hydrogen contained in the oxide 230b or the like diffuses into the conductor 242a or the conductor 242b in some cases. In particular, when a nitride containing tantalum is used for the conductor 242a and the conductor 242b, hydrogen contained in the oxide 230b or the like is likely to diffuse into the conductor 242a or the conductor 242b, and the diffused hydrogen is bonded to nitrogen contained in the conductor 242a or the conductor 242b in some cases. That is, hydrogen contained in the oxide 230b or the like is absorbed by the conductor 242a or the conductor 242b in some cases.

No curved surface is preferably formed between the side surface of the conductor 242 and the top surface of the conductor 242. When no curved surface is formed in the conductor 242, the conductor 242 can have a large cross-sectional area in the channel width direction as illustrated in FIG. 1D. Accordingly, the conductivity of the conductor 242 is increased, so that the on-state current of the transistor 200 can be increased.

When heat treatment is performed in the state where the conductor 242a and the oxide 230b are in contact with each other, the sheet resistance of the oxide 230b in a region overlapping with the conductor 242a is decreased in some cases. Furthermore, the carrier concentration is sometimes increased. Thus, the resistance of the oxide 230b in the region overlapping with the conductor 242a can be lowered in a self-aligned manner. Similarly, when heat treatment is performed in the state where the conductor 242b and the oxide 230b are in contact with each other, the sheet resistance of the oxide 230b in a region overlapping with the conductor 242b is decreased in some cases. Furthermore, the carrier concentration is sometimes increased. Thus, the resistance of the oxide 230b in the region overlapping with the conductor 242b can be lowered in a self-aligned manner.

The conductor 242a and the conductor 242b are preferably formed using a conductive film having compressive stress. This can form distortion extended in the tensile direction (hereinafter, such distortion is sometimes referred to as tensile distortion) in the region 230ba and the region 230bb. When V_{O}H is stably formed in the tensile distortion, the region 230ba and the region 230bb can be stable n-type regions. Note that the compressive stress of the conductor 242a refers to stress for relaxing the compressive shape of the conductor 242a that has a vector in a direction from a center portion to an end portion of the conductor 242a. The same applies to the compressive stress of the conductor 242b.

The level of the compressive stress of the conductor 242a is, for example, higher than or equal to 500 MPa, preferably higher than or equal to 1000 MPa, further preferably higher than or equal to 1500 MPa, still further preferably higher than or equal to 2000 MPa. Note that the level of the stress of the conductor 242a may be determined from the measured stress of a sample fabricated by depositing a conductive film to be used for the conductor 242a on a substrate. The same applies to the level of the compressive stress of the conductor 242b.

Due to the action of the compressive stress in the conductor 242a and the conductor 242b, distortion is formed in each of the region 230ba and the region 230bb. The distortion is distortion (tensile distortion) extended in the tensile direction by the action of the compressive stress in the conductor 242a and the conductor 242b. In the case where the region 230ba and the region 230bb have a CAAC structure, the distortion corresponds to extension in the direction perpendicular to the c-axis of the CAAC structure. When the CAAC structure is extended in the direction perpendicular to the c-axis of the CAAC structure, oxygen vacancies are likely to be formed in the distortion. Furthermore, hydrogen is likely to be taken in the distortion, so that V_{O}H is likely to be formed. Thus, oxygen vacancies and V_{O}H are likely to be formed in the distortion and likely to have a stable structure. Thus, the region 230ba and the region 230bb can be stable n-type regions with high carrier concentrations.

Note that although the distortion formed in the oxide 230b is described above, the present invention is not limited thereto. In some cases, a similar distortion is formed in the oxide 230a.

In one embodiment of the present invention, a nitride containing tantalum or a nitride containing titanium is particularly preferably used for the conductor 242a and the conductor 242b. In this case, the conductor 242a and the conductor 242b contain tantalum or titanium and nitrogen.

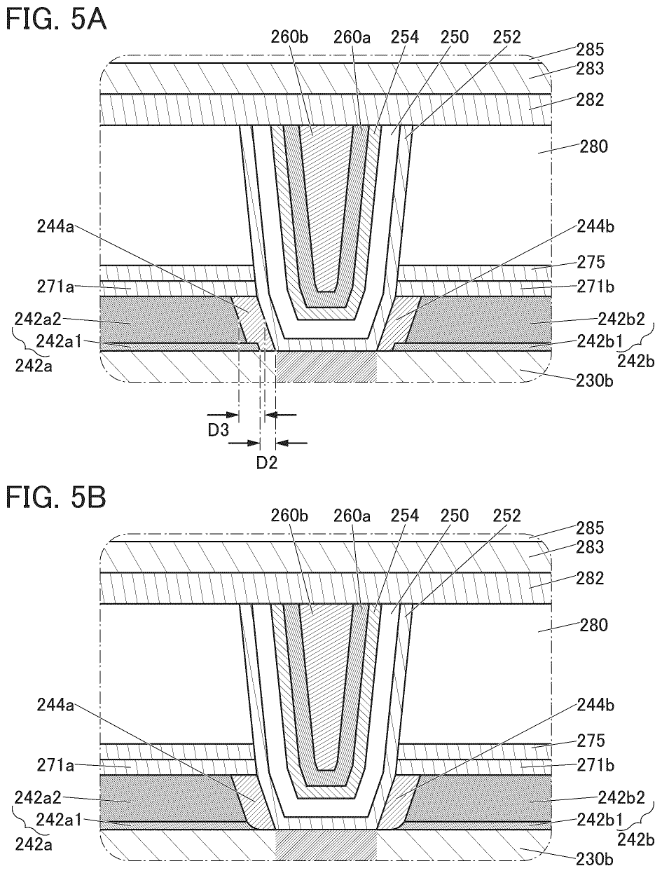

Although FIG. 1A to FIG. 1D and the like illustrate a single-layer structure of the conductor 242, the present invention is not limited to this structure, and a stacked-layer structure of two or more layers may be employed. For example, as illustrated in FIG. 5A, the conductor 242a may have a stacked-layer structure of two layers of a conductor 242a1 and a conductor 242a2 over the conductor 242a1, and the conductor 242b may have a stacked-layer structure of two layers of a conductor 242b1 and a conductor 242b2 over the conductor 242b1. In that case, the conductor 242a1 and the conductor 242b1 are placed on the side in contact with the oxide 230b.

Hereinafter, the conductor 242a1 and the conductor 242b1 are collectively referred to as a lower layer of the conductor 242 in some cases. The conductor 242a2 and the conductor 242b2 are collectively referred to as an upper layer of the conductor 242 in some cases.

The lower layer (the conductor 242a1 and the conductor 242b1) of the conductor 242 is preferably formed using a conductive material having a property of being less likely to be oxidized. This can inhibit the oxidation of the lower layer of the conductor 242 and a reduction in the conductivity of the conductor 242. Note that the lower layer of the conductor 242 may have a property of being likely to absorb (extract) hydrogen. Accordingly, hydrogen in the oxide 230 is diffused into the lower layer of the conductor 242, so that the hydrogen concentration of the oxide 230 can be reduced. Thus, the transistor 200 can have stable electrical characteristics.

The upper layer of the conductor 242 (the conductor 242a2 and the conductor 242b2) is preferably formed using a conductive material with a higher conductivity than that of the lower layer of the conductor 242 (the conductor 242a1 and the conductor 242b1). In this case, at least part of the upper layer of the conductor 242 includes a region with a higher conductivity than that of the lower layer of the conductor 242. Alternatively, the upper layer of the conductor 242 is preferably formed using a conductive material with a lower resistivity than that of the lower layer of the conductor 242. Accordingly, a semiconductor device with reduced wiring delay can be fabricated.

Note that the upper layer of the conductor 242 may have a property of being likely to absorb hydrogen. Accordingly, hydrogen absorbed by the lower layer of the conductor 242 is also diffused into the upper layer of the conductor 242, so that the hydrogen concentration in the oxide 230 can be further reduced. Thus, the transistor 200 can have stable electrical characteristics.

Here, for the lower layer of the conductor 242 and the upper layer of the conductor 242, conductive materials containing the same constituent elements and having different chemical compositions are preferably used. In this case, the lower layer of the conductor 242 and the upper layer of the conductor 242 can be deposited successively without being exposed to an atmospheric environment. By the deposition without exposure to the atmosphere, impurities or moisture from the atmospheric environment can be prevented from being attached onto the surface of the lower layer of the conductor 242, so that the vicinity of the interface between the lower layer of the conductor 242 and the upper layer of the conductor 242 can be kept clean.

In addition, a nitride containing tantalum with a high atomic ratio of nitrogen to tantalum is preferably used for the lower layer of the conductor 242, and a nitride containing tantalum with a low atomic ratio of nitrogen to tantalum is preferably used for the upper layer of the conductor 242. For example, a nitride containing tantalum with an atomic ratio of nitrogen to tantalum being greater than or equal to 1.0 and less than or equal to 2.0, preferably greater than or equal to 1.1 and less than or equal to 1.8, further preferably greater than or equal to 1.2 and less than or equal to 1.5 is used for the lower layer of the conductor 242. In addition, for example, a nitride containing tantalum with an atomic ratio of nitrogen to tantalum being greater than or equal to 0.3 and less than or equal to 1.5, preferably greater than or equal to 0.5 and less than or equal to 1.3, further preferably greater than or equal to 0.6 and less than or equal to 1.0 is used for the upper layer of the conductor 242.

The high atomic ratio of nitrogen to tantalum in a nitride containing tantalum can inhibit oxidation of the nitride containing tantalum. In addition, the oxidation resistance of the nitride containing tantalum can be improved. Moreover, the diffusion of oxygen into the nitride containing tantalum can be inhibited. Hence, the nitride containing tantalum with a high atomic ratio of nitrogen to tantalum is preferably used for the lower layer of the conductor 242. It is thus possible to prevent an oxide layer from being formed between the lower layer of the conductor 242 and the oxide 230 or reduce the thickness of the oxide layer.

The low atomic ratio of nitrogen to tantalum in a nitride containing tantalum can reduce the resistivity of the nitride. Hence, the nitride containing tantalum with a low atomic ratio of nitrogen to tantalum is preferably used for the upper layer of the conductor 242. Accordingly, a semiconductor device with reduced wiring delay can be manufactured.

When the lower layer of the conductor 242 is formed using a conductive material having a property of being less likely to be oxidized and the upper layer of the conductor 242 is formed using a conductive material having a higher conductivity than that of the lower layer of the conductor 242, the insulator 244a and the insulator 244b each include regions having different lengths in the channel length direction as illustrated in FIG. 5A. Here, a distance from the lower layer of the conductor 242 to the insulator 252 is referred to as a length D2, and a distance from the upper layer of the conductor 242 to the insulator 252 is referred to as a length D3. In this case, it can be said that the insulator 244a and the insulator 244b each include a first region whose length in the channel length direction is the length D2 and a second region whose length in the channel length direction is the length D3 over the first region. With such a structure, parasitic capacitance between the conductor 242a and the conductor 260 and parasitic capacitance between the conductor 242b and the conductor 260 can be reduced, and an increase in the channel length can be inhibited. Thus, the switching speed of the transistor 200 can be improved, and the transistor can have high frequency characteristics. In addition, a decrease in the on-state current or field-effect mobility of the transistor 200 can be inhibited.

Although FIG. 5A illustrates the structure in which the lengths of the insulator 244a and the insulator 244b in the channel length direction are discontinuous at the boundary between the upper layer of the conductor 242 and the lower layer of the conductor 242, the lengths of the insulator 244a and the insulator 244b in the channel length direction may be continuously changed at the boundary between the upper layer of the conductor 242 and the lower layer of the conductor 242 as illustrated in FIG. 5B. In this case, the side surface of the insulator 244a in contact with the conductor 242a has a curve in a cross-sectional view. Similarly, the side surface of the insulator 244b in contact with the conductor 242b has a curve in a cross-sectional view. Also with this structure, parasitic capacitance between the conductor 242a and the conductor 260 and parasitic capacitance between the conductor 242b and the conductor 260 can be reduced, and an increase in the channel length can be inhibited.

Note that even when the conductor 242a is a single layer, the side surface of the insulator 244a in contact with the conductor 242a has a curve in some cases. Similarly, even when the conductor 242b is a single layer, the side surface of the insulator 244b in contact with the conductor 242b has a curve in some cases.

Note that the boundary between the upper layer and the lower layer of the conductor 242 is difficult to detect clearly in some cases. In the case where a nitride containing tantalum is used for the conductor 242, the tantalum concentration and the nitrogen concentration detected in each layer may gradually change within each layer or may change continuously (or in a gradation manner) in a region between the upper layer and the lower layer. That is, the atomic ratio of nitrogen to tantalum is higher in the region of the conductor 242 that is closer to the oxide 230. Thus, the atomic ratio of nitrogen to tantalum in a lower region of the conductor 242 is preferably higher than the atomic ratio of nitrogen to tantalum in an upper region of the conductor 242.

The thickness of the lower layer of the conductor 242 is greater than or equal to 0.1 nm and less than or equal to 5.0 nm, preferably greater than or equal to 0.5 nm and less than or equal to 3.0 nm, further preferably greater than or equal to 1.0 nm and less than or equal to 3.0 nm. In this case, at least part of the lower layer of the conductor 242 includes a region having a thickness like the above-described thickness. The thickness of the lower layer of the conductor 242 is preferably smaller than the thickness of the upper layer of the conductor 242. In this case, at least part of the lower layer of the conductor 242 includes a region having a thickness smaller than that of the upper layer of the conductor 242.

In the example shown above, conductive materials containing the same constituent elements and having different chemical compositions are used for the lower layer of the conductor 242 and the upper layer of the conductor 242; however, the present invention is not limited thereto, and the lower layer of the conductor 242 and the upper layer of the conductor 242 may be formed using different conductive materials.

Note that the structures of the lower layer of the conductor 242 and the upper layer of the conductor 242 are not limited to the above. For example, one or more selected from the constituent elements, chemical compositions, and deposition conditions of the lower layer of the conductor 242 and the upper layer of the conductor 242 may be different from each other. For example, a nitride containing tantalum may be used for the lower layer of the conductor 242, and a nitride containing titanium may be used for the upper layer of the conductor 242.

The insulator 271a is provided in contact with the top surface of the conductor 242a, and the insulator 271b is provided in contact with the top surface of the conductor 242b. The insulator 271 preferably functions as at least a barrier insulating film against oxygen. Thus, the insulator 271 preferably has a function of inhibiting oxygen diffusion. For example, the insulator 271 preferably has a function of inhibiting diffusion of oxygen more than the insulator 280. As the insulator 271, an insulator such as silicon nitride, aluminum oxide, or magnesium oxide is used, for example.

The insulator 275 is provided to cover the insulator 224, the oxide 230a, the oxide 230b, the conductor 242a, the conductor 242b, the insulator 271a, and the insulator 271b. Specifically, the insulator 275 includes a region in contact with the side surface of the insulator 224, a region in contact with the side surface of the oxide 230a, a region in contact with the side surface of the oxide 230b, a region in contact with the side surface of the conductor 242a, a region in contact with the side surface of the conductor 242b, a region in contact with the side surface and the top surface of the insulator 271a, and a region in contact with the side surface and the top surface of the insulator 271b.

The insulator 275 preferably has a function of capturing and fixing hydrogen. In that case, the insulator 275 preferably includes an insulator such as silicon nitride or a metal oxide having an amorphous structure, e.g., aluminum oxide or magnesium oxide. Alternatively, for example, a stacked-layer film of aluminum oxide and silicon nitride over the aluminum oxide may be used as the insulator 275.

The insulator 275 preferably has a barrier property against oxygen. Accordingly, oxygen contained in the insulator 280 can be inhibited from diffusing into the side surface of the conductor 242a on the side in contact with the insulator 275 and the side surface of the conductor 242b on the side in contact with the insulator 275. This can inhibit an increase in resistivity and a reduction in on-state current which are caused by oxidation of the side surface of the conductor 242a on the side in contact with the insulator 275 and the side surface of the conductor 242b on the side in contact with the insulator 275 by oxygen contained in the insulator 280. Note that oxygen is less likely to pass through the insulator 275 than the insulator 280, for example. For the insulator 275, a material through which oxygen is less likely to pass than the insulator 280 is used, for example.

When the insulator 275 has a barrier property against oxygen, oxygen contained in the insulator 280 can be inhibited from diffusing into the side surfaces of the oxide 230a and the oxide 230b. Note that the insulator 275 is in contact with the region 230ba and the region 230bb functioning as the source region and the drain region of the transistor 200 and is not in contact with the region 230bc functioning as the channel formation region of the transistor 200. Thus, it is possible to inhibit supply of excess oxygen to the source region and the drain region and a decrease in the on-state current or field-effect mobility of the transistor 200.

When the insulator 271 and the insulator 275 are provided as described above, the conductor 242 can be surrounded by the insulators having a barrier property against oxygen. That is, oxygen contained in the insulator 224 and the insulator 280 can be prevented from diffusing into the conductor 242. As a result, the conductor 242 can be inhibited from being directly oxidized by oxygen contained in the insulator 224 and the insulator 280, so that an increase in resistivity and a reduction in on-state current can be inhibited.

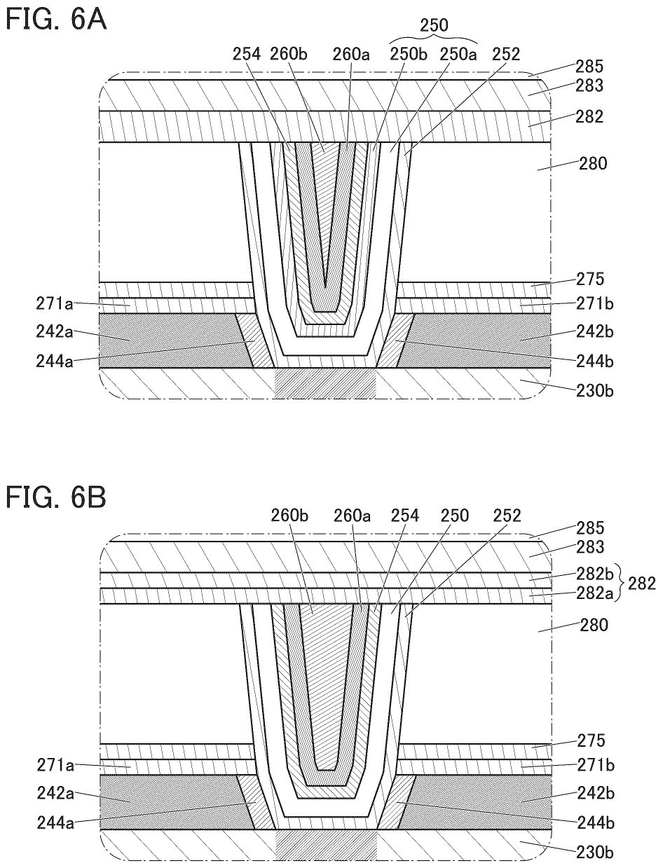

The insulator 250 functions as part of the gate insulator. Although FIG. 1A to FIG. 1D and the like illustrate a single-layer structure of the insulator 250, the present invention is not limited to this structure, and a stacked-layer structure of two or more layers may be employed. For example, as illustrated in FIG. 6A, the insulator 250 may have a stacked-layer structure of two layers of an insulator 250a and an insulator 250b over the insulator 250a.

In the case where the insulator 250 has a stacked-layer structure of two layers as illustrated in FIG. 6A, it is preferable that the insulator 250a be formed using an insulator through which oxygen is likely to pass and the insulator 250b be formed using an insulator having a function of inhibiting oxygen diffusion. With such a structure, oxygen contained in the insulator 250a can be inhibited from diffusing into the conductor 260. That is, a reduction in the amount of oxygen supplied to the oxide 230 can be inhibited. In addition, oxidation of the conductor 260 due to oxygen contained in the insulator 250a can be inhibited. For example, it is preferable that the insulator 250a be provided using any of the above-described materials that can be used for the insulator 250 and the insulator 250b be provided using an insulator containing an oxide of one or both of aluminum and hafnium. As the insulator, aluminum oxide, hafnium oxide, an oxide containing aluminum and hafnium (hafnium aluminate), an oxide containing hafnium and silicon (hafnium silicate), or the like can be used. In this embodiment, hafnium oxide is used as the insulator 250b. In this case, the insulator 250b contains at least oxygen and hafnium. The thickness of the insulator 250b is greater than or equal to 0.5 nm and less than or equal to 5.0 nm, preferably greater than or equal to 1.0 nm and less than or equal to 5.0 nm, further preferably greater than or equal to 1.0 nm and less than or equal to 3.0 nm. In that case, at least part of the insulator 250b includes a region having a thickness like the above-described thickness.

In the case where silicon oxide, silicon oxynitride, or the like is used for the insulator 250a, the insulator 250b may be formed using an insulating material that is a high-k material having a high relative permittivity. The gate insulator having a stacked-layer structure of the insulator 250a and the insulator 250b can be thermally stable and can have a high relative permittivity. Accordingly, a gate potential applied during the operation of the transistor can be reduced while the physical thickness of the gate insulator is maintained. In addition, the equivalent oxide thickness (EOT) of the insulator functioning as the gate insulator can be reduced. Therefore, the withstand voltage of the insulator 250 can be increased.

Note that in the case where the insulator 250 has a stacked-layer structure of two layers as illustrated in FIG. 6A, an insulator having a function of inhibiting the passage of oxygen and impurities such as hydrogen, e.g., hafnium oxide, is used as the insulator 250b, whereby the insulator 250b can also have the function of the insulator 254. In such a case, the structure without the insulator 254 enables simplification of the manufacturing process and the improvement in productivity of the semiconductor device.

The conductor 260 functions as the first gate electrode of the transistor 200. The conductor 260 preferably includes the conductor 260a and the conductor 260b placed over the conductor 260a. For example, the conductor 260a is preferably placed to cover the bottom surface and the side surface of the conductor 260b. As illustrated in FIG. 1B and FIG. 1C, the top surface of the conductor 260 is level or substantially level with the uppermost portion of the insulator 254, the uppermost portion of the insulator 250, the uppermost portion of the insulator 252, and the top surface of the insulator 280. Although the conductor 260 has a two-layer structure of the conductor 260a and the conductor 260b in FIG. 1B and FIG. 1C, the conductor 260 may have a single-layer structure or a stacked-layer structure of three or more layers.

For the conductor 260a, it is preferable to use a conductive material having a function of inhibiting diffusion of impurities such as a hydrogen atom, a hydrogen molecule, a water molecule, a nitrogen atom, a nitrogen molecule, a nitrogen oxide molecule, and a copper atom. Alternatively, it is preferable to use a conductive material having a function of inhibiting diffusion of oxygen (e.g., at least one of an oxygen atom, an oxygen molecule, and the like).

In addition, when the conductor 260a has a function of inhibiting diffusion of oxygen, the conductivity of the conductor 260b can be inhibited from being lowered because of oxidation due to oxygen contained in the insulator 250. As the conductive material having a function of inhibiting diffusion of oxygen, for example, titanium, titanium nitride, tantalum, tantalum nitride, ruthenium, or ruthenium oxide is preferably used. In the case where titanium nitride or tantalum nitride is used for the conductor 260a, the conductor 260a contains titanium or tantalum and nitrogen.

The conductor 260 also functions as a wiring and thus is preferably formed using a conductor having high conductivity. For example, a conductive material containing tungsten, copper, or aluminum as its main component can be used for the conductor 260b. The conductor 260b may have a stacked-layer structure; for example, a stacked-layer structure of the conductive material and titanium or titanium nitride may be employed.

In the transistor 200, the conductor 260 is formed in a self-aligned manner to fill the opening formed in the insulator 280 and the like. The formation of the conductor 260 in this manner allows the conductor 260 to be placed properly in a region between the conductor 242a and the conductor 242b without alignment. That is, the transistor structure of the transistor 200 can be referred to as a TGSA (Trench Gate Self Align) structure and can also be regarded as a kind of the Fin-type structure.

As illustrated in FIG. 1C, in the channel width direction of the transistor 200, with reference to the bottom surface of the insulator 222, the level of the bottom surface of the conductor 260 in a region not overlapping with the oxide 230b is preferably lower than the level of the bottom surface of the oxide 230b. When the conductor 260 functioning as the gate electrode covers the side surface and the top surface of the channel formation region of the oxide 230b with the insulator 250 and the like therebetween, the electric field of the conductor 260 is likely to act on the entire channel formation region of the oxide 230b. Thus, the on-state current of the transistor 200 can be increased, and the frequency characteristics of the transistor 200 can be improved. With reference to the bottom surface of the insulator 222, the difference between the level of the bottom surface of the conductor 260 in the region not overlapping with the oxide 230b and the level of the bottom surface of the oxide 230b is greater than or equal to 0 nm and less than or equal to 100 nm, preferably greater than or equal to 3 nm and less than or equal to 50 nm, further preferably greater than or equal to 5 nm and less than or equal to 20 nm.

The insulator 282 is in contact with at least parts of the top surfaces of the conductor 260, the insulator 252, the insulator 250, the insulator 254, and the insulator 280, as illustrated in FIG. 1B.

The insulator 282 preferably functions as a barrier insulating film that inhibits impurities such as water and hydrogen from diffusing into the insulator 280 from above and preferably has a function of capturing impurities such as hydrogen. The insulator 282 preferably functions as a barrier insulating film that inhibits passage of oxygen. For the insulator 282, an insulator such as a metal oxide having an amorphous structure, e.g., aluminum oxide, is used. In this case, the insulator 282 contains at least oxygen and aluminum. The insulator 282, which has a function of capturing impurities such as hydrogen, is provided in contact with the insulator 280 in a region sandwiched between the insulator 212 and the insulator 283, whereby impurities such as hydrogen contained in the insulator 280 and the like can be captured and the amount of hydrogen in the region can be constant. It is particularly preferable to use aluminum oxide having an amorphous structure for the insulator 282, because hydrogen can be captured or fixed more effectively in some cases. Accordingly, the transistor 200 and the semiconductor device which have favorable characteristics and high reliability can be manufactured.

The insulator 282 provided over the insulator 280 is preferably formed by a method in which oxygen can be added to the insulator 280. Thus, excess oxygen can be contained in the insulator 280. As the insulator 282, aluminum oxide is preferably deposited by a sputtering method, and aluminum oxide is further preferably deposited by a pulsed DC sputtering method using an aluminum target in an atmosphere containing an oxygen gas. The use of the pulsed DC sputtering method can achieve more uniform film thickness and improve the sputtering rate and film quality. Here, RF (Radio Frequency) power may be applied to the substrate. The amount of oxygen implanted into a layer below the insulator 282 can be controlled depending on the amount of the RF power applied to the substrate. For example, the amount of oxygen implanted into the layer below the insulator 282 decreases as the RF power decreases, and the amount of oxygen is easily saturated even when the insulator 282 has a small thickness. Moreover, the amount of oxygen implanted into the layer below the insulator 282 increases as the RF power increases.

The RF power is higher than or equal to 0 W/cm² and lower than or equal to 1.86 W/cm², for example. That is, an appropriate amount of oxygen for the transistor characteristics can be changed and implanted by RF power used for the formation of the insulator 282. Accordingly, an appropriate amount of oxygen for improving the reliability of the transistor can be implanted.

The RF frequency is preferably 10 MHz or higher. The typical frequency is 13.56 MHZ. The higher the RF frequency is, the less damage the substrate receives.

Although FIG. 1A to FIG. 1D and the like illustrate a single-layer structure of the insulator 282, the present invention is not limited to this structure, and a stacked-layer structure of two or more layers may be employed. For example, as illustrated in FIG. 6B, the insulator 282 may have a stacked-layer structure of two layers of an insulator 282a and an insulator 282b over the insulator 282a.

The insulator 282a and the insulator 282b are preferably formed using the same material by different methods. For example, when aluminum oxide is deposited as the insulator 282 by a pulsed DC sputtering method using an aluminum target in an atmosphere containing an oxygen gas, RF power applied to the substrate in the deposition of the insulator 282a and RF power applied to the substrate in the deposition of the insulator 282b are preferably different from each other, and the RF power applied to the substrate in the deposition of the insulator 282a is preferably lower than the RF power applied to the substrate in the deposition of the insulator 282b. Specifically, the insulator 282a is deposited with the RF power applied to the substrate being higher than or equal to 0 W/cm² and lower than or equal to 0.62 W/cm², and the insulator 282b is deposited with the RF power applied to the substrate being lower than or equal to 1.86 W/cm². More specifically, the insulator 282a is deposited with the RF power applied to the substrate being 0 W/cm², and the insulator 282b is deposited with the RF power applied to the substrate being 0.31 W/cm². With such a structure, the insulator 282 can have an amorphous structure, and the amount of oxygen supplied to the insulator 280 can be adjusted.

Note that the RF power applied to the substrate in the deposition of the insulator 282a may be higher than the RF power applied to the substrate in the deposition of the insulator 282b. Specifically, the insulator 282a is deposited with the RF power applied to the substrate being lower than or equal to 1.86 W/cm², and the insulator 282b is deposited with the RF power applied to the substrate being higher than or equal to 0 W/cm² and lower than or equal to 0.62 W/cm². More specifically, the insulator 282a is deposited with the RF power applied to the substrate being 1.86 W/cm², and the insulator 282b is deposited with the RF power applied to the substrate being 0.62 W/cm². With such a structure, the amount of oxygen supplied to the insulator 280 can be increased.

The thickness of the insulator 282a is greater than or equal to 1 nm and less than or equal to 20 nm, preferably greater than or equal to 1.5 nm and less than or equal to 15 nm, further preferably greater than or equal to 2 nm and less than or equal to 10 nm, still further preferably greater than or equal to 3 nm and less than or equal to 8 nm. With such a structure, the insulator 282a can have an amorphous structure regardless of the RF power. When the insulator 282a has an amorphous structure, the insulator 282b is likely to have an amorphous structure, so that the insulator 282 can have an amorphous structure.

Although the insulator 282a and the insulator 282b described above form the stacked-layer structure of the same material, the present invention is not limited thereto. The insulator 282a and the insulator 282b may form a stacked-layer structure of different materials.

The insulator 283 is in contact with part of the top surface of the insulator 214, the side surface of the insulator 216, the side surface of the insulator 222, the side surface of the insulator 275, the side surface of the insulator 280, and the side surface and the top surface of the insulator 282.

The insulator 283 functions as a barrier insulating film that inhibits impurities such as water and hydrogen from diffusing into the insulator 280 from above. The insulator 283 is placed over the insulator 282. The insulator 283 is preferably formed using a nitride containing silicon such as silicon nitride or silicon nitride oxide. For example, silicon nitride deposited by a sputtering method is used for the insulator 283. When the insulator 283 is deposited by a sputtering method, a high-density silicon nitride film can be formed. As the insulator 283, silicon nitride deposited by a PEALD method or a CVD method may be stacked over silicon nitride deposited by a sputtering method.

For the conductor 240a and the conductor 240b, a conductive material containing tungsten, copper, or aluminum as its main component is preferably used. The conductor 240a and the conductor 240b may each have a stacked-layer structure.

In the case where the conductor 240a and the conductor 240b each have a stacked-layer structure, a conductive material having a function of inhibiting passage of impurities such as water and hydrogen is preferably used for a first conductor placed in the vicinity of the insulator 285, the insulator 283, the insulator 282, the insulator 280, the insulator 275, and the insulator 271. For example, tantalum, tantalum nitride, titanium, titanium nitride, ruthenium, ruthenium oxide, or the like is preferably used. The conductive material having a function of inhibiting passage of impurities such as water and hydrogen may be used as a single layer or stacked layers. Moreover, impurities such as water and hydrogen contained in a layer above the insulator 283 can be inhibited from entering the oxide 230 through the conductor 240a and the conductor 240b.

For the insulator 241a and the insulator 241b, a barrier insulating film that can be used for the insulator 275 or the like is used. For the insulator 241a and the insulator 241b, for example, an insulator such as silicon nitride, aluminum oxide, or silicon nitride oxide is used. Since the insulator 241a and the insulator 241b are provided in contact with the insulator 283, the insulator 282, the insulator 275, and the insulator 271, impurities such as water and hydrogen contained in the insulator 280 and the like can be inhibited from entering the oxide 230 through the conductor 240a and the conductor 240b. In particular, silicon nitride is suitable because of its high blocking property against hydrogen. Furthermore, oxygen contained in the insulator 280 can be prevented from being absorbed by the conductor 240a and the conductor 240b.

When the insulator 241a and the insulator 241b each have a stacked-layer structure as illustrated in FIG. 1B, the first insulator in contact with the inner wall of the opening formed in the insulator 280 and the like and the second insulator located inward from the first insulator are preferably formed using a combination of a barrier insulating film against oxygen and a barrier insulating film against hydrogen.

For example, aluminum oxide deposited by an ALD method may be used as the first insulator, and silicon nitride deposited by a PEALD method is used as the second insulator. With such a structure, oxidation of the conductor 240a and the conductor 240b can be inhibited, and hydrogen can be inhibited from entering the conductor 240a and the conductor 240b.

The conductor 246a functioning as a wiring may be placed in contact with the top surface of the conductor 240a, and the conductor 246b functioning as a wiring may be placed in contact with the top surface of the conductor 240b. For the conductor 246a and the conductor 246b, a conductive material containing tungsten, copper, or aluminum as its main component is preferably used. Furthermore, the conductors may each have a stacked-layer structure and may each be a stacked layer of titanium or titanium nitride and the conductive material, for example. Note that the conductors may be formed so as to be embedded in an opening provided in an insulator.

### <Component Material of Semiconductor Device>

Component materials that can be used for the semiconductor device are described below.

### <<Substrate>>

As a substrate where the transistor 200 is formed, an insulator substrate, a semiconductor substrate, or a conductor substrate is used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate having an insulator region in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate including a metal nitride and a substrate including a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor, a resistor, a switching element, a light-emitting element, and a storage element.

### <<Insulator>>

Examples of the insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, for example, a problem such as a leakage current may arise because of a thinner gate insulator. When a high-k material is used for the insulator functioning as a gate insulator, the voltage at the time of the operation of the transistor can be reduced while the physical thickness is maintained. In contrast, when a material with a low relative permittivity is used for the insulator functioning as an interlayer film, parasitic capacitance generated between wirings can be reduced. Thus, a material is preferably selected depending on the function of the insulator.

Examples of the insulator with a high relative permittivity include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator with a low relative permittivity include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

When a transistor including a metal oxide is surrounded by an insulator having a function of inhibiting passage of oxygen and impurities such as hydrogen, the transistor can have stable electrical characteristics. As the insulator having a function of inhibiting passage of oxygen and impurities such as hydrogen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum are used. Specifically, as the insulator having a function of inhibiting passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

The insulator functioning as the gate insulator is preferably an insulator including a region containing oxygen to be released by heating. For example, when a structure is employed in which silicon oxide or silicon oxynitride including a region containing oxygen to be released by heating is in contact with the oxide 230, oxygen vacancies included in the oxide 230 can be compensated for.

### <<Conductor>>

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like: an alloy containing any of the above metal elements; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are conductive materials that are less likely to be oxidized or materials that maintain their conductivity even after absorbing oxygen. Alternatively, a semiconductor having high electrical conductivity, typified by polycrystalline silicon containing an impurity element such as phosphorus, or silicide such as nickel silicide may be used.

A stack of a plurality of conductive layers formed of the above materials may be used. For example, a stacked-layer structure combining a material containing the above metal element and a conductive material containing oxygen may be employed. In addition, a stacked-layer structure combining a material containing the above metal element and a conductive material containing nitrogen may be employed. Furthermore, a stacked-layer structure combining a material containing the above metal element, a conductive material containing oxygen, and a conductive material containing nitrogen may be employed.

In the case where an oxide is used for the channel formation region of the transistor, the conductor functioning as the gate electrode preferably employs a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. Indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

### <<Metal Oxide>>

The oxide 230 is preferably formed using a metal oxide functioning as a semiconductor (an oxide semiconductor). A metal oxide that can be used as the oxide 230 according to the present invention is described below.

The metal oxide preferably contains at least indium or zinc. In particular, indium and zinc are preferably contained. In addition, aluminum, gallium, yttrium, tin, or the like is preferably contained. Furthermore, one or more kinds selected from boron, titanium, iron, nickel, germanium, zirconium, molybdenum, lanthanum, cerium, neodymium, hafnium, tantalum, tungsten, magnesium, cobalt, and the like may be contained.

Here, the case where the metal oxide is an In-M-Zn oxide containing indium, an element M, and zinc is considered. The element M is aluminum, gallium, yttrium, or tin. Examples of other elements that can be used as the element M include boron, titanium, iron, nickel, germanium, zirconium, molybdenum, lanthanum, cerium, neodymium, hafnium, tantalum, tungsten, magnesium, and cobalt. Note that a combination of two or more of the above elements may be used as the element M. In particular, the element M is preferably one or more kinds selected from gallium, aluminum, yttrium, and tin.

It is particularly preferable to use an oxide containing indium (In), gallium (Ga), and zinc (Zn) (also referred to as IGZO) for the semiconductor layer of the transistor. Alternatively, an oxide containing indium (In), aluminum (Al), and zinc (Zn) (also referred to as IAZO) may be used for the semiconductor layer of the transistor. Alternatively, an oxide containing indium (In), aluminum (Al), gallium (Ga), and zinc (Zn) (IAGZO or IGAZO) may be used for the semiconductor layer.

Note that in this specification and the like, a metal oxide containing nitrogen is also collectively referred to as a metal oxide in some cases. A metal oxide containing nitrogen may be referred to as a metal oxynitride.

Hereinafter, an oxide containing indium (In), gallium (Ga), and zinc (Zn) is described as an example of the metal oxide. Note that an oxide containing indium (In), gallium (Ga), and zinc (Zn) may be referred to as an In—Ga—Zn oxide.

### <Classification of Crystal Structure>

Amorphous (including completely amorphous), CAAC (c-axis-aligned crystalline), nc (nanocrystalline), CAC (cloud-aligned composite), single crystal, and polycrystalline (poly crystal) structures can be given as examples of a crystal structure of an oxide semiconductor.

Note that the crystal structure of a film or a substrate can be evaluated with an X-ray diffraction (XRD) spectrum. For example, evaluation is possible using an XRD spectrum that is obtained by GIXD (Grazing-Incidence XRD) measurement. Note that a GIXD method is also referred to as a thin film method or a Seemann-Bohlin method. Hereinafter, an XRD spectrum obtained from GIXD measurement is simply referred to as an XRD spectrum in some cases.

For example, the XRD spectrum of a quartz glass substrate shows a peak with a substantially bilaterally symmetrical shape. On the other hand, the peak of the XRD spectrum of an In—Ga—Zn oxide film having a crystal structure has a bilaterally asymmetrical shape. The bilaterally asymmetrical peak of the XRD spectrum clearly shows the existence of a crystal in the film or the substrate. In other words, the film or the substrate cannot be regarded as being in an amorphous state unless it has a bilaterally symmetrical peak in the XRD spectrum.

The crystal structure of a film or a substrate can be evaluated with a diffraction pattern observed by a nanobeam electron diffraction (NBED) method (such a pattern is also referred to as a nanobeam electron diffraction pattern). For example, a halo pattern is observed in the diffraction pattern of a quartz glass substrate, which indicates that quartz glass is in an amorphous state. Furthermore, not a halo pattern but a spot-like pattern is observed in the diffraction pattern of an In—Ga—Zn oxide film deposited at room temperature. This suggests that the In—Ga—Zn oxide deposited at room temperature is in an intermediate state, which is neither a single crystal nor polycrystal nor an amorphous state, and it cannot be concluded that the In—Ga—Zn oxide is in an amorphous state.

### <<Structure of Oxide Semiconductor>>

Note that oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the thickness direction of a CAAC-OS film, the normal direction of the surface where the CAAC-OS film is formed, or the normal direction of the surface of the CAAC-OS film. The crystal region refers to a region having a periodic atomic arrangement. Note that when an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the orientation of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more minute crystals (crystals each of which has a maximum diameter of less than 10 nm). In the case where the crystal region is formed of one minute crystal, the maximum diameter of the crystal region is less than 10 nm. In the case where the crystal region is formed of a large number of minute crystals, the maximum diameter of the crystal region may be approximately several tens of nanometers.

In the case of an In—Ga—Zn oxide, the CAAC-OS tends to have a layered crystal structure (also referred to as a layered structure) in which a layer containing indium (In) and oxygen (hereinafter, an In layer) and a layer containing gallium (Ga), zinc (Zn), and oxygen (hereinafter, a (Ga,Zn) layer) are stacked. Note that indium and gallium can be replaced with each other. Therefore, indium may be contained in the (Ga,Zn) layer. In addition, gallium may be contained in the In layer. Note that zinc may be contained in the In layer. Such a layered structure is observed as a lattice image in a high-resolution TEM (Transmission Electron Microscope) image, for example.

When the CAAC-OS film is subjected to structural analysis by Out-of-plane XRD measurement with an XRD apparatus using θ/2θ scanning, for example, a peak indicating c-axis alignment is detected at or around 20 of 31°. Note that the position of the peak indicating c-axis alignment (the value of 20) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of an incident electron beam passing through a sample (also referred to as a direct spot) as a symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear grain boundary cannot be observed even in the vicinity of the distortion in the CAAC-OS. That is, formation of a crystal grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

Note that a crystal structure where a clear crystal grain boundary is observed is what is called polycrystal. It is highly probable that the crystal grain boundary becomes a recombination center and captures carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a crystal grain boundary as compared with an In oxide.

The CAAC-OS is an oxide semiconductor with high crystallinity in which no clear crystal grain boundary is observed. Thus, in the CAAC-OS, a reduction in electron mobility due to the crystal grain boundary is unlikely to occur. Moreover, since the crystallinity of an oxide semiconductor might be decreased by entry of impurities, formation of defects, or the like, the CAAC-OS can also be regarded as an oxide semiconductor that has small amounts of impurities and defects (e.g., oxygen vacancies). Thus, an oxide semiconductor including the CAAC-OS is physically stable. Therefore, the oxide semiconductor including the CAAC-OS is resistant to heat and has high reliability. In addition, the CAAC-OS is also stable with respect to high temperatures in the manufacturing process (what is called thermal budget). Accordingly, the use of the CAAC-OS for the transistor including a metal oxide in its channel formation region (referred to as an OS transistor in some cases) can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a minute crystal. Note that the size of the minute crystal is, for example, greater than or equal to 1 nm and less than or equal to 10 nm, particularly greater than or equal to 1 nm and less than or equal to 3 nm; thus, the minute crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis by Out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter greater than the diameter of a nanocrystal (e.g., greater than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or less than the diameter of a nanocrystal (e.g., greater than or equal to 1 nm and less than or equal to 30 nm).

### [A-Like OS]

The a-like OS is an oxide semiconductor having a structure between those of the nc-OS and the amorphous oxide semiconductor. The a-like OS includes a void or a low-density region. That is, the a-like OS has lower crystallinity than the nc-OS and the CAAC-OS. Moreover, the a-like OS has a higher hydrogen concentration in the film than the nc-OS and the CAAC-OS.

### <<Composition of Oxide Semiconductor>>

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state where one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter also referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic ratio of In, Ga, and Zn to the metal elements contained in the CAC-OS in an In—Ga—Zn oxide are denoted by [In], [Ga], and [Zn], respectively. For example, the first region in the CAC-OS in the In—Ga—Zn oxide is a region having [In] higher than [In] in the composition of the CAC-OS film. Moreover, the second region is a region having [Ga] higher than [Ga] in the composition of the CAC-OS film. Alternatively, for example, the first region is a region having [In] higher than [In] in the second region and [Ga] lower than [Ga] in the second region. Moreover, the second region is a region having [Ga] higher than [Ga] in the first region and [In] lower than [In] in the first region.

Specifically, the first region is a region containing indium oxide, indium zinc oxide, or the like as its main component. The second region is a region containing gallium oxide, gallium zinc oxide, or the like as its main component. That is, the first region can be rephrased as a region containing In as its main component. The second region can be rephrased as a region containing Ga as its main component.

Note that a clear boundary between the first region and the second region cannot be observed in some cases.

In addition, in a material composition of a CAC-OS in an In—Ga—Zn oxide that contains In, Ga, Zn, and O, there are regions containing Ga as a main component in part of the CAC-OS and regions containing In as a main component in another part of the CAC-OS. These regions are randomly present to form a mosaic pattern. Thus, it is suggested that the CAC-OS has a structure where metal elements are unevenly distributed.

The CAC-OS can be formed by a sputtering method under a condition where a substrate is not heated, for example. In addition, in the case of forming the CAC-OS by a sputtering method, one or more selected from an inert gas (typically, argon), an oxygen gas, and a nitrogen gas are used as a deposition gas. The proportion of the flow rate of an oxygen gas in the total flow rate of the deposition gas during deposition is preferably as low as possible. For example, the proportion of the flow rate of an oxygen gas in the total flow rate of the deposition gas during deposition is higher than or equal to 0% and lower than 30%, preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide has a structure where the region containing In as its main component (the first region) and the region containing Ga as its main component (the second region) are unevenly distributed and mixed.

Here, the first region is a region having a higher conductivity than the second region. That is, when carriers flow through the first region, the conductivity of a metal oxide is exhibited. Accordingly, when the first regions are distributed in a metal oxide like a cloud, high field-effect mobility (u) can be achieved.

On the other hand, the second region is a region having a higher insulating property than the first region. That is, when the second regions are distributed in a metal oxide, off-state current can be inhibited.

Thus, in the case where the CAC-OS is used for a transistor, the complementary action of the conductivity due to the first region and the insulating property due to the second region enables the CAC-OS to have a switching function (On/Off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, a high on-state current (Ion), a high field-effect mobility (u), and favorable switching operation can be achieved.

A transistor using the CAC-OS has high reliability. Thus, the CAC-OS is most suitable for a variety of semiconductor devices such as a display device.

Oxide semiconductors have various structures with different properties. Two or more kinds among an amorphous oxide semiconductor, a polycrystalline oxide semiconductor, an a-like OS, a CAC-OS, an nc-OS, and a CAAC-OS may be included in an oxide semiconductor of one embodiment of the present invention.

### <Transistor Including Oxide Semiconductor>

Next, the case where the above oxide semiconductor is used for a transistor is described.

When the above oxide semiconductor is used for a transistor, a transistor with high field-effect mobility can be achieved. In addition, a transistor with high reliability can be achieved.

An oxide semiconductor having a low carrier concentration is preferably used for a transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon. Note that an impurity in an oxide semiconductor refers to, for example, an element other than the main components of the oxide semiconductor. For example, an element with a concentration lower than 0.1 atomic % can be regarded as an impurity.

### <Impurity>

Here, the influence of each impurity in the oxide semiconductor is described.

When silicon or carbon, which is one of Group 14 elements, is contained in the oxide semiconductor, defect states are formed in the oxide semiconductor. Thus, the concentration of silicon or carbon (the concentration obtained by SIMS) in the semiconductor is set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the oxide semiconductor, which is obtained by SIMS, is set lower than or equal to 1×10¹⁸ atoms/cm³, preferably lower than or equal to 2×10¹⁶ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor that contains nitrogen as a semiconductor is likely to have normally-on characteristics. Alternatively, when the oxide semiconductor contains nitrogen, trap states are sometimes formed. This might make the electrical characteristics of the transistor unstable. Therefore, the concentration of nitrogen in the oxide semiconductor, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor that contains hydrogen is likely to have normally-on characteristics. For this reason, hydrogen in the oxide semiconductor is preferably reduced as much as possible. Specifically, the concentration of hydrogen in the oxide semiconductor, which is obtained by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, the transistor can have stable electrical characteristics.

### <<Other Semiconductor Materials>>

The oxide 230 can be rephrased as a semiconductor layer including a channel formation region of the transistor 200. A semiconductor material that can be used for the semiconductor layer is not limited to the above metal oxides. A semiconductor material that has a band gap (a semiconductor material that is not a zero-gap semiconductor) may be used for the semiconductor layer. For example, a single element semiconductor such as silicon, a compound semiconductor such as gallium arsenide, or a layered material functioning as a semiconductor (also referred to as an atomic layer material or a two-dimensional material) is preferably used as a semiconductor material. The layered material functioning as a semiconductor is particularly suitable as a semiconductor material.

Here, in this specification and the like, the layered material generally refers to a group of materials having a layered crystal structure. In the layered crystal structure, layers formed by covalent bonding or ionic bonding are stacked with bonding such as the Van der Waals force, which is weaker than covalent bonding or ionic bonding. The layered material has high electrical conductivity in a monolayer, that is, high two-dimensional electrical conductivity. When a material that functions as a semiconductor and has high two-dimensional electrical conductivity is used for a channel formation region, a transistor having a high on-state current can be provided.

Examples of the layered material include graphene, silicene, and chalcogenide. Chalcogenide is a compound containing chalcogen. Chalcogen is a general term for elements belonging to Group 16, which includes oxygen, sulfur, selenium, tellurium, polonium, and livermorium. Examples of chalcogenide include transition metal chalcogenide and chalcogenide of Group 13 elements.

For the semiconductor layer, transition metal chalcogenide functioning as a semiconductor is preferably used, for example. Specific examples of the transition metal chalcogenide that can be used for the semiconductor layer include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

### <Method for Manufacturing Semiconductor Device>

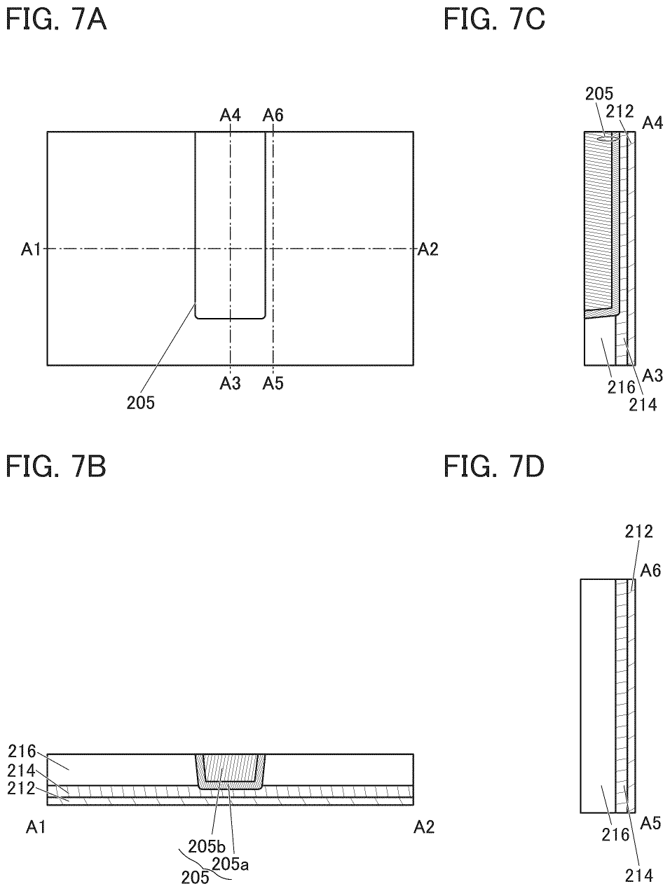

Next, a method for manufacturing the semiconductor device of one embodiment of the present invention illustrated in FIG. 1A to FIG. 1D is described with reference to FIG. 7A to FIG. 17D.

A of each figure is a top view. Moreover, B of each figure is a cross-sectional view corresponding to a portion indicated by the dashed-dotted line A1-A2 in A of each figure, and is also a cross-sectional view of the transistor 200 in the channel length direction. Furthermore, C of each figure is a cross-sectional view corresponding to a portion indicated by the dashed-dotted line A3-A4 in A of each figure, and is also a cross-sectional view of the transistor 200 in the channel width direction. Furthermore, D of each figure is a cross-sectional view of a portion indicated by the dashed-dotted line A5-A6 in A of each figure. Note that for clarity of the drawing, some components are omitted in the top view of A of each figure.

Hereinafter, an insulating material for forming an insulator, a conductive material for forming a conductor, or a semiconductor material for forming a semiconductor can be deposited by a sputtering method, a CVD method, an MBE method, a PLD method, an ALD method, or the like as appropriate.

Examples of the sputtering method include an RF sputtering method in which a high-frequency power source is used as a sputtering power source, a DC sputtering method in which a DC power source is used, and a pulsed DC sputtering method in which a voltage applied to an electrode is changed in a pulsed manner. The RF sputtering method is mainly used in the case where an insulating film is deposited, and the DC sputtering method is mainly used in the case where a metal conductive film is deposited. The pulsed DC sputtering method is mainly used in the case where a compound such as an oxide, a nitride, or a carbide is deposited by a reactive sputtering method.

Note that the CVD method can be classified into a plasma CVD (PECVD) method using plasma, a thermal CVD (TCVD) method using heat, a photo CVD method using light, and the like. Moreover, the CVD method can be classified into a metal CVD (MCVD) method and a metal organic CVD (MOCVD) method depending on a source gas to be used.

A high-quality film can be obtained at a relatively low temperature by the plasma CVD method. Furthermore, the thermal CVD method is a deposition method that does not use plasma and thus enables less plasma damage to an object to be processed. For example, a wiring, an electrode, an element (a transistor, a capacitor, or the like), or the like included in a semiconductor device may be charged up by receiving electric charge from plasma. In that case, accumulated electric charge may break the wiring, the electrode, the element, or the like included in the semiconductor device. In contrast, such plasma damage is not caused in the case of the thermal CVD method, which does use plasma, and thus the yield of the semiconductor device can be increased. In addition, the thermal CVD method does not cause plasma damage during deposition, so that a film with few defects can be obtained.

As the ALD method, a thermal ALD method, in which a precursor and a reactant react with each other only by a thermal energy, a PEALD method, in which a reactant excited by plasma is used, and the like can be used.

The CVD method and the ALD method are different from the sputtering method in which particles ejected from a target or the like are deposited. Thus, the CVD method and the ALD method are deposition methods that enable favorable step coverage almost regardless of the shape of an object to be processed. In particular, the ALD method enables excellent step coverage and excellent thickness uniformity and thus is suitable for covering a surface of an opening portion with a high aspect ratio, for example. On the other hand, the ALD method has a relatively low deposition rate, and thus is preferably used in combination with another deposition method with a high deposition rate, such as the CVD method, in some cases.

By the CVD method, a film with a certain composition can be deposited depending on the flow rate ratio of the source gases. For example, by the CVD method, a film whose composition is continuously changed can be deposited by changing the flow rate ratio of the source gases during deposition. In the case where the film is deposited while the flow rate ratio of the source gases is changed, as compared with the case where the film is deposited using a plurality of deposition chambers, the time taken for the deposition can be shortened because the time taken for transfer or pressure adjustment is not required. Thus, the productivity of the semiconductor device can be increased in some cases.

By the ALD method, a film with a freely selected composition can be deposited by concurrently introducing different kinds of precursors. In the case where different kinds of precursors are introduced, a film with a freely selected composition can be deposited by controlling the number of cycles for each of the precursors.

First, a substrate (not illustrated) is prepared, and the insulator 212 is deposited over the substrate (see FIG. 7A to FIG. 7D). The insulator 212 is preferably deposited by a sputtering method. By using a sputtering method that does not need to use a molecule containing hydrogen as a deposition gas, the hydrogen concentration in the insulator 212 can be reduced. Without limitation to a sputtering method, the insulator 212 may be deposited by a CVD method, an MBE method, a PLD method, an ALD method, or the like as appropriate.

In this embodiment, for the insulator 212, silicon nitride is deposited by a pulsed DC sputtering method using a silicon target in an atmosphere containing a nitrogen gas. The use of the pulsed DC sputtering method can inhibit generation of particles due to arcing on the target surface, achieving more uniform film thickness. In addition, by using the pulsed voltage, rising and falling in discharge can be made steep as compared with the case where a high-frequency voltage is used. As a result, power can be supplied to an electrode more efficiently to improve the sputtering rate and film quality.

The use of an insulator through which impurities such as water and hydrogen are less likely to pass, such as silicon nitride, can inhibit diffusion of impurities such as water and hydrogen contained in a layer below the insulator 212. When an insulator through which copper is less likely to pass, such as silicon nitride, is used for the insulator 212, even in the case where a metal that is likely to diffuse, such as copper, is used for a conductor (not illustrated) in a layer below the insulator 212, upward diffusion of the metal through the insulator 212 can be inhibited.

Next, the insulator 214 is deposited over the insulator 212 (see FIG. 7A to FIG. 7D). The insulator 214 is preferably deposited by a sputtering method. By using a sputtering method that does not need to use a molecule containing hydrogen as a deposition gas, the hydrogen concentration in the insulator 214 can be reduced. Without limitation to a sputtering method, the insulator 214 may be deposited by a CVD method, an MBE method, a PLD method, an ALD method, or the like as appropriate.

A metal oxide having an amorphous structure and an excellent function of capturing and fixing hydrogen, such as aluminum oxide, is preferably used for the insulator 214. In this case, the insulator 214 captures or fixes hydrogen contained in the insulator 216 and the like and prevents the hydrogen from diffusing into the oxide 230. It is particularly preferable to use aluminum oxide having an amorphous structure or amorphous aluminum oxide for the insulator 214 because hydrogen can be captured or fixed more effectively in some cases. Accordingly, the transistor 200 and the semiconductor device which have favorable characteristics and high reliability can be manufactured.

In this embodiment, for the insulator 214, aluminum oxide is deposited by a pulsed DC sputtering method using an aluminum target in an atmosphere containing an oxygen gas. The use of the pulsed DC sputtering method can achieve more uniform film thickness and improve the sputtering rate and film quality. Here, RF power may be applied to the substrate. The amount of oxygen implanted into a layer below the insulator 214 can be controlled depending on the amount of the RF power applied to the substrate. The RF power is higher than or equal to 0 W/cm² and lower than or equal to 1.86 W/cm². That is, an appropriate amount of oxygen for the transistor characteristics can be changed and implanted by RF power used for the formation of the insulator 214. Accordingly, an appropriate amount of oxygen for improving the reliability of the transistor can be implanted. The RF frequency is preferably 10 MHz or higher. The typical frequency is 13.56 MHZ. The higher the RF frequency is, the less damage the substrate receives.

Next, the insulator 216 is deposited over the insulator 214. The insulator 216 is preferably deposited by a sputtering method. By using a sputtering method that does not need to use a molecule containing hydrogen as a deposition gas, the hydrogen concentration in the insulator 216 can be reduced. Without limitation to a sputtering method, the insulator 216 may be deposited by a CVD method, an MBE method, a PLD method, an ALD method, or the like as appropriate.

In this embodiment, for the insulator 216, silicon oxide is deposited by a pulsed DC sputtering method using a silicon target in an atmosphere containing an oxygen gas. The use of the pulsed DC sputtering method can achieve more uniform film thickness and improve the sputtering rate and film quality.

The insulator 212, the insulator 214, and the insulator 216 are preferably successively deposited without exposure to the air. For example, a multi-chamber deposition apparatus is used. As a result, the amounts of hydrogen in the deposited insulator 212, insulator 214, and insulator 216 can be reduced, and furthermore, entry of hydrogen into the films in intervals between deposition steps can be inhibited.

Then, an opening reaching the insulator 214 is formed in the insulator 216. Examples of the opening include a groove and a slit. A region where an opening is formed is referred to as an opening portion in some cases. Wet etching can be used for the formation of the opening; however, dry etching is preferably used for microfabrication. As the insulator 214, it is preferable to select an insulator that functions as an etching stopper film in forming the opening by etching the insulator 216. For example, in the case where silicon oxide or silicon oxynitride is used for the insulator 216 in which the opening is to be formed, silicon nitride, aluminum oxide, or hafnium oxide is preferably used for the insulator 214.

As a dry etching apparatus, a capacitively coupled plasma (CCP) etching apparatus having parallel plate electrodes can be used. The capacitively coupled plasma etching apparatus including parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes. Alternatively, a dry etching apparatus having a high-density plasma source can be used. As the dry etching apparatus including a high-density plasma source, an inductively coupled plasma (ICP) etching apparatus or the like can be used, for example.

After the formation of the opening, a conductive film to be the conductor 205a is deposited. The conductive film desirably includes a conductor having a function of inhibiting passage of oxygen. For example, tantalum nitride, tungsten nitride, or titanium nitride can be used. Alternatively, a stacked-layer film of the conductor having a function of inhibiting passage of oxygen and tantalum, tungsten, titanium, molybdenum, aluminum, copper, or a molybdenum-tungsten alloy can be used. The conductive film can be deposited by a sputtering method, a CVD method, an MBE method, a PLD method, an ALD method, or the like.

In this embodiment, titanium nitride is deposited as the conductive film to be the conductor 205a. When such a metal nitride is used for a layer below the conductor 205b, oxidation of the conductor 205b by the insulator 216 or the like can be inhibited. Furthermore, even when a metal that is likely to diffuse, such as copper, is used for the conductor 205b, the metal can be prevented from diffusing to the outside through the conductor 205a.

Next, a conductive film to be the conductor 205b is deposited. Tantalum, tungsten, titanium, molybdenum, aluminum, copper, a molybdenum-tungsten alloy, or the like can be used for the conductive film. The conductive film can be deposited by a plating method, a sputtering method, a CVD method, an MBE method, a PLD method, an ALD method, or the like. In this embodiment, tungsten is deposited for the conductive film.

Next, by performing CMP treatment, the conductive film to be the conductor 205a and the conductive film to be the conductor 205b are partly removed to expose the insulator 216 (see FIG. 7A to FIG. 7D). As a result, the conductor 205a and the conductor 205b remain only in the opening portion. Note that the insulator 216 is partly removed by the CMP treatment in some cases.

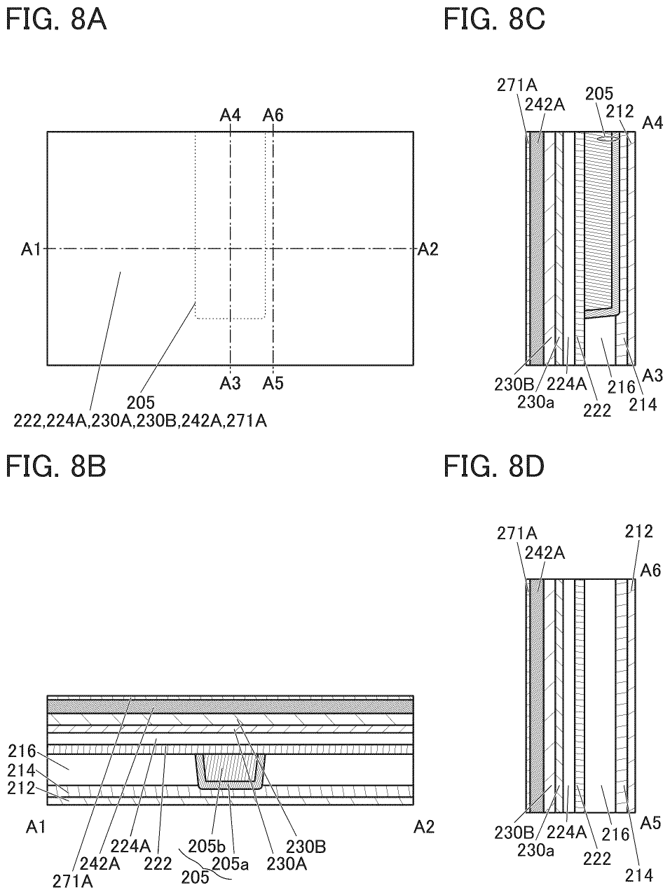

Next, the insulator 222 is deposited over the insulator 216 and the conductor 205 (see FIG. 8A to FIG. 8D). An insulator containing an oxide of one or both of aluminum and hafnium is preferably deposited as the insulator 222. Note that as the insulator containing an oxide of one or both of aluminum and hafnium, aluminum oxide, hafnium oxide, an oxide containing aluminum and hafnium (hafnium aluminate), or the like is preferably used. Alternatively, hafnium-zirconium oxide is preferably used. The insulator containing an oxide of one or both of aluminum and hafnium has a barrier property against oxygen, hydrogen, and water. When the insulator 222 has a barrier property against hydrogen and water, hydrogen and water contained in components provided around the transistor 200 are inhibited from diffusing into the transistor 200 through the insulator 222, and generation of oxygen vacancies in the oxide 230 can be inhibited.

The insulator 222 can be deposited by a sputtering method, a CVD method, an MBE method, a PLD method, an ALD method, or the like. In this embodiment, for the insulator 222, hafnium oxide is deposited by an ALD method.

Subsequently, heat treatment is preferably performed. The heat treatment is performed at higher than or equal to 250° C. and lower than or equal to 650° C., preferably higher than or equal to 300° C. and lower than or equal to 500° C., further preferably higher than or equal to 320° C. and lower than or equal to 450° C. Note that the heat treatment is performed in a nitrogen gas or inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is approximately 20%. The heat treatment may be performed under reduced pressure. Alternatively, the heat treatment may be performed in an atmosphere containing an oxidizing gas at 10 ppm or more, 1% or more, or 10% or more in order to compensate for oxygen released, after heat treatment is performed in a nitrogen gas or inert gas atmosphere.

The gas used in the above heat treatment is preferably highly purified. For example, the amount of moisture contained in the gas used in the above heat treatment is 1 ppb or less, preferably 0.1 ppb or less, further preferably 0.05 ppb or less. The heat treatment using a highly purified gas can prevent entry of moisture or the like into the insulator 222 and the like as much as possible.

In this embodiment, as the heat treatment, treatment is performed at 400° C. for one hour with a flow rate ratio of a nitrogen gas to an oxygen gas of 4:1 after the deposition of the insulator 222. Through the heat treatment, impurities such as water and hydrogen contained in the insulator 222 can be removed, for example. In the case where an oxide containing hafnium is used for the insulator 222, the insulator 222 is partly crystallized by the heat treatment in some cases. The heat treatment can also be performed after the deposition of an insulating film to be the insulator 224, for example.

Next, an insulating film 224A is deposited over the insulator 222 (see FIG. 8A to FIG. 8D). The insulating film 224A can be deposited by a sputtering method, a CVD method, an MBE method, a PLD method, an ALD method, or the like. In this embodiment, for the insulating film 224A, silicon oxide is deposited by a sputtering method. By using a sputtering method that does not need to use a molecule containing hydrogen as a deposition gas, the hydrogen concentration in the insulating film 224A can be reduced. The hydrogen concentration in the insulating film 224A is preferably reduced in this manner because the insulating film 224A is in contact with the oxide 230a in a later step.

Next, an oxide film 230A and an oxide film 230B are deposited in this order over the insulating film 224A (see FIG. 8A to FIG. 8D). The oxide film 230A is a metal oxide film to be the oxide 230a, and the oxide film 230B is a metal oxide film to be the oxide 230b. Note that the oxide film 230A and the oxide film 230B are preferably deposited successively without being exposed to an atmospheric environment. By the deposition without exposure to the atmosphere, impurities or moisture from the atmospheric environment can be prevented from being attached onto the oxide film 230A and the oxide film 230B, so that the vicinity of an interface between the oxide film 230A and the oxide film 230B can be kept clean.

The oxide film 230A and the oxide film 230B can be deposited by a sputtering method, a CVD method, an MBE method, a PLD method, an ALD method, or the like. In this embodiment, the oxide film 230A and the oxide film 230B are deposited by a sputtering method.

For example, in the case where the oxide film 230A and the oxide film 230B are deposited by a sputtering method, oxygen or a mixed gas of oxygen and a noble gas is used as a sputtering gas. Increasing the proportion of oxygen contained in the sputtering gas can increase the amount of excess oxygen in the deposited oxide films. In the case where the oxide films are deposited by a sputtering method, the above In-M-Zn oxide target or the like can be used.

In particular, when the oxide film 230A is deposited, part of oxygen contained in the sputtering gas is supplied to the insulator 224 in some cases. Thus, the proportion of oxygen contained in the sputtering gas is higher than or equal to 70%, preferably higher than or equal to 80%, further preferably 100%.

In the case where the oxide film 230B is formed by a sputtering method and the proportion of oxygen contained in the sputtering gas for deposition is higher than 30% and lower than or equal to 100%, preferably higher than or equal to 70% and lower than or equal to 100%, an oxygen-excess oxide semiconductor is formed. In a transistor including an oxygen-excess oxide semiconductor for its channel formation region, relatively high reliability can be obtained. Note that one embodiment of the present invention is not limited thereto. In the case where the oxide film 230B is formed by a sputtering method and the proportion of oxygen contained in the sputtering gas for deposition is higher than or equal to 1% and lower than or equal to 30%, preferably higher than or equal to 5% and lower than or equal to 20%, an oxygen-deficient oxide semiconductor is formed. In a transistor including an oxygen-deficient oxide semiconductor for its channel formation region, relatively high field-effect mobility can be obtained. Furthermore, when the deposition is performed while the substrate is being heated, the crystallinity of the oxide film can be improved.

In this embodiment, the oxide film 230A is deposited by a sputtering method using an oxide target with In:Ga:Zn=1:3:4 [atomic ratio]. In addition, the oxide film 230B is deposited by a sputtering method using an oxide target with In:Ga:Zn=4:2:4.1 [atomic ratio], an oxide target with In:Ga:Zn=1:1:1 [atomic ratio], an oxide target with In:Ga:Zn=1:1:1.2 [atomic ratio], or an oxide target with In:Ga:Zn=1:1:2 [atomic ratio]. Note that each of the oxide films is preferably formed so as to have characteristics required for the oxide 230a and the oxide 230b by selecting the deposition conditions and the atomic ratios as appropriate.

Note that the insulating film 224A, the oxide film 230A, and the oxide film 230B are preferably deposited by a sputtering method without exposure to the air. For example, a multi-chamber deposition apparatus is used. As a result, entry of hydrogen into the insulating film 224A, the oxide film 230A, and the oxide film 230B in intervals between deposition steps can be inhibited.

Next, heat treatment is preferably performed. The heat treatment is performed in a temperature range where the oxide film 230A and the oxide film 230B do not become polycrystals, i.e., at higher than or equal to 250° C. and lower than or equal to 650° C., preferably higher than or equal to 400° C. and lower than or equal to 600° C. Note that the heat treatment is performed in a nitrogen gas or inert gas atmosphere, or an atmosphere containing an oxidizing gas at 10 ppm or more, 1% or more, or 10% or more. For example, the heat treatment is preferably performed in an oxygen atmosphere. Accordingly, oxygen can be supplied to the oxide film 230A and the oxide film 230B to reduce oxygen vacancies. For example, in the case where the heat treatment is performed in a mixed atmosphere of a nitrogen gas and an oxygen gas, the proportion of the oxygen gas is approximately 20%. The heat treatment may be performed under reduced pressure. Alternatively, the heat treatment may be performed in an atmosphere containing an oxidizing gas at 10 ppm or more, 1% or more, or 10% or more in order to compensate for oxygen released, after heat treatment is performed in a nitrogen gas or inert gas atmosphere. Alternatively, the heat treatment may be performed in a nitrogen gas or inert gas atmosphere successively after heat treatment is performed in an atmosphere containing an oxidizing gas at 10 ppm or more, 1% or more, or 10% or more.

Note that by oxygen adding treatment performed on the oxide 230, oxygen vacancies in the oxide 230 can be repaired with supplied oxygen. Furthermore, hydrogen remaining in the oxide 230 reacts with supplied oxygen, so that the hydrogen can be removed as H₂O (dehydration). This can inhibit recombination of hydrogen remaining in the oxide 230 with oxygen vacancies and formation of V_{O}H.

The gas used in the above heat treatment is preferably highly purified. For example, the amount of moisture contained in the gas used in the above heat treatment is 1 ppb or less, preferably 0.1 ppb or less, further preferably 0.05 ppb or less. The heat treatment using a highly purified gas can prevent entry of moisture or the like into the oxide film 230A, the oxide film 230B, and the like as much as possible.

In this embodiment, the heat treatment is performed at 400° C. for one hour with a flow rate ratio of a nitrogen gas to an oxygen gas being 4:1. Through such heat treatment using the oxygen gas, impurities such as water and hydrogen in the oxide film 230A and the oxide film 230B can be reduced, for example. The reduction of impurities in the films in this manner improves the crystallinity of the oxide film 230B, thereby offering a dense structure with a higher density. Thus, crystalline regions in the oxide film 230A and the oxide film 230B are expanded, so that in-plane variations of the crystalline regions in the oxide film 230A and the oxide film 230B can be reduced. Accordingly, an in-plane variation of electrical characteristics of the transistor 200 can be reduced.

By performing the heat treatment, hydrogen in the insulator 216, the insulating film 224A, the oxide film 230A, and the oxide film 230B moves into the insulator 222 and is absorbed by the insulator 222. In other words, hydrogen in the insulator 216, the insulating film 224A, the oxide film 230A, and the oxide film 230B diffuses into the insulator 222. Accordingly, the hydrogen concentration in the insulator 222 increases, while the hydrogen concentrations in the insulator 216, the insulating film 224A, the oxide film 230A, and the oxide film 230B decrease.

In particular, the insulating film 224A functions as a gate insulator of the transistor 200, and the oxide film 230A and the oxide film 230B function as a channel formation region of the transistor 200. Thus, the transistor 200 preferably includes the insulating film 224A, the oxide film 230A, and the oxide film 230B with reduced hydrogen concentrations because favorable reliability can be obtained.

Next, a conductive film 242A is deposited over the oxide film 230B (see FIG. 8A to FIG. 8D). The conductive film 242A can be deposited by a sputtering method, a CVD method, an MBE method, a PLD method, an ALD method, or the like. For example, as the conductive film 242A, a tantalum nitride film is deposited by a sputtering method. Note that heat treatment may be performed before the deposition of the conductive film 242A. This heat treatment may be performed under reduced pressure, and the conductive film 242A may be successively deposited without exposure to the air. Such treatment can remove moisture and hydrogen adsorbed onto the surface of the oxide film 230B, and further can reduce the moisture concentration and the hydrogen concentration in the oxide film 230A and the oxide film 230B. The heat treatment is preferably performed at a temperature higher than or equal to 100° C. and lower than or equal to 400° C. In this embodiment, the heat treatment is performed at 200° C.

Next, an insulating film 271A is deposited over the conductive film 242A (see FIG. 8A to FIG. 8D). The insulating film 271A can be deposited by a sputtering method, a CVD method, an MBE method, a PLD method, an ALD method, or the like. As the insulating film 271A, an insulating film having a function of inhibiting passage of oxygen is preferably used. For example, as the insulating film 271A, an aluminum oxide film or a silicon nitride film is deposited by a sputtering method. Alternatively, for example, a silicon nitride film and a silicon oxide film over the silicon nitride film may be deposited as the insulating film 271A by a sputtering method.

Note that the conductive film 242A and the insulating film 271A are preferably deposited by a sputtering method without exposure to the air. For example, a multi-chamber deposition apparatus is used. As a result, the amounts of hydrogen in the conductive film 242A and the insulating film 271A can be reduced, and furthermore, entry of hydrogen into the films in intervals between deposition steps can be inhibited. In the case where a hard mask is provided over the insulating film 271A, a film to be the hard mask is successively deposited without exposure to the air.

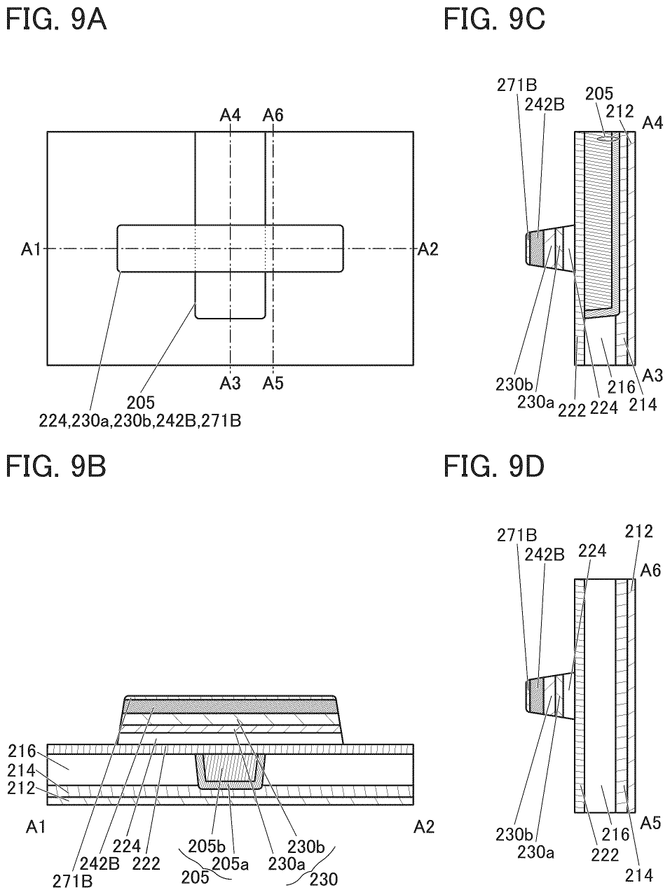

Next, the insulating film 224A, the oxide film 230A, the oxide film 230B, the conductive film 242A, and the insulating film 271A are processed into island shapes by a lithography method to form the insulator 224, the oxide 230a, the oxide 230b, a conductive layer 242B, and an insulating layer 271B (see FIG. 9A to FIG. 9D). Here, the insulator 224, the oxide 230a, the oxide 230b, the conductive layer 242B, and the insulating layer 271B are formed to at least partly overlap with the conductor 205. A dry etching method or a wet etching method can be used for the processing. Processing by a dry etching method is suitable for microfabrication. The insulating film 224A, the oxide film 230A, the oxide film 230B, the conductive film 242A, and the insulating film 271A may be processed under different conditions.

Note that in the lithography method, first, a resist is exposed to light through a mask. Next, a region exposed to light is removed or left using a developing solution, so that a resist mask is formed. Then, etching treatment through the resist mask is conducted, whereby a conductor, a semiconductor, an insulator, or the like can be processed into a desired shape. The resist mask is formed through, for example, exposure of the resist to KrF excimer laser light, ArF excimer laser light, EUV (Extreme Ultraviolet) light, or the like. A liquid immersion technique may be employed in which a gap between a substrate and a projection lens is filled with a liquid (e.g., water) in light exposure. An electron beam or an ion beam may be used instead of the light. Note that a mask is unnecessary in the case of using an electron beam or an ion beam. Note that the resist mask can be removed by dry etching treatment such as ashing, wet etching treatment, wet etching treatment after dry etching treatment, or dry etching treatment after wet etching treatment.

In addition, a hard mask formed of an insulator or a conductor may be used under the resist mask. In the case of using a hard mask, a hard mask with a desired shape can be formed in the following manner: an insulating film or a conductive film that is the material of the hard mask is formed over the conductive film 242A, a resist mask is formed thereover, and then the hard mask material is etched. The etching of the conductive film 242A and the like may be performed after removing the resist mask or with the resist mask remaining. In the latter case, the resist mask sometimes disappears during the etching. The hard mask may be removed by etching after 20) the etching of the conductive film 242A and the like. Meanwhile, the hard mask is not necessarily removed when the hard mask material does not affect later steps or can be utilized in later steps. In this embodiment, the insulating layer 271B is used as a hard mask.

Here, the insulating layer 271B functions as a mask for the conductive layer 242B; thus, as illustrated in FIG. 9B to FIG. 9D, the conductive layer 242B does not have a curved surface between the side surface and the top surface. Thus, end portions at the intersections of the side surfaces and the top surfaces of the conductor 242a and the conductor 242b illustrated in FIG. 1B and FIG. 1D are angular. The cross-sectional area of the conductor 242 is larger in the case where the end portion at the intersection of the side surface and the top surface of the conductor 242 is angular than that in the case where the end portion is rounded. Accordingly, the resistance of the conductor 242 is reduced, so that the on-state current of the transistor 200 can be increased.

Furthermore, as illustrated in FIG. 9B to FIG. 9D, the side surfaces of the insulator 224, the oxide 230a, the oxide 230b, the conductive layer 242B, and the insulating layer 271B may have tapered shapes. Note that in this specification and the like, a tapered shape refers to a shape such that at least part of a side surface of a component is inclined to a substrate surface. For example, the angle formed between the inclined side surface and the substrate surface (the angle is also referred to as a taper angle) is preferably less than 90°. The side surfaces of the insulator 224, the oxide 230a, the oxide 230b, the conductive layer 242B, and the insulating layer 271B have a taper angle greater than or equal to 60° and less than 90°, for example. With such tapered shapes of the side surfaces, the coverage with the insulator 275 and the like can be improved in a later step, so that defects such as a void can be reduced.

Not being limited to the above, the insulator 224, the oxide 230a, the oxide 230b, the conductive layer 242B, and the insulating layer 271B may be processed to have side surfaces that are substantially perpendicular to the top surface of the insulator 222. With such a structure, a plurality of the transistors 200 can be provided with high density in a small area.

A by-product generated in the above etching step is sometimes formed in a layered manner on the side surfaces of the insulator 224, the oxide 230a, the oxide 230b, the conductive layer 242B, and the insulating layer 271B. In this case, the layered by-product is formed between the insulator 275 and the insulator 224, the oxide 230a, the oxide 230b, the conductive layer 242B, and the insulating layer 271B. Hence, the layered by-product formed in contact with the top surface of the insulator 222 is preferably removed.

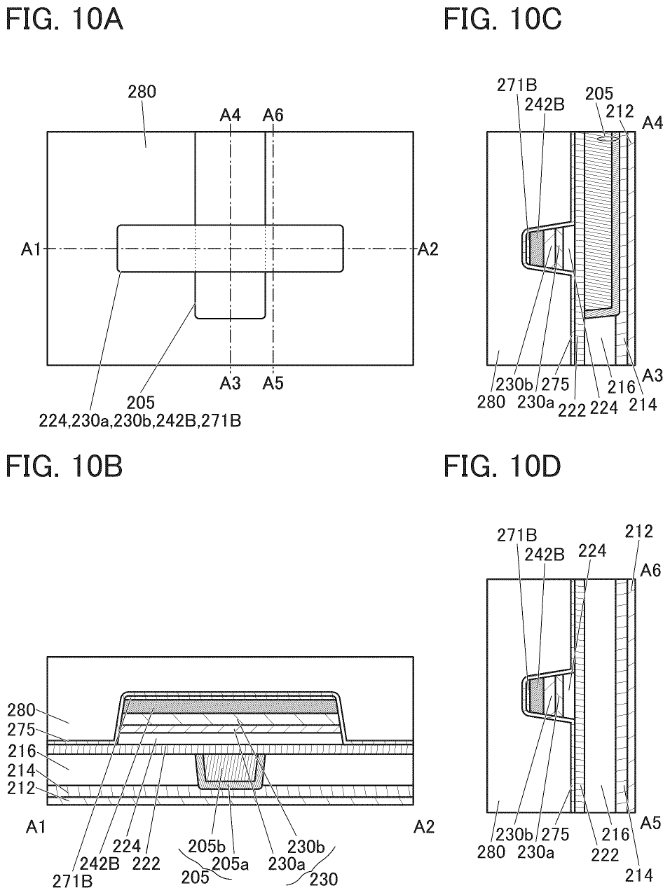

Next, the insulator 275 is deposited to cover the insulator 224, the oxide 230a, the oxide 230b, the conductive layer 242B, and the insulating layer 271B (see FIG. 10A to FIG. 10D). Here, it is preferable that the insulator 275 be in contact with the top surface of the insulator 222 and the side surface of the insulator 224. The insulator 275 can be deposited by a sputtering method, a CVD method, an MBE method, a PLD method, an ALD method, or the like. As the insulator 275, an insulating film having a function of inhibiting passage of oxygen is preferably used. For example, silicon nitride is deposited as the insulator 275 by an ALD method. Alternatively, as the insulator 275, aluminum oxide is deposited by a sputtering method, and silicon nitride is deposited thereover by a PEALD method. When the insulator 275 has such a stacked-layer structure, the function of inhibiting diffusion of oxygen and impurities such as water and hydrogen is improved in some cases.

In this manner, the insulator 224, the oxide 230a, the oxide 230b, and the conductive layer 242B can be covered with the insulator 275 and the insulating layer 271B, which have a function of inhibiting diffusion of oxygen. This can reduce direct diffusion of oxygen from the insulator 280 into the insulator 224, the oxide 230a, the oxide 230b, and the conductive layer 242B in a later step.

Next, an insulating film to be the insulator 280 is deposited over the insulator 275. The insulating film can be deposited by a sputtering method, a CVD method, an MBE method, a PLD method, an ALD method, or the like. A silicon oxide film is deposited by a sputtering method as the insulating film, for example. When the insulating film is deposited by a sputtering method in an oxygen-containing atmosphere, the insulator 280 containing excess oxygen can be formed. By using a sputtering method that does not need to use a molecule containing hydrogen as a deposition gas, the hydrogen concentration in the insulator 280 can be reduced. Note that heat treatment may be performed before the deposition of the insulating film. The heat treatment may be performed under reduced pressure, and the insulating film may be successively deposited without exposure to the air. Such treatment can remove moisture and hydrogen adsorbed onto the surface of the insulator 275 and the like, and further can reduce the moisture concentration and the hydrogen concentration in the oxide 230a, the oxide 230b, and the insulator 224. For the heat treatment, the above heat treatment conditions can be used.

Next, the insulating film to be the insulator 280 is subjected to CMP treatment, so that the insulator 280 with a flat top surface is formed (see FIG. 10A to FIG. 10D). Note that, for example, silicon nitride may be deposited over the insulator 280 by a sputtering method and CMP treatment may be performed on the silicon nitride until the insulator 280 is reached.

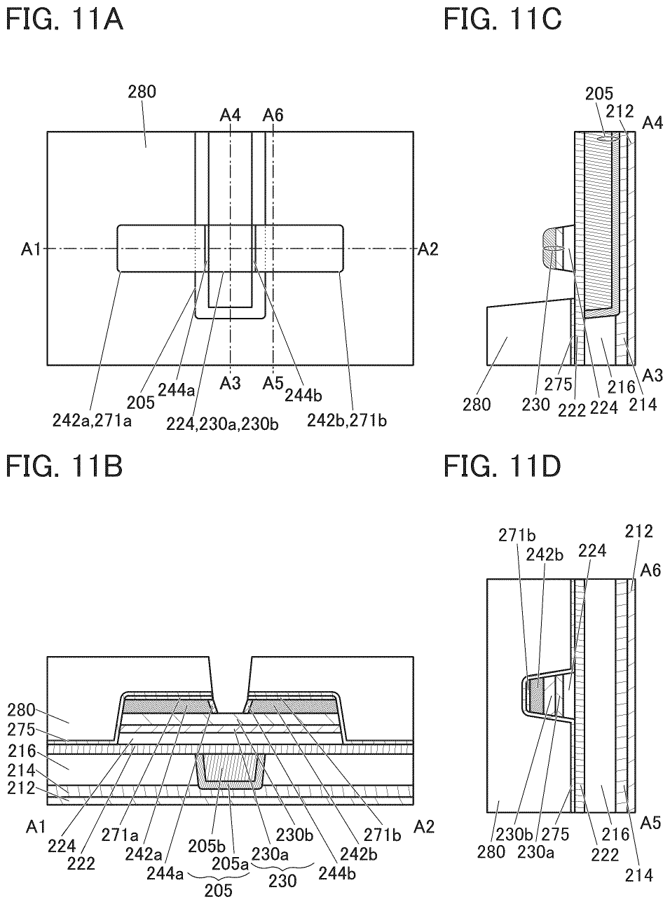

Then, part of the insulator 280, part of the insulator 275, part of the insulating layer 271B, and part of the conductive layer 242B are processed to form an opening reaching the oxide 230b. The opening is preferably formed to overlap with the conductor 205. The insulator 271a, the insulator 271b, the conductor 242a, and the conductor 242b are formed through the formation of the opening (see FIG. 11A to FIG. 11D).

Here, as illustrated in FIG. 11B and FIG. 11C, the side surfaces of the insulator 280, the insulator 275, the insulator 271, and the conductor 242 may be tapered. The taper angle of the insulator 280 is larger than that of the conductor 242 in some cases. Although not illustrated in FIG. 11A to FIG. 11C, the upper portion of the oxide 230b is removed in some cases when the opening is formed. When part of the oxide 230b is removed, a groove portion is sometimes formed in the oxide 230b.

The part of the insulator 280, the part of the insulator 275, the part of the insulating layer 271B, and the part of the conductive layer 242B can be processed by a dry etching method or a wet etching method. Processing by a dry etching method is suitable for microfabrication. The processing may be performed under different conditions. For example, the part of the insulator 280 may be processed by a dry etching method, the part of the insulator 275 and the part of the insulating layer 271B may be processed by a wet etching method, and the part of the conductive layer 242B may be processed by a dry etching method.

In the case where silicon nitride is used for the insulator 275 and silicon oxide is used for the insulator 280, the insulator 275 can function as an etching stopper in forming the opening in the insulator 280. Thus, an extremely minute transistor (a transistor having a small gate length and a small channel width) can be manufactured.

In forming the opening reaching the oxide 230b, the side surface of the conductor 242a is oxidized to form the insulator 244a in some cases. Furthermore, the side surface of the conductor 242b is oxidized to form the insulator 244b in some cases. Note that the lengths of the insulator 244a and the insulator 244b in the channel length direction change depending on the processing conditions for forming the opening.

A dry etching apparatus used for forming the conductor 242a and the conductor 242b has a function of eliminating static electricity accumulated on a substrate during etching. That is, plasma treatment is performed with power lower than that in the formation of the conductor 242a and the conductor 242b after the etching treatment for forming the conductor 242a and the conductor 242b is completed, whereby static electricity accumulated on the substrate is eliminated. This plasma treatment is referred to as static neutralization plasma treatment. For example, in the case where nitrogen is used in the static neutralization plasma treatment, the lengths of the insulator 244a and the insulator 244b in the channel length direction tend to be smaller than those in the case where oxygen is used in the static neutralization plasma treatment.

Here, impurities are attached onto the side surface of the oxide 230a, the top surface and the side surface of the oxide 230b, the side surface of the conductor 242, the side surface of the insulator 280, and the like or the impurities might be diffused thereinto in some cases. A step of removing such impurities may be performed. In addition, a damaged region might be formed on the surface of the oxide 230b by the above dry etching. Such a damaged region may be removed. The impurities come from components contained in the insulator 280, the insulator 275, part of the insulating layer 271B, and the conductive layer 242B; components contained in a member of an apparatus used to form the opening; and components contained in a gas or a liquid used for etching, for instance. Examples of the impurities include hafnium, silicon, tantalum, fluorine, and chlorine.

In particular, impurities such as silicon might reduce the crystallinity of the oxide 230b. Thus, it is preferable that impurities such as silicon be removed from the surface of the oxide 230b and the vicinity thereof. The concentration of the impurities is preferably reduced. For example, the concentration of silicon atoms at the surface of the oxide 230b and the vicinity thereof is lower than or equal to 5.0 atomic %, preferably lower than or equal to 2.0 atomic %, further preferably lower than or equal to 1.5 atomic %, still further preferably lower than or equal to 1.0 atomic %, and yet further preferably lower than 0.3 atomic %.

Note that since the density of a crystal structure is reduced in a low-crystallinity region of the oxide 230b due to impurities such as silicon, a large amount of V_{O}H is formed; thus, the transistor is likely to be normally on. Hence, the low-crystallinity region of the oxide 230b is preferably reduced or removed.

In contrast, the oxide 230b preferably has a layered CAAC structure. In particular, the CAAC structure preferably reaches a lower end portion of a drain in the oxide 230b. Here, in the transistor 200, the conductor 242a or the conductor 242b, and its vicinity function as a drain. In other words, the oxide 230b in the vicinity of the lower end portion of the conductor 242a or the conductor 242b preferably has a CAAC structure. In this manner, the low-crystallinity region of the oxide 230b is removed and the CAAC structure is formed also in the end portion of the drain, which significantly affects the drain withstand voltage, so that a variation in electrical characteristics of the transistor 200 can be further suppressed. In addition, the reliability of the transistor 200 can be improved.

In order to remove impurities and the like attached to the surface of the oxide 230b in the above etching step, cleaning treatment is performed. Examples of the cleaning method include wet cleaning using a cleaning solution or the like (which can also be referred to as wet etching treatment), plasma treatment using plasma, and cleaning by heat treatment, and any of these cleanings may be performed in appropriate combination. Note that the cleaning treatment sometimes makes the groove portion deeper.

The cleaning treatment may be performed using an aqueous solution in which ammonia water, oxalic acid, phosphoric acid, hydrofluoric acid, or the like is diluted with carbonated water or pure water; pure water; carbonated water; or the like. Alternatively, ultrasonic cleaning using such an aqueous solution, pure water, or carbonated water may be performed. Alternatively, such cleaning methods may be performed in combination as appropriate.

Note that in this specification and the like, in some cases, an aqueous solution in which hydrofluoric acid is diluted with pure water is referred to as diluted hydrofluoric acid, and an aqueous solution in which ammonia water is diluted with pure water is referred to as diluted ammonia water. The concentration, temperature, and the like of the aqueous solution are adjusted as appropriate in accordance with an impurity to be removed, the structure of a semiconductor device to be cleaned, or the like. The concentration of ammonia in the diluted ammonia water is higher than or equal to 0.01% and lower than or equal to 5%, preferably higher than or equal to 0.1% and lower than or equal to 0.5%. The concentration of hydrogen fluoride in the diluted hydrofluoric acid is higher than or equal to 0.01 ppm and lower than or equal to 100 ppm, preferably higher than or equal to 0.1 ppm and lower than or equal to 10 ppm.

For the ultrasonic cleaning, a frequency higher than or equal to 200 kHz is preferable, and a frequency higher than or equal to 900 kHz is further preferable. Damage to the oxide 230b and the like can be reduced with this frequency.

The cleaning treatment may be performed a plurality of times, and the cleaning solution may be changed in every cleaning treatment. For example, first cleaning treatment may use diluted hydrofluoric acid or diluted ammonia water, and second cleaning treatment may use pure water or carbonated water.

As the cleaning treatment in this embodiment, wet cleaning using diluted ammonia water is performed. The cleaning treatment can remove impurities that are attached onto the surfaces of the oxide 230a, the oxide 230b, and the like or diffused into the oxide 230a, the oxide 230b, and the like. Furthermore, the crystallinity of the oxide 230b can be increased.

After the etching or the cleaning, heat treatment may be performed. The heat treatment is performed at higher than or equal to 100° C. and lower than or equal to 450° C., preferably higher than or equal to 350° C. and lower than or equal to 400° C. Note that the heat treatment is performed in a nitrogen gas or inert gas atmosphere, or an atmosphere containing an oxidizing gas at 10 ppm or more, 1% or more, or 10% or more. For example, the heat treatment is preferably performed in an oxygen atmosphere. Accordingly, oxygen can be supplied to the oxide 230a and the oxide 230b to reduce oxygen vacancies. In addition, the crystallinity of the oxide 230b can be improved by such heat treatment. The heat treatment may be performed under reduced pressure. Alternatively, heat treatment may be performed in an oxygen atmosphere, and then heat treatment may be successively performed in a nitrogen atmosphere without exposure to the air.

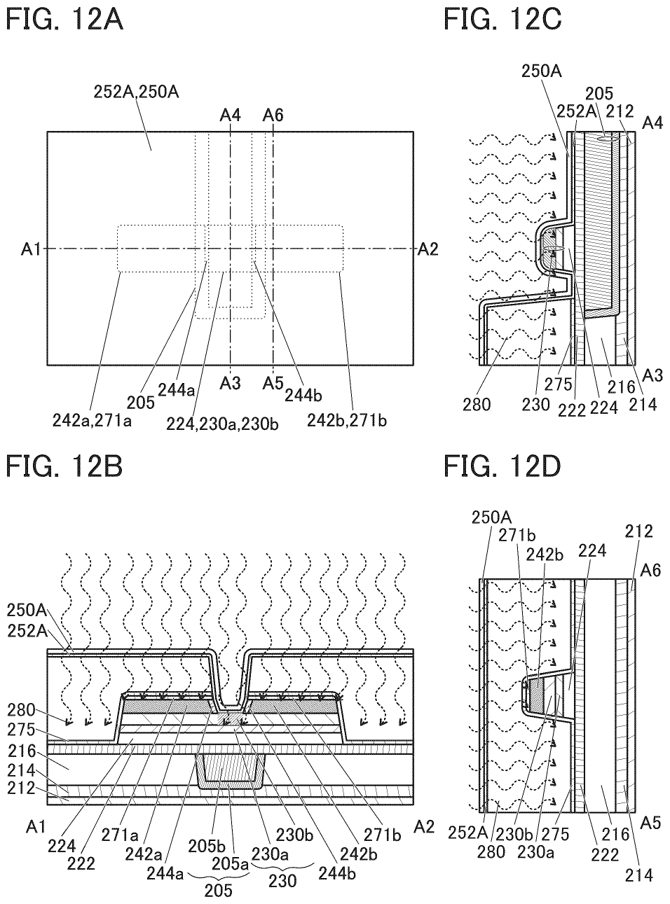

Next, an insulating film 252A is deposited (see FIG. 12A to FIG. 12D). The insulating film 252A can be deposited by a sputtering method, a CVD method, an MBE method, a PLD method, an ALD method, or the like. The insulating film 252A is preferably deposited by an ALD method. As described above, it is preferable to deposit the insulating film 252A to have a small thickness, and a variation in the film thickness needs to be reduced. Since an ALD method is a deposition method in which a precursor and a reactant (e.g., oxidizer) are alternately introduced and the film thickness can be adjusted with the number of repetition times of the cycle, accurate control of the film thickness is possible. Furthermore, as illustrated in FIG. 12B and FIG. 12C, the insulating film 252A needs to be deposited on the bottom surface and the side surface of the opening formed in the insulator 280 and the like so as to have good coverage. In particular, it is preferable that the insulating film 252A be deposited on the top surface and the side surface of the oxide 230 and the side surface of the conductor 242, with good coverage. An atomic layer can be deposited one by one on the bottom surface and the side surface of the opening, whereby the insulating film 252A can be deposited in the opening with good coverage.

When the insulating film 252A is deposited by an ALD method, ozone (O₃), oxygen (O₂), water (H₂O), or the like can be used as the oxidizer. When an oxidizer without containing hydrogen, such as ozone (O₃) or oxygen (O₂), is used, the amount of hydrogen diffusing into the oxide 230b can be reduced.

In this embodiment, aluminum oxide is deposited as the insulating film 252A by a thermal ALD method.

Note that the lengths of the insulator 244a and the insulator 244b in the channel length direction are increased by the deposition of the insulating film 252A in some cases. Note that in the case where the insulator 244a and the insulator 244b are not formed before the deposition of the insulating film 252A, the side surface of the conductor 242a is oxidized during the deposition of the insulating film 252A to form the insulator 244a in some cases. Furthermore, the side surface of the conductor 242b is oxidized to form the insulator 244b in some cases.

Next, an insulating film 250A is deposited (see FIG. 12A to FIG. 12D). Heat treatment may be performed before the deposition of the insulating film 250A; the heat treatment may be performed under reduced pressure, and the insulating film 250A may be successively deposited without exposure to the air. The heat treatment is preferably performed in an oxygen-containing atmosphere. Such treatment can remove moisture and hydrogen adsorbed onto the surface of the insulating film 252A and the like, and further can reduce the moisture concentration and the hydrogen concentration in the oxide 230a and the oxide 230b. The heat treatment is preferably performed at a temperature higher than or equal to 100° C. and lower than or equal to 400° C.

The insulating film 250A can be deposited by a sputtering method, a CVD method, a PECVD method, an MBE method, a PLD method, an ALD method, or the like. The insulating film 250A is preferably deposited by a deposition method using a gas in which hydrogen atoms are reduced or removed. This can reduce the hydrogen concentration in the insulating film 250A. The hydrogen concentration in the insulating film 250A is preferably reduced because the insulating film 250A becomes the insulator 250 that faces the oxide 230b with the insulator 252 with a small thickness therebetween, in a later step.

In this embodiment, silicon oxynitride is deposited for the insulating film 250A by a PECVD method.

Note that the lengths of the insulator 244a and the insulator 244b in the channel length direction are increased by the deposition of the insulating film 250A in some cases. Note that in the case where the insulator 244a and the insulator 244b are not formed before the deposition of the insulating film 250A, the side surface of the conductor 242a is oxidized during the deposition of the insulating film 250A to form the insulator 244a in some cases. Furthermore, the side surface of the conductor 242b is oxidized to form the insulator 244b in some cases.

Next, it is preferable to perform microwave treatment in an atmosphere containing oxygen. Here, the microwave treatment refers to, for example, treatment using an apparatus including a power source that generates high-density plasma with the use of a microwave. In this specification and the like, a microwave refers to an electromagnetic wave having a frequency greater than or equal to 300 MHz and less than or equal to 300 GHZ.

Dotted lines in FIG. 12B to FIG. 12D indicate high-frequency waves such as microwaves or RF, oxygen plasma, oxygen radicals, or the like. The microwave treatment is preferably performed with a microwave treatment apparatus including a power source for generating high-density plasma using microwaves, for example. Here, the frequency of the microwave treatment apparatus is set to greater than or equal to 300 MHz and less than or equal to 300 GHZ, preferably greater than or equal to 2.4 GHZ and less than or equal to 2.5 GHZ, for example, 2.45 GHZ. Oxygen radicals at a high density can be generated with high-density plasma. The electric power of the power source that applies microwaves of the microwave treatment apparatus is set to higher than or equal to 1000 W and lower than or equal to 10000 W, preferably higher than or equal to 2000 W and lower than or equal to 5000 W. The microwave treatment apparatus may be provided with a power source that applies RF to the substrate side. Furthermore, application of RF to the substrate side allows oxygen ions generated by the high-density plasma to be introduced into the oxide 230b efficiently.

The microwave treatment is preferably performed under reduced pressure, and the pressure is set to higher than or equal to 10 Pa and lower than or equal to 1000 Pa, preferably higher than or equal to 300 Pa and lower than or equal to 700 Pa. The treatment temperature is set to lower than or equal to 750° C., preferably lower than or equal to 500° C., and is approximately 250° C., for example. The oxygen plasma treatment can be followed successively by heat treatment without exposure to air. For example, the temperature is set to higher than or equal to 100° C. and lower than or equal to 750° C., preferably higher than or equal to 300° C. and lower than or equal to 500° C.

Furthermore, the microwave treatment is performed using an oxygen gas and an argon gas, for example. Here, the oxygen flow rate ratio (O₂/(O₂+Ar)) is higher than 0% and lower than or equal to 100%, preferably higher than 0) % and lower than or equal to 50%, further preferably higher than or equal to 10% and lower than or equal to 40%, or still further preferably higher than or equal to 10% and lower than or equal to 30%. The carrier concentration in the region 230bc can be reduced by thus performing the microwave treatment in an atmosphere containing oxygen. In addition, the carrier concentrations in the region 230ba and the region 230bb can be prevented from being excessively reduced by preventing an excess amount of oxygen from being introduced into the chamber in the microwave treatment.

As illustrated in FIG. 12B to FIG. 12D, the microwave treatment in an oxygen-containing atmosphere can convert an oxygen gas into plasma using a high-frequency wave such as a microwave or RF, and apply the oxygen plasma to a region of the oxide 230b which is between the conductor 242a and the conductor 242b. At this time, the region 230bc can also be irradiated with the high-frequency wave such as a microwave or RF. In other words, the high-frequency wave such as a microwave or RF, the oxygen plasma, or the like can be applied to the region 230bc illustrated in FIG. 2. By the effect of the plasma, the microwave, or the like, V_{O}H in the region 230bc can be divided into an oxygen vacancy (V_{O}) and hydrogen (H). That is, the reaction “V_{O}H→H+V_{O}” occurs in the region 230bc, so that V_{O}H contained in the region 230bc can be reduced. In addition, oxygen radicals generated by the oxygen plasma or oxygen contained in the insulator 250 can be supplied to oxygen vacancies in the region 230bc, thereby further reducing oxygen vacancies in the region 230bc. That is, the reaction “V_{O}+O→null” can be promoted. In addition, hydrogen in the region 230bc is drifted (diffused) into distortion formed in the region 230ba and the region 230bb by the effect of compressive stress of the conductor 242a and the conductor 242b. Thus, the hydrogen concentration in the region 230bc can be reduced. Accordingly, V_{O}H, oxygen vacancies, and the hydrogen concentration in the region 230bc can be reduced to lower the carrier concentration. In this manner, the region 230bc can be an i-type or substantially i-type region.

The conductor 242a and the conductor 242b are provided over the region 230ba and the region 230bb illustrated in FIG. 2. Here, the conductor 242 preferably functions as a blocking film preventing the effect caused by the high-frequency wave such as a microwave or RF, the oxygen plasma, or the like in the microwave treatment in an atmosphere containing oxygen. Therefore, the conductor 242 preferably has a function of blocking an electromagnetic wave of greater than or equal to 300 MHz and less than or equal to 300 GHZ, for example, greater than or equal to 2.4 GHZ and less than or equal to 2.5 GHZ . . .

As illustrated in FIG. 12B to FIG. 12D, in the microwave treatment in an oxygen-containing atmosphere, the effect of the high-frequency wave such as a microwave or RF, the oxygen plasma, or the like is blocked by the conductor 242a and the conductor 242b and does not affect the region 230ba nor the region 230bb. In addition, the above effect can be reduced by the insulator 271 and the insulator 280 that are provided to cover the oxide 230b and the conductor 242. In the region 230ba and the region 230bb, oxygen vacancies and hydrogen diffused from the region 230bc react with each other to form V_{O}H. Hence, a reduction in V_{O}H and supply of an excess amount of oxygen do not occur in the region 230ba or the region 230bb in the microwave treatment, preventing a decrease in carrier concentration. In this manner, the region 230ba and the region 230bb can be n-type regions.

The effect of the high-frequency wave such as a microwave or RF, the oxygen plasma, or the like is reduced but not blocked by the insulator 244a and the insulator 244b as much as by the conductor 242a and the conductor 242b. Accordingly, the effect on the region 230bd and the region 230be is weaker than that on the region 230bc and stronger than that on the region 230ba and the region 230bb. Thus, the carrier concentrations of the region 230bd and the region 230be due to the microwave treatment are lower than those of the region 230ba and the region 230bb and are not as low as that of the region 230bc.

Furthermore, the insulator 252 having a barrier property against oxygen is provided in contact with the side surfaces of the conductor 242a and the conductor 242b. This can inhibit supply of an excess amount of oxygen to the side surfaces of the conductor 242a and the conductor 242b by the microwave treatment.

Furthermore, the insulator 275 having a barrier property against oxygen is provided above the conductor 242a and the conductor 242b and in contact with the side surface of the conductor 242a and the side surface of the conductor 242b. This can inhibit oxidation of the top surfaces and the side surfaces of the conductor 242a and the conductor 242b by the microwave treatment. As illustrated in FIG. 12D, the insulator 275 is in contact with the side surface of the oxide 230b in a region overlapping with the conductor 242a or the conductor 242b. Thus, the insulator 275 can inhibit supply of an excess amount of oxygen to the side surface of the oxide 230b in the region, preventing a decrease in carrier concentration.

Microwave treatment is preferably performed in an oxygen-containing atmosphere after the deposition of the insulating film 252A or after the deposition of the insulating film 250A. By performing the microwave treatment in an oxygen-containing atmosphere through the insulating film 252A or the insulating film 250A in such a manner, oxygen can be efficiently implanted into the region 230bc. In addition, the insulating film 252A is placed in contact with the surface of the region 230bc, thereby inhibiting more than a necessary amount of oxygen from being implanted into the region 230bc. Furthermore, the insulating film 252A is placed in the vicinity of the side surface of the conductor 242, thereby inhibiting excessive oxidation of the side surface of the conductor 242.

The oxygen implanted into the region 230bc has any of a variety of forms such as an oxygen atom, an oxygen molecule, and an oxygen radical (also referred to as O radical, which is an atom, a molecule, or an ion having an unpaired electron). Note that the oxygen implanted into the region 230bc has any one or more of the above forms, particularly suitably an oxygen radical.

Furthermore, the film quality of the insulator 252 and the insulator 250 can be improved, leading to higher reliability of the transistor 200.

In the above manner, oxygen vacancies and V_{O}H can be selectively removed from the region 230bc in the oxide semiconductor, whereby the region 230bc can be an i-type or substantially i-type region. Furthermore, supply of an excess amount of oxygen to the region 230ba and the region 230bb functioning as the source region and the drain region can be inhibited, and the state of the n-type regions before the microwave treatment is performed can be maintained. Moreover, the region 230bd and the region 230be can each function as a junction region or an offset region. As a result, a change in the electrical characteristics of the transistor 200 can be inhibited, and thus a variation in the electrical characteristics of the transistors 200 in the substrate plane can be inhibited.

The microwave treatment is a significantly effective method for making the region 230bc an i-type or substantially i-type region and making the region 230ba and the region 230bb n-type regions. With the microwave treatment, the transistor 200 can be manufactured to be minute with a gate length of 6 nm or even 3 nm.

In the microwave treatment, thermal energy is directly transmitted to the oxide 230b in some cases owing to an electromagnetic interaction between the microwave and a molecule in the oxide 230b. The oxide 230b may be heated by this thermal energy. Such heat treatment is sometimes referred to as microwave annealing. When microwave treatment is performed in an atmosphere containing oxygen, an effect equivalent to that of oxygen annealing is sometimes obtained. That is, oxygen vacancies can be repaired (nullified) by the microwave annealing. In the case where hydrogen is contained in the oxide 230b, it is probable that the thermal energy is transmitted to the hydrogen in the oxide 230b and the hydrogen activated by the energy is released from the oxide 230b.

Note that the lengths of the insulator 244a and the insulator 244b in the channel length direction are increased by the microwave treatment in some cases. Note that in the case where the insulator 244a and the insulator 244b are not formed before the microwave treatment, the side surface of the conductor 242a is oxidized during the microwave treatment to form the insulator 244a in some cases. Furthermore, the side surface of the conductor 242b is oxidized to form the insulator 244b in some cases.

Appropriate adjustment of the deposition condition of the insulating film 250A, the condition of the microwave treatment performed in an oxygen-containing atmosphere, the amount of oxygen added to the insulator 280 by the deposition of the insulator 282, and the like can reduce oxygen vacancies and V_{O}H in the region 230bc and inhibit supply of excess oxygen to the region 230ba and the region 230bb in some cases. In such a case, the insulator 252 is not necessarily provided. Accordingly, the manufacturing process of the semiconductor device can be simplified, and the productivity can be improved.

The microwave treatment may be performed after the deposition of the insulating film 252A. Alternatively, microwave treatment may be performed after the deposition of the insulating film 252A, without the microwave treatment performed after the deposition of the insulating film 250A.

In the case where the insulator 250 has a stacked-layer structure of two layers as illustrated in FIG. 6A, an insulating film to be the insulator 250b is deposited after the deposition of the above insulating film 250A. The insulating film can be deposited by a sputtering method, a CVD method, an MBE method, a PLD method, an ALD method, or the like. The insulating film is preferably formed using an insulator having a function of inhibiting diffusion of oxygen. With such a structure, oxygen contained in the insulator 250a can be inhibited from diffusing into the conductor 260. That is, a reduction in the amount of oxygen supplied to the oxide 230 can be inhibited. In addition, oxidation of the conductor 260 due to oxygen contained in the insulator 250a can be inhibited. The insulating film can be provided using a material similar to that for the insulator 222. For example, hafnium oxide is deposited by a thermal ALD method for the insulating film.

Note that in the case where the insulator 250 has a stacked-layer structure of two layers as illustrated in FIG. 6A, the microwave treatment is preferably performed after the deposition of the insulating film 250A. Alternatively, microwave treatment may be performed after the deposition of the insulating film to be the insulator 250b, without the microwave treatment performed after the deposition of the insulating film 250A.

After the microwave treatment, heat treatment may be performed with the reduced pressure being maintained. Such treatment enables hydrogen in the oxide 230b and the oxide 230a to be removed efficiently. In addition, hydrogen in the insulating film deposited before the microwave treatment among the insulating film 252A, the insulating film 250A, and the insulating film to be the insulator 250b can be removed efficiently. Part of hydrogen is gettered by the conductor 242a and the conductor 242b in some cases. Alternatively, the step of performing microwave treatment and then performing heat treatment with the reduced pressure being maintained may be repeated a plurality of cycles. The repetition of the heat treatment enables hydrogen in the oxide 230b and the oxide 230a to be removed more efficiently. In addition, hydrogen in the insulating film deposited before the microwave treatment among the insulating film 252A, the insulating film 250A, and the insulating film to be the insulator 250b can be removed more efficiently. Note that the temperature of the heat treatment is preferably higher than or equal to 300° C. and lower than or equal to 500° C. The microwave treatment, i.e., the microwave annealing may also serve as the heat treatment. The heat treatment is not necessarily performed in the case where the oxide 230b and the like are adequately heated by the microwave annealing.

Furthermore, the microwave treatment improves the film quality of one or more of the insulating film 252A, the insulating film 250A, and the insulating film to be the insulator 250b, thereby inhibiting diffusion of hydrogen, water, impurities, and the like. Accordingly, hydrogen, water, impurities, and the like can be inhibited from diffusing into the oxide 230b, the oxide 230a, and the like through the insulator 252 in a later step such as deposition of a conductive film to be the conductor 260 or later treatment such as heat treatment.

Note that through the foregoing steps, the insulator 244a is formed on the side surface of the conductor 242a, and the insulator 244b is formed on the side surface of the conductor 242b. In other words, the insulator 244a and the insulator 244b are formed in any one of the step of processing part of the insulator 280 and the like to form the opening reaching the oxide 230b, the step of depositing the insulating film 252A, the step of depositing the insulating film 250A, and the step of performing the microwave treatment. That is, the insulator 244a and the insulator 244b are formed in a self-aligned manner in the manufacturing process of the semiconductor device.

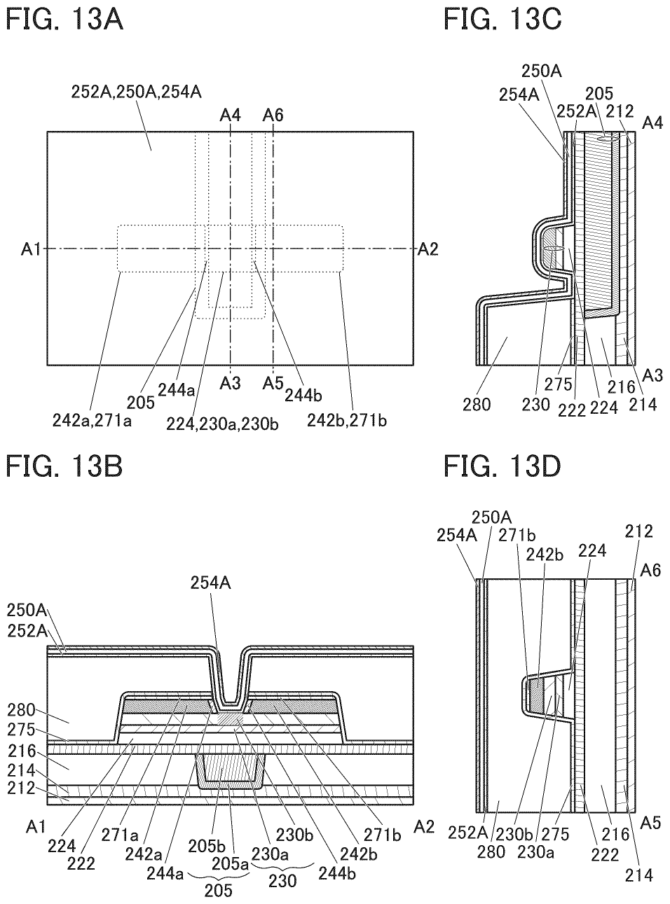

Next, an insulating film 254A is deposited (see FIG. 13A to FIG. 13D). The insulating film 254A can be deposited by a sputtering method, a CVD method, an MBE method, a PLD method, an ALD method, or the like. Like the insulating film 252A, the insulating film 254A is preferably deposited by an ALD method. By an ALD method, the insulating film 254A can be deposited to have a small thickness and good coverage. In this embodiment, as the insulating film 254A, a silicon nitride film is deposited by a PEALD method.

Next, a conductive film to be the conductor 260a and a conductive film to be the conductor 260b are deposited in this order. The conductive film to be the conductor 260a and the conductive film to be the conductor 260b can be deposited by a sputtering method, a CVD method, an MBE method, a PLD method, an ALD method, or the like. In this embodiment, a titanium nitride film is deposited by an ALD method as the conductive film to be the conductor 260a, and a tungsten film is deposited by a CVD method as the conductive film to be the conductor 260b.

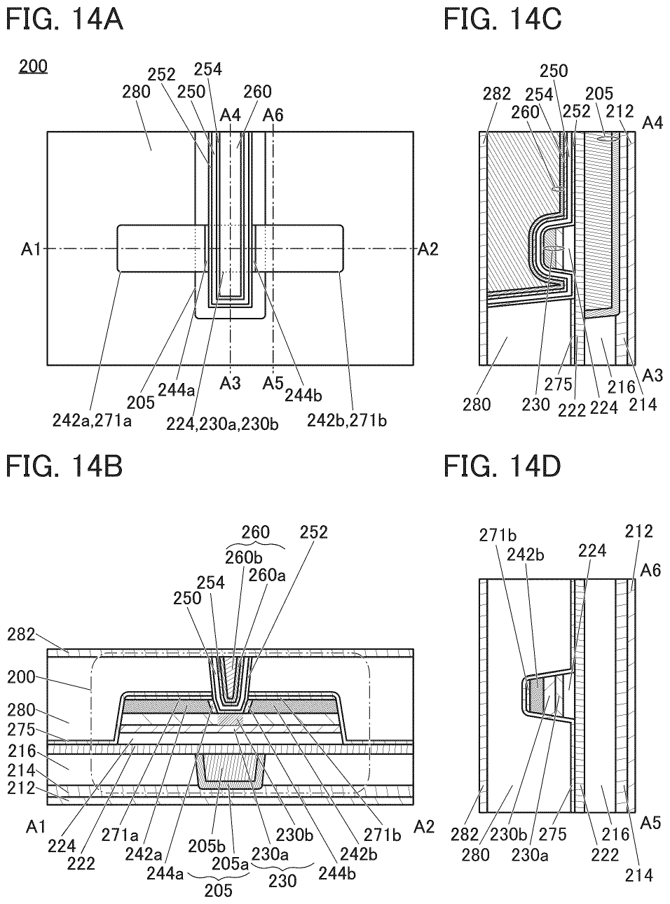

Then, the insulating film 252A, the insulating film 250A, the insulating film 254A, the conductive film to be the conductor 260a, and the conductive film to be the conductor 260b are polished by CMP treatment until the insulator 280 is exposed, whereby the insulator 252, the insulator 250, the insulator 254, and the conductor 260 (the conductor 260a and the conductor 260b) are formed (see FIG. 14A to FIG. 14D). Accordingly, the insulator 252 is placed to cover the opening reaching the oxide 230b. The conductor 260 is placed to fill the opening with the insulator 252, the insulator 250, and the insulator 254 therebetween.

Then, heat treatment may be performed under conditions similar to those for the above heat treatment. In this embodiment, treatment is performed at 400° C. for one hour in a nitrogen atmosphere. The heat treatment can reduce the moisture concentration and the hydrogen concentration in the insulator 250 and the insulator 280. After the heat treatment, the insulator 282 may be successively deposited without exposure to the air.

Next, the insulator 282 is formed over the insulator 252, the insulator 250, the insulator 254, the conductor 260, and the insulator 280 (see FIG. 14A to FIG. 14D). The insulator 282 can be deposited by a sputtering method, a CVD method, an MBE method, a PLD method, an ALD method, or the like. The insulator 282 is preferably deposited by a sputtering method. By using a sputtering method that does not need to use a molecule containing hydrogen as a deposition gas, the hydrogen concentration in the insulator 282 can be reduced.

In this embodiment, for the insulator 282, aluminum oxide is deposited by a pulsed DC sputtering method using an aluminum target in an atmosphere containing an oxygen gas. The RF power applied to the substrate is lower than or equal to 1.86 W/cm², preferably higher than or equal to 0 W/cm² and lower than or equal to 0.62 W/cm². With low RF power, the amount of oxygen implanted into the insulator 280 can be reduced. Alternatively, the insulator 282 may have a stacked-layer structure of two layers. In that case, the lower layer of the insulator 282 is deposited with an RF power of 0 W/cm² applied to the substrate, and the upper layer of the insulator 282 is deposited with an RF power of 0.62 W/cm² applied to the substrate.

When the insulator 282 is deposited by a sputtering method in an oxygen-containing atmosphere, oxygen can be added to the insulator 280 during the deposition. Thus, excess oxygen can be contained in the insulator 280. At this time, the insulator 282 is preferably deposited while the substrate is being heated.

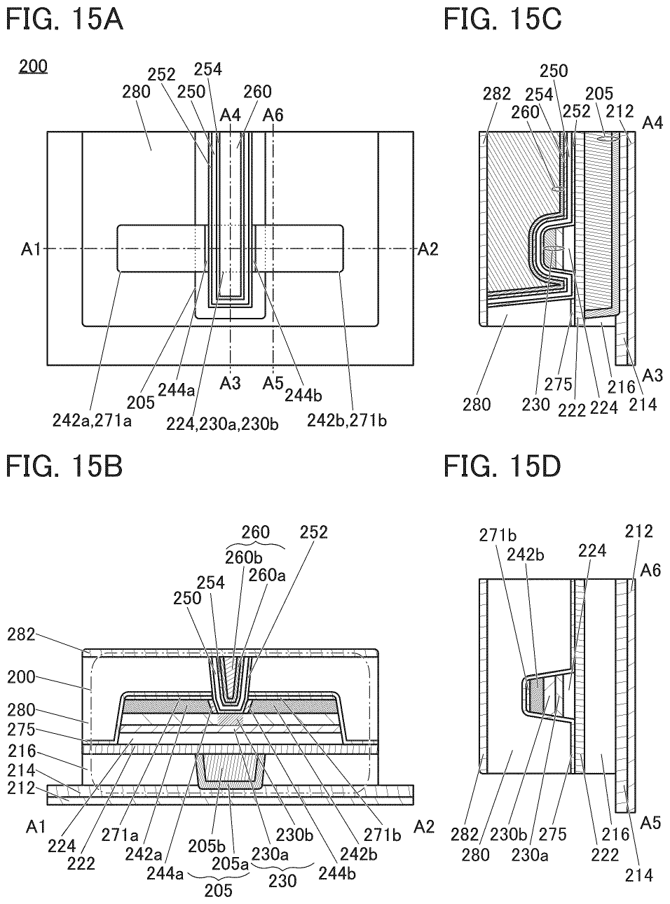

Next, an etching mask is formed over the insulator 282 by a lithography method, and part of the insulator 282, part of the insulator 280, part of the insulator 275, part of the insulator 222, and part of the insulator 216 are processed until the top surface of the insulator 214 is exposed (see FIG. 15A to FIG. 15D). Wet etching can be used for the processing; however, dry etching is preferably used for microfabrication.

Next, heat treatment may be performed. The heat treatment is performed at higher than or equal to 250° C. and lower than or equal to 650° C., preferably higher than or equal to 350° C. and lower than or equal to 600° C. The heat treatment is preferably performed at a temperature lower than that of the heat treatment performed after the deposition of the oxide film 230B. Note that the heat treatment is performed in a nitrogen gas or inert gas atmosphere. By the heat treatment, part of oxygen added to the insulator 280 is diffused into the oxide 230 through the insulator 250 and the like.

By the heat treatment, oxygen contained in the insulator 280 and hydrogen bonded to the oxygen can be released to the outside from the side surface of the insulator 280 formed by the above processing. Note that the hydrogen bonded to oxygen is released as water. Thus, unnecessary oxygen and hydrogen contained in the insulator 280 can be reduced.

In a region of the oxide 230 that overlaps with the conductor 260, the insulator 252 is provided to be in contact with the top surface and the side surface of the oxide 230. Since the insulator 252 has a barrier property against oxygen, diffusion of an excess amount of oxygen into the oxide 230 can be reduced. Thus, oxygen can be supplied to the region 230bc and the vicinity thereof such that an excess amount of oxygen is not supplied thereto. Accordingly, oxygen vacancies and V_{O}H in the region 230bc can be reduced, and excess oxygen can be inhibited from being supplied to the region 230ba and the region 230bb. Thus, the transistor 200 can have favorable electrical characteristics and higher reliability.

On the other hand, in the case where the transistors 200 are integrated at a high density, the volume of the insulator 280 per transistor 200 becomes excessively small in some cases. In this case, the amount of oxygen diffusing into the oxide 230 in the heat treatment becomes significantly small. When the oxide 230 is heated while being in contact with the oxide insulator (e.g., the insulator 250) which does not contain sufficient oxygen, oxygen contained in the oxide 230 might be released. However, in the transistor 200 described in this embodiment, the insulator 252 is provided in contact with the top surface and the side surface of the oxide 230 in the region of the oxide 230 that overlaps with the conductor 260. Since the insulator 252 has a barrier property against oxygen, release of the oxygen from the oxide 230 can be reduced also in the heat treatment. This can inhibit formation of oxygen vacancies and V_{O}H in the region 230bc. Thus, the transistor 200 can have favorable electrical characteristics and higher reliability.

As described above, in either case of a large or small amount of oxygen supplied from the insulator 280 in the semiconductor device according to this embodiment, a transistor having favorable electrical characteristics and favorable reliability can be formed. Thus, a semiconductor device with a reduced variation in electrical characteristics of the transistors 200 in the substrate plane can be provided.

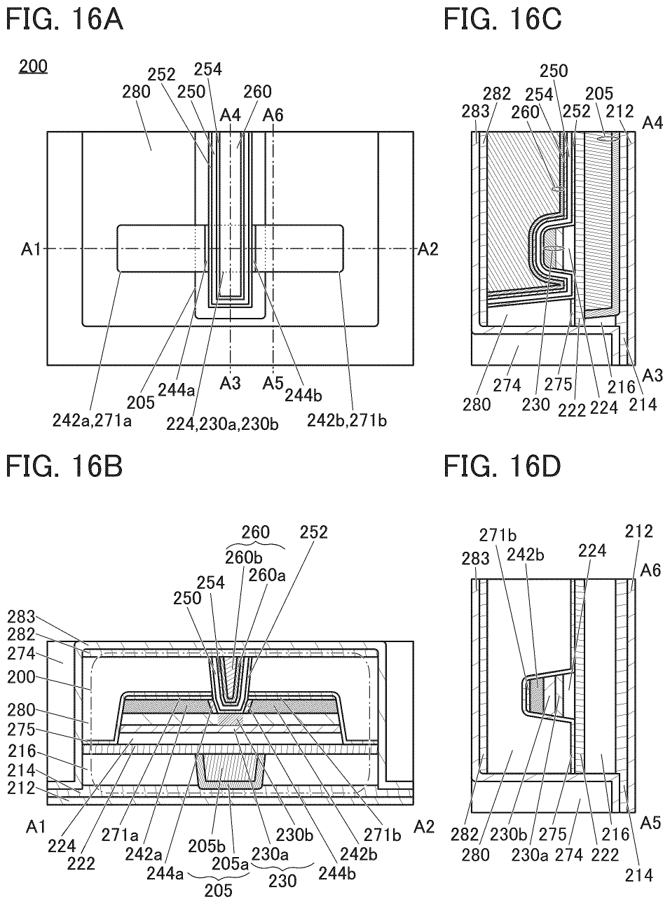

Next, the insulator 283 is formed over the insulator 282 (see FIG. 16A to FIG. 16D). The insulator 283 can be deposited by a sputtering method, a CVD method, an MBE method, a PLD method, an ALD method, or the like. The insulator 283 is preferably deposited by a sputtering method. By using a sputtering method that does not need to use a molecule containing hydrogen as a deposition gas, the hydrogen concentration in the insulator 283 can be reduced. The insulator 283 may be a multilayer. For example, silicon nitride may be deposited by a sputtering method, and silicon nitride may be deposited over the silicon nitride by an ALD method. Surrounding the transistor 200 by the insulator 283 and the insulator 214 that have a high barrier property can prevent entry of moisture and hydrogen from the outside.

Next, an insulating film to be the insulator 274 is formed over the insulator 283. The insulating film can be deposited by a sputtering method, a CVD method, an MBE method, a PLD method, an ALD method, or the like. In this embodiment, a silicon oxide film is deposited by a CVD method as the insulator film.

Next, the insulating film to be the insulator 274 is polished by CMP treatment until the insulator 283 is exposed, whereby the top surface of the insulating film is planarized; thus, the insulator 274 is formed (see FIG. 16A to FIG. 16D). The top surface of the insulator 283 is partly removed by the CMP treatment in some cases.

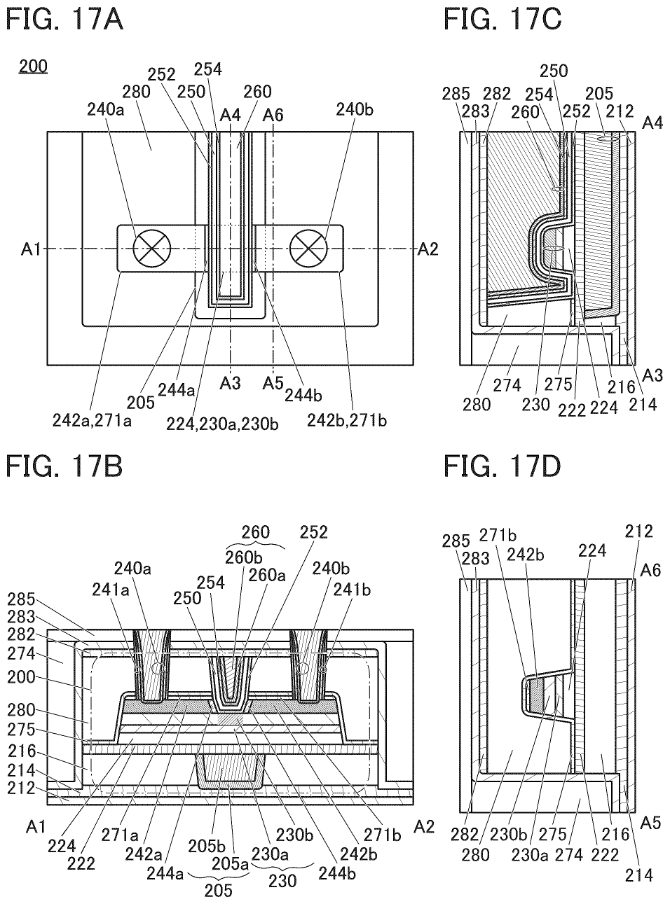

Next, the insulator 285 is formed over the insulator 274 and the insulator 283 (see FIG. 17A to FIG. 17D). The insulator 285 can be deposited by a sputtering method, a CVD method, an MBE method, a PLD method, an ALD method, or the like. The insulator 285 is preferably deposited by a sputtering method. By using a sputtering method that does not need to use a molecule containing hydrogen as a deposition gas, the hydrogen concentration in the insulator 285 can be reduced.

In this embodiment, for the insulator 285, silicon oxide is deposited by a sputtering method.

Subsequently, openings reaching the conductor 242 are formed in the insulator 271, the insulator 275, the insulator 280, the insulator 282, the insulator 283, and the insulator 285 (see FIG. 17A and FIG. 17B). The openings are formed by a lithography method. Note that the openings in the top view in FIG. 17A have a circular shape; however, the shapes of the openings are not limited thereto. For example, the openings in the top view may have an almost circular shape such as an elliptical shape, a polygonal shape such as a quadrangular shape, or a polygonal shape such as a quadrangular shape with rounded corners.

Next, an insulating film to be the insulator 241a and the insulator 241b is deposited, and the insulating film is subjected to anisotropic etching, so that the insulator 241a and the insulator 241b are formed. (See FIG. 17B.) The insulating film can be deposited by a sputtering method, a CVD method, an MBE method, a PLD method, an ALD method, or the like. As the insulating film, an insulating film having a function of inhibiting passage of oxygen is preferably used. For example, preferably, an aluminum oxide film is deposited by an ALD method, and a silicon nitride film is deposited thereover by a PEALD method. Silicon nitride is preferable because of its high blocking property against hydrogen.

For the anisotropic etching of the insulating film to be the insulator 241a and the insulator 241b, a dry etching method is employed, for example. Providing the insulator 241a and the insulator 241b on the side wall portions of the openings can inhibit passage of oxygen from the outside and can prevent oxidation of the conductor 240a and the conductor 240b to be formed next. Furthermore, impurities such as water and hydrogen contained in the insulator 280 or the like can be prevented from diffusing into the conductor 240a and the conductor 240b.

Next, a conductive film to be the conductor 240a and the conductor 240b is deposited. The conductive film desirably has a stacked-layer structure which includes a conductor having a function of inhibiting passage of impurities such as water and hydrogen. For example, a stacked layer of tantalum nitride, titanium nitride, or the like and tungsten, molybdenum, copper, or the like can be employed. The conductive film can be deposited by a sputtering method, a CVD method, an MBE method, a PLD method, an ALD method, or the like.

Next, by performing CMP treatment, the conductive film to be the conductor 240a and the conductor 240b is partly removed to expose the top surface of the insulator 285. As a result, the conductive film remains only in the openings, so that the conductor 240a and the conductor 240b having flat top surfaces can be formed (see FIG. 17A to FIG. 17D). Note that the top surface of the insulator 285 is partly removed by the CMP treatment in some cases.

Next, a conductive film to be the conductor 246a and the conductor 246b is deposited. The conductive film can be deposited by a sputtering method, a CVD method, an MBE method, a PLD method, an ALD method, or the like.

Next, the conductive film to be the conductor 246a and the conductor 246b is processed by a lithography method to form the conductor 246a in contact with the top surface of the conductor 240a and the conductor 246b in contact with the top surface of the conductor 240b. At this time, part of the insulator 285 in a region where the insulator 285 does not overlap with the conductor 246a or the conductor 246b is sometimes removed.

Through the above process, the semiconductor device including the transistor 200 illustrated in FIG. 1A to FIG. 1D can be manufactured. As illustrated in FIG. 7A to FIG. 17D, the transistor 200 can be manufactured with the use of the method for manufacturing the semiconductor device described in this embodiment.

### <Microwave Treatment Apparatus>

A microwave treatment apparatus that can be used for the above method for manufacturing the semiconductor device is described below.

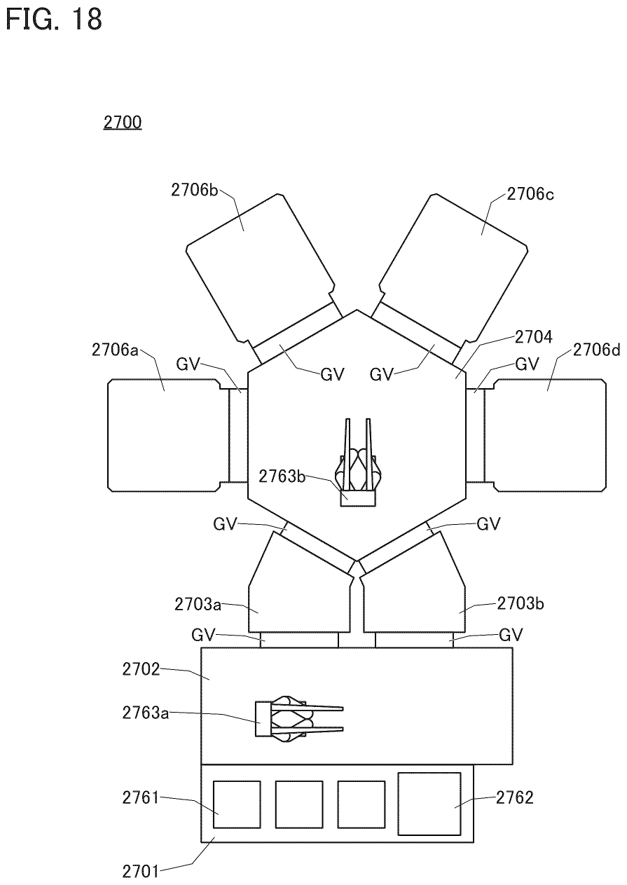

First, a structure of a manufacturing apparatus that hardly allows entry of impurities in manufacturing a semiconductor device or the like is described with reference to FIG. 18 to FIG. 21.

FIG. 18 schematically illustrates a top view of a single wafer multi-chamber manufacturing apparatus 2700. The manufacturing apparatus 2700 includes an atmosphere-side substrate supply chamber 2701 including a cassette port 2761 for storing a substrate and an alignment port 2762 for performing alignment of a substrate; an atmosphere-side substrate transfer chamber 2702 for transferring a substrate from the atmosphere-side substrate supply chamber 2701; a load lock chamber 2703a for carrying in a substrate and switching the pressure inside the chamber from atmospheric pressure to reduced pressure or from reduced pressure to atmospheric pressure; an unload lock chamber 2703b for carrying out a substrate and switching the pressure inside the chamber from reduced pressure to atmospheric pressure or from atmospheric pressure to reduced pressure; a transfer chamber 2704 for transferring a substrate in a vacuum; a chamber 2706a; a chamber 2706b; a chamber 2706c; and a chamber 2706d.

Furthermore, the atmosphere-side substrate transfer chamber 2702 is connected to the load lock chamber 2703a and the unload lock chamber 2703b, the load lock chamber 2703a and the unload lock chamber 2703b are connected to the transfer chamber 2704, and the transfer chamber 2704 is connected to the chamber 2706a, the chamber 2706b, the chamber 2706c, and the chamber 2706d.

Note that gate valves GV are provided in connecting portions between the chambers so that the chambers other than the atmosphere-side substrate supply chamber 2701 and the atmosphere-side substrate transfer chamber 2702 can be each independently kept in a vacuum state. Furthermore, the atmosphere-side substrate transfer chamber 2702 is provided with a transfer robot 2763a, and the transfer chamber 2704 is provided with a transfer robot 2763b. With the transfer robot 2763a and the transfer robot 2763b, a substrate can be transferred inside the manufacturing apparatus 2700.

The back pressure (total pressure) in the transfer chamber 2704 and each of the chambers is, for example, lower than or equal to 1×10⁻⁴ Pa, preferably lower than or equal to 3×10⁻⁵ Pa, further preferably lower than or equal to 1×10⁻⁵ Pa. Furthermore, the partial pressure of a gas molecule (atom) having a mass-to-charge ratio (m/z) of 18 in the transfer chamber 2704 and each of the chambers is, for example, lower than or equal to 3×10⁻⁵ Pa, preferably lower than or equal to 1×10⁻⁵ Pa, further preferably lower than or equal to 3×10⁻⁶ Pa. Furthermore, the partial pressure of a gas molecule (atom) having m/z of 28 in the transfer chamber 2704 and each of the chambers is, for example, lower than or equal to 3×10⁻⁵ Pa, preferably lower than or equal to 1×10⁻⁵ Pa, further preferably lower than or equal to 3×10⁻⁶ Pa. Furthermore, the partial pressure of a gas molecule (atom) having m/z of 44 in the transfer chamber 2704 and each of the chambers is, for example, lower than or equal to 3×10⁻⁵ Pa, preferably lower than or equal to 1×10⁻⁵ Pa, further preferably lower than or equal to 3×10⁻⁶ Pa.

Note that the total pressure and the partial pressure in the transfer chamber 2704 and each of the chambers can be measured using an ionization vacuum gauge, a mass analyzer, or the like.

Furthermore, the transfer chamber 2704 and the chambers each desirably have a structure in which the amount of external leakage or internal leakage is small. For example, the leakage rate in the transfer chamber 2704 is less than or equal to 1×10⁰ Pa/min, preferably less than or equal to 5×10⁻¹ Pa/min. Furthermore, the leakage rate in each chamber is less than or equal to 1×10⁻¹ Pa/min, preferably less than or equal to 5×10⁻² Pa/min.

Note that a leakage rate is derived from the total pressure and partial pressure measured using the ionization vacuum gauge, the mass analyzer, or the like. For example, the leakage rate is preferably derived from the total pressure at the time when 10 minutes have passed from the start of evacuation to a vacuum using a vacuum pump such as a turbo molecular pump and the total pressure at the time when 10 minutes have passed from the operation of closing the valve. Note that the total pressure at the time when 10 minutes have passed from the start of evacuation to a vacuum is preferably an average value of the total pressures measured a plurality of times.

The leakage rate depends on external leakage and internal leakage. The external leakage refers to inflow of gas from the outside of a vacuum system through a minute hole, a sealing defect, or the like. The internal leakage is due to leakage through a partition, such as a valve, in a vacuum system or released gas from an internal member. Measures need to be taken from both aspects of external leakage and internal leakage in order that the leakage rate can be set to less than or equal to the above-described value.

For example, open/close portions of the transfer chamber 2704 and each of the chambers are preferably sealed with a metal gasket. For the metal gasket, metal covered with iron fluoride, aluminum oxide, or chromium oxide is preferably used. The metal gasket achieves higher adhesion than an O-ring and can reduce the external leakage. Furthermore, with the use of passive metal covered with iron fluoride, aluminum oxide, chromium oxide, or the like, the release of gas containing impurities released from the metal gasket is inhibited, so that the internal leakage can be reduced.

Furthermore, for a member of the manufacturing apparatus 2700, aluminum, chromium, titanium, zirconium, nickel, or vanadium, which releases a small amount of gas containing impurities, is used. Furthermore, an alloy containing any of iron, chromium, nickel, and the like covered with the above-described metal, which releases a small amount of gas containing impurities, may be used. The alloy containing any of iron, chromium, nickel, and the like is rigid, resistant to heat, and suitable for processing. Here, when surface unevenness of the member is reduced by polishing or the like to reduce the surface area, the release of gas can be reduced.

Alternatively, the above-described member of the manufacturing apparatus 2700 may be covered with iron fluoride, aluminum oxide, chromium oxide, or the like.

The member of the manufacturing apparatus 2700 is preferably formed using only metal when possible, and in the case where a viewing window formed of quartz or the like is provided, for example, the surface is preferably thinly covered with iron fluoride, aluminum oxide, chromium oxide, or the like to inhibit release of gas.

An adsorbed substance present in the transfer chamber 2704 and each of the chambers does not affect the pressure in the transfer chamber 2704 and each of the chambers because it is adsorbed onto an inner wall or the like; however, it causes a release of gas when the transfer chamber 2704 and each of the chambers are evacuated. Thus, although there is no correlation between the leakage rate and the exhaust rate, it is important that the adsorbed substance present in the transfer chamber 2704 and each of the chambers be desorbed as much as possible and exhaust be performed in advance with the use of a pump having high exhaust capability. Note that the transfer chamber 2704 and each of the chambers may be subjected to baking to promote desorption of the adsorbed substance. By the baking, the desorption rate of the adsorbed substance can be increased about tenfold. The baking is performed at higher than or equal to 100° C. and lower than or equal to 450° C. At this time, when the adsorbed substance is removed while an inert gas is introduced into the transfer chamber 2704 and each of the chambers, the desorption rate of water or the like, which is difficult to desorb simply by exhaust, can be further increased. Note that when the inert gas to be introduced is heated to substantially the same temperature as the baking temperature, the desorption rate of the adsorbed substance can be further increased. Here, a noble gas is preferably used as the inert gas.

Alternatively, treatment for evacuating the transfer chamber 2704 and each of the chambers is preferably performed after a certain period of time after a heated inert gas such as a noble gas, heated oxygen, or the like is introduced to increase the pressure in the transfer chamber 2704 and each of the chambers. The introduction of the heated gas can desorb the adsorbed substance in the transfer chamber 2704 and each of the chambers, and impurities present in the transfer chamber 2704 and each of the chambers can be reduced. Note that this treatment is effective when repeated more than or equal to 2 times and less than or equal to 30 times, preferably more than or equal to 5 times and less than or equal to 15 times. Specifically, an inert gas, oxygen, or the like at a temperature higher than or equal to 40° C. and lower than or equal to 400° C., preferably higher than or equal to 50° C. and lower than or equal to 200° C. is introduced, so that the pressure in the transfer chamber 2704 and each of the chambers can be kept to be higher than or equal to 0.1 Pa and lower than or equal to 10 kPa, preferably higher than or equal to 1 Pa and lower than or equal to 1 kPa, further preferably higher than or equal to 5 Pa and lower than or equal to 100 Pa in the time range of 1 minute to 300 minutes, preferably 5 minutes to 120 minutes. After that, the transfer chamber 2704 and each of the chambers are evacuated in the time range of 5 minutes to 300 minutes, preferably 10 minutes to 120 minutes.

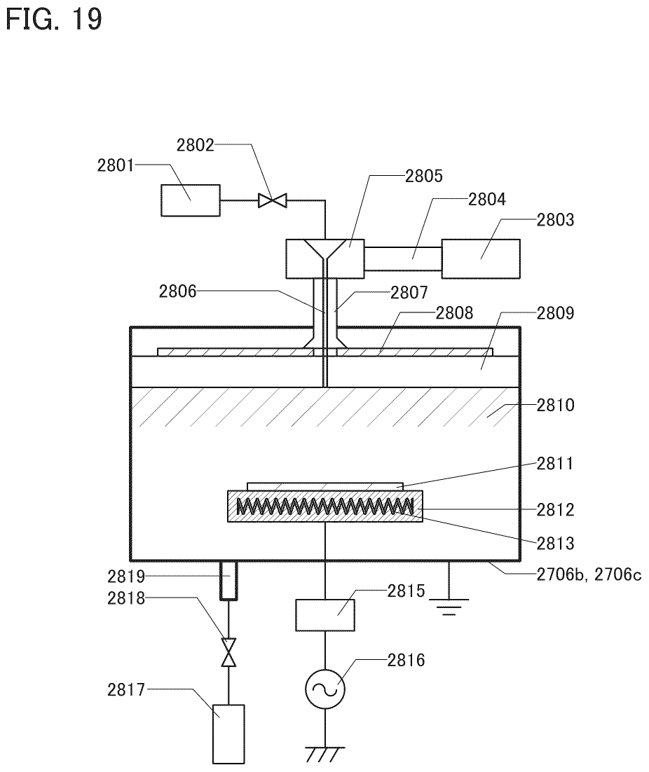

Next, the chamber 2706b and the chamber 2706c are described with reference to a schematic cross-sectional view illustrated in FIG. 19.

The chamber 2706b and the chamber 2706c are chambers in which microwave treatment can be performed on an object, for example. Note that the chamber 2706b is different from the chamber 2706c only in the atmosphere in performing the microwave treatment. The other structures are common and thus collectively described below.

The chamber 2706b and the chamber 2706c each include a slot antenna plate 2808, a dielectric plate 2809, a substrate holder 2812, and an exhaust port 2819. Furthermore, a gas supply source 2801, a valve 2802, a high-frequency generator 2803, a waveguide 2804, a mode converter 2805, a gas pipe 2806, a waveguide 2807, a matching box 2815, a high-frequency power source 2816, a vacuum pump 2817, and a valve 2818 are provided outside the chamber 2706b and the chamber 2706c, for example.

The high-frequency generator 2803 is connected to the mode converter 2805 through the waveguide 2804. The mode converter 2805 is connected to the slot antenna plate 2808 through the waveguide 2807. The slot antenna plate 2808 is placed in contact with the dielectric plate 2809. Furthermore, the gas supply source 2801 is connected to the mode converter 2805 through the valve 2802. Then, gas is transferred to the chamber 2706b and the chamber 2706c through the gas pipe 2806 that runs through the mode converter 2805, the waveguide 2807, and the dielectric plate 2809. Furthermore, the vacuum pump 2817 has a function of exhausting gas or the like from the chamber 2706b and the chamber 2706c through the valve 2818 and the exhaust port 2819. Furthermore, the high-frequency power source 2816 is connected to the substrate holder 2812 through the matching box 2815.

The substrate holder 2812 has a function of holding a substrate 2811. For example, the substrate holder 2812 has a function of an electrostatic chuck or a mechanical chuck for holding the substrate 2811. Furthermore, the substrate holder 2812 has a function of an electrode to which electric power is supplied from the high-frequency power source 2816. Furthermore, the substrate holder 2812 includes a heating mechanism 2813 therein and has a function of heating the substrate 2811.

As the vacuum pump 2817, a dry pump, a mechanical booster pump, an ion pump, a titanium sublimation pump, a cryopump, or a turbomolecular pump can be used, for example. Furthermore, in addition to the vacuum pump 2817, a cryotrap may be used. The use of the cryopump and the cryotrap is particularly preferable because water can be efficiently exhausted.

Furthermore, for example, the heating mechanism 2813 is a heating mechanism that uses a resistance heater or the like for heating. Alternatively, a heating mechanism that uses heat conduction or heat radiation from a medium such as a heated gas for heating may be used. For example, RTA (Rapid Thermal Annealing) such as GRTA (Gas Rapid Thermal Annealing) or LRTA (Lamp Rapid Thermal Annealing) can be used. In GRTA, heat treatment is performed using a high-temperature gas. An inert gas is used as the gas.

Furthermore, the gas supply source 2801 may be connected to a purifier through a mass flow controller. As the gas, a gas whose dew point is −80° C. or lower, preferably −100° C. or lower is preferably used. For example, an oxygen gas, a nitrogen gas, or a noble gas (an argon gas or the like) is used.

As the dielectric plate 2809, silicon oxide (quartz), aluminum oxide (alumina), or yttrium oxide (yttria) is used, for example. Furthermore, another protective layer may be further formed on a surface of the dielectric plate 2809. For the protective layer, magnesium oxide, titanium oxide, chromium oxide, zirconium oxide, hafnium oxide, tantalum oxide, silicon oxide, aluminum oxide, yttrium oxide, or the like is used. The dielectric plate 2809 is exposed to an especially high-density region of high-density plasma 2810 described later; thus, provision of the protective layer can reduce the damage. Consequently, an increase in the number of particles or the like during the treatment can be suppressed.

The high-frequency generator 2803 has a function of generating a microwave at, for example, higher than or equal to 0.3 GHZ and lower than or equal to 3.0 GHZ, higher than or equal to 0.7 GHZ and lower than or equal to 1.1 GHZ, or higher than or equal to 2.2 GHZ and lower than or equal to 2.8 GHZ. The microwave generated by the high-frequency generator 2803 is propagated to the mode converter 2805 through the waveguide 2804. The mode converter 2805 converts the microwave propagated in the TE (Transverse Electric) mode into the microwave in the TEM (Transverse Electric and Magnetic) mode. Then, the microwave is propagated to the slot antenna plate 2808 through the waveguide 2807. The slot antenna plate 2808 is provided with a plurality of slot holes, and the microwave passes through the slot holes and the dielectric plate 2809. Then, an electric field is generated below the dielectric plate 2809, and the high-density plasma 2810 can be generated. In the high-density plasma 2810, ions and radicals based on the gas species supplied from the gas supply source 2801 are present. For example, oxygen radicals are present.

At this time, the quality of a film or the like over the substrate 2811 can be modified by the ions and radicals generated in the high-density plasma 2810. Note that it is preferable in some cases to apply a bias to the substrate 2811 side using the high-frequency power source 2816. As the high-frequency power source 2816, an RF (Radio Frequency) power source with a frequency of 13.56 MHz, 27.12 MHz, or the like is used, for example. The application of a bias to the substrate side allows ions in the high-density plasma 2810 to efficiently reach a deep portion of an opening portion of the film or the like over the substrate 2811.

For example, in the chamber 2706b or the chamber 2706c, oxygen radical treatment using the high-density plasma 2810 can be performed by introducing oxygen from the gas supply source 2801.

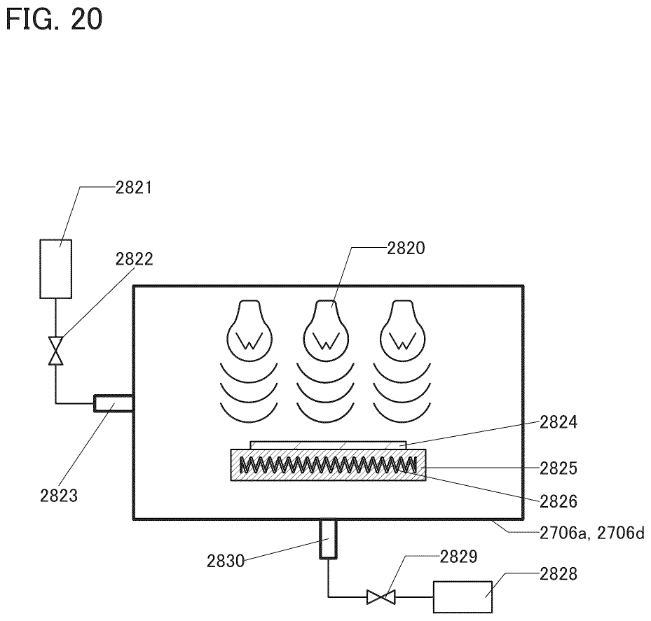

Next, the chamber 2706a and the chamber 2706d are described with reference to a schematic cross-sectional view illustrated in FIG. 20.

The chamber 2706a and the chamber 2706d are chambers in which an object can be irradiated with an electromagnetic wave, for example. Note that the chamber 2706a is different from the chamber 2706d only in the kind of the electromagnetic wave. The other structures have many common portions and thus are collectively described below.

The chamber 2706a and the chamber 2706d each include one or more lamps 2820, a substrate holder 2825, a gas inlet 2823, and an exhaust port 2830. Furthermore, a gas supply source 2821, a valve 2822, a vacuum pump 2828, and a valve 2829 are provided outside the chamber 2706a and the chamber 2706d, for example.

The gas supply source 2821 is connected to the gas inlet 2823 through the valve 2822. The vacuum pump 2828 is connected to the exhaust port 2830 through the valve 2829. The lamp 2820 is placed to face the substrate holder 2825. The substrate holder 2825 has a function of holding a substrate 2824. Furthermore, the substrate holder 2825 includes a heating mechanism 2826 therein and has a function of heating the substrate 2824.

As the lamp 2820, a light source having a function of emitting an electromagnetic wave such as visible light or ultraviolet light is used, for example. For example, a light source having a function of emitting an electromagnetic wave which has a peak at a wavelength longer than or equal to 10 nm and shorter than or equal to 2500 nm, longer than or equal to 500 nm and shorter than or equal to 2000 nm, or longer than or equal to 40 nm and shorter than or equal to 340 nm is used.

As the lamp 2820, a light source such as a halogen lamp, a metal halide lamp, a xenon arc lamp, a carbon arc lamp, a high-pressure sodium lamp, or a high-pressure mercury lamp is used, for example.

For example, part or the whole of electromagnetic wave emitted from the lamp 2820 is absorbed by the substrate 2824, so that the quality of a film or the like over the substrate 2824 can be modified. For example, generation or reduction of defects or removal of impurities can be performed. Note that generation or reduction of defects, removal of impurities, or the like can be efficiently performed while the substrate 2824 is heated.

Alternatively, for example, the electromagnetic wave emitted from the lamp 2820 may allow the substrate holder 2825 to generate heat for heating the substrate 2824. In that case, the substrate holder 2825 does not need to include the heating mechanism 2826 therein.

For the vacuum pump 2828, refer to the description of the vacuum pump 2817. Furthermore, for the heating mechanism 2826, refer to the description of the heating mechanism 2813. Furthermore, for the gas supply source 2821, refer to the description of the gas supply source 2801.

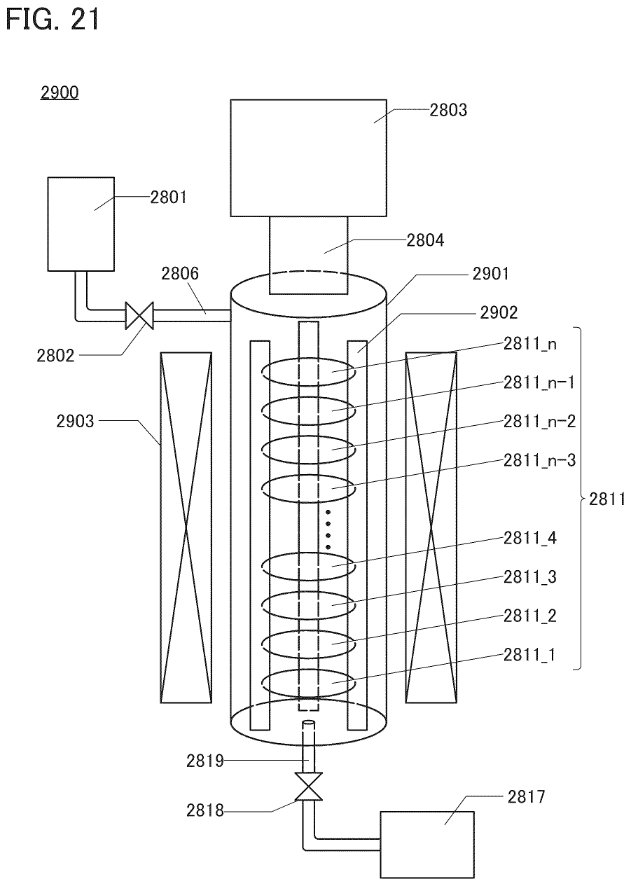

A microwave treatment apparatus that can be used in this embodiment is not limited to the above. A microwave treatment apparatus 2900 illustrated in FIG. 21 can be used. The microwave treatment apparatus 2900 includes a quartz tube 2901, the exhaust port 2819, the gas supply source 2801, the valve 2802, the high-frequency generator 2803, the waveguide 2804, the gas pipe 2806, the vacuum pump 2817, and the valve 2818. Furthermore, the microwave treatment apparatus 2900 includes a substrate holder 2902 that holds a plurality of substrates 2811 (2811_1 to 2811_n, n is an integer greater than or equal to 2) in the quartz tube 2901. The microwave treatment apparatus 2900 may further include a heating means 2903 outside the quartz tube 2901.

The substrate provided in the quartz tube 2901 is irradiated with the microwave generated by the high-frequency generator 2803, through the waveguide 2804. The vacuum pump 2817 is connected to the exhaust port 2819 through the valve 2818 and can adjust the pressure inside the quartz tube 2901. The gas supply source 2801 is connected to the gas pipe 2806 through the valve 2802 and can introduce a desired gas into the quartz tube 2901. The heating means 2903 can heat the substrate 2811 in the quartz tube 2901 to a desired temperature. Alternatively, the heating means 2903 may heat the gas which is supplied from the gas supply source 2801. With the use of the microwave treatment apparatus 2900, the substrate 2811 can be subjected to heat treatment and microwave treatment at the same time. Alternatively, the substrate 2811 can be heated and then subjected to microwave treatment. Alternatively, the substrate 2811 can be subjected to microwave treatment and then heat treatment.

All of the substrate 2811_1 to the substrate 2811_n may be substrates to be treated where a semiconductor device or a storage device is to be formed, or some of the substrates may be dummy substrates. For example, the substrate 2811_1 and the substrate 2811_n may be dummy substrates, and the substrate 2811_2 to the substrate 2811_n−1 may be substrates to be treated. Alternatively, the substrate 2811_1, the substrate 2811_2, the substrate 2811_n−1, and the substrate 2811_n may be dummy substrates, and the substrate 2811_3 to the substrate 2811_n−2 may be substrates to be treated. A dummy substrate is preferably used, in which case a plurality of substrates to be treated can be uniformly treated at the time of microwave treatment or heat treatment and a variation between the substrates to be treated can be reduced. For example, a dummy substrate is preferably placed over the substrate to be treated which is the closest to the high-frequency generator 2803 and the waveguide 2804, in which case the substrate to be treated is inhibited from being directly exposed to a microwave.

With the use of the above-described manufacturing apparatus, the quality of a film or the like can be modified while the entry of impurities into an object is inhibited.

### Modification Example of Semiconductor Device

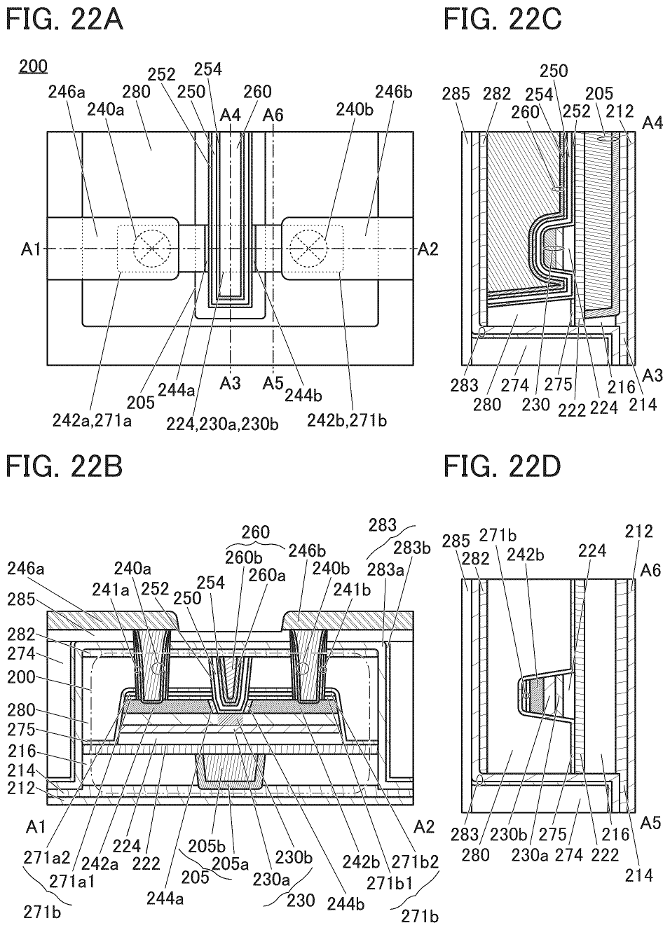

Examples of the semiconductor device of one embodiment of the present invention are described below with reference to FIG. 22A to FIG. 25D.

A of each figure is a top view of the semiconductor device. Moreover, B of each figure is a cross-sectional view corresponding to a portion indicated by dashed-dotted line A1-A2 in A of each figure. Furthermore, C of each figure is a cross-sectional view corresponding to a portion indicated by dashed-dotted line A3-A4 in A of each figure. Furthermore, D of each figure is a cross-sectional view corresponding to a portion indicated by dashed-dotted line A5-A6 in A of each figure. For clarity of the drawing, some components are omitted in the top view of A of each figure.

Note that in the semiconductor device illustrated in A to D of each figure, components having the same functions as the components included in the semiconductor device described in <Structure example of semiconductor device> are denoted by the same reference numerals. Note that the materials described in detail in <Structure example of semiconductor device> can be used as component materials of the semiconductor devices also in this section.

### Modification Example 1 of Semiconductor Device

A semiconductor device illustrated in FIG. 22A to FIG. 22D is a modification example of the semiconductor device illustrated in FIG. 1A to FIG. 1D. The semiconductor device illustrated in FIG. 22A to FIG. 22D differs from the semiconductor device illustrated in FIG. 1A to FIG. 1D in that the insulator 271 and the insulator 283 each have a stacked-layer structure of two layers.

The insulator 271a includes an insulator 271a1 and an insulator 271a2 over the insulator 271a1. The insulator 271b includes an insulator 271b1 and an insulator 271b2 over the insulator 271b1.

The insulator 271a1 and the insulator 271b1 preferably function as at least a barrier insulating film against oxygen. Thus, the insulator 271a1 and the insulator 271b1 preferably have a function of inhibiting oxygen diffusion. Accordingly, oxygen contained in the insulator 280 can be prevented from diffusing into the conductor 242a and the conductor 242b. Thus, the conductor 242a and the conductor 242b can be inhibited from being oxidized by oxygen contained in the insulator 280, so that an increase in resistivity and a reduction in on-state current can be inhibited.

The insulator 271a2 and the insulator 271b2 function as protective layers for making the insulator 271a1 and the insulator 271b1 remain. When the hard mask is removed after the conductive film 242A, the oxide film 230B, and the like are processed into an island shape, an insulating layer to be the insulator 271a1 and the insulator 271b1 might be removed. Thus, an insulating layer to be the insulator 271a2 and the insulator 271b2 is provided between the hard mask and the insulating layer to be the insulator 271a1 and the insulator 271b1, whereby the insulating layer to be the insulator 271a1 and the insulator 271b1 can remain. For example, in the case where tungsten is used for the hard mask, silicon oxide or the like is preferably used for the insulator 271a2 and the insulator 271b2.

The insulator 283 includes an insulator 283a and an insulator 283b over the insulator 283a. The insulator 283a and the insulator 283b are preferably formed using the same material by different methods. For example, silicon nitride may be deposited by a sputtering method as the insulator 283a, and silicon nitride may be deposited by an ALD method as the insulator 283b. By using a sputtering method that does not need to use a molecule containing hydrogen as a deposition gas, the hydrogen concentration in the insulator 282a can be reduced. Furthermore, in the case where a pinhole, disconnection, or the like is formed in the film formed by a sputtering method, a portion overlapping with the pinhole, the disconnection, or the like can be filled with the film deposited by an ALD method with excellent coverage.

Note that as illustrated in FIG. 22B, the top surface of the insulator 283b is partly removed in some cases. The boundary between the insulator 283a and the insulator 283b is difficult to detect clearly in some cases.

Without limitation to a stacked-layer structure formed of the same material, the insulator 283a and the insulator 283b may have a stacked-layer structure formed of different materials.

### Modification Example 2 of Semiconductor Device

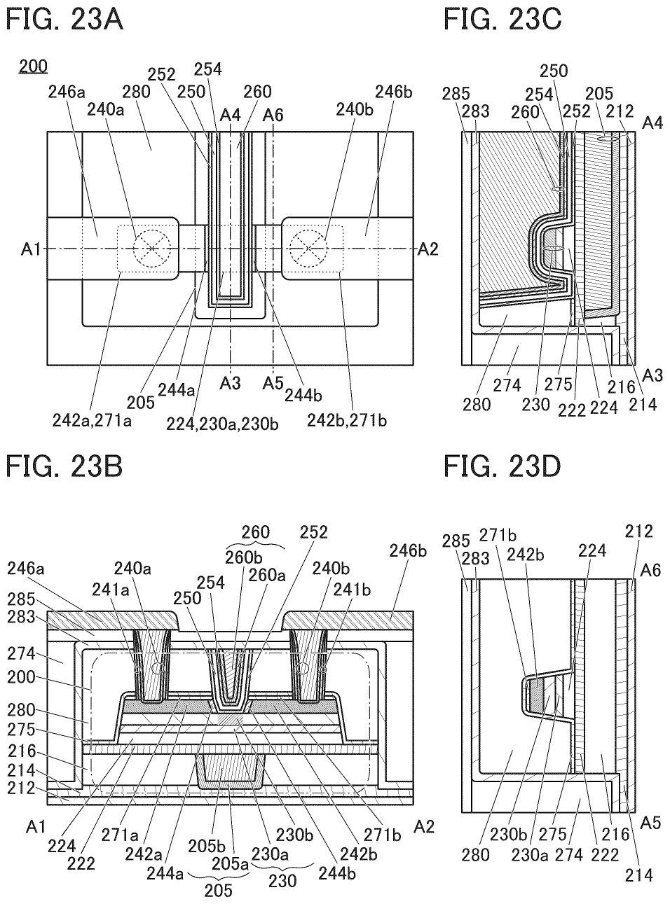

A semiconductor device illustrated in FIG. 23A to FIG. 23D is a modification example of the semiconductor device illustrated in FIG. 1A to FIG. 1D. The semiconductor device illustrated in FIG. 23A to FIG. 23D differs from the semiconductor device illustrated in FIG. 1A to FIG. 1D in that the insulator 282 is not provided. Thus, in the semiconductor device illustrated in FIG. 23A to FIG. 23D, the insulator 283 is in contact with the top surface of the conductor 260, the top surface of the insulator 280, the uppermost portion of the insulator 254, the uppermost portion of the insulator 250, and the uppermost portion of the insulator 252.

For example, in the case where oxygen can be supplied sufficiently to the oxide 230 by the microwave treatment or the like as illustrated in FIG. 12B to FIG. 12D, the region 230bc can be substantially i-type without the insulator 282 for adding oxygen to the insulator 280. In such a case, the structure without the insulator 282 as illustrated in FIG. 23A to FIG. 23D enables the simplification of the manufacturing process and the improvement in productivity of the semiconductor device.

### Modification Example 3 of Semiconductor Device

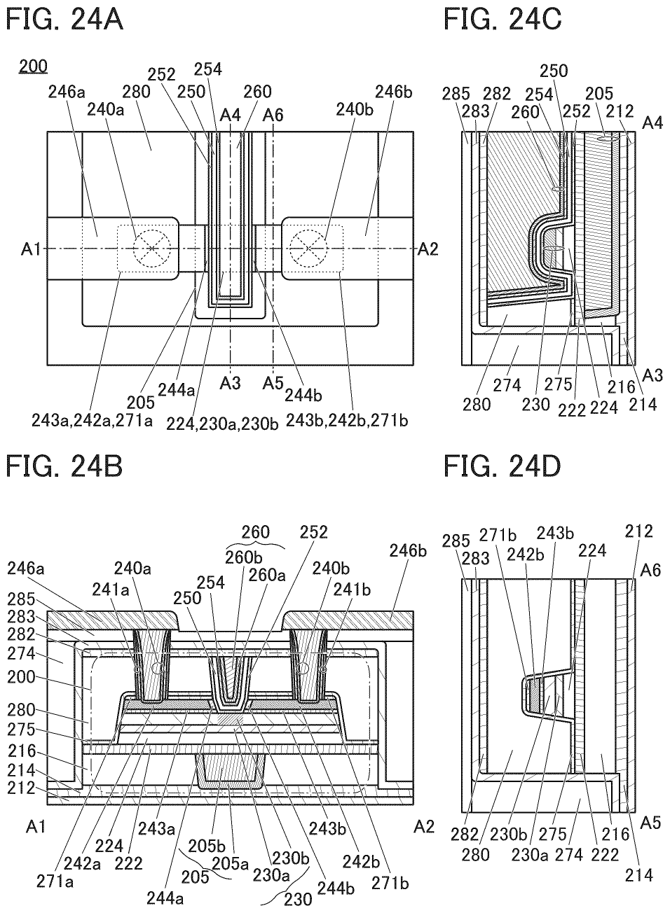

A semiconductor device illustrated in FIG. 24A to FIG. 24D is a modification example of the semiconductor device illustrated in FIG. 1A to FIG. 1D. The semiconductor device illustrated in FIG. 24A to FIG. 24D differs from the semiconductor device illustrated in FIG. 1A to FIG. 1D in that an oxide 243 (an oxide 243a and an oxide 243b) is provided. The oxide 243a is provided between the oxide 230b and the conductor 242a, and the oxide 243b is provided between the oxide 230b and the conductor 242b. Here, the oxide 243a is preferably in contact with the top surface of the oxide 230b and the bottom surface of the conductor 242a. The oxide 243b is preferably in contact with the top surface of the oxide 230b and the bottom surface of the conductor 242b.

The oxide 243 preferably has a function of inhibiting passage of oxygen. The oxide 243 having a function of inhibiting passage of oxygen is preferably placed between the oxide 230b and the conductor 242 functioning as the source electrode or the drain electrode, in which case the electric resistance between the conductor 242 and the oxide 230b is reduced. Such a structure can improve the electrical characteristics, the field-effect mobility, and the reliability of the transistor 200 in some cases.

A metal oxide containing the element M may be used as the oxide 243. In particular, aluminum, gallium, yttrium, or tin is preferably used as the element M. The concentration of the element M in the oxide 243 is preferably higher than that in the oxide 230b. Furthermore, gallium oxide may be used for the oxide 243. A metal oxide such as an In-M-Zn oxide may be used as the oxide 243. Specifically, the atomic ratio of the element M to In in the metal oxide used as the oxide 243 is preferably greater than the atomic ratio of the element M to In in the metal oxide used as the oxide 230b. The thickness of the oxide 243 is preferably greater than or equal to 0.5 nm and less than or equal to 5 nm, further preferably greater than or equal to 1 nm and less than or equal to 3 nm, still further preferably greater than or equal to 1 nm and less than or equal to 2 nm. The oxide 243 preferably has crystallinity. In the case where the oxide 243 has crystallinity, release of oxygen from the oxide 230 can be favorably inhibited. When the oxide 243 has a hexagonal crystal structure, for example, release of oxygen from the oxide 230 can sometimes be inhibited.

### Modification Example 4 of Semiconductor Device

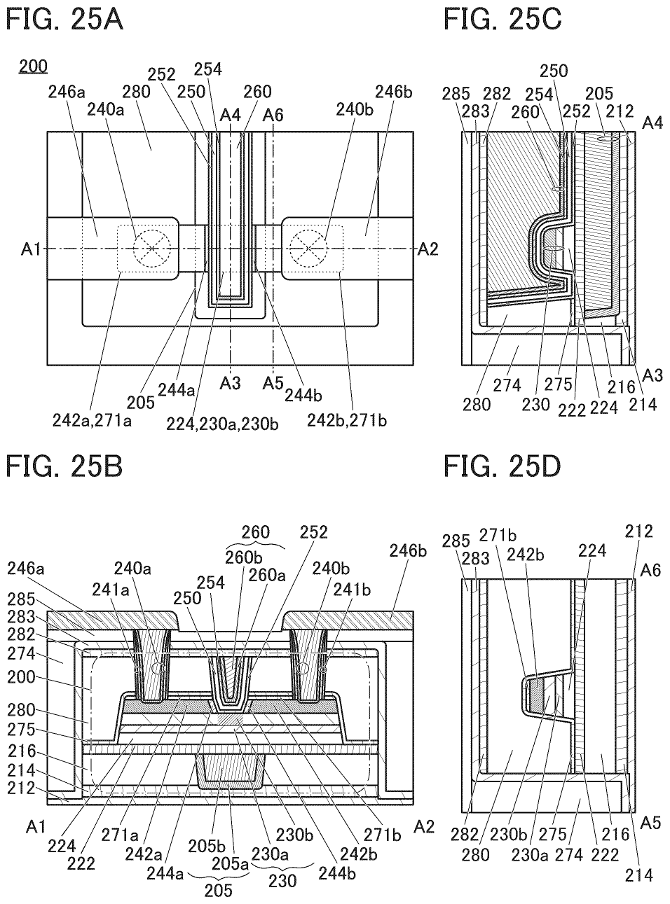

A semiconductor device illustrated in FIG. 25A to FIG. 25D is a modification example of the semiconductor device illustrated in FIG. 1A to FIG. 1D. The semiconductor device illustrated in FIG. 25A to FIG. 25D differs from the semiconductor device illustrated in FIG. 1A to FIG. 1D in that the insulator 283 is in contact with part of the top surface of the insulator 212. Accordingly, the transistor 200 is placed in a region sealed with the insulator 283 and the insulator 212. With such a structure, entry of hydrogen contained in a region outside the sealed region into the sealed region can be inhibited. Although FIG. 25A to FIG. 25D illustrate the transistor 200 having a structure in which the insulator 212 and the insulator 283 are each provided to have a single-layer structure, the present invention is not limited thereto. For example, one or both of the insulator 212 and the insulator 283 may be provided to have a stacked-layer structure of two or more layers.

A change in electrical characteristics of an OS transistor such as the transistor 200 due to exposure to radiation is small, i.e., an OS transistor has high tolerance to radiation; thus, an OS transistor can be suitably used even in an environment where radiation might enter. For example, OS transistors can be suitably used in outer space. Specifically, OS transistors can be used as transistors included in semiconductor devices provided in a space shuttle, an artificial satellite, a space probe, and the like. Examples of radiation include X-rays and a neutron beam. Outer space refers to, for example, space at an altitude greater than or equal to 100 km, and outer space in this specification may also include thermosphere, mesosphere, and stratosphere.

Alternatively, for example, OS transistors can be used as transistors included in semiconductor devices provided in working robots in a nuclear power plant and a treatment plant or a disposal plant for radioactive wastes. In particular, OS transistors can be suitably used as transistors included in semiconductor devices provided in remote control robots that are controlled remotely in demolishment of a reactor facility, taking out of a nuclear fuel or a fuel debris, a field investigation on a space with a large amount of radioactive substance, and the like.

### Application Example of Semiconductor Device

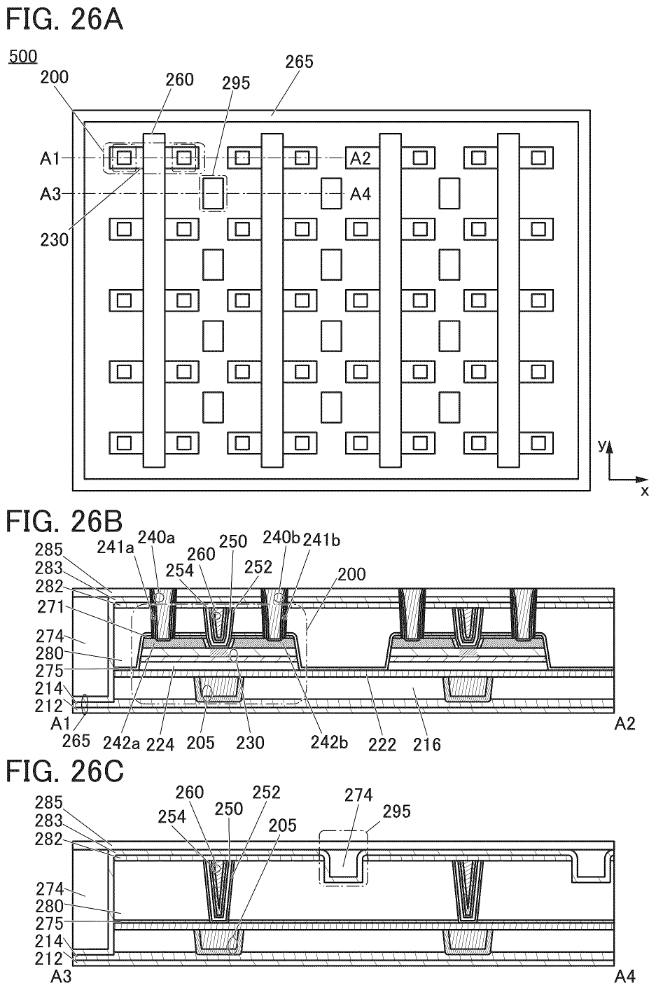

An example of the semiconductor device of one embodiment of the present invention is described below with reference to FIG. 26.

FIG. 26A is a top view of a semiconductor device 500. In FIG. 26A, the x-direction is parallel to the channel length direction of the transistor 200, and the y-direction is perpendicular to the x-direction. FIG. 26B is a cross-sectional view corresponding to a portion indicated by dashed-dotted line A1-A2 in FIG. 26A, and is also a cross-sectional view of the transistor 200 in the channel length direction. FIG. 26C is a cross-sectional view corresponding to a portion indicated by dashed-dotted line A3-A4 in FIG. 26A, and is also a cross-sectional view of an opening region 295 and the vicinity thereof. Note that some components are omitted in the top view of FIG. 26A for clarity of the drawing.

Note that in the semiconductor device illustrated in FIG. 26A to FIG. 26C, components having the same functions as the components included in the semiconductor device described in <Structure example of semiconductor device> are denoted by the same reference numerals. Note that the materials described in detail in <Structure example of semiconductor device> can be used as component materials of the semiconductor device also in this section.

The semiconductor device 500 illustrated in FIG. 26A to FIG. 26C is a modification example of the semiconductor device illustrated in FIG. 1A to FIG. 1D. The semiconductor device 500 illustrated in FIG. 26A to FIG. 26C differs from the semiconductor device illustrated in FIG. 1A to FIG. 1D in that the opening region 295 is formed in the insulator 282 and the insulator 280. Moreover, a sealing portion 265 is formed to surround a plurality of transistors 200, which is a different point from the semiconductor device illustrated in FIG. 1A to FIG. 1D.

The semiconductor device 500 includes a plurality of transistors 200 and a plurality of opening regions 295 arranged in a matrix. In addition, a plurality of conductors 260 functioning as gate electrodes of the transistors 200 are provided to extend in the y-direction. The opening regions 295 are provided in regions not overlapping with the oxide 230 or the conductor 260. The sealing portion 265 is formed to surround the plurality of transistors 200, the plurality of conductors 260, and the plurality of opening regions 295. Note that the number, the position, and the size of the transistors 200, the conductors 260, and the opening regions 295 are not limited to those illustrated in FIG. 26 and is set as appropriate in accordance with the design of the semiconductor device 500.

As illustrated in FIG. 26B and FIG. 26C, the sealing portion 265 is provided to surround the plurality of transistors 200, the insulator 216, the insulator 222, the insulator 275, the insulator 280, and the insulator 282. In other words, the insulator 283 is provided to cover the insulator 216, the insulator 222, the insulator 275, the insulator 280, and the insulator 282. In the sealing portion 265, the insulator 283 is in contact with the top surface of the insulator 214. Over the sealing portion 265, the insulator 274 is provided between the insulator 283 and the insulator 285. The top surface of the insulator 274 is substantially level with the uppermost surface of the insulator 283. As the insulator 274, an insulator similar to the insulator 280 can be used.

With such a structure, the plurality of transistors 200 can be surrounded by the insulator 283, the insulator 214, and the insulator 212. Here, one or more of the insulator 283, the insulator 214, and the insulator 212 preferably function as a barrier insulating film against hydrogen. Accordingly, entry of hydrogen contained in the region outside the sealing portion 265 into a region in the sealing portion 265 can be inhibited.

As illustrated in FIG. 26C, the insulator 282 in the opening region 295 has an opening portion. In the opening region 295, the insulator 280 may have a groove portion to overlap with the opening portion in the insulator 282. The depth of the groove portion of the insulator 280 is less than or equal to the depth at which the top surface of the insulator 275 is exposed and is, for example, approximately greater than or equal to ¼ and less than or equal to ½ of the maximum thickness of the insulator 280.

As illustrated in FIG. 26C, the insulator 283 inside the opening region 295 is in contact with the side surface of the insulator 282, the side surface of the insulator 280, and the top surface of the insulator 280. Part of the insulator 274 is formed in the opening region 295 to fill the depressed portion formed in the insulator 283 in some cases. At this time, the top surface of the insulator 274 formed in the opening region 295 is level or substantially level with the uppermost surface of the insulator 283, in some cases.

When heat treatment is performed in such a state that the opening region 295 is formed and the insulator 280 is exposed in the opening portion of the insulator 282, part of oxygen contained in the insulator 280 can be made to diffuse outwardly from the opening region 295 while oxygen is supplied to the oxide 230. This enables oxygen to be sufficiently supplied to the region functioning as the channel formation region and its vicinity in the oxide semiconductor layer from the insulator 280 containing excess oxygen, and also prevents an excess amount of oxygen from being supplied thereto.

At this time, hydrogen contained in the insulator 280 can be bonded to oxygen and released to the outside through the opening region 295. The hydrogen bonded to oxygen is released as water. Thus, the amount of hydrogen contained in the insulator 280 can be reduced, and hydrogen contained in the insulator 280 can be inhibited from entering the oxide 230.

In FIG. 26A, the shape of the opening region 295 in the top view is substantially rectangular; however, the present invention is not limited to the shape. For example, the shape of the opening region 295 in the top view can be a rectangular shape, an elliptical shape, a circular shape, a rhombus shape, or a shape obtained by combining any of the above shapes. The area and arrangement interval of the opening regions 295 can be set as appropriate in accordance with the design of the semiconductor device including the transistor 200. For example, in the region where the density of the transistors 200 is low, the area of the opening region 295 is increased, or the arrangement interval of the opening regions 295 is narrowed. For example, in the region where the density of the transistors 200 is high, the area of the opening region 295 is decreased, or the arrangement interval of the opening regions 295 is increased.

According to one embodiment of the present invention, a novel transistor can be provided. Alternatively, a semiconductor device with a small variation in transistor characteristics can be provided. Alternatively, a semiconductor device having favorable electrical characteristics can be provided. Alternatively, a semiconductor device having favorable reliability can be provided. Alternatively, a semiconductor device with a high on-state current can be provided. Alternatively, a semiconductor device with a high field-effect mobility can be provided. Alternatively, a semiconductor device with favorable frequency characteristics can be provided. Alternatively, a semiconductor device that can be miniaturized or highly integrated can be provided. Alternatively, a semiconductor device with low power consumption can be provided.

At least part of the structure, method, and the like described in this embodiment can be implemented in appropriate combination with any of the other embodiments and the examples described in this specification.

### Embodiment 2

In this embodiment, structure examples of a display device (display panel) of one embodiment of the present invention are described with reference to drawings. The transistor 200 described in the above embodiment can be used as a transistor included in the display device of one embodiment of the present invention. Note that the semiconductor device described in the above embodiment includes the transistor 200; therefore, it can be said that the display device includes a light-emitting element and the semiconductor device.

One embodiment of the present invention is a display device including a light-emitting element (also referred to as a light-emitting device). The display device includes two or more light-emitting elements that emit light of different colors. The light-emitting elements each include a pair of electrodes and an EL layer therebetween. The light-emitting elements are preferably organic EL elements (organic electroluminescent elements). The two or more light-emitting elements that exhibit different colors include EL layers containing different light-emitting materials. For example, when three kinds of light-emitting elements that emit red (R), green (G), and blue (B) light are included, a full-color display device can be achieved.

In the case of manufacturing a display device including a plurality of light-emitting elements that emit light of different emission colors, layers (light-emitting layers) containing at least light-emitting materials of different emission colors each need to be formed in an island shape. In the case of separately forming part of the whole of an EL layer, a method for forming an island-shaped organic film by an evaporation method using a shadow mask such as a metal mask is known. However, this method causes a deviation from the designed shape and position of the island-shaped organic film due to various influences such as the accuracy of the metal mask, the positional deviation between the metal mask and a substrate, a warp of the metal mask, and expansion of the outline of a deposited film due to vapor scattering, for example: accordingly, it is difficult to achieve a high resolution and a high aperture ratio of the display device. In addition, the outline of the layer might blur during evaporation, so that the thickness of an end portion might be reduced. That is, the thickness of an island-shaped light-emitting layer might vary from place to place. In addition, in the case of manufacturing a display device with a large size, high definition, or high resolution, a manufacturing yield might be reduced because of low dimensional accuracy of the metal mask and deformation due to heat or the like. Thus, a measure has been taken for a pseudo increase in resolution (also referred to as pixel density) by employing a unique pixel arrangement such as a PenTile arrangement.

Note that in this specification and the like, the term “island shape” refers to a state where two or more layers formed using the same material in the same step are physically separated from each other. For example, “island-shaped light-emitting layer” means a state where the light-emitting layer and its adjacent light-emitting layer are physically separated from each other.

In one embodiment of the present invention, fine patterning of EL layers is performed by photolithography without using a shadow mask such as a fine metal mask (an FMM). Accordingly, it is possible to achieve a display device with high resolution and a high aperture ratio, which has been difficult to achieve. Moreover, since the EL layers can be formed separately, it is possible to achieve a display device that performs extremely clear display with high contrast and high display quality. Note that fine patterning of the EL layers may be performed using both a metal mask and photolithography, for example.

In addition, part or the whole of an EL layer can be physically divided. This can inhibit leakage current flowing between adjacent light-emitting elements through a layer (also referred to as a common layer) shared by the light-emitting elements. This can prevent crosstalk due to unintended light emission, so that a display device with extremely high contrast can be achieved. In particular, a display device having high current efficiency at low luminance can be achieved.

In one embodiment of the present invention, the display device can be also obtained by combining a light-emitting element that emits white light with a color filter. In that case, light-emitting elements having the same structure can be employed as light-emitting elements provided in pixels (subpixels) that emit light of different colors, which allows all the layers to be common layers. In addition, part or the whole of each EL layer is divided by photolithography. Thus, leakage current through the common layer is suppressed; accordingly, a high-contrast display device can be achieved. In particular, when an element has a tandem structure in which a plurality of light-emitting layers are stacked with a highly conductive intermediate layer therebetween, leakage current through the intermediate layer can be effectively prevented, so that a display device with high luminance, high resolution, and high contrast can be achieved.

Furthermore, an insulating layer covering at least a side surface of the island-shaped light-emitting layer is preferably provided. The insulating layer may cover part of a top surface of an island-shaped EL layer. For the insulating layer, a material having a barrier property against water and oxygen is preferably used. For example, an inorganic insulating film in which water or oxygen is less likely to diffuse can be used. This can inhibit degradation of the EL layer and can achieve a highly reliable display device.

Moreover, between two adjacent light-emitting elements, there is a region (a depressed portion) where none of the EL layers of the light-emitting elements is provided. In the case where a common electrode or a common electrode and a common layer are formed to cover the depressed portion, a phenomenon where the common electrode is divided by a step at an end portion of the EL layer (such a phenomenon is also referred to as disconnection) might occur, which might cause insulation of the common electrode over the EL layer. In view of this, a local gap positioned between two adjacent light-emitting elements is preferably filled with a resin layer functioning as a planarization film (also referred to as LFP: Local Filling Planarization). The resin layer has a function of the planarization film. This structure can inhibit disconnection of the common layer or the common electrode and can achieve a highly reliable display device.

### [Display Module]

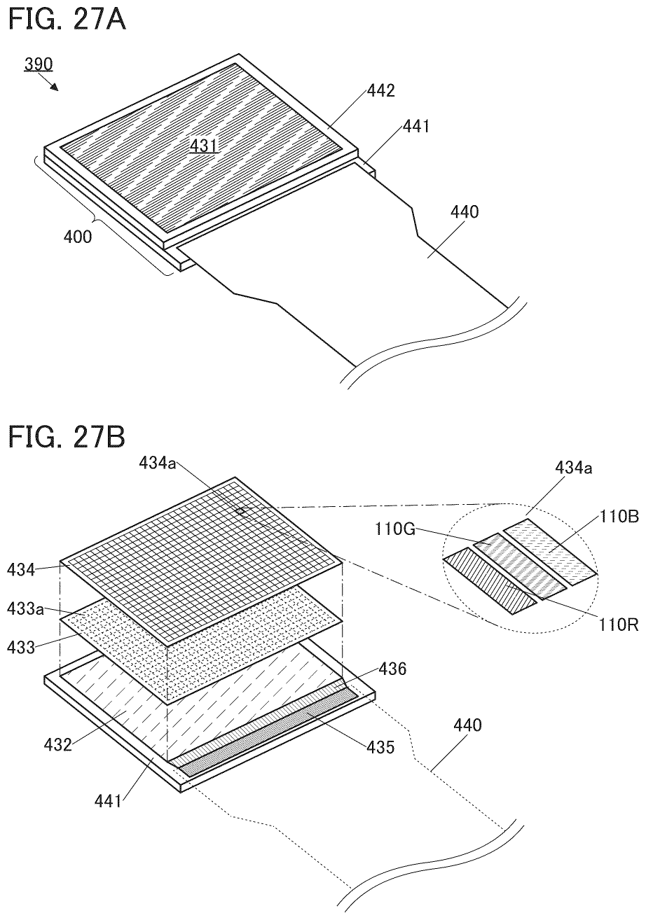

FIG. 27A is a perspective view of a display module 390. The display module 390 includes a display device 400 and an FPC 440. Note that a display panel included in the display module 390 is not limited to the display device 400 and may be any of a display device 400A to a display device 400D described later.

The display module 390 includes a substrate 441 and a substrate 442. The display module 390 includes a display portion 431. The display portion 431 is a region where an image is displayed.

FIG. 27B is a perspective view schematically illustrating a structure on the substrate 441 side. Over the substrate 441, a circuit portion 432, a pixel circuit portion 433 over the circuit portion 432, and a pixel portion 434 over the pixel circuit portion 433 are stacked. A terminal portion 435 to be connected to the FPC 440 is provided in a portion over the substrate 441 that does not overlap with the pixel portion 434. The terminal portion 435 and the circuit portion 432 are electrically connected to each other with a wiring portion 436 formed of a plurality of wirings.

The pixel portion 434 includes a plurality of pixels 434a arranged periodically. An enlarged view of one pixel 434a is illustrated on the right side of FIG. 27B. The pixel 434a includes a light-emitting element 110R that emits red light, a light-emitting element 110G that emits green light, and a light-emitting element 110B that emits blue light.

The pixel circuit portion 433 includes a plurality of pixel circuits 433a arranged periodically. One pixel circuit 433a is a circuit that controls light emission of three light-emitting devices included in one pixel 434a. One pixel circuit 433a may be provided with three circuits each of which controls light emission of one light-emitting device. For example, the pixel circuit 433a can include at least one selection transistor, one current control transistor (driving transistor), and a capacitor for one light-emitting device. In this case, a gate signal is input to a gate of the selection transistor, and a source signal is input to a source of the selection transistor. Thus, an active-matrix display panel is achieved.

The transistor 200 described in the above embodiment can be used as at least one of the transistors included in the pixel circuit 433a.

The circuit portion 432 includes a circuit for driving the pixel circuits 433a in the pixel circuit portion 433. For example, one or both of a gate line driver circuit and a source line driver circuit are preferably included. In addition, at least one of an arithmetic circuit, a memory circuit, a power supply circuit, and the like may be included. Note that the transistor 200 described in the above embodiment may be used as at least one of the transistors included in the circuit portion 432.

A transistor included in the circuit portion 432 may constitute part of the pixel circuit 433a. That is, the pixel circuit 433a may be constituted by a transistor included in the pixel circuit portion 433 and a transistor included in the circuit portion 432.

The FPC 440 functions as a wiring for supplying a video signal, a power supply potential, or the like to the circuit portion 432 from the outside. An IC may be mounted on the FPC 440.

The display module 390 can have a structure where one or both of the pixel circuit portion 433 and the circuit portion 432 are stacked below the pixel portion 434; hence, the aperture ratio (effective display area ratio) of the display portion 431 can be significantly high. For example, the aperture ratio of the display portion 431 can be higher than or equal to 40% and lower than 100%, preferably higher than or equal to 50% and lower than or equal to 95%, further preferably higher than or equal to 60% and lower than or equal to 95%. Furthermore, the pixels 434a can be arranged extremely densely and thus the display portion 431 can have extremely high resolution. For example, the pixels 434a are preferably arranged in the display portion 431 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 390 has extremely high resolution, and thus can be suitably used for a device for VR such as a head-mounted display or a glasses-type device for AR. For example, even in the case of a structure in which the display portion of the display module 390 is seen through a lens, pixels of the extremely-high-resolution display portion 431 included in the display module 390 are not seen when the display portion is enlarged by the lens, so that display providing a high sense of immersion can be performed. Without being limited thereto, the display module 390 can also be suitably used for an electronic device having a relatively small display portion. For example, the display module 390 can be suitably used for a display portion of a wearable electronic device, such as a wrist watch.

### [Structure Example of Pixel Circuit]

Structure examples of a pixel circuit that can be used in the display device of one embodiment of the present invention are described below.

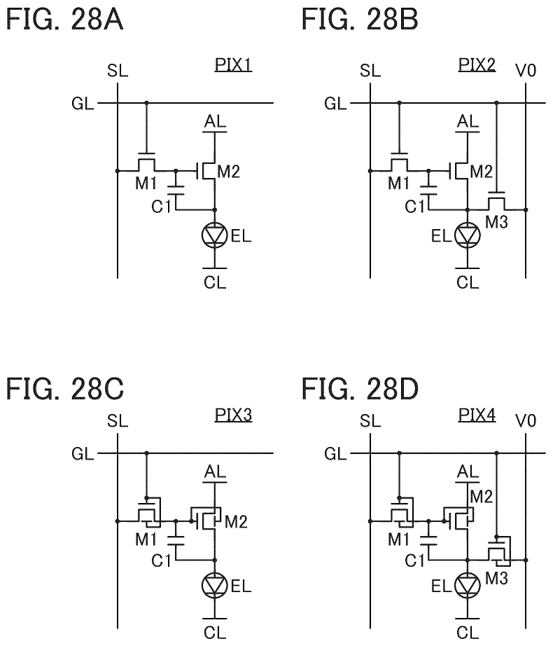

A pixel circuit PIX1 illustrated in FIG. 28A includes a transistor M1, a transistor M2, a capacitor C1, and a light-emitting element EL. A wiring SL, a wiring GL, a wiring AL, and a wiring CL are electrically connected to the pixel circuit PIX1.

A gate of the transistor M1 is electrically connected to the wiring GL, one of a source and a drain of the transistor M1 is electrically connected to the wiring SL, and the other of the source and the drain of the transistor M1 is electrically connected to a gate of the transistor M2 and one electrode of the capacitor C1. One of a source and a drain of the transistor M2 is electrically connected to the wiring AL, and the other of the source and the drain of the transistor M2 is electrically connected to an anode of the light-emitting element EL. The other electrode of the capacitor C1 is electrically connected to the anode of the light-emitting element EL. A cathode of the light-emitting element EL is electrically connected to the wiring CL.

The transistor M1 can also be referred to as a selection transistor and functions as a switch for controlling selection/non-selection of the pixel. The transistor M2 can also be referred to as a driving transistor and has a function of controlling current flowing to the light-emitting element EL. The capacitor C1 functions as a storage capacitor and has a function of retaining a gate potential of the transistor M2. A capacitor such as a MIM capacitor may be used as the capacitor C1; alternatively, capacitance between wirings, a gate capacitance of the transistor, or the like may be used as the capacitor C1.

The wiring SL is supplied with a source signal. The wiring GL is supplied with a gate signal. The wiring AL and the wiring CL are each supplied with a constant potential. The anode side of the light-emitting element EL can be set to a high potential, and the cathode side thereof can be set to a lower potential than the anode side.

A pixel circuit PIX2 illustrated in FIG. 28B has a structure in which a transistor M3 is added to the pixel circuit PIX1. In addition, a wiring V0 is electrically connected to the pixel circuit PIX2.

A gate of the transistor M3 is electrically connected to the wiring GL, one of a source and a drain of the transistor M3 is electrically connected to the anode of the light-emitting element EL, and the other of the source and the drain of the transistor M3 is electrically connected to the wiring V0.

The wiring V0 is supplied with a constant potential when data is written to the pixel circuit PIX2. Thus, a variation in the gate-source voltage of the transistor M2 can be inhibited.

A pixel circuit PIX3 illustrated in FIG. 28C is an example of the case where a transistor in which a pair of gates are electrically connected to each other is used as each of the transistor M1 and the transistor M2 of the pixel circuit PIX1. A pixel circuit PIX4 illustrated in FIG. 28D is an example of the case where such transistors are used in the pixel circuit PIX2. Thus, current that can flow through the transistors can be increased. Note that although a transistor in which a pair of gates are electrically connected to each other is used as each of the transistors here, one embodiment of the present invention is not limited thereto. A transistor that includes a pair of gates electrically connected to different wirings may be used. For example, when a transistor in which one of the gates is electrically connected to the source is used, the reliability can be increased.

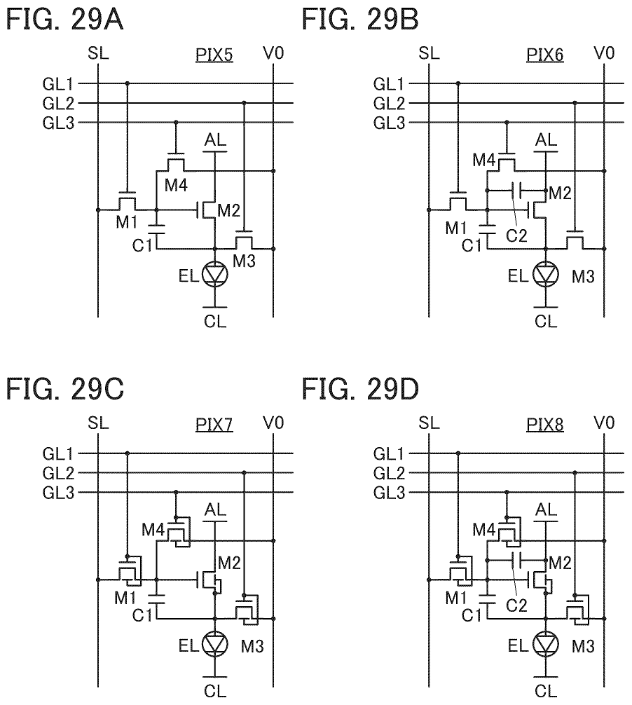

A pixel circuit PIX5 illustrated in FIG. 29A has a structure in which a transistor M4 is added to the pixel circuit PIX2. Three wirings (a wiring GL1, a wiring GL2, and a wiring GL3) functioning as gate lines are electrically connected to the pixel circuit PIX5.

A gate of the transistor M4 is electrically connected to the wiring GL3, one of a source and a drain of the transistor M4 is electrically connected to the gate of the transistor M2, and the other of the source and the drain of the transistor M4 is electrically connected to the wiring V0. The gate of the transistor M1 is electrically connected to the wiring GL1, and the gate of the transistor M3 is electrically connected to the wiring GL2.

When the transistor M3 and the transistor M4 are turned on at the same time, the source and the gate of the transistor M2 have the same potential, so that the transistor M2 can be turned off. Thus, current flowing to the light-emitting element EL can be blocked forcibly. Such a pixel circuit is suitable for the case of using a display method in which a display period and a non-lighting period are alternately provided.

A pixel circuit PIX6 illustrated in FIG. 29B is an example of the case where a capacitor C2 is added to the pixel circuit PIX5. One electrode of the capacitor C2 is electrically connected to the gate of the transistor M2, and the other electrode of the capacitor C2 is electrically connected to the wiring AL. The capacitor C2 functions as a storage capacitor.

A pixel circuit PIX7 illustrated in FIG. 29C is an example of the case where transistors each including a pair of gates are employed in the pixel circuit PIX5. A pixel circuit PIX8 illustrated in FIG. 29D is an example of the case where transistors each including a pair of gates are employed in the pixel circuit PIX6. A transistor including a pair of gates electrically connected to each other is used as each of the transistor M1, the transistor M3, and the transistor M4, and a transistor whose source is electrically connected to one of the gates is used as the transistor M2.

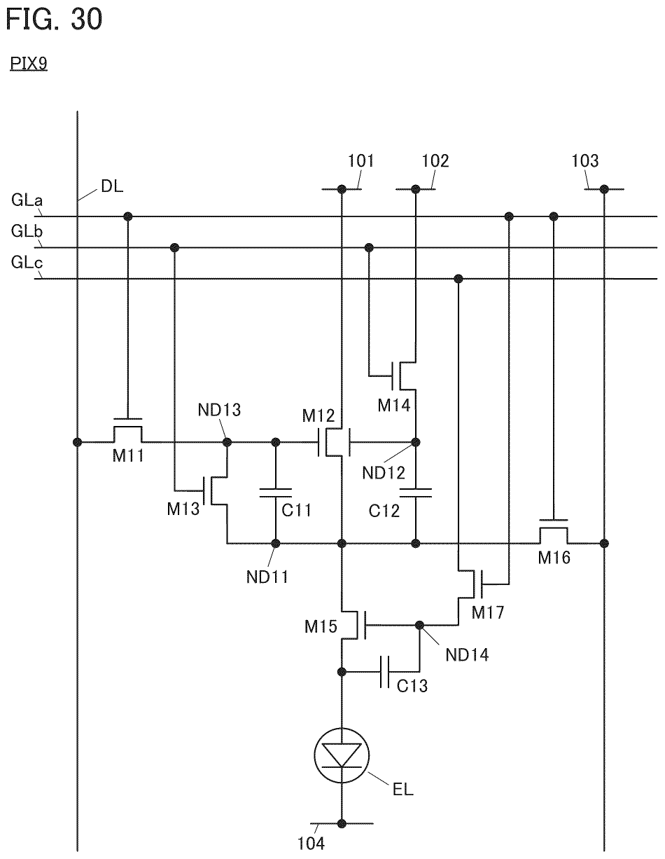

A pixel circuit PIX9 illustrated in FIG. 30 includes a transistor M11 to a transistor M17, a capacitor C11 to a capacitor C13, and a light-emitting element EL.

Note that in this specification and the like, unless otherwise specified, the transistor M11 to the transistor M17 are enhancement-mode (normally-off) n-channel field-effect transistors. Thus, the threshold voltages (Vth) are higher than 0 V.

One terminal of the light-emitting element EL is electrically connected to one of a source and a drain of the transistor M15 and one terminal of the capacitor C13. The other terminal of the light-emitting element EL is electrically connected to a wiring 104. For example, the one terminal of the light-emitting element EL can be an anode terminal, and the other terminal of the light-emitting element EL can be a cathode terminal. Note that the one terminal of the light-emitting element EL may be a cathode terminal, and the other terminal of the light-emitting element EL may be an anode terminal.

A gate of the transistor M15 is electrically connected to the other terminal of the capacitor C13 and one of a source and a drain of the transistor M17. The other of the source and the drain of the transistor M15 is electrically connected to one terminal of the capacitor C11, one terminal of the capacitor C12, one of a source and a drain of the transistor M12, one of a source and a drain of the transistor M13, and one of a source and a drain of the transistor M16.

A gate of the transistor M12 is electrically connected to the other terminal of the capacitor C11, the other of the source and the drain of the transistor M13, and one of a source and a drain of the transistor M11. The transistor M12 includes a back gate. The back gate of the transistor M12 is electrically connected to the other terminal of the capacitor C12 and one of a source and a drain of the transistor M14.

The other of the source and the drain of the transistor M11 is electrically connected to a wiring DL, and a gate of the transistor M11 is electrically connected to a wiring GLa. The transistor M11 has a function of selecting whether to establish electrical continuity between the gate of the transistor M12 and the wiring DL.

The other of the source and the drain of the transistor M12 is electrically connected to a wiring 101. The transistor M12 includes the back gate. The transistor M12 has a function of controlling the amount of current flowing through the light-emitting element EL. That is, the transistor M12 has a function of controlling the amount of light emitted from the light-emitting element EL. Thus, the transistor M12 can be referred to as a “driving transistor”.

A gate of the transistor M13 is electrically connected to a wiring GLb. The transistor M13 has a function of selecting whether to establish electrical continuity between the gate and the source of the transistor M12.

A gate of the transistor M14 is electrically connected to the wiring GLb, and the other of the source and the drain of the transistor M14 is electrically connected to a wiring 102. The transistor M14 has a function of selecting whether to establish electrical continuity between the wiring 102 and the one terminal of the capacitor C12.

The transistor M15 has a function of switching electrical continuity between the transistor M12 and the light-emitting element EL. The light-emitting element EL is off when the transistor M15 is in the off state, and the light-emitting element EL can emit light when the transistor M15 is in the on state. In order to surely supply current with the amount determined by the driving transistor to the light-emitting element EL, the transistor M15 needs to be surely turned on regardless of the values of the source potential and the drain potential.

A gate of the transistor M16 is electrically connected to the wiring GLa, and the other of the source and the drain of the transistor M16 is electrically connected to a wiring 103. The transistor M16 has a function of selecting whether to establish electrical continuity between the one of the source and the drain of the transistor M12 and the wiring 103.

A gate of the transistor M17 is electrically connected to the wiring GLa, and the other of the source and the drain of the transistor M17 is electrically connected to a wiring GLc. The transistor M17 has a function of selecting whether to establish electrical continuity between the gate of the transistor M15 and the wiring GLc.

A region where the one terminal of the capacitor C11, the one terminal of the capacitor C12, the one of the source and the drain of the transistor M12, the one of the source and the drain of the transistor M13, the other of the source and the drain of the transistor M15, and the one of the source and the drain of the transistor M16 are electrically connected to one another is also referred to as a node ND11.

A region where the other terminal of the capacitor C12, the back gate of the transistor M12, and the one of the source and the drain of the transistor M14 are electrically connected to one another is also referred to as a node ND12.

A region where the one of the source and the drain of the transistor M11, the other of the source and the drain of the transistor M13, the other terminal of the capacitor C11, and the gate of the transistor M12 are electrically connected to one another is also referred to as a node ND13.

A region where the gate of the transistor M15, the other terminal of the capacitor C13, and the one of the source and the drain of the transistor M17 are electrically connected to one another is also referred to as a node ND14.

The capacitor C11 has a function of retaining a potential difference between the one of the source and the drain of the transistor M12 and the gate of the transistor M12 at the time when the node ND13 is in a floating state. The capacitor C12 has a function of retaining a potential difference between the one of the source and the drain of the transistor M12 and the back gate of the transistor M12 at the time when the node ND12 is in a floating state. The capacitor C13 has a function of retaining a potential difference between the one of the source and the drain of the transistor M15 and the gate of the transistor M15 at the time when the node ND14 is in a floating state.

The capacitor C11 to the capacitor C13 preferably have high capacitances. In particular, the capacitances of the capacitor C11 and the capacitor C12 are preferably high and preferably higher than the capacitance of the capacitor C13. The capacitances of the capacitor C11 and the capacitor C12 are each preferably greater than or equal to 2 fF, further preferably greater than or equal to 4 fF, still further preferably greater than or equal to 6 fF, yet further preferably greater than or equal to 8 fF, yet still further preferably greater than or equal to 10 fF. The capacitance of the capacitor C13 is preferably greater than or equal to 1 fF, further preferably greater than or equal to 2 fF, still further preferably greater than or equal to 3 fF, yet further preferably greater than or equal to 4 fF, yet still further preferably greater than or equal to 5 fF. Note that since higher capacitances of the capacitor C11 to the capacitor C13 are preferable, the upper limits do not need to be particularly provided for the capacitances of the capacitor C11 to the capacitor C13. However, in the case where the upper limits are provided, the capacitances of the capacitor C11 and the capacitor C12 are set to less than or equal to 20 fF, and the capacitance of the capacitor C13 is set to less than or equal to 10 fF.

When the capacitance of the capacitor C11 is high, the potential difference between the one of the source and the drain of the transistor M12 and the gate of the transistor M12 can be retained for a long time. When the capacitance of the capacitor C12 is high, the potential difference between the one of the source and the drain of the transistor M12 and the back gate of the transistor M12 can be retained for a long time. When the capacitance of the capacitor C13 is high, the potential difference between the one of the source and the drain of the transistor M15 and the gate of the transistor M15 can be retained for a long time.

Since data retained in the capacitor C11 and the capacitor C12 greatly affects the display quality, the influence of external noise is preferably small. When the capacitances of the capacitor C11 and the capacitor C12 are high, the influence of external noise can be reduced, so that a display device with high display quality can be achieved. The capacitor C11 preferably retains data longer than one frame period. Similarly, the capacitor C12 preferably retains data longer than one frame period, further preferably longer than or equal to 1 second, still further preferably longer than or equal to 1 minute, yet still further preferably longer than or equal to 1 hour. Thus, the capacitance of the capacitor C12 may be higher than the capacitance of the capacitor C11. Meanwhile, the capacitance of the capacitor C13 may be lower than the capacitances of the capacitor C11 and the capacitor C12 as long as the capacitor C13 can retain a voltage that can sufficiently make the transistor M15 in an on state.

The capacitance of the capacitor C11 is preferably higher than or equal to 2 times, further preferably higher than or equal to 3 times, still further preferably higher than or equal to 4 times, yet further preferably higher than or equal to 5 times the capacitance of the capacitor C13. The capacitance of the capacitor C12 is preferably higher than or equal to 2 times, further preferably higher than or equal to 3 times, still further preferably higher than or equal to 4 times, yet further preferably higher than or equal to 5 times the capacitance of the capacitor C13.

In a top view, the area of the capacitor C11 is preferably larger than or equal to 2 times, further preferably larger than or equal to 3 times, still further preferably larger than or equal to 4 times, yet further preferably larger than or equal to 5 times the area of the capacitor C13. The area of the capacitor C12 is preferably larger than or equal to 2 times, further preferably larger than or equal to 3 times, still further preferably larger than or equal to 4 times, yet further preferably larger than or equal to 5 times the area of the capacitor C13.

Note that in this specification and the like, the area of a capacitor refers to the area of a region where the upper electrode and the lower electrode of the capacitor overlap with each other.

In the case where any one of the pixel circuit PIX1 to the pixel circuit PIX9 is used as the pixel circuit included in the display device of one embodiment of the present invention, an OS transistor such as the transistor 200 described in the above embodiment is preferably used as at least one of the transistors included in the pixel circuit. An oxide semiconductor has a band gap of 2 eV or more; thus, an OS transistor has an extremely small off-state current value. Thus, when the OS transistor is used in the pixel circuit, charge written to the nodes can be retained for a long period. For example, in the case of displaying a still image for which rewriting every frame is not required, displaying an image can be kept even when the operation of a peripheral driver circuit is stopped. Such a driving method in which the operation of a peripheral driver circuit is stopped during displaying a still image is also referred to as “idling stop driving”. The power consumption of a display device can be reduced by performing idling stop driving.

The off-state current of the OS transistor hardly increases even in a high temperature environment. Specifically, the off-state current of the OS transistor hardly increases even at an environment temperature higher than or equal to room temperature and lower than or equal to 200° C. Furthermore, the on-state current of the OS transistor is unlikely to decrease even in a high-temperature environment. A display device including the OS transistor can operate stably and have high reliability even in a high-temperature environment.

The OS transistor has a high source-drain withstand voltage. The use of the OS transistor in the pixel circuit PIX9, for example, makes the operation stable even in the case where a potential difference between a potential Va and a potential Vc is large, so that the display device can have favorable reliability. It is particularly preferable to use the OS transistor as one or both of the transistor M12 and the transistor M15.

The pixel circuit may include a plurality of kinds of transistors formed using different semiconductor materials. For example, the pixel circuit may include LTPS transistors and OS transistors. A structure in which the LTPS transistors and the OS transistors are combined is referred to as LTPO in some cases. Note that the LTPS transistor refers to a transistor including low-temperature polysilicon (LTPS) in its channel formation region. The LTPS transistor has high field-effect mobility and excellent frequency characteristics.

In the case where the pixel circuit includes a plurality of kinds of transistors formed using different semiconductor materials, the transistors may be provided in different layers for each kind of transistor. For example, in the case where the pixel circuit includes Si transistors and OS transistors, a layer including the Si transistors and a layer including the OS transistors may be provided to overlap with each other. Such a structure can reduce the area of the pixel circuit.

Either or both of the Si transistors and the OS transistors may be used as the transistors included in the peripheral driver circuit. For example, OS transistors may be used as the transistors included in the pixel circuit, and Si transistors may be used as the transistors included in the peripheral driver circuit. The off-state current of the OS transistor is low, so that power consumption can be reduced. Since the Si transistor has a higher operation speed than the OS transistor, the Si transistor is suitably used in the peripheral driver circuit. The display device may include the OS transistors as both the transistors included in the pixel circuit and the transistors included in the peripheral driver circuit and the peripheral driver circuit. Alternatively, the display device may include the Si transistors as the transistors included in the pixel circuit and the OS transistors as the transistors included in the peripheral driver circuit.

Among the transistors included in the pixel circuit PIX9, for example, the transistor M11 and the transistor M13 to the transistor M17 each function as a switch. Therefore, the transistor M11 and the transistor M13 to the transistor M17 can be replaced with elements that can function as switches.

Although FIG. 30 illustrates a structure in which the transistor M12 includes the back gate and the transistors other than the transistor M12 do not include a back gate, one embodiment of the present invention is not limited thereto. The transistors other than the transistor M12 may include a back gate.

A multi-channel-type transistor may be used in the pixel circuit. The multi-channel-type transistor includes a plurality of gates electrically connected to each other and includes a plurality of regions where a semiconductor layer and the gates overlap with each other between a source and a drain. That is, a multi-channel-type transistor includes a plurality of gates electrically connected to each other and includes a plurality of channel formation regions between a source and a drain. Note that in this specification and the like, a multi-channel-type transistor is referred to as a “multi-channel transistor”, a “multi-gate transistor”, or a “multi-gate-type transistor” in some cases.

The structure of the transistor included in the display device of one embodiment of the present invention is not limited to the above structure. For example, any of transistors having a variety of structures such as a planar type, a FIN-type, a TRI-GATE type, a top-gate type, a bottom-gate type, and a dual-gate type (a structure in which gates are placed above and below a channel) can be used in the pixel circuit and the peripheral driver circuit. A MOS transistor, a junction transistor, a bipolar transistor, or the like can be used as the transistor according to one embodiment of the present invention.

Note that a semiconductor material used in a transistor included in the display device of one embodiment of the present invention is not limited to the above materials. For example, the transistor may include a single crystal semiconductor, a polycrystalline semiconductor, a microcrystalline semiconductor, or an amorphous semiconductor in its channel formation region. Furthermore, a compound semiconductor (e.g., gallium arsenide (GaAs), indium phosphide (InP), gallium nitride (GaN), or silicon germanium (SiGe)), an oxide semiconductor, or the like as well as a single element semiconductor whose main component is a single element (e.g., silicon (Si) or germanium (Ge)) may be used as the semiconductor material.

Note that in this embodiment and the like, an example is described in which the display device is formed using n-channel transistors; however, one embodiment of the present invention is not limited thereto. As some or all of the transistors included in the display device, p-channel transistors may be used.

### [Structure Example of Display Device]

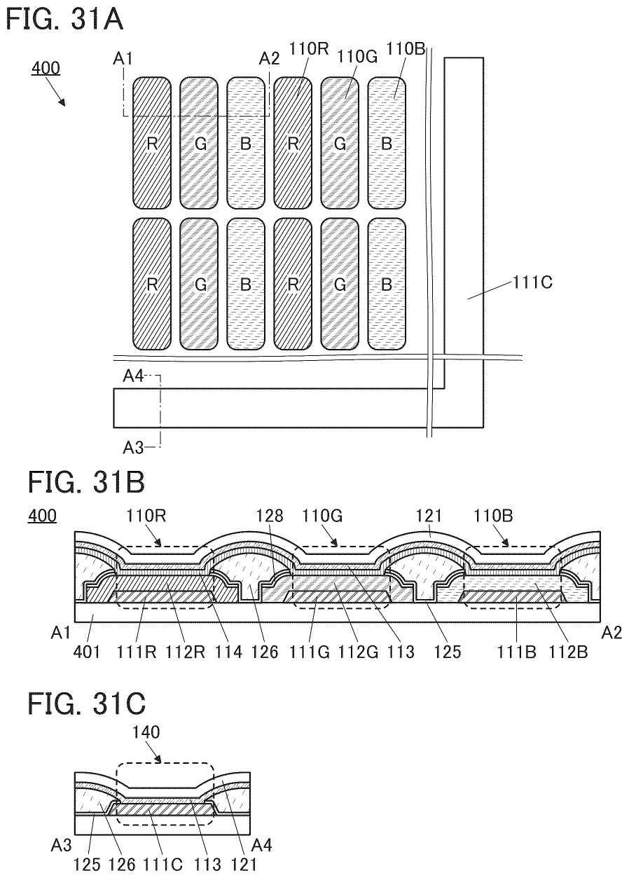

FIG. 31A illustrates a schematic top view of the display device 400 of one embodiment of the present invention. The display device 400 includes, over a substrate 401, a plurality of light-emitting elements 110R exhibiting red, a plurality of light-emitting elements 110G exhibiting green, and a plurality of light-emitting elements 110B exhibiting blue. In FIG. 31A, light-emitting regions of the light-emitting elements are denoted by R, G, and B to easily differentiate the light-emitting elements.

The light-emitting elements 110R, the light-emitting elements 110G, and the light-emitting elements 110B are arranged in a matrix. FIG. 31A illustrates what is called a stripe arrangement, in which light-emitting elements of the same color are arranged in one direction.

Note that an arrangement method of the light-emitting elements is not limited thereto; an arrangement method such as an S-stripe arrangement, a delta arrangement, a Bayer arrangement, or a zigzag arrangement may be employed, or a PenTile arrangement, a diamond arrangement, or the like can be also used.

As each of the light-emitting elements 110R, the light-emitting elements 110G, and the light-emitting elements 110B, an OLED (Organic Light Emitting Diode) or a QLED (Quantum-dot Light Emitting Diode) is preferably used, for example. Examples of a light-emitting substance contained in the EL element include a substance that emits fluorescent light (a fluorescent material), a substance that emits phosphorescent light (a phosphorescent material), a substance that exhibits thermally activated delayed fluorescence (a thermally activated delayed fluorescence (TADF) material), and an inorganic compound (e.g., a quantum dot material).

FIG. 31A also illustrates a connection electrode 111C that is electrically connected to a common electrode 113. The connection electrode 111C is supplied with a potential (e.g., an anode potential or a cathode potential) that is to be supplied to the common electrode 113. The connection electrode 111C is provided outside a display region where the light-emitting elements 110R and the like are arranged.

The connection electrode 111C can be provided along the outer periphery of the display region. For example, the connection electrode 111C may be provided along one side of the outer periphery of the display region or may be provided along two or more sides of the outer periphery of the display region. That is, in the case where the display region has a rectangular top surface shape, a top surface shape of the connection electrode 111C can have a band shape (a rectangle), an L shape, a U shape (a square bracket shape), a quadrangular shape, or the like.

FIG. 31B and FIG. 31C are each a schematic cross-sectional view corresponding to the dashed-dotted line A1-A2 and the dashed-dotted line A3-A4 in FIG. 31A. FIG. 31B illustrates a schematic cross-sectional view of the light-emitting element 110R, the light-emitting element 110G, and the light-emitting element 110B, and FIG. 31C illustrates a schematic cross-sectional view of a connection portion 140 where the connection electrode 111C and the common electrode 113 are connected to each other.

The light-emitting element 110R includes a pixel electrode 111R, an organic layer 112R, a common layer 114, and the common electrode 113. The light-emitting element 110G includes a pixel electrode 111G, an organic layer 112G, the common layer 114, and the common electrode 113. The light-emitting element 110B includes a pixel electrode 111B, an organic layer 112B, the common layer 114, and the common electrode 113. The common layer 114 and the common electrode 113 are provided to be shared by the light-emitting element 110R, the light-emitting element 110G, and the light-emitting element 110B.

The organic layer 112R included in the light-emitting element 110R contains at least a light-emitting organic compound that emits light with intensity in a red wavelength range. The organic layer 112G included in the light-emitting element 110G contains at least a light-emitting organic compound that emits light with intensity in a green wavelength range. The organic layer 112B included in the light-emitting element 110B contains at least a light-emitting organic compound that emits light with intensity in a blue wavelength range. Each of the organic layer 112R, the organic layer 112G, and the organic layer 112B can be also referred to as an EL layer and includes at least a layer containing a light-emitting organic compound (a light-emitting layer).

Hereinafter, the term “light-emitting element 110” is sometimes used to describe matters common to the light-emitting element 110R, the light-emitting element 110G, and the light-emitting element 110B. Similarly, in the description of matters common to components that are distinguished from each other using alphabets, such as the organic layer 112R, the organic layer 112G, and the organic layer 112B, reference numerals without alphabets are sometimes used.

The organic layer 112 and the common layer 114 can each independently include one or more of an electron-injection layer, an electron-transport layer, a hole-injection layer, and a hole-transport layer. For example, it is possible to employ a structure in which the organic layer 112 includes a stacked-layer structure of a hole-injection layer, a hole-transport layer, a light-emitting layer, and an electron-transport layer from the pixel electrode 111 side and the common layer 114 includes an electron-injection layer.

The pixel electrode 111R, the pixel electrode 111G, and the pixel electrode 111B are provided for the respective light-emitting elements. In addition, the common electrode 113 and the common layer 114 are each provided as a continuous layer shared by the light-emitting elements. A conductive film having a property of transmitting visible light is used for either the pixel electrodes or the common electrode 113, and a conductive film having a reflective property is used for the other. When the pixel electrodes have a light-transmitting property and the common electrode 113 has a reflective property, a bottom-emission display device can be obtained. In contrast, when the pixel electrodes have a reflective property and the common electrode 113 has a light-transmitting property, a top-emission display device can be obtained. Note that when both the pixel electrodes and the common electrode 113 have a light-transmitting property, a dual-emission display device can be also obtained.

A protective layer 121 is provided over the common electrode 113 to cover the light-emitting element 110R, the light-emitting element 110G, and the light-emitting element 110B. The protective layer 121 has a function of preventing diffusion of impurities such as water into each light-emitting element from the above.

An end portion of the pixel electrode 111 preferably has a tapered shape. In the case where the pixel electrode 111 has an end portion with a tapered shape, the organic layer 112 that is provided along the side surface of the pixel electrode 111 also has a tapered shape. When the side surfaces of the pixel electrodes have a tapered shape, coverage with the EL layers provided along the side surfaces of the pixel electrodes can be improved. Furthermore, when the side surfaces of the pixel electrodes have a tapered shape, a foreign substance (for example, also referred to as dust or particles) in a manufacturing step is easily removed by processing such as cleaning, which is preferable.

The organic layer 112 is processed into an island shape by a photolithography method. Thus, an angle formed between a top surface and a side surface of an end portion of the organic layer 112 is approximately 90°. By contrast, an organic film formed using an FMM or the like has a thickness that tends to gradually decrease with decreasing distance to the end portion, and the top surface has a slope shape in the range of greater than or equal to 1 μm and less than or equal to 10 μm, for example; thus, such an organic film has a shape whose top surface and side surface cannot be easily distinguished from each other.

An insulating layer 125, a resin layer 126, and a layer 128 are included between two adjacent light-emitting elements.

Between two adjacent light-emitting elements, side surfaces of the organic layers 112 are provided to face each other with the resin layer 126 therebetween. The resin layer 126 is positioned between the two adjacent light-emitting elements and is provided to bury end portions of the organic layers 112 and a region between the two organic layers 112. The resin layer 126 has a top surface with a smooth convex shape. The common layer 114 and the common electrode 113 are provided to cover the top surface of the resin layer 126.

The resin layer 126 functions as a planarization film that fills a step positioned between two adjacent light-emitting elements. Providing the resin layer 126 can prevent a phenomenon in which the common electrode 113 is divided by a step at an end portion of the organic layer 112 (such a phenomenon is also referred to as disconnection) from occurring and the common electrode over the organic layer 112 from being insulated. The resin layer 126 can also be referred to as an LFP.

An insulating layer containing an organic material can be suitably used as the resin layer 126. For the resin layer 126, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of these resins, or the like can be used, for example. For the resin layer 126, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin may be used.

Alternatively, a photosensitive resin can be used for the resin layer 126. A photoresist may be used as the photosensitive resin. As the photosensitive resin, a positive material or a negative material can be used.

The resin layer 126 may contain a material absorbing visible light. For example, the resin layer 126 itself may be made of a material absorbing visible light, or the resin layer 126 may contain a pigment absorbing visible light. For example, for the resin layer 126, it is possible to use a resin that can be used as a color filter transmitting red, blue, or green light and absorbing other light, a resin that contains carbon black as a pigment and functions as a black matrix, or the like.

The insulating layer 125 is provided in contact with the side surfaces of the organic layers 112. In addition, the insulating layer 125 is provided to cover an upper end portion of the organic layer 112. Furthermore, part of the insulating layer 125 is provided in contact with a top surface of the substrate 401.

The insulating layer 125 is positioned between the resin layer 126 and the organic layer 112 and functions as a protective film for preventing contact between the resin layer 126 and the organic layer 112. When the organic layer 112 and the resin layer 126 are in contact with each other, the organic layer 112 might be dissolved by an organic solvent or the like used at the time of forming the resin layer 126. Therefore, the insulating layer 125 is provided between the organic layer 112 and the resin layer 126 as described in this embodiment to protect the side surfaces of the organic layer 112.

An insulating layer containing an inorganic material can be used for the insulating layer 125. For the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, when a metal oxide film such as an aluminum oxide film or a hafnium oxide film or an inorganic insulating film such as a silicon oxide film that is formed by an ALD method is employed for the insulating layer 125, it is possible to form the insulating layer 125 that has a small number of pinholes and has an excellent function of protecting the EL layer.

Note that in this specification and the like, oxynitride refers to a material that contains more oxygen than nitrogen in its composition, and nitride oxide refers to a material that contains more nitrogen than oxygen in its composition. For example, an aluminum oxynitride refers to a material that contains more oxygen than nitrogen in its composition, and an aluminum nitride oxide refers to a material that contains more nitrogen than oxygen in its composition. The insulating layer 125 can be formed by a sputtering method, a CVD method, a PLD method, an ALD method, or the like. The insulating layer 125 is preferably formed by an ALD method with excellent coverage.

In addition, a structure may be employed in which a reflective film (e.g., a metal film containing one or more selected from silver, palladium, copper, titanium, aluminum, and the like) is provided between the insulating layer 125 and the resin layer 126 so that light emitted from the light-emitting layer is reflected by the reflective film. This can improve light extraction efficiency.

The layer 128 is a remaining part of a protective layer (also referred to as a mask layer or a sacrificial layer) for protecting the organic layer 112 during etching of the organic layer 112. For the layer 128, a material that can be used for the insulating layer 125 can be used. It is particularly preferable to use the same material for the layer 128 and the insulating layer 125 because an apparatus or the like for processing can be used in common.

In particular, since a metal oxide film such as an aluminum oxide film or a hafnium oxide film or an inorganic insulating film such as a silicon oxide film that is formed by an ALD method has a small number of pinholes, such a film has an excellent function of protecting the EL layer and can be suitably used for the insulating layer 125 and the layer 128.

The protective layer 121 is provided to cover the common electrode 113.

The protective layer 121 can have, for example, a single-layer structure or a stacked-layer structure including at least an inorganic insulating film. Examples of the inorganic insulating film include an oxide film, an oxynitride film, a nitride oxide film, and a nitride film, such as a silicon oxide film, a silicon oxynitride film, a silicon nitride oxide film, a silicon nitride film, an aluminum oxide film, an aluminum oxynitride film, and a hafnium oxide film.

Alternatively, a semiconductor material or a conductive material such as indium gallium oxide, indium zinc oxide, indium tin oxide, or indium gallium zinc oxide may be used for the protective layer 121.

For the protective layer 121, a stacked-layer film of an inorganic insulating film and an organic insulating film can also be used. For example, a structure in which an organic insulating film is sandwiched between a pair of inorganic insulating films is preferable. Furthermore, the organic insulating film preferably functions as a planarization film. This enables a top surface of the organic insulating film to be flat, which results in improved coverage with the inorganic insulating film thereover and a higher barrier property. Moreover, the top surface of the protective layer 121 is flat; therefore, when a component (e.g., a color filter, an electrode of a touch sensor, a lens array, or the like) is provided above the protective layer 121, the component can be less affected by an uneven shape caused by a lower structure.

FIG. 31C illustrates the connection portion 140 in which the connection electrode 111C is electrically connected to the common electrode 113. In the connection portion 140, an opening portion is provided in the insulating layer 125 and the resin layer 126 over the connection electrode 111C. The connection electrode 111C and the common electrode 113 are electrically connected to each other in the opening portion.

Note that although FIG. 31C illustrates the connection portion 140 in which the connection electrode 111C and the common electrode 113 are electrically connected to each other, the common electrode 113 may be provided over the connection electrode 111C with the common layer 114 therebetween. Particularly in the case where a carrier-injection layer is used as the common layer 114, for example, a material used for the common layer 114 has sufficiently low electrical resistivity and the common layer 114 can be formed to be thin. Thus, problems do not arise in many cases even when the common layer 114 is positioned in the connection portion 140. Accordingly, the common electrode 113 and the common layer 114 can be formed using the same shielding mask, so that manufacturing cost can be reduced.

The above is the description of the structure example of the display device.

### [Pixel Layout]

Pixel layouts different from the layout in FIG. 31A are mainly described below. There is no particular limitation on the arrangement of light-emitting elements (subpixels), and a variety of methods can be employed.

In addition, examples of a top surface shape of the subpixel include polygons such as a triangle, a tetragon (including a rectangle and a square), and a pentagon; polygons with rounded corners; an ellipse; and a circle. Here, the top surface shape of the subpixel corresponds to a top surface shape of a light-emitting region of the light-emitting element.

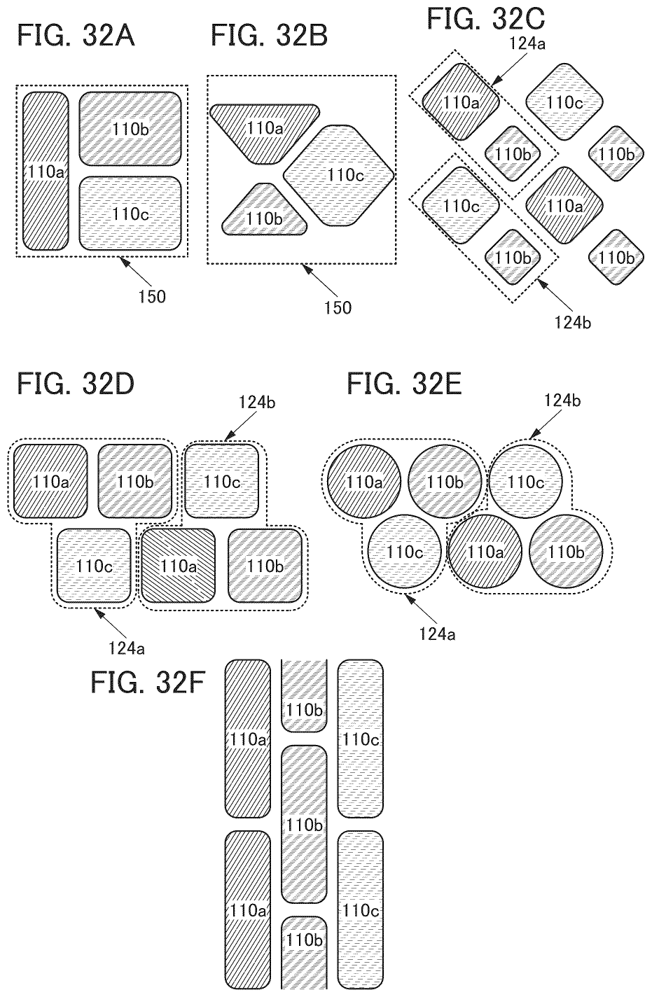

A pixel 150 illustrated in FIG. 32A employs an S-stripe arrangement. The pixel 150 illustrated in FIG. 32A is composed of three subpixels; a light-emitting element 110a, a light-emitting element 110b, and a light-emitting element 110c. For example, the light-emitting element 110a may be a blue light-emitting element, the light-emitting element 110b may be a red light-emitting element, and the light-emitting element 110c may be a green light-emitting element.

The pixel 150 illustrated in FIG. 32B includes the light-emitting element 110a whose top surface has a rough trapezoidal shape with rounded corners, the light-emitting element 110b whose top surface has a rough triangle shape with rounded corners, and the light-emitting element 110c whose top surface has a rough tetragonal or rough hexagonal shape with rounded corners. In addition, the light-emitting element 110a has a larger light-emitting area than the light-emitting element 110b. In this manner, the shapes and sizes of the light-emitting elements can be determined independently. For example, the size of a light-emitting element with higher reliability can be made smaller. For example, the light-emitting element 110a may be a green light-emitting element, the light-emitting element 110b may be a red light-emitting element, and the light-emitting element 110c may be a blue light-emitting element.

A pixel 124a and a pixel 124b illustrated in FIG. 32C employ a PenTile arrangement. FIG. 32C illustrates an example in which the pixels 124a each including the light-emitting element 110a and the light-emitting element 110b and the pixels 124b each including the light-emitting element 110b and the light-emitting element 110c are alternately arranged. For example, the light-emitting element 110a may be a red light-emitting element, the light-emitting element 110b may be a green light-emitting element, and the light-emitting element 110c may be a blue light-emitting element.

The pixel 124a and the pixel 124b illustrated in FIG. 32D and FIG. 32E employ a delta arrangement. The pixel 124a includes two light-emitting elements (the light-emitting elements 110a and 110b) in an upper row (a first row) and one light-emitting element (the light-emitting element 110c) in a lower row (a second row). The pixel 124b includes one light-emitting element (the light-emitting element 110c) in the upper row (the first row) and two light-emitting elements (the light-emitting elements 110a and 110b) in the lower row (the second row). For example, the light-emitting element 110a may be a red light-emitting element, the light-emitting element 110b may be a green light-emitting element, and the light-emitting element 110c may be a blue light-emitting element.

FIG. 32D illustrates an example in which the top surface of each light-emitting element has a rough tetragonal shape with rounded corners, and FIG. 32E illustrates an example in which the top surface of each light-emitting element has a circular shape.

FIG. 32F illustrates an example in which light-emitting elements of different colors are arranged in a zigzag manner. Specifically, the positions of top sides of two light-emitting elements arranged in a column direction (e.g., the light-emitting element 110a and the light-emitting element 110b or the light-emitting element 110b and the light-emitting element 110c) are not aligned in a top view. For example, the light-emitting element 110a may be a red light-emitting element, the light-emitting element 110b may be a green light-emitting element, and the light-emitting element 110c may be a blue light-emitting element.

In a photolithography method, as a pattern to be processed becomes finer, the influence of light diffraction becomes more difficult to ignore; accordingly, fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a light-emitting element has a polygonal shape with rounded corners, an elliptical shape, a circular shape, or the like in some cases.

Furthermore, in a method for manufacturing a display panel in one embodiment of the present invention, the EL layer is processed into an island shape with the use of a resist mask. A resist film formed over the EL layer needs to be cured at a temperature lower than the upper temperature limit of the EL layer. Thus, the resist film is insufficiently cured in some cases depending on the upper temperature limit of the material of the EL layer and the curing temperature of a resist material. An insufficiently cured resist film might have a shape different from a desired shape at the time of processing. As a result, a top surface of the EL layer has a polygonal shape with rounded corners, an elliptical shape, a circular shape, or the like in some cases. For example, when a resist mask with a square top surface is intended to be formed, a resist mask with a circular top surface might be formed, and the top surface of the EL layer might be circular.

Note that to obtain a desired top surface shape of the EL layer, a technique of correcting a mask pattern in advance so that a transferred pattern agrees with a design pattern (an OPC (Optical Proximity Correction) technique) may be used. Specifically, with the OPC technique, a pattern for correction is added to a corner portion or the like of a figure on a mask pattern.

### [Display Device 400A]

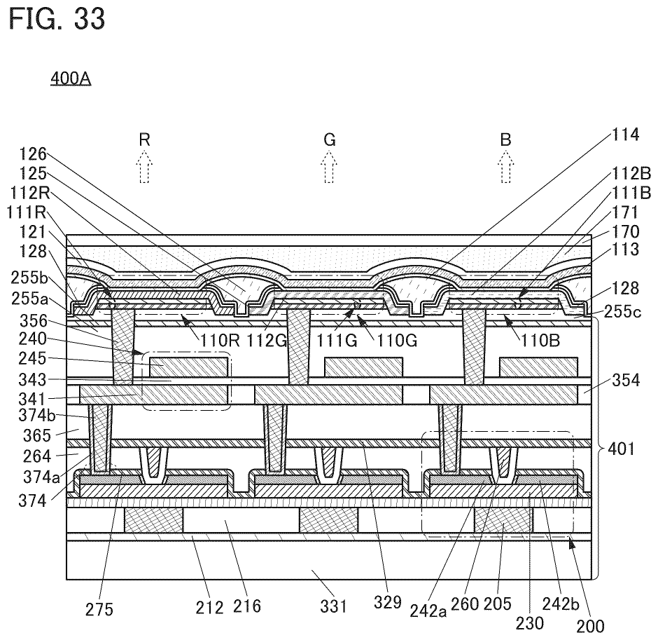

The display device 400A illustrated in FIG. 33 includes a substrate 331, the light-emitting element 110R, the light-emitting element 110G, the light-emitting element 110B, a capacitor 240, and a transistor 200.

The substrate 331 corresponds to the substrate 441 in FIG. 27A and FIG. 27B.

The transistor 200 is provided over the substrate 331. The transistor 200 is the transistor 200 described in Embodiment 1. Thus, Embodiment 1 can be referred to for the structure of the transistor 200.

A plug 374 electrically connected to one of the conductor 242a and the conductor 242b is provided to be embedded in an insulating layer 365, an insulating layer 329, an insulating layer 264, and the insulator 275. Here, the plug 374 preferably includes a conductive layer 374a that covers a side surface of an opening of the insulating layer 365, the insulating layer 329, the insulating layer 264, and the insulator 275 and part of the top surface of one of the conductor 242a and the conductor 242b, and a conductive layer 374b in contact with the top surface of the conductive layer 374a. In that case, a conductive material in which hydrogen and oxygen are less likely to diffuse is preferably used for the conductive layer 374a.

In addition, the capacitor 240 is provided over the insulating layer 365.

The capacitor 240 includes a conductive layer 341, a conductive layer 245, and an insulating layer 343 positioned therebetween. The conductive layer 341 functions as one electrode of the capacitor 240, the conductive layer 245 functions as the other electrode of the capacitor 240, and the insulating layer 343 functions as a dielectric of the capacitor 240.

The conductive layer 341 is provided over the insulating layer 365 and is embedded in an insulating layer 354. The conductive layer 341 is electrically connected to one of the source and the drain of the transistor 200 through the plug 374 embedded in the insulating layer 365 and the like. The insulating layer 343 is provided to cover the conductive layer 341. The conductive layer 245 is provided in a region overlapping with the conductive layer 341 with the insulating layer 343 therebetween.

An insulating layer 255a is provided to cover the capacitor 240, an insulating layer 255b is provided over the insulating layer 255a, and an insulating layer 255c is provided over the insulating layer 255b.

An inorganic insulating film can be suitably used for each of the insulating layer 255a, the insulating layer 255b, and the insulating layer 255c. For example, it is preferable that a silicon oxide film be used for each of the insulating layer 255a and the insulating layer 255c and that a silicon nitride film be used for the insulating layer 255b. This enables the insulating layer 255b to function as an etching protective film. Although this embodiment shows an example in which the insulating layer 255c is partly etched and a depressed portion is formed, the depressed portion is not necessarily provided in the insulating layer 255c.

The light-emitting element 110R, the light-emitting element 110G, and the light-emitting element 110B are provided over the insulating layer 255c. The above description in [Structure example of display device] can be referred to for the structures of the light-emitting element 110R, the light-emitting element 110G, and the light-emitting element 110B.

In the display device 400A, since the light-emitting devices of different colors are separately formed, a change in chromaticity between light emission at low luminance and light emission at high luminance is small. Furthermore, since the organic layers 112R, 112G, and 112B are separated from each other, crosstalk generated between adjacent subpixels can be inhibited while the display panel has high resolution. Accordingly, the display panel can have high resolution and high display quality.

In a region between adjacent light-emitting elements, the insulating layer 125, the resin layer 126, and the layer 128 are provided.

The pixel electrode 111R, the pixel electrode 111G, and the pixel electrode 111B of the light-emitting elements are each electrically connected to one of the source and the drain of the transistor 200 through a plug 356 that is embedded in the insulating layer 255a, the insulating layer 255b, and the insulating layer 255c and the plug 374 that is embedded in the insulating layer 365 and the like. The level of the top surface of the insulating layer 255c is equal to or substantially equal to the level of the top surface of the plug 356. A variety of conductive materials can be used for the plugs.

In addition, the protective layer 121 is provided over the light-emitting elements 110R, 110G, and 110B. A substrate 170 is attached to the protective layer 121 with an adhesive layer 171.

An insulating layer covering an end portion of a top surface of the pixel electrode 111 is not provided between two adjacent pixel electrodes 111. Thus, the distance between adjacent light-emitting elements can be extremely narrowed. Accordingly, the display device can have high resolution or high definition.

The transistor 200 includes an oxide semiconductor in its channel formation region and therefore has extremely low leakage current. In addition, the transistor 200 can be miniaturized, and the channel formation regions of adjacent transistors 200 can be separated from each other. Accordingly, leakage current (also referred to as lateral leakage current, side leakage current, or the like) that might flow between adjacent light-emitting elements can be reduced. Thus, even in the case where the distance between adjacent light-emitting elements is significantly narrow, leakage current between the light-emitting elements is suppressed, and a high-contrast display device can be achieved.

### [Display Device 400B]

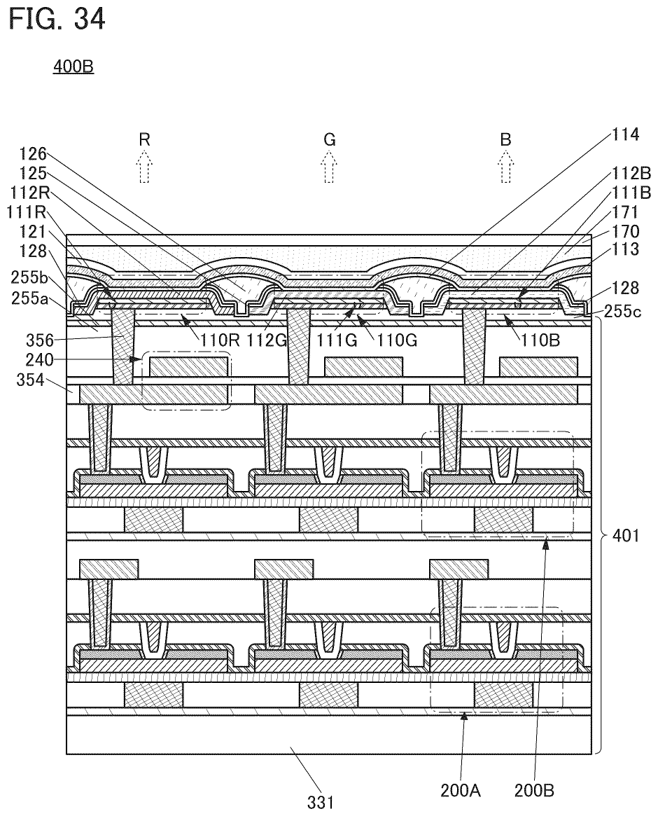

The display device 400B illustrated in FIG. 34 has a structure where a transistor 200A and a transistor 200B each including an oxide semiconductor in a semiconductor where a channel is formed are stacked.

The above description of the display device 400A can be referred to for the transistor 200A, the transistor 200B, and the components around them.

Note that although the structure where two transistors including an oxide semiconductor are stacked is described here, the present invention is not limited thereto. For example, three or more transistors may be stacked.

### [Display Device 400C]

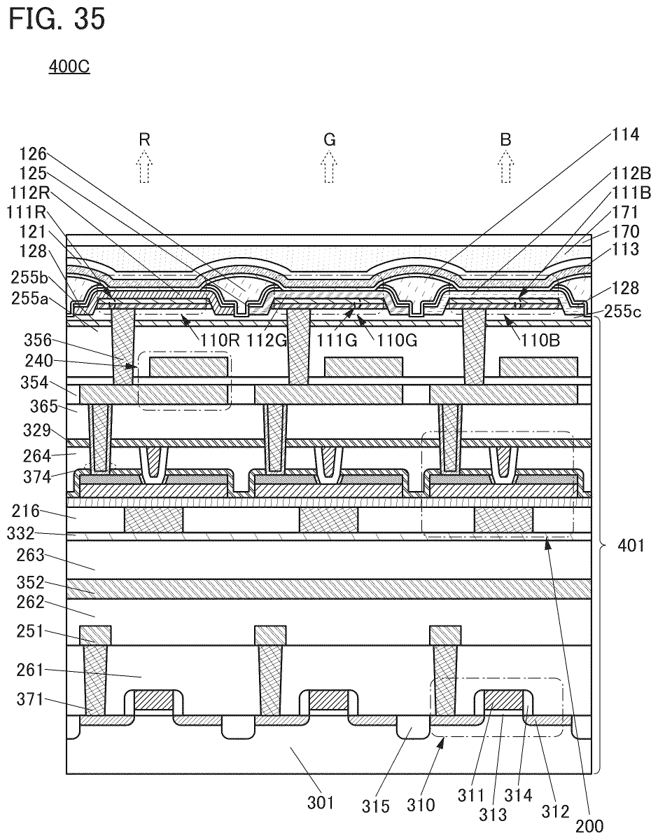

The display device 400C illustrated in FIG. 35 has a structure where a transistor 310 whose channel is formed in a substrate 301 and the transistor 200 including a metal oxide in the semiconductor layer where the channel is formed are stacked.

The substrate 301 corresponds to the substrate 441 in FIG. 27A and FIG. 27B.

The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region of the substrate 301 which is doped with an impurity, and functions as one of a source and a drain. The insulating layer 314 is provided to cover the side surface of the conductive layer 311 and functions as an insulating layer.

In addition, an element isolation layer 315 is provided between two adjacent transistors 310 to be embedded in the substrate 301.

An insulating layer 261 is provided to cover the transistor 310, and a conductive layer 251 is provided over the insulating layer 261. The conductive layer 251 is electrically connected to one of the source and the drain of the transistor 310 through a plug 371 embedded in the insulating layer 261. An insulating layer 262 is provided to cover the conductive layer 251, and a conductive layer 352 is provided over the insulating layer 262. The conductive layer 251 and the conductive layer 352 each function as a wiring. An insulating layer 263 and an insulating layer 332 are provided to cover the conductive layer 352, and the transistor 200 is provided over the insulating layer 332. The insulating layer 365 is provided to cover the transistor 200, and the capacitor 240 is provided over the insulating layer 365. The capacitor 240 and the transistor 200 are electrically connected to each other through the plug 374.

Although FIG. 35 illustrates the structure in which the transistor 310 including single crystal silicon in the semiconductor layer where the channel is formed and the transistor 200 including the metal oxide in the semiconductor layer where the channel is formed are stacked, one embodiment of the present invention is not limited thereto. For example, the transistor 310 may be a high electron mobility transistor (HEMT), a transistor using gallium nitride (also referred to as GaN), or a transistor using gallium (Ga). Thus, the stacked-layer structure of the transistor 310 and the transistor 200 can be SiVOS (silicon and an oxide semiconductor over the silicon), HEMTIOS (a high electron mobility transistor and an oxide semiconductor over the high electron mobility transistor), GaNOS (gallium nitride and an oxide semiconductor over the gallium nitride), Ga\OS (gallium and an oxide semiconductor over the gallium), or the like. Note that any one or more selected from GaAs, InP, GaN, and SiGe can be used as a material used for the HEMT, for example.

The transistor 200 can be used as a transistor included in the pixel circuit. The transistor 310 can be used as a transistor included in the pixel circuit or a transistor included in a driver circuit (a gate line driver circuit or a source line driver circuit) for driving the pixel circuit. The transistor 310 and the transistor 200 can also be used as transistors included in a variety of circuits such as an arithmetic circuit and a storage circuit.

With such a structure, not only the pixel circuit but also the driver circuit and the like can be formed directly under the light-emitting devices; thus, the display panel can be downsized as compared with the case where a driver circuit is provided around a display region.

### [Display Device 400D]

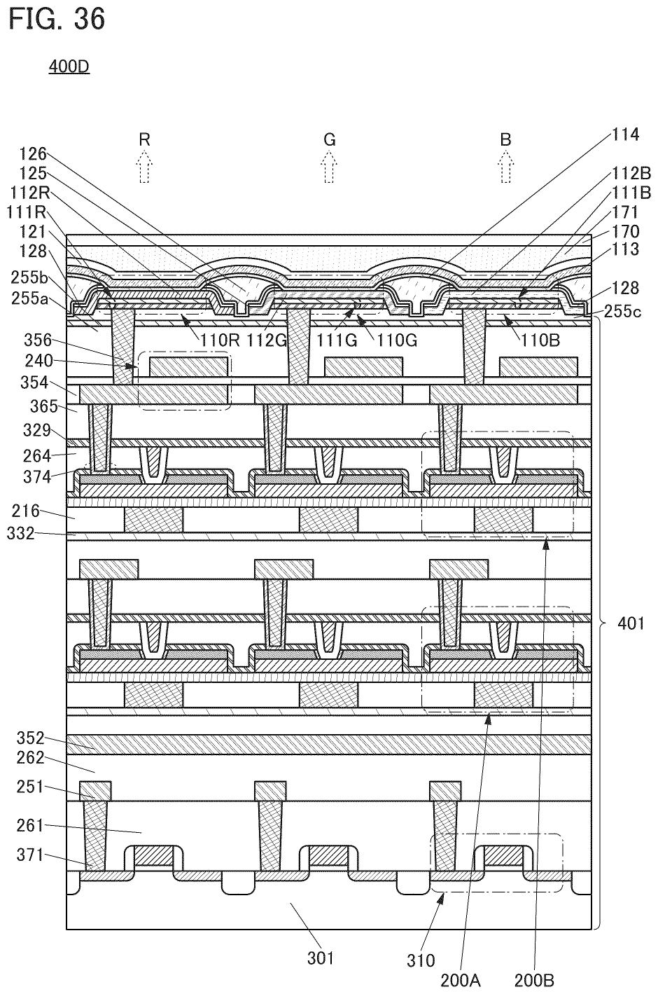

The display device 400D illustrated in FIG. 36 has a structure in which the transistor 310 whose channel is formed in the substrate 301 and the transistor 200A and the transistor 200B each including a metal oxide in the semiconductor layer where the channel is formed are stacked.

The transistor 200A can be used as a transistor included in the pixel circuit. The transistor 310 can be used as a transistor included in the pixel circuit or a transistor included in a driver circuit (a gate line driver circuit or a source line driver circuit) for driving the pixel circuit. The transistor 200B may be used as a transistor included in the pixel circuit or a transistor included in the driver circuit. The transistor 310, the transistor 200A, and the transistor 200B can also be used as transistors included in a variety of circuits such as an arithmetic circuit and a storage circuit.

At least part of this embodiment can be implemented in appropriate combination with the other embodiments described in this specification.

### Embodiment 3

In this embodiment, light-emitting elements that can be used in the display device of one embodiment of the present invention are described.

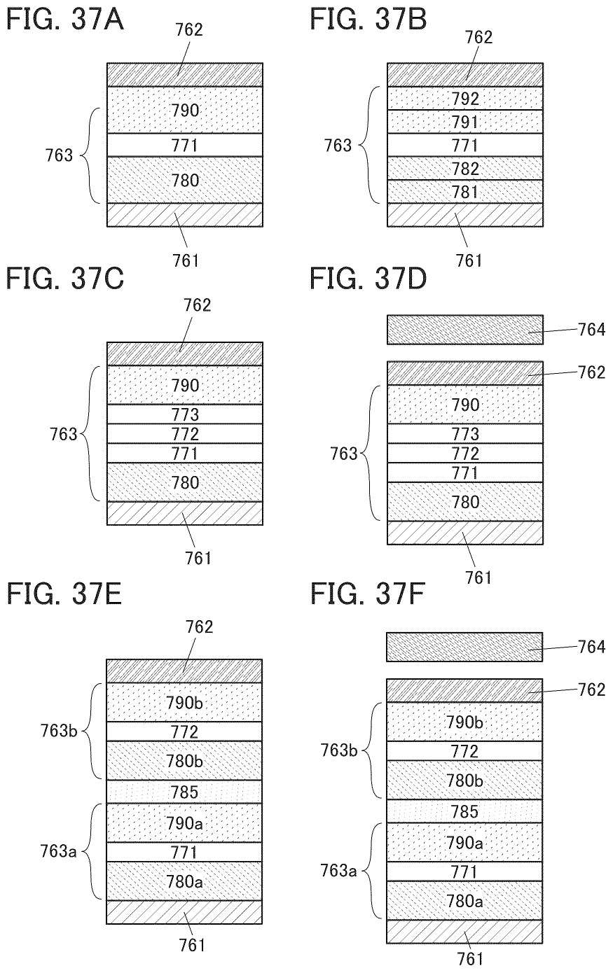

As illustrated in FIG. 37A, a light-emitting element includes an EL layer 763 between a pair of electrodes (a lower electrode 761 and an upper electrode 762). The EL layer 763 can be formed of a plurality of layers such as a layer 780, a light-emitting layer 771, and a layer 790.

The light-emitting layer 771 contains at least a light-emitting substance (also referred to as a light-emitting material).

In the case where the lower electrode 761 is an anode and the upper electrode 762 is a cathode, the layer 780 includes one or more of a layer containing a substance having a high hole-injection property (a hole-injection layer), a layer containing a substance having a high hole-transport property (a hole-transport layer), and a layer containing a substance having a high electron-blocking property (an electron-blocking layer). Furthermore, the layer 790 includes one or more of a layer containing a substance having a high electron-injection property (an electron-injection layer), a layer containing a substance having a high electron-transport property (an electron-transport layer), and a layer containing a substance having a high hole-blocking property (a hole-blocking layer). In the case where the lower electrode 761 is a cathode and the upper electrode 762 is an anode, the above structures of the layer 780 and the layer 790 are replaced with each other.

The structure including the layer 780, the light-emitting layer 771, and the layer 790, which is provided between the pair of electrodes, can function as a single light-emitting unit, and the structure in FIG. 37A is referred to as a single structure in this specification.

FIG. 37B is a modification example of the EL layer 763 included in the light-emitting element illustrated in FIG. 37A. Specifically, the light-emitting element illustrated in FIG. 37B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layer structure, carriers can be efficiently injected into the light-emitting layer 771, and the efficiency of the recombination of carriers in the light-emitting layer 771 can be increased.

Note that structures in which a plurality of light-emitting layers (the light-emitting layer 771, a light-emitting layer 772, and a light-emitting layer 773) are provided between the layer 780 and the layer 790 as illustrated in FIG. 37C and FIG. 37D are also variations of the single structure. Although FIG. 37C and FIG. 37D illustrate the examples where three light-emitting layers are included, the light-emitting element having a single structure may include two light-emitting layers or four or more light-emitting layers. In addition, the light-emitting element having a single structure may include a buffer layer between two light-emitting layers.

A structure where a plurality of light-emitting units (a light-emitting unit 763a and a light-emitting unit 763b) are connected in series with a charge-generation layer 785 (also referred to as an intermediate layer) therebetween as illustrated in FIG. 37E and FIG. 37F is referred to as a tandem structure in this specification. Note that the tandem structure may be referred to as a stack structure. The tandem structure enables a light-emitting element capable of high-luminance light emission. Furthermore, the tandem structure reduces the amount of current needed for obtaining the same luminance as compared with the single structure, and thus can improve the reliability.

Note that FIG. 37D and FIG. 37F illustrate examples where the display device includes a layer 764 overlapping with the light-emitting element. FIG. 37D illustrates an example in which the layer 764 overlaps with the light-emitting element illustrated in FIG. 37C, and FIG. 37F illustrates an example in which the layer 764 overlaps with the light-emitting element illustrated in FIG. 37E. In FIG. 37D and FIG. 37F, a conductive film transmitting visible light is used for the upper electrode 762 to extract light from the upper electrode 762 side.

One or both of a color conversion layer and a color filter (a coloring layer) can be used as the layer 764.

In the case where the light-emitting element having a single structure includes three light-emitting layers, for example, a light-emitting layer containing a light-emitting substance that emits red (R) light, a light-emitting layer containing a light-emitting substance that emits green (G) light, and a light-emitting layer containing a light-emitting substance that emits blue (B) light are preferably included. The stacking order of the light-emitting layers can be R, G, and B from the anode side or R, B, and G from the anode side, for example. In that case, a buffer layer may be provided between R and G or between R and B.

For example, in the case where the light-emitting element having a single structure includes two light-emitting layers, the light-emitting element preferably includes a light-emitting layer containing a light-emitting substance that emits blue (B) light and a light-emitting layer containing a light-emitting substance that emits yellow (Y) light. Such a structure may be referred to as a BY single structure.

The light-emitting element that emits white light preferably contains two or more kinds of light-emitting substances. To obtain white light emission, two or more kinds of light-emitting substances are selected such that they emit light of complementary colors. For example, when the emission color of a first light-emitting layer and the emission color of a second light-emitting layer have a relationship of complementary colors, it is possible to obtain a light-emitting element which emits white light as a whole. The same applies to a light-emitting element including three or more light-emitting layers.

Also in FIG. 37C and FIG. 37D, the layer 780 and the layer 790 may each independently have a stacked-layer structure of two or more layers as illustrated in FIG. 37B.

In the case where the light-emitting element having the structure illustrated in FIG. 37E or FIG. 37F is used for the subpixels emitting different colors, the subpixels may use different light-emitting substances. Specifically, in the light-emitting element included in the subpixel emitting red light, a light-emitting substance that emits red light can be used for each of the light-emitting layer 771 and the light-emitting layer 772. Similarly, in the light-emitting element included in the subpixel emitting green light, a light-emitting substance that emits green light can be used for each of the light-emitting layer 771 and the light-emitting layer 772. In the light-emitting element included in the subpixel emitting blue light, a light-emitting substance that emits blue light can be used for each of the light-emitting layer 771 and the light-emitting layer 772. A display device with such a structure includes a light-emitting element with a tandem structure and can be regarded as having an SBS structure. Thus, the display device can take advantages of both the tandem structure and the SBS structure. Accordingly, a light-emitting element being capable of high-luminance light emission and having high reliability can be obtained.

Although FIG. 37E and FIG. 37F illustrate examples where the light-emitting unit 763a includes one light-emitting layer 771 and the light-emitting unit 763b includes one light-emitting layer 772, one embodiment of the present invention is not limited thereto. Each of the light-emitting unit 763a and the light-emitting unit 763b may include two or more light-emitting layers.

In addition, although FIG. 37E and FIG. 37F illustrate the light-emitting element including two light-emitting units, one embodiment of the present invention is not limited thereto. The light-emitting element may include three or more light-emitting units. Note that a structure including two light-emitting units and a structure including three light-emitting units may be referred to as a two-unit tandem structure and a three-unit tandem structure, respectively.

In FIG. 37E and FIG. 37F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, the layer 780a and the layer 780b each include one or more of a hole-injection layer, a hole-transport layer, and an electron-blocking layer. The layer 790a and the layer 790b each include one or more of an electron-injection layer, an electron-transport layer, and a hole-blocking layer. In the case where the lower electrode 761 is a cathode and the upper electrode 762 is an anode, the above structures of the layer 780a and the layer 790a are replaced with each other, and the above structures of the layer 780b and the layer 790b are also replaced with each other.

In the case where the lower electrode 761 is an anode and the upper electrode 762 is a cathode, for example, the layer 780a includes a hole-injection layer and a hole-transport layer over the hole-injection layer, and may further include an electron-blocking layer over the hole-transport layer. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 761 is a cathode and the upper electrode 762 is an anode, for example, the layer 780a includes an electron-injection layer and an electron-transport layer over the electron-injection layer, and may further include a hole-blocking layer over the electron-transport layer. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In the case of manufacturing a light-emitting element having a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes into the other when voltage is applied between the pair of electrodes.

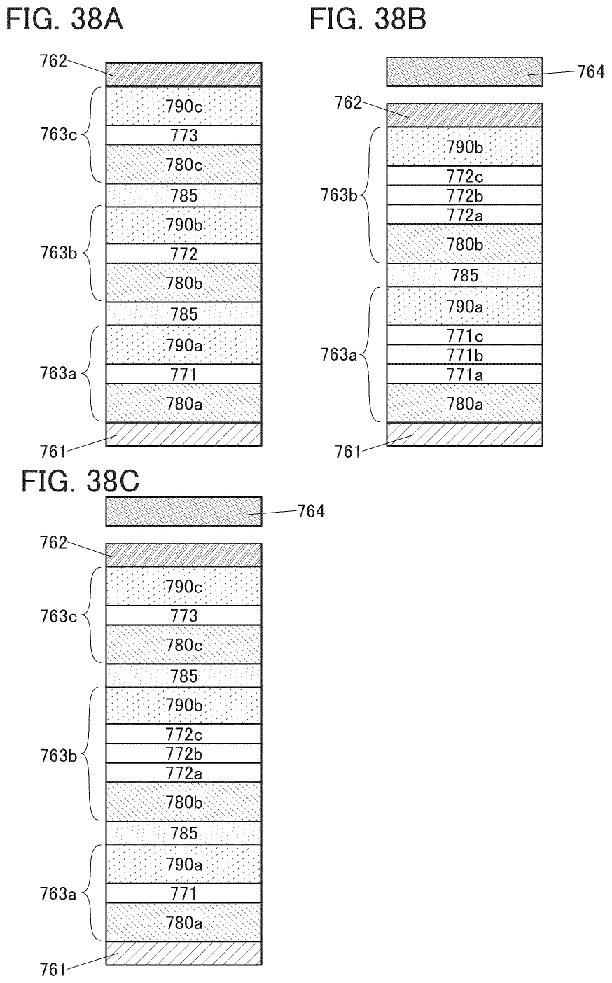

Examples of the light-emitting element having a tandem structure include structures illustrated in FIG. 38A to FIG. 38C.

FIG. 38A illustrates a structure including three light-emitting units. In FIG. 38A, a plurality of light-emitting units (the light-emitting unit 763a, the light-emitting unit 763b, and a light-emitting unit 763c) are connected in series with the charge-generation layers 785 therebetween. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. Note that the layer 780c can have a structure applicable to the layer 780a and the layer 780b, and the layer 790c can have a structure applicable to the layer 790a and the layer 790b.

In FIG. 38A, the light-emitting layer 771, the light-emitting layer 772, and the light-emitting layer 773 preferably contain light-emitting substances that emit light of the same color. Specifically, the light-emitting layer 771, the light-emitting layer 772, and the light-emitting layer 773 can each contain a red (R) light-emitting substance (a so-called three-unit tandem structure of R\R\R); the light-emitting layer 771, the light-emitting layer 772, and the light-emitting layer 773 can each contain a green (G) light-emitting substance (a so-called three-unit tandem structure of G\G\G); or the light-emitting layer 771, the light-emitting layer 772, and the light-emitting layer 773 can each contain a blue (B) light-emitting substance (a so-called three-unit tandem structure of B\B\B). Note that “a\b” means that a light-emitting unit containing a light-emitting substance that emits light of b is provided over a light-emitting unit containing a light-emitting substance that emits light of a with a charge-generation layer therebetween, where a and b represent colors.

In FIG. 38A, light-emitting substances that emit light of different colors may be used for some or all of the light-emitting layer 771, the light-emitting layer 772, and the light-emitting layer 773. Examples of a combination of emission colors for the light-emitting layer 771, the light-emitting layer 772, and the light-emitting layer 773 include blue (B) for two of them and yellow (Y) for the other; and red (R) for one of them, green (G) for another, and blue (B) for the other.

Note that the structure containing the light-emitting substances that emit light of the same color is not limited to the above structure. For example, a light-emitting element with a tandem structure may be employed in which light-emitting units each including a plurality of light-emitting layers are stacked as illustrated in FIG. 38B. FIG. 38B illustrates a structure in which two light-emitting units (the light-emitting unit 763a and the light-emitting unit 763b) are connected in series with the charge-generation layer 785 therebetween. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 38B, the light-emitting unit 763a is configured to emit white (W) light by selecting light-emitting substances to satisfy the relationship of complementary colors for the light-emitting layer 771a, the light-emitting layer 771b, and the light-emitting layer 771c. Furthermore, the light-emitting unit 763b is configured to emit white (W) light by selecting light-emitting substances to satisfy the relationship of complementary colors for the light-emitting layer 772a. the light-emitting layer 772b, and the light-emitting layer 772c. That is, the structure illustrated in FIG. 38B is a two-unit tandem structure of WWW. Note that there is no particular limitation on the stacking order of the light-emitting substances satisfying the relationship of complementary colors. The practitioner can select the optimal stacking order as appropriate. Although not illustrated, a three-unit tandem structure of WWWWW or a tandem structure with four or more units may be employed.

In the case of a light-emitting element with a tandem structure, examples of the structure include a two-unit tandem structure of BY or Y\B including a light-emitting unit that emits yellow (Y) light and a light-emitting unit that emits blue (B) light; a two-unit tandem structure of R·G\B or B\R·G including a light-emitting unit that emits red (R) and green (G) light and a light-emitting unit that emits blue (B) light; a three-unit tandem structure of B\Y\B including a light-emitting unit that emits blue (B) light, a light-emitting unit that emits yellow (Y) light, and a light-emitting unit that emits blue (B) light in this order; a three-unit tandem structure of BYG\B including a light-emitting unit that emits blue (B) light, a light-emitting unit that emits yellow-green (YG) light, and a light-emitting unit that emits blue (B) light in this order; and a three-unit tandem structure of B\GIB including a light-emitting unit that emits blue (B) light, a light-emitting unit that emits green (G) light, and a light-emitting unit that emits blue (B) light in this order. Note that “a·b” means that one light-emitting unit contains a light-emitting substance that emits light of a and a light-emitting substance that emits light of b.

As illustrated in FIG. 38C, a light-emitting unit including one light-emitting layer and a light-emitting unit including a plurality of light-emitting layers may be used in combination.

Specifically, in the structure illustrated in FIG. 38C, a plurality of light-emitting units (the light-emitting unit 763a, the light-emitting unit 763b, and the light-emitting unit 763c) are connected in series with the charge-generation layers 785 therebetween. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

As the structure illustrated in FIG. 38C, for example, a three-unit tandem structure of B\R·G·YG\B in which the light-emitting unit 763a is a light-emitting unit that emits blue (B) light, the light-emitting unit 763b is a light-emitting unit that emits red (R), green (G), and yellow-green (YG) light, and the light-emitting unit 763c is a light-emitting unit that emits blue (B) light can be employed.

Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from the anode side include a two-layer structure of R and Y; a two-layer structure of R and G; a two-layer structure of G and R; a three-layer structure of G, R, and G; and a three-layer structure of R. G. and R. Another layer may be provided between two light-emitting layers.

Next, materials that can be used for the light-emitting element are described.

A conductive film that transmits visible light is used for the electrode through which light is extracted, which is either the lower electrode 761 or the upper electrode 762. A conductive film that reflects visible light is preferably used as the electrode through which light is not extracted. In the case where a display device includes a light-emitting element that emits infrared light, it is preferable that a conductive film that transmits visible light and infrared light be used for the electrode through which light is extracted and a conductive film that reflects visible light and infrared light be used for the electrode through which light is not extracted.

A conductive film that transmits visible light may be used also for the electrode through which light is not extracted. In that case, the electrode is preferably placed between a reflective layer and the EL layer 763. That is, light emitted from the EL layer 763 may be reflected by the reflective layer to be extracted from the display device.

As a material that forms the pair of electrodes of the light-emitting element, a metal, an alloy, an electrically conductive compound, a mixture thereof, and the like can be used as appropriate. Specific examples of the material include metals such as aluminum, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide (In—Sn oxide, also referred to as ITO), In—Si—Sn oxide (also referred to as ITSO), indium zinc oxide (In—Zn oxide), and In—W—Zn oxide. Other examples of the material include an alloy containing aluminum (aluminum alloy) such as an alloy of aluminum, nickel, and lanthanum (Al—Ni—La), and an alloy of silver, palladium, and copper (Ag—Pd—Cu, also referred to as APC). Other example of the material include elements belonging to Group 1 or Group 2 of the periodic table, which are not exemplified above (e.g., lithium, cesium, calcium, and strontium), rare earth metals such as europium and ytterbium, an alloy containing any of these metals in appropriate combination, and graphene.

The light-emitting element preferably employs a microcavity structure. Therefore, one of the pair of electrodes of the light-emitting element preferably includes an electrode having properties of transmitting and reflecting visible light (a transflective electrode), and the other preferably includes an electrode having a property of reflecting visible light (a reflective electrode). When the light-emitting element has a microcavity structure, light obtained from the light-emitting layer can be resonated between the electrodes, whereby light emitted from the light-emitting element can be intensified.

Note that the transflective electrode can have a stacked-layer structure of a conductive layer that can be used as a reflective electrode and a conductive layer that can be used as an electrode having a visible-light-transmitting property (also referred to as a transparent electrode).

The light transmittance of the transparent electrode is higher than or equal to 40%. For example, an electrode having a visible light (light with a wavelength greater than or equal to 400 nm and less than 750 nm) transmittance higher than or equal to 40% is preferably used as the transparent electrode of the light-emitting element. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity less than or equal to 1×10⁻² Ωcm.

The light-emitting element includes at least the light-emitting layer. The light-emitting element may further include, as a layer other than the light-emitting layer, a layer containing a substance with a high hole-injection property, a substance with a high hole-transport property, a hole-blocking material, a substance with a high electron-transport property, an electron-blocking material, a substance with a high electron-injection property, a substance with a bipolar property (a substance with a high electron-transport property and a high hole-transport property), or the like. For example, the light-emitting element can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used for the light-emitting element, and an inorganic compound may also be contained. Each of the layers included in the light-emitting element can be formed by an evaporation method (including a vacuum evaporation method), a transfer method, a printing method, an inkjet method, a coating method, or the like.

The light-emitting layer contains one or more kinds of light-emitting substances. As the light-emitting substance, a substance whose emission color is blue, purple, blue-purple, green, yellow-green, yellow, orange, red, or the like is appropriately used. As the light-emitting substance, a substance emitting near-infrared light can also be used.

Examples of the light-emitting substance include a fluorescent material, a phosphorescent material, a TADF material, and a quantum dot material.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of the phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material or an assist material) in addition to the light-emitting substance (guest material). As one or more kinds of organic compounds, one or both of a substance having a high hole-transport property (a hole-transport material) and a substance having a high electron-transport property (an electron-transport material) can be used. As the hole-transport material, it is possible to use a material having a high hole-transport property which can be used for the hole-transport layer and will be described later. As the electron-transport material, it is possible to use a material having a high electron-transport property which can be used for the electron-transport layer and will be described later. As one or more kinds of organic compounds, a bipolar material or a TADF material may be used.

The light-emitting layer preferably includes a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from an exciplex to a light-emitting substance (a phosphorescent material). When a combination of materials is selected so as to form an exciplex that exhibits light emission whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time.

The hole-injection layer is a layer that injects holes from the anode to the hole-transport layer and contains a material with a high hole-injection property. Examples of the material with a high hole-injection property include an aromatic amine compound, and a composite material containing a hole-transport material and an acceptor material (an electron-accepting material).

As the hole-transport material, it is possible to use a material having a high hole-transport property which can be used for the hole-transport layer and will be described later.

As the acceptor material, an oxide of a metal belonging to any of Group 4 to Group 8 of the periodic table can be used, for example. Specific examples include molybdenum oxide, vanadium oxide, niobium oxide, tantalum oxide, chromium oxide, tungsten oxide, manganese oxide, and rhenium oxide. Among these, molybdenum oxide is particularly preferable because it is stable in the air, has a low hygroscopic property, and is easy to handle. Alternatively, an organic acceptor material containing fluorine can be used. Alternatively, organic acceptor materials such as a quinodimethane derivative, a chloranil derivative, and a hexaazatriphenylene derivative can be used.

As the material with a high hole-injection property, a material containing a hole-transport material and the above-described oxide of a metal belonging to any of Group 4 to Group 8 of the periodic table (typically, molybdenum oxide) may be used, for example.

The hole-transport layer is a layer that transports holes, which are injected from the anode by the hole-injection layer, to the light-emitting layer. The hole-transport layer is a layer that contains a hole-transport material. As the hole-transport material, a substance having a hole mobility greater than or equal to 1×10⁻⁶ cm²/Vs is preferable. Note that other substances can also be used as long as they have a property of transporting more holes than electrons. As the hole-transport material, a material with a high hole-transport property, such as a x-electron rich heteroaromatic compound (e.g., a carbazole derivative, a thiophene derivative, or a furan derivative) or an aromatic amine (a compound having an aromatic amine skeleton), is preferable.

The electron-blocking layer is provided in contact with the light-emitting layer. The electron-blocking layer is a layer that has a hole-transport property and contains a material capable of blocking electrons. Any of the materials having an electron-blocking property among the above hole-transport materials can be used for the electron-blocking layer.

The electron-blocking layer has a hole-transport property, and thus can also be referred to as a hole-transport layer. A layer having an electron-blocking property among the hole-transport layers can also be referred to as an electron-blocking layer.

The electron-transport layer is a layer that transports electrons, which are injected from the cathode by the electron-injection layer, to the light-emitting layer. The electron-transport layer is a layer that contains an electron-transport material. As the electron-transport material, a substance having an electron mobility greater than or equal to 1×10⁻⁶ cm²/Vs is preferable. Note that other substances can also be used as long as they have a property of transporting more electrons than holes. As the electron-transport material, it is possible to use a material with a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a x-electron deficient heteroaromatic compound such as a nitrogen-containing heteroaromatic compound.

The hole-blocking layer is provided in contact with the light-emitting layer. The hole-blocking layer is a layer that has an electron-transport property and contains a material capable of blocking holes. Any of the materials having a hole-blocking property among the above electron-transport materials can be used for the hole-blocking layer.

The hole-blocking layer has an electron-transport property, and thus can also be referred to as an electron-transport layer. A layer having a hole-blocking property among the electron-transport layers can also be referred to as a hole-blocking layer.

The electron-injection layer is a layer that injects electrons from the cathode to the electron-transport layer and contains a material with a high electron-injection property. As the material with a high electron-injection property, an alkali metal, an alkaline earth metal, or a compound thereof can be used. As the material with a high electron-injection property, a composite material containing an electron-transport material and a donor material (an electron-donating material) can also be used.

The difference between the LUMO level of the material having a high electron-injection property and the work function value of the material used for the cathode is preferably small (specifically, smaller than or equal to 0.5 eV).

For the electron-injection layer, it is possible to use an alkali metal, an alkaline earth metal, or a compound thereof, such as lithium, cesium, ytterbium, lithium fluoride (LiF), cesium fluoride (CsF), calcium fluoride (CaFx, where X is a given number), 8-(quinolinolato) lithium (abbreviation: Liq), 2-(2-pyridyl) phenolatolithium (abbreviation: LiPP), 2-(2-pyridyl)-3-pyridinolatolithium (abbreviation: LiPPy), 4-phenyl-2-(2-pyridyl) phenolatolithium (abbreviation: LiPPP), lithium oxide (LiOx), or cesium carbonate, for example. The electron-injection layer may have a stacked-layer structure of two or more layers. The stacked-layer structure can be, for example, a structure where lithium fluoride is used for the first layer and ytterbium is used for the second layer.

The electron-injection layer may contain an electron-transport material. For example, a compound having an unshared electron pair and a x-electron deficient heteroaromatic ring can be used as the electron-transport material. Specifically, it is possible to use a compound having at least one of a pyridine ring, a diazine ring (a pyrimidine ring, a pyrazine ring, or a pyridazine ring), and a triazine ring.

Note that the lowest unoccupied molecular orbital (LUMO) level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino [2,3-a: 2′,3′-c] phenazine (abbreviation: HATNA), 2,4,6-tris [3′-(pyridin-3-yl) biphenyl-3-yl]-1,3,5-triazine (abbreviation: TmPPPyTz), or the like can be used for the organic compound having an unshared electron pair. Note that NBPhen has a higher glass transition temperature (Tg) than BPhen and thus has high heat resistance.

As described above, the charge-generation layer includes at least a charge-generation region. The charge-generation region preferably contains an acceptor material, and for example, preferably contains a hole-transport material and an acceptor material which can be used for the above-described hole-injection layer.

The charge-generation layer preferably includes a layer containing a material having a high electron-injection property. The layer can also be referred to as an electron-injection buffer layer. The electron-injection buffer layer is preferably provided between the charge-generation region and the electron-transport layer. By provision of the electron-injection buffer layer, an injection barrier between the charge-generation region and the electron-transport layer can be lowered; thus, electrons generated in the charge-generation region can be easily injected into the electron-transport layer.

The electron-injection buffer layer preferably contains an alkali metal or an alkaline earth metal, and for example, can be configured to contain an alkali metal compound or an alkaline earth metal compound. Specifically, the electron-injection buffer layer preferably contains an inorganic compound containing an alkali metal and oxygen or an inorganic compound containing an alkaline earth metal and oxygen, and further preferably contains an inorganic compound containing lithium and oxygen (e.g., lithium oxide (Li₂O)). Alternatively, a material that can be used for the above-described electron-injection layer can be suitably used for the electron-injection buffer layer.

The charge-generation layer preferably includes a layer containing a material having a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing interaction between the charge-generation region and the electron-injection buffer layer (or the electron-transport layer) and smoothly transferring electrons.

A phthalocyanine-based material such as copper (II) phthalocyanine (abbreviation: CuPc) or a metal complex having a metal-oxygen bond and an aromatic ligand is preferably used for the electron-relay layer.

Note that the above-described charge-generation region, electron-injection buffer layer, and electron-relay layer cannot be clearly distinguished from each other in some cases on the basis of the cross-sectional shapes, properties, or the like.

Note that the charge-generation layer may contain a donor material instead of an acceptor material. For example, the charge-generation layer may include a layer containing an electron-transport material and a donor material, which can be used for the above-described electron-injection layer.

When the light-emitting units are stacked, provision of a charge-generation layer between two light-emitting units can suppress an increase in driving voltage.

This embodiment can be combined with the other embodiments as appropriate.

### Embodiment 4

In this embodiment, electronic devices of one embodiment of the present invention are described.

Electronic devices of this embodiment each include the display device of one embodiment of the present invention in a display portion. The resolution and definition of the display device of one embodiment of the present invention can be easily increased. Thus, the display device of one embodiment of the present invention can be used for display portions of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or laptop personal computer, a monitor of a computer, digital signage, and a large game machine such as a pachinko machine.

In particular, the display device of one embodiment of the present invention can have a high resolution, and thus can be suitably used for an electronic device having a relatively small display portion. Examples of such an electronic device include watch-type and bracelet-type information terminal devices (wearable devices) and wearable devices worn on the head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the definition is preferably 4K. 8K, or higher. The pixel density (resolution) of the display device of one embodiment of the present invention is preferably higher than or equal to 100 ppi, further preferably higher than or equal to 300 ppi, still further preferably higher than or equal to 500 ppi, yet further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. With the use of such a display device with one or both of high definition and high resolution, the electronic device can provide higher realistic sensation, sense of depth, and the like in personal use such as portable use and home use. There is no particular limitation on the screen ratio (aspect ratio) of the display device of one embodiment of the present invention. For example, the display device is compatible with a variety of screen ratios such as 1:1 (square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device can have a function of displaying a variety of information (e.g., a still image, a moving image, or a text image) on the display portion, a touch panel function, a function of displaying a calendar, date, time, or the like, a function of executing a variety of software (programs), a wireless communication function, or a function of reading out a program or data stored in a recording medium.

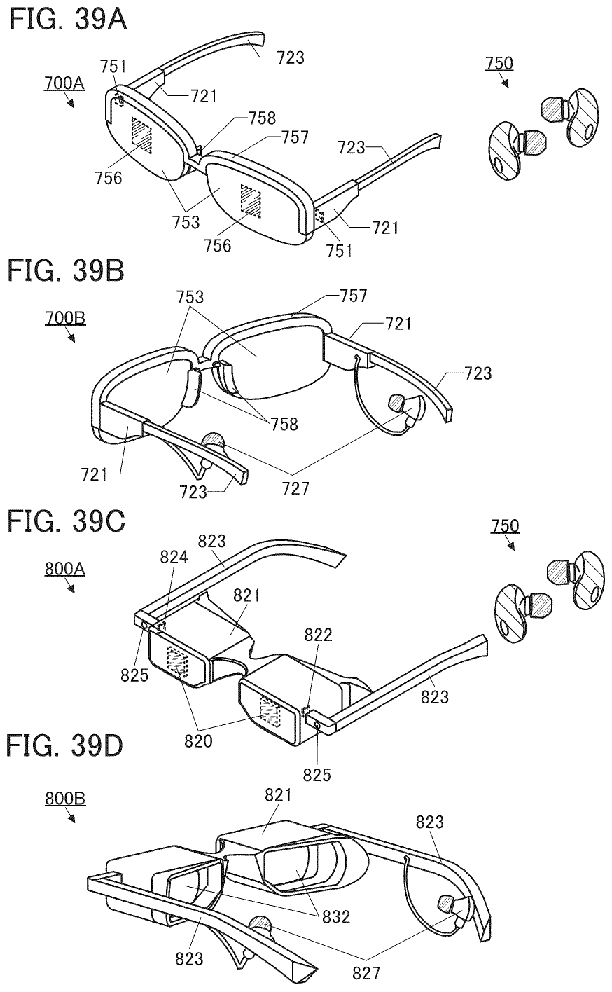

Examples of a wearable device that can be worn on the head are described with reference to FIG. 39A to FIG. 39D. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher sense of immersion.

An electronic device 700A illustrated in FIG. 39A and an electronic device 700B illustrated in FIG. 39B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic device can perform display with extremely high resolution.

The electronic device 700A and the electronic device 700B can each project an image displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are each provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Note that instead of or in addition to the wireless communication device, a connector to which a cable for supplying a video signal and a power supply potential can be connected may be provided.

The electronic device 700A and the electronic device 700B are provided with a battery so that they can be charged wirelessly and/or by wire.

A touch sensor module may be provided in the housing 721. The touch sensor module has a function of detecting a touch on the outer surface of the housing 721. A tap operation, a slide operation, or the like by the user can be detected with the touch sensor module, whereby a variety of processing can be executed. For example, processing such as a pause or a restart of a moving image can be executed by a tap operation, and processing such as fast forward or fast rewind can be executed by a slide operation. When the touch sensor module is provided in each of the two housings 721, the range of the operation can be increased.

Any of various touch sensors can be applied to the touch sensor module. Any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion element (also referred to as a photoelectric conversion device) can be used as a light-receiving element. One or both of an inorganic semiconductor and an organic semiconductor can be used for an active layer of the photoelectric conversion element.

An electronic device 800A illustrated in FIG. 39C and an electronic device 800B illustrated in FIG. 39D each include a pair of display portions 820, a housing 821, a communication portion 822, a pair of wearing portions 823, a control portion 824, a pair of image capturing portions 825, and a pair of lenses 832.

The display device of one embodiment of the present invention can be used in the display portion 820. Thus, the electronic device can perform display with extremely high resolution.

The display portions 820 are positioned inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B each preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B each preferably include a mechanism for adjusting focus by changing the distance between the lenses 832 and the display portions 820.

The electronic device 800A or the electronic device 800B can be mounted on the user's head with the wearing portions 823. Note that FIG. 39C illustrates an example in which the wearing portion 823 has a shape like a temple (also referred to as a joint or the like) of glasses, for example; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

Although an example where the image capturing portions 825 are provided is described here, a range sensor capable of measuring a distance from an object (also referred to as a sensing portion) may be provided. In other words, the image capturing portion 825 is one embodiment of the sensing portion. As the sensing portion, an image sensor or a range image sensor such as LIDAR (Light Detection and Ranging) can be used, for example. By using images obtained by the camera and images obtained by the range image sensor, more information can be obtained and a gesture operation with higher accuracy is possible.

The electronic device 800A may include a vibration mechanism that functions as bone-conduction earphones. For example, a structure including the vibration mechanism can be applied to any one or more of the display portion 820, the housing 821, and the wearing portion 823. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 39A has a function of transmitting information to the earphones 750 with the wireless communication function. As another example, the electronic device 800A illustrated in FIG. 39C has a function of transmitting information to the earphones 750 with the wireless communication function.

The electronic device may include an earphone portion. The electronic device 700B illustrated in FIG. 39B includes earphone portions 727. For example, the earphone portions 727 and the control portion can be connected to each other by wire. Part of a wiring that connects the earphone portions 727 and the control portion may be positioned inside the housing 721 or the wearing portion 723.

Similarly, the electronic device 800B illustrated in FIG. 39D includes earphone portions 827. For example, the earphone portions 827 and the control portion 824 can be connected to each other by wire. Part of a wiring that connects the earphone portions 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

Note that the electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 700A and the electronic device 700B) and the goggles-type device (e.g., the electronic device 800A and the electronic device 800B) are suitable for the electronic device of one embodiment of the present invention.

The electronic device of one embodiment of the present invention can transmit information to earphones by wire or wirelessly.

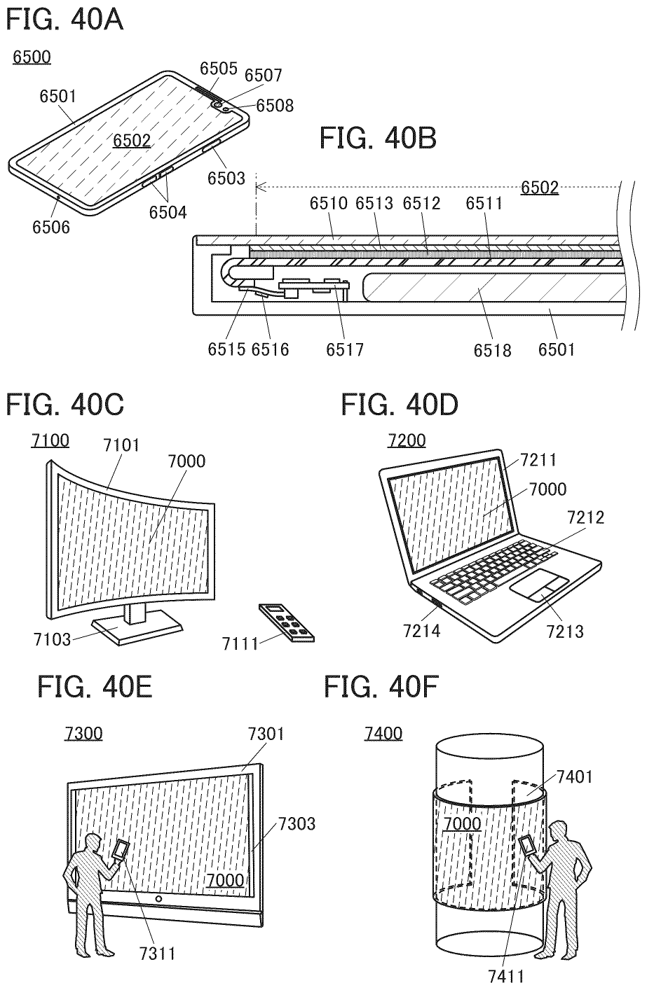

An electronic device 6500 illustrated in FIG. 40A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502. Thus, the electronic device can perform display with extremely high resolution.

FIG. 40B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the region that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be obtained. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of a pixel portion, whereby an electronic device with a narrow bezel can be achieved.

FIG. 40C illustrates an example of a television device. In a television device 7100, a display portion 7000 is incorporated in a housing 7101. Here, the housing 7101 is supported by a stand 7103.

The display device of one embodiment of the present invention can be used in the display portion 7000. Thus, the electronic device can perform display with extremely high resolution.

Operation of the television device 7100 illustrated in FIG. 40C can be performed with an operation switch provided in the housing 7101 and a separate remote control 7111. Alternatively, the display portion 7000 may be provided with a touch sensor, and the television device 7100 may be operated by a touch on the display portion 7000 with a finger or the like. The remote control 7111 may include a display portion for displaying information output from the remote control 7111. With operation keys or a touch panel provided in the remote control 7111, channels and volume can be controlled, and videos displayed on the display portion 7000 can be controlled.

Note that the television device 7100 has a structure in which a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) information communication can also be performed.

FIG. 40D illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

The display device of one embodiment of the present invention can be used in the display portion 7000. Thus, the electronic device can perform display with extremely high resolution.

FIG. 40E and FIG. 40F illustrate examples of digital signage.

Digital signage 7300 illustrated in FIG. 40E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 40F is digital signage 7400 attached to a cylindrical pillar 7401. The digital signage 7400 includes the display portion 7000 provided along a curved surface of the pillar 7401.

The display device of one embodiment of the present invention can be used in the display portion 7000 in each of FIG. 40E and FIG. 40F. Thus, the electronic device can perform display with extremely high resolution.

A larger area of the display portion 7000 can increase the amount of information that can be provided at a time. The larger display portion 7000 attracts more attentions, so that the effectiveness of the advertisement can be increased, for example.

The use of a touch panel in the display portion 7000 is preferable because in addition to display of a still image or a moving image on the display portion 7000, intuitive operation by a user is possible. Moreover, for an application for providing information such as route information or traffic information, usability can be enhanced by intuitive operation.

As illustrated in FIG. 40E and FIG. 40F, it is preferable that the digital signage 7300 or the digital signage 7400 can work with an information terminal 7311 or an information terminal 7411 such as a smartphone of a user through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

Furthermore, it is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

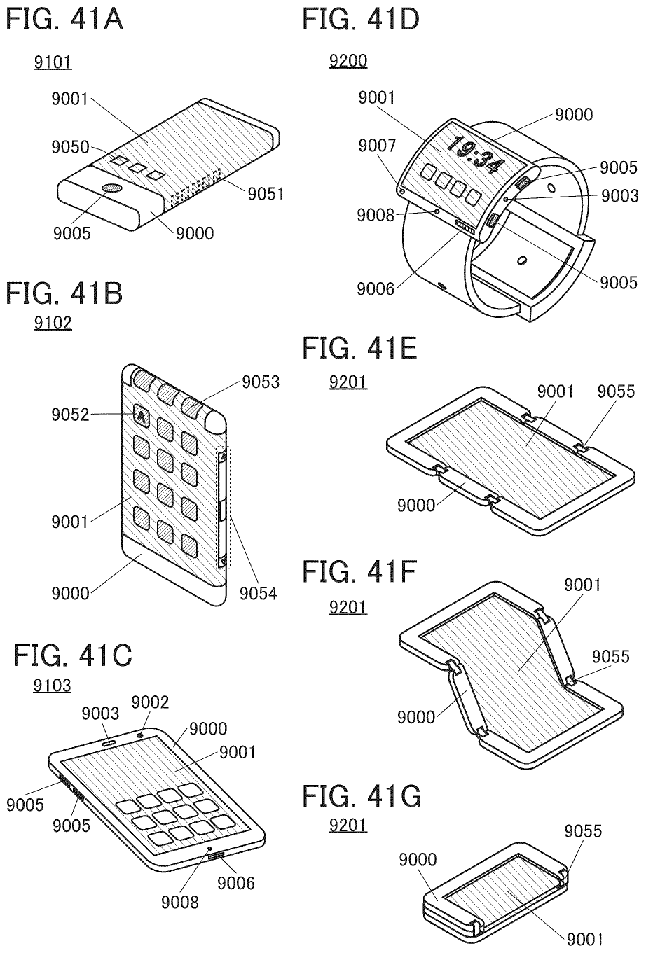

Electronic devices illustrated in FIG. 41A to FIG. 41G each include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The electronic devices illustrated in FIG. 41A to FIG. 41G have a variety of functions. For example, the electronic devices can have a function of displaying a variety of information (e.g., a still image, a moving image, or a text image) on the display portion, a touch panel function, a function of displaying a calendar, date, time, or the like, a function of controlling processing with the use of a variety of software (programs), a wireless communication function, or a function of reading out and processing a program or data stored in a recording medium. Note that the functions of the electronic devices are not limited thereto, and the electronic devices can have a variety of functions. The electronic devices may include a plurality of display portions. The electronic devices may each include a camera or the like and have a function of taking a still image or a moving image and storing the taken image in a recording medium (an external recording medium or a recording medium incorporated in the camera), a function of displaying the taken image on the display portion, and the like.

The electronic devices illustrated in FIG. 41A to FIG. 41G are described in detail below:

FIG. 41A is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. The portable information terminal 9101 can display text and image information on its plurality of surfaces. FIG. 41A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, for example, the icon 9050 may be displayed at the position where the information 9051 is displayed.

FIG. 41B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is illustrated. For example, a user of the portable information terminal 9102 can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 41C is a perspective view illustrating a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 41D is a perspective view illustrating a watch-type portable information terminal 9200. For example, the portable information terminal 9200 can be used as a Smartwatch (registered trademark). The display surface of the display portion 9001 is curved, and display can be performed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and can be charged. Note that the charging operation may be performed by wireless power feeding.

FIG. 41E to FIG. 41G are perspective views illustrating a foldable portable information terminal 9201. FIG. 41E is a perspective view of an opened state of the portable information terminal 9201, FIG. 41G is a perspective view of a folded state thereof, and FIG. 41F is a perspective view of a state in the middle of change from one of FIG. 41E and FIG. 41G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with the other embodiments as appropriate. In this specification, in the case where a plurality of structure examples are described in one embodiment, the structure examples can be combined as appropriate.

### Embodiment 5

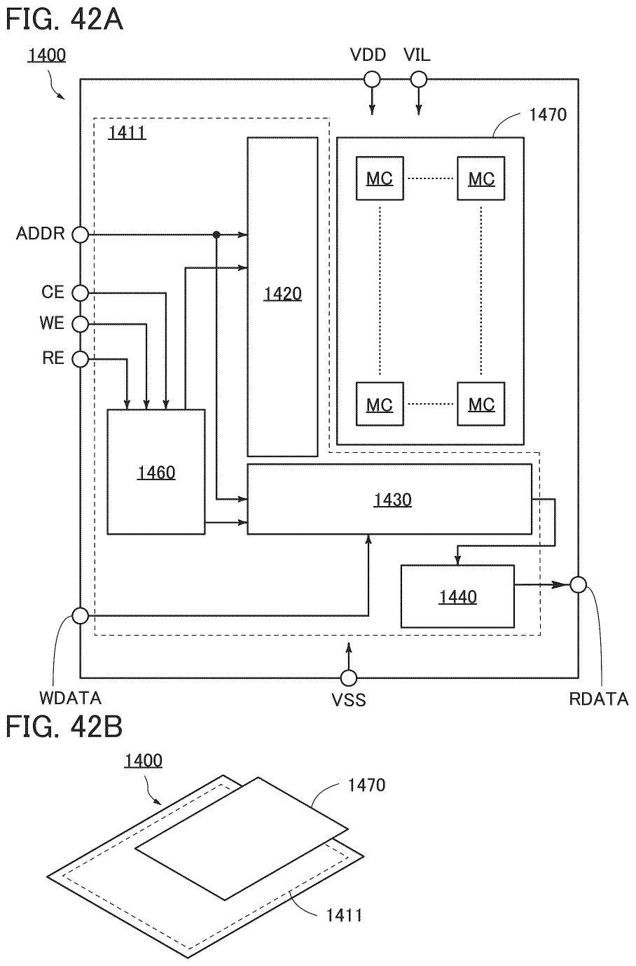

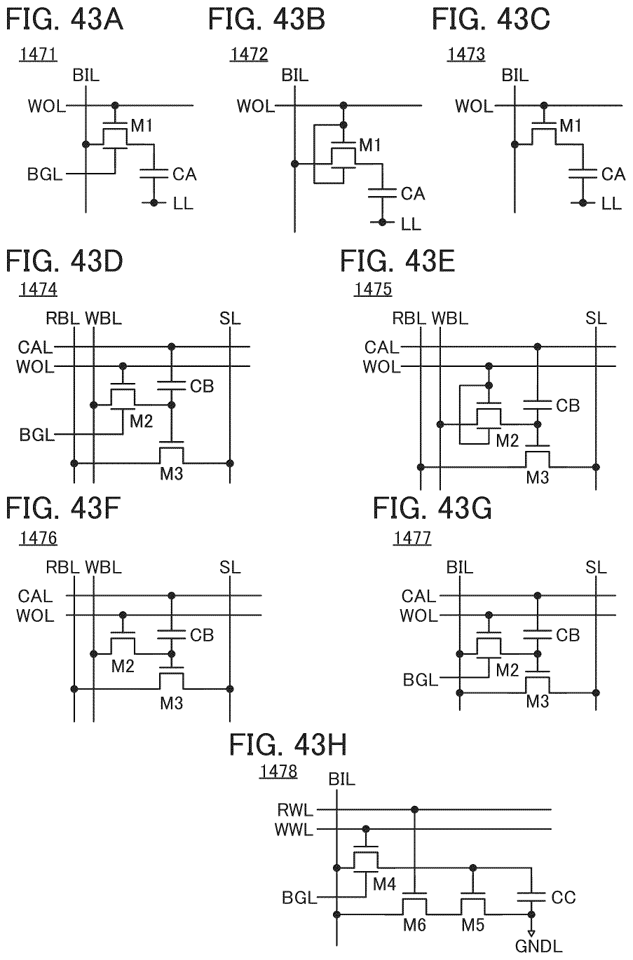

The application range of the transistor 200 described in Embodiment 1 is not limited to display devices, electronic devices including display devices, and the like. In this embodiment, a storage device including a transistor in which an oxide is used as a semiconductor (hereinafter sometimes referred to as an OS transistor) (such a storage device is hereinafter sometimes referred to as an OS memory device) according to one embodiment of the present invention is described with reference to FIG. 42A, FIG. 42B, and FIG. 43A to FIG. 43H. The OS memory device is a storage device that includes at least a capacitor and an OS transistor that controls the charging and discharging of the capacitor. Since the OS transistor has an extremely low off-state current, the OS memory device has excellent retention characteristics and thus can function as a nonvolatile memory.

### <Structure Example of Storage Device>

FIG. 42A illustrates a structure example of the OS memory device. A storage device 1400 includes a peripheral circuit 1411 and a memory cell array 1470. The peripheral circuit 1411 includes a row circuit 1420, a column circuit 1430, an output circuit 1440, and a control logic circuit 1460.

The column circuit 1430 includes, for example, a column decoder, a precharge circuit, a sense amplifier, a write circuit, and the like. The precharge circuit has a function of precharging wirings. The sense amplifier has a function of amplifying a data signal read from a memory cell. Note that the wirings are connected to memory cells included in the memory cell array 1470, and are described later in detail. The amplified data signal is output as a data signal RDATA to the outside of the storage device 1400 through the output circuit 1440. The row circuit 1420 includes, for example, a row decoder and a word line driver circuit, and can select a row to be accessed.

As power supply voltages from the outside, a low power supply voltage (VSS), a high power supply voltage (VDD) for the peripheral circuit 1411, and a high power supply voltage (VIL) for the memory cell array 1470 are supplied to the storage device 1400. Control signals (CE, WE, and RE), an address signal ADDR, and a data signal WDATA are also input to the storage device 1400 from the outside. The address signal ADDR is input to the row decoder and the column decoder, and the data signal WDATA is input to the write circuit.

The control logic circuit 1460 processes the control signals (CE, WE, and RE) input from the outside, and generates control signals for the row decoder and the column decoder. The control signal CE is a chip enable signal, the control signal WE is a write enable signal, and the control signal RE is a read enable signal. Signals processed by the control logic circuit 1460 are not limited thereto, and other control signals are input as necessary.

The memory cell array 1470 includes a plurality of memory cells MC arranged in a matrix and a plurality of wirings. Note that the number of wirings that connect the memory cell array 1470 to the row circuit 1420 depends on the structure of the memory cell MC, the number of memory cells MC in a column, and the like. The number of wirings that connect the memory cell array 1470 to the column circuit 1430 depends on the structure of the memory cell MC, the number of memory cells MC in a row, and the like.

Note that FIG. 42A illustrates an example where the peripheral circuit 1411 and the memory cell array 1470 are formed on the same plane; however, this embodiment is not limited to the example. For example, as illustrated in FIG. 42B, the memory cell array 1470 may be provided to overlap with part of the peripheral circuit 1411. For example, the sense amplifier may be provided below the memory cell array 1470 so that they overlap with each other.

FIG. 43A to FIG. 43H each illustrate a structure example of a memory cell that can be used as the memory cell MC described above.

### [DOSRAM]

FIG. 43A to FIG. 43C show circuit structure examples of DRAM memory cells. In this specification and the like, a DRAM using a memory cell including one OS transistor and one capacitor is referred to as a DOSRAM (Dynamic Oxide Semiconductor Random Access Memory) in some cases. A memory cell 1471 illustrated in FIG. 43A includes a transistor M1 and a capacitor CA. Note that the transistor M1 includes a gate (sometimes referred to as a top gate) and a back gate.

A first terminal of the transistor M1 is connected to a first terminal of the capacitor CA. A second terminal of the transistor M1 is connected to a wiring BIL. The gate of the transistor M1 is connected to a wiring WOL. The back gate of the transistor M1 is connected to a wiring BGL. A second terminal of the capacitor CA is connected to a wiring LL.

The wiring BIL functions as a bit line, and the wiring WOL functions as a word line. The wiring LL functions as a wiring for applying a predetermined potential to the second terminal of the capacitor CA. At the time of data writing and data reading, the wiring LL may be at a ground potential or a low-level potential. The wiring BGL functions as a wiring for applying a potential to the back gate of the transistor M1. When a given potential is applied to the wiring BGL, the threshold voltage of the transistor M1 can be increased or decreased.

The circuit structure of the memory cell MC is not limited to that of the memory cell 1471 and can be changed. For example, as in a memory cell 1472 illustrated in FIG. 43B, the back gate of the transistor M1 may be connected not to the wiring BGL but to the wiring WOL in the memory cell MC. Alternatively, for example, the transistor M1 may be a single-gate transistor, that is, a transistor without a back gate in the memory cell MC as in a memory cell 1473 illustrated in FIG. 43C.

In the case where the semiconductor device described in the above embodiments is used in the memory cell 1471 and the like, the transistor 200 can be used as the transistor M1. When an OS transistor is used as the transistor M1, the off-state current of the transistor M1 can be extremely low. That is, with use of the transistor M1, written data can be retained for a long time, and thus the frequency of the refresh operation for the memory cell can be decreased. Alternatively, refresh operation for the memory cell can be unnecessary. In addition, since the transistor M1 has an extremely low off-state current, multi-level data or analog data can be retained in the memory cell 1471, the memory cell 1472, and the memory cell 1473.

In the DOSRAM, when the sense amplifier is provided below the memory cell array 1470 so that they overlap with each other as described above, the bit line can be shortened. This reduces bit line capacitance, which can reduce the storage capacitance of the memory cell.

### [NOSRAM]

FIG. 43D to FIG. 43G each illustrate a circuit structure example of a gain-cell memory cell including two transistors and one capacitor. A memory cell 1474 illustrated in FIG. 43D includes a transistor M2, a transistor M3, and a capacitor CB. Note that the transistor M2 includes a top gate (simply referred to as a gate in some cases) and a back gate. In this specification and the like, a storage device including a gain-cell memory cell using an OS transistor as the transistor M2 is referred to as a NOSRAM (Nonvolatile Oxide Semiconductor RAM) in some cases.

A first terminal of the transistor M2 is connected to a first terminal of the capacitor CB. A second terminal of the transistor M2 is connected to a wiring WBL. The gate of the transistor M2 is connected to the wiring WOL. The back gate of the transistor M2 is connected to the wiring BGL. A second terminal of the capacitor CB is connected to a wiring CAL. A first terminal of the transistor M3 is connected to a wiring RBL. A second terminal of the transistor M3 is connected to a wiring SL. A gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. At the time of data writing and data reading, a high-level potential is preferably applied to the wiring CAL. During data retaining, a low-level potential is preferably applied to the wiring CAL. The wiring BGL functions as a wiring for applying a potential to the back gate of the transistor M2. The threshold voltage of the transistor M2 can be increased or decreased by applying a given potential to the wiring BGL.

The circuit structure of the memory cell MC is not limited to that of the memory cell 1474 and can be changed as appropriate. For example, as in a memory cell 1475 illustrated in FIG. 43E, the back gate of the transistor M2 may be connected not to the wiring BGL but to the wiring WOL in the memory cell MC. Alternatively, for example, the transistor M2 may be a single-gate transistor, that is, a transistor without a back gate in the memory cell MC as in a memory cell 1476 illustrated in FIG. 43F. For example, the memory cell MC may have a structure in which the wiring WBL and the wiring RBL are combined into one wiring BIL as in a memory cell 1477 illustrated in FIG. 43G.

In the case where the semiconductor device described in the above embodiments is used in the memory cell 1474 and the like, the transistor 200 can be used as the transistor M2. When an OS transistor is used as the transistor M2, the off-state current of the transistor M2 can be extremely low. Consequently, with use of the transistor M2, written data can be retained for a long time, and thus the frequency of the refresh operation for the memory cell can be decreased. Alternatively, refresh operation for the memory cell can be unnecessary. In addition, since the transistor M2 has an extremely low off-state current, multi-level data or analog data can be retained in the memory cell 1474. The same applies to the memory cell 1475 to the memory cell 1477.

Note that the transistor M3 may be a transistor containing silicon in a channel formation region (hereinafter sometimes referred to as a Si transistor). The Si transistor may be either an n-channel transistor or a p-channel transistor. A Si transistor has higher field-effect mobility than an OS transistor in some cases. Therefore, a Si transistor may be used as the transistor M3 functioning as a reading transistor. Furthermore, the transistor M2 can be stacked over the transistor M3 when a Si transistor is used as the transistor M3, in which case the area occupied by the memory cell can be reduced, leading to high integration of the storage device.

Alternatively, the transistor M3 may be an OS transistor. When OS transistors are used as the transistor M2 and the transistor M3, the circuit of the memory cell array 1470 can be formed using only n-channel transistors.

FIG. 43H illustrates an example of a gain-cell memory cell including three transistors and one capacitor. A memory cell 1478 illustrated in FIG. 43H includes a transistor M4 to a transistor M6 and a capacitor CC. The capacitor CC is provided as appropriate. The memory cell 1478 is electrically connected to the wiring BIL, a wiring RWL, a wiring WWL, the wiring BGL, and a wiring GNDL. The wiring GNDL is a wiring for supplying a low-level potential. Note that the memory cell 1478 may be electrically connected to the wiring RBL and the wiring WBL instead of the wiring BIL.

The transistor M4 is an OS transistor with a back gate, and the back gate is electrically connected to the wiring BGL. Note that the back gate and the gate of the transistor M4 may be electrically connected to each other. Alternatively, the transistor M4 does not necessarily include the back gate.

Note that each of the transistor M5 and the transistor M6 may be an n-channel Si transistor or a p-channel Si transistor. Alternatively, the transistor M4 to the transistor M6 may be OS transistors. In that case, the circuit of the memory cell array 1470 can be formed using only n-channel transistors.

In the case where the semiconductor device described in the above embodiments is used in the memory cell 1478, the transistor 200 can be used as the transistor M4. When an OS transistor is used as the transistor M4, the off-state current of the transistor M4 can be extremely low.

Note that the structures of the peripheral circuit 1411, the memory cell array 1470, and the like described in this embodiment are not limited to the above. The arrangement and functions of these circuits and the wirings, circuit elements, and the like connected to the circuits can be changed, removed, or added as needed.

The structure, method, and the like described in this embodiment can be used in an appropriate combination with any of other structures, methods, and the like described in this embodiment or the other embodiments.

### Embodiment 6

In this embodiment, a storage device, a chip, and an electronic device in which the semiconductor device of the present invention is mounted are described.

### <Storage Device>

The semiconductor device described in the above embodiment can be applied to, for example, storage devices of a variety of electronic devices (e.g., information terminals, computers, smartphones, e-book readers, digital cameras (including video cameras), video recording/reproducing devices, and navigation systems). Here, the computers refer not only to tablet computers, laptop computers, and desktop computers, but also to large computers such as server systems. Alternatively, the semiconductor device described in the above embodiment is applied to a variety of removable storage devices such as memory cards (e.g., SD cards), USB memories, and SSDs (solid state drives).

### <Chip>

A plurality of circuits (systems) are mounted on a chip. A technique for integrating a plurality of circuits (systems) into one chip is referred to as system on chip (SoC) in some cases.

A chip includes a CPU, a GPU, one or more analog arithmetic units, one or more memory controllers, one or more interfaces, one or more network circuits, and the like.

The chip is provided with a bump and is connected to a first surface of a printed circuit board (PCB). In addition, a plurality of bumps are provided on a rear side of the first surface of the PCB, and the PCB is connected to a motherboard.

Storage devices such as a DRAM and a flash memory may be provided over a motherboard. For example, the DOSRAM described in the above embodiment can be used as the DRAM. In addition, for example, the NOSRAM described in the above embodiment can be used as the flash memory.

The CPU preferably includes a plurality of CPU cores. In addition, the GPU preferably includes a plurality of GPU cores. Furthermore, the CPU and the GPU may each include a memory for temporarily storing data. Alternatively, a common memory for the CPU and the GPU may be provided in the chip. The NOSRAM or the DOSRAM described above can be used as the memory. Moreover, the GPU is suitable for parallel computation of a number of data and thus can be used for image processing and product-sum operation. When an image processing circuit and a product-sum operation circuit using an oxide semiconductor of the present invention are provided in the GPU, image processing and product-sum operation can be performed with low power consumption.

The analog arithmetic unit includes one or both of an A/D (analog/digital) converter circuit and a D/A (digital/analog) converter circuit. Furthermore, the product-sum operation circuit may be provided in the analog arithmetic unit.

The memory controller includes a circuit functioning as a controller of the DRAM and a circuit functioning as an interface of the flash memory.

The interface includes an interface circuit for an external connection device such as a display device, a speaker, a microphone, a camera, or a controller.

The network circuit includes a circuit for a network such as a LAN (Local Area Network). The network circuit may further include a circuit for network security.

The motherboard provided with the PCB on which a chip including a GPU is mounted, DRAMs, and a flash memory can be referred to as a GPU module.

The GPU module includes a chip formed using the SoC technology, and thus can have a small size. In addition, the GPU module is excellent in image processing, and thus is suitably used in a portable electronic device such as a smartphone, a tablet terminal, a laptop PC, or a portable (mobile) game machine. Furthermore, the product-sum operation circuit using the GPU can perform a method such as a deep neural network (DNN), a convolutional neural network (CNN), a recurrent neural network (RNN), an autoencoder, a deep Boltzmann machine (DBM), or a deep belief network (DBN); hence, the chip can be used as an AI chip or the GPU module can be used as an AI system module.

### <Electronic Device>

The above-described chip can be mounted on a variety of electronic devices. Examples of electronic devices include a digital camera, a digital video camera, a digital photo frame, an e-book reader, a mobile phone (a smartphone), a portable game machine, a portable information terminal, an audio reproducing device, a moving vehicle, and a household appliance, in addition to electronic devices with a relatively large screen, such as a television device, a monitor for a desktop or laptop information terminal or the like, digital signage, a large game machine like a pachinko machine, and a large computer. Examples of moving vehicles include an automobile, a train, a monorail train, a ship, and a flying object (a helicopter, an unmanned aircraft (a drone), an airplane, and a rocket). Examples of household appliances include an electric refrigerator-freezer, a vacuum cleaner, a microwave oven, an electric oven, a rice cooker, a water heater, an IH cooker, a water server, a heating-cooling combination appliance including an air conditioner, a washing machine, a drying machine, and an audio visual appliance. In addition, when the above-described chip is provided in an electronic device, the electronic device can include artificial intelligence.

The electronic device of one embodiment of the present invention may include an antenna. When a signal is received by the antenna, the electronic device can display a video, information, or the like on a display portion. When the electronic device includes the antenna and a secondary battery, the antenna may be used for contactless power transmission.

The electronic device of one embodiment of the present invention may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, power, radioactive rays, flow rate, humidity, gradient, oscillation, a smell, or infrared rays).

The electronic device of one embodiment of the present invention can have a variety of functions. For example, the electronic device can have a function of displaying a variety of information (a still image, a moving image, a text image, and the like) on the display portion, a touch panel function, a function of displaying a calendar, date, time, or the like, a function of executing a variety of software (programs), a wireless communication function, or a function of reading out a program or data stored in a recording medium.

The electronic devices, the functions of the electronic devices, the application examples of artificial intelligence, their effects, and the like described in this embodiment can be combined as appropriate with the description of another electronic device.

This embodiment can be implemented in an appropriate combination with any of the structures described in the other embodiments.

### Example 1

In this example, evaluation of the etching rate of an oxide semiconductor by a dry etching method and cross-sectional observation of the oxide semiconductor processed into an island shape using a dry etching method were performed.

In this example, an In—Ga—Zn oxide was used as the oxide semiconductor. Here, Table 1 shows the boiling points of by-products generated in etching of the In—Ga—Zn oxide. As shown in Table 1, halogen compounds of In, Ga, and Zn have high boiling points; thus, a wet etching method is generally used for etching of the In—Ga—Zn oxide in many cases. However, it is difficult to form a minute pattern using a wet etching method. Thus, a minute pattern of the In—Ga—Zn oxide is preferably formed by a dry etching method. Note that the boiling points of organic compounds of In, Ga, and Zn are lower than the boiling points of the halogen compounds of In, Ga, and Zn, respectively; thus, in addition to a halogen gas such as a chlorine gas, a gas containing methane is used as an etching gas for the In—Ga—Zn oxide in some cases.

TABLE 1

| | In | Ga | Zn |
|---|---|---|---|
| Chloride | 800° C. | 201.2° C. | 732° C. |
| | InCl₃ | GaCl₃ | ZnCl₂ |
| Fluoride | 1200° C. | 1000° C. | 1500° C. |
| | InF₃ | GaF₃ | ZnF₂ |

First, the result of evaluating the etching rate of an oxide by a dry etching method is described. Specifically, the etching rate of an oxide semiconductor was evaluated under conditions of different etching gases and high-frequency powers applied to an electrode in a dry etching step. Note that a plurality of samples having the same structure were prepared for the conditions of different etching gases and high-frequency powers applied to the electrode.

The samples were fabricated in the following manner. First, a silicon oxide film for an etching stopper was deposited over a silicon wafer, an oxide semiconductor with a thickness of 100 nm was deposited over the silicon oxide film, and a resist mask was formed over the oxide semiconductor. Here, the oxide semiconductor was deposited by a DC sputtering method in which an oxygen gas at 45 sccm was used as a deposition gas, the deposition pressure was 0.7 Pa, the deposition power was 500 W, the substrate temperature was 200° C., and the target-substrate distance was 60 mm. An oxide semiconductor deposited under these conditions is an oxide semiconductor having a CAAC structure (CAAC-OS).

The above samples were subjected to a dry etching step using a CCP etching apparatus. As common conditions in the dry etching step, the high-frequency power applied to an upper electrode was 1000 W, the pressure was 1.2 Pa, the substrate temperature was 70° C., and the treatment time was 30 seconds. The etching gas was a chlorine (Cl₂) gas, a mixed gas of chlorine and argon (Ar) (Cl₂:Ar=7:3), or a mixed gas of methane (CH₄) and argon (CH₄:Ar=7:3). The high-frequency power applied to a lower electrode was within the range of 0 W to 400 W.

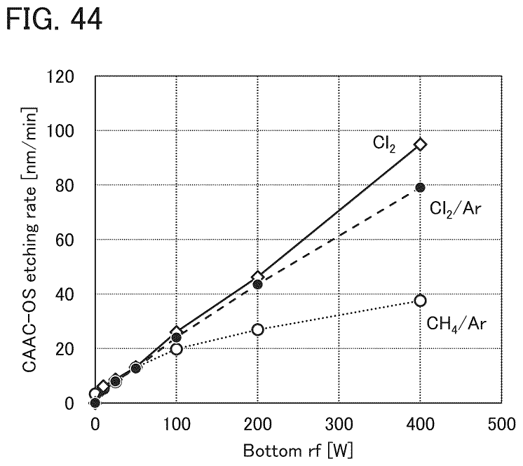

FIG. 44 shows the etching rate of the oxide semiconductor under each condition. In FIG. 44, the vertical axis represents the etching rate of the oxide semiconductor (CAAC-OS etching rate) [nm/min], and the horizontal axis represents the high-frequency power applied to the lower electrode (Bottom rf) [W]. In FIG. 44, a plot indicated by rhombuses is a result of the case of using the chlorine gas (Cl₂) as the etching gas, a plot indicated by black circles is a result of the case of using the mixed gas of chlorine and argon (Cl₂/Ar) as the etching gas, and a plot indicated by white circles is a result of the case of using the mixed gas of methane and argon (CH₄/Ar).

FIG. 44 reveals that the oxide semiconductor can be etched by dry etching using the chlorine gas, the mixed gas of chlorine and argon, or the mixed gas of methane and argon. Accordingly, a minute pattern of the In—Ga—Zn oxide can be accurately formed by using a gas containing a halogen or methane as an etching gas. FIG. 44 also reveals that the etching rate of the oxide semiconductor has a strong dependence on the high-frequency power applied to the lower electrode in all cases of the chlorine gas, the mixed gas of chlorine and argon, and the mixed gas of methane and argon. That is, it can be seen that dry etching of an oxide semiconductor follows the mechanisms of ion sputtering and reactive etching including a chemical reaction. In other words, it can be seen that an assist effect of a relatively high ion incident energy is necessary for dry etching of an oxide semiconductor.

Next, cross-sectional observation of a sample including an oxide semiconductor processed into an island shape by a dry etching method was performed.

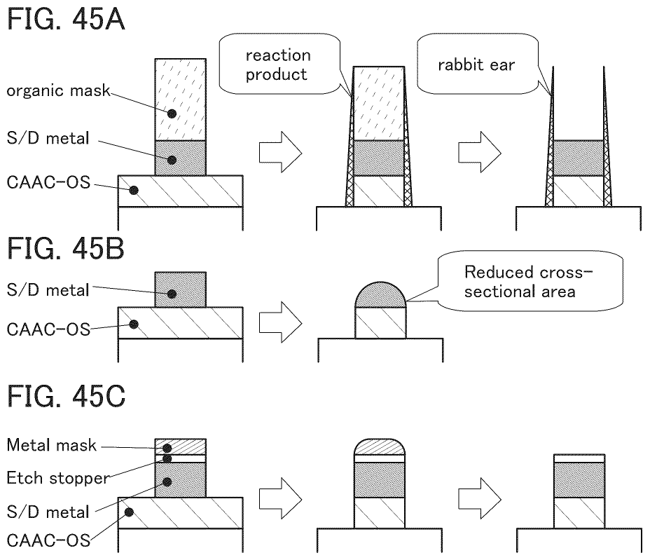

First, a fabrication method of the above-described sample is described with reference to FIG. 45C. Note that Embodiment 1 can be referred to for details of the fabrication method.

A silicon wafer was prepared, and silicon oxynitride with a thickness of 200 nm was deposited over the silicon wafer by a CVD method. The silicon oxynitride corresponds to the insulator 216 described in Embodiment 1.

Hafnium oxide with a thickness of 20 nm was deposited over the silicon oxynitride by an ALD method. The hafnium oxide corresponds to the insulator 222 described in Embodiment 1.

A first silicon oxide film with a thickness of 20 nm was deposited over the hafnium oxide by a sputtering method. The first silicon oxide film corresponds to the insulating film 224A described in Embodiment 1.

An oxide semiconductor film was deposited over the first silicon oxide film by a sputtering method. The oxide semiconductor film has a stacked-layer structure of a first oxide semiconductor film and a second oxide semiconductor film over the first oxide semiconductor film. The first oxide semiconductor film was deposited using an oxide target with In:Ga:Zn=1:3:4 [atomic ratio]. The second oxide semiconductor film was deposited using an oxide target with In:Ga:Zn=1:1:1 [atomic ratio]. The thickness of the first oxide semiconductor film is 10 nm, and the thickness of the second oxide semiconductor film is 15 nm. The first oxide semiconductor film and the second oxide semiconductor film correspond respectively to the oxide film 230A and the oxide film 230B described in Embodiment 1. Note that the above oxide semiconductor film has a CAAC structure and is thus denoted by “CAAC-OS” in FIG. 45C.

Over the oxide semiconductor film, a tantalum nitride film with a thickness of 20 nm, a silicon nitride film with a thickness of 5 nm, and a second silicon oxide film with a thickness of nm were deposited in this order by a sputtering method. Note that the tantalum nitride film, the silicon nitride film, and the second silicon oxide film were successively deposited without exposure to the air using a multi-chamber sputtering apparatus. The tantalum nitride film corresponds to the conductive film 242A described in Embodiment 1, and the stacked-layer film of the silicon nitride film and the second silicon oxide film corresponds to the insulating film 271A.

A tungsten film was deposited over the second silicon oxide film.

An organic mask was formed over the tungsten film, and the tungsten film, the second silicon oxide film, the silicon nitride film, and the tantalum nitride film were processed into an island shape by a dry etching method using the organic mask as a mask, whereby a tungsten layer (a “Metal Mask” in FIG. 45C), a silicon oxide layer, a silicon nitride layer, and a tantalum nitride layer having an island shape were formed (the left side in FIG. 45C). The tantalum nitride layer corresponds to the conductive layer 242B described in Embodiment 1, and the stack of the silicon nitride layer and the silicon oxide layer corresponds to the insulating layer 271B. Note that the conductive layer 242B is a conductive layer to be a source electrode and a drain electrode and is thus denoted by “S/D metal” in FIG. 45C. In addition, the stack of the silicon nitride layer and the silicon oxide layer functions as an etching stopper and is thus denoted by “Etch stopper” in FIG. 45C.

Next, an island-shaped oxide semiconductor was formed by processing the oxide semiconductor layer having a stacked-layer structure by a dry etching method using the above-described island-shaped tungsten layer as a mask (the middle in FIG. 45C). The island-shaped oxide semiconductor has a stacked-layer structure of a first oxide semiconductor formed of the first oxide semiconductor film and a second oxide semiconductor formed of the second oxide semiconductor film. Note that a mixed gas of methane and argon was used as an etching gas. When the island-shaped oxide semiconductor is formed, an end portion of the island-shaped tungsten layer is etched, but the shape of the tantalum nitride layer is maintained.

Next, the island-shaped tungsten layer was removed (the right side in FIG. 45C). At this time, the tantalum nitride layer is protected by the stack of the silicon nitride layer and the silicon oxide layer; thus, the shape of the tantalum nitride layer is maintained.

In the above manner, the sample including the island-shaped oxide semiconductor was fabricated. FIG. 9B can be referred to for a cross-sectional view showing the structure of the sample.

Here, a fabrication method different from the fabrication method of the sample described with reference to FIG. 45C is described. FIG. 45A illustrates an example of a method for processing the oxide semiconductor film using an organic mask (“organic mask” illustrated in FIG. 45A) instead of “Metal mask” and “Etch stopper” in FIG. 45C. FIG. 45B illustrates an example of a method for processing the oxide semiconductor film without using “Metal mask” or “Etch stopper” in FIG. 45C.

In the case where the oxide semiconductor film is etched using the mixed gas of methane and argon, an organometallic compound is generated as a reaction product. In the case where the oxide semiconductor film is etched using the organic mask, a reaction product (“reaction product” in FIG. 45A) is reattached to the side surfaces of the organic mask and the oxide semiconductor, whereby a layer (“rabbit ear” in FIG. 45A) is formed.

One possible method for inhibiting the formation of the above layer (“rabbit ear” in FIG. 45A) is to form the conductive layer to be the source electrode and the drain electrode (“S/D metal” in FIG. 45B) using the organic mask, remove the organic mask, and etch the oxide semiconductor film using the conductive layer as a mask. However, as described above, the assist effect of a relatively high ion incident energy is necessary for etching of the oxide semiconductor. Thus, in the case where the oxide semiconductor film is etched using the above-described conductive layer as a mask, the end portion of the conductive layer is etched (Reduced cross-sectional area), so that the cross-sectional area of the conductive layer is reduced (the right side in FIG. 45B). A reduction in the cross-sectional area of the conductive layer has a more adverse effect on the characteristics of a transistor as the transistor becomes minuter.

Accordingly, etching of the oxide semiconductor by the method illustrated in FIG. 45C enables processing into a minute island-shaped oxide semiconductor.

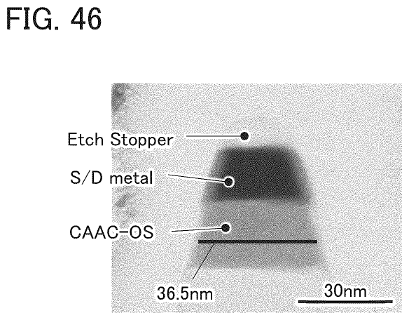

A cross-sectional STEM image of the fabricated sample was taken with “HD-2700” produced by Hitachi High-Technologies Corporation. FIG. 46 shows the cross-sectional STEM image of the fabricated sample. In FIG. 46, “Etch Stopper” is the stack of the silicon nitride layer and the silicon oxide layer, “S/D metal” is the tantalum nitride layer, and “CAAC-OS” is the island-shaped oxide semiconductor having a stacked-layer structure.

As shown in FIG. 46, the length of the interface between the first oxide semiconductor and the second oxide semiconductor in the channel width direction is 36.5 nm.

In addition, the hard mask and the etching stopper were provided over the tantalum nitride film, whereby a layer (rabbit ear) was not formed on the side surface of the oxide semiconductor as shown in FIG. 46. It can also be seen that an end portion at the intersection of the side surface and the top surface of the tantalum nitride layer is angular. In other words, the shape of the tantalum nitride layer is maintained even after the oxide semiconductor is etched. Thus, the cross-sectional area of the tantalum nitride layer can be increased as compared with the case where the end portion has a curved surface.

This example can be used in an appropriate combination with any of the structures, configurations, methods, and the like described in the embodiments and other examples.

### Example 2

In this example, the results of verification of a transistor including the insulator 244a and the insulator 244b by device simulation are described. Note that the device simulation is performed using TCAD Sentaurus of Synopsys Inc.

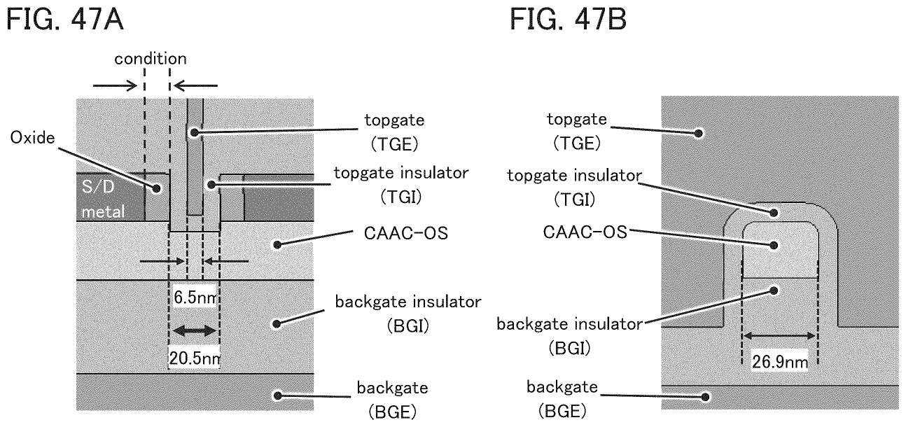

FIG. 47A and FIG. 47B illustrate schematic cross-sectional views of a transistor used for the device simulation. FIG. 47A is a schematic cross-sectional view of the transistor in the channel length direction. FIG. 47B is a schematic cross-sectional view of the transistor in the channel width direction.

The transistor used for the device simulation includes a back gate electrode (backgate, BGE), a back gate insulating film (backgate insulator, BGI) over the back gate electrode, an oxide semiconductor having a CAAC structure (CAAC-OS) over the back gate insulating film, a source electrode and a drain electrode (S/D metal) over the oxide semiconductor, a top gate electrode (topgate, TGE) overlapping with the oxide semiconductor, and a top gate insulating film (topgate insulator, TGI) positioned between the oxide semiconductor and the top gate electrode. The transistor also includes an oxide (Oxide) positioned between one of the source electrode and the drain electrode and the top gate insulating film and an oxide positioned between the other of the source electrode and the drain electrode and the top gate insulating film. Hereinafter, the oxide positioned between one of the source electrode and the drain electrode and the top gate insulating film is referred to as a first oxide, and the oxide positioned between the other of the source electrode and the drain electrode and the top gate insulating film is referred to as a second oxide.

Note that the transistor used for the device simulation corresponds to the transistor 200 described in Embodiment 1. Specifically, the back gate electrode corresponds to the conductor 205, the back gate insulating film corresponds to the insulator 222 and the insulator 224, the oxide semiconductor corresponds to the oxide 230, the source electrode and the drain electrode correspond to the conductor 242a and the conductor 242b, the top gate insulating film corresponds to the insulator 252, the insulator 250, and the insulator 254, and the top gate electrode corresponds to the conductor 260. The first oxide and the second oxide correspond to the insulator 244a and the insulator 244b, respectively.

First, an effect of the length of each of the first oxide and the second oxide in the channel length direction on the electrical characteristics of the transistor is evaluated. In the transistor used for the device simulation, the length of the first oxide in the channel length direction (condition in FIG. 47A) is set to 0 nm, 3 nm, 5 nm, or 10 nm. Note that the length of the second oxide in the channel length direction is equal to the length of the first oxide in the channel length direction. Here, the length of the first oxide in the channel length direction corresponds to the length D1 described in Embodiment 1. The transistor with the first oxide and the second oxide each having a length of 0 nm in the channel length direction can be regarded as a transistor that does not include the first oxide or the second oxide.

A gate length (the width of the top gate electrode in the channel length direction) is 6.5 nm. A distance between the side surface of the first oxide and the side surface of the second oxide is 20.5 nm. The length of the oxide semiconductor in the channel width direction is 26.9 nm.

Parameters other than those described above, which are set for the device simulation, are shown in Table 2.

TABLE 2

| | | | |
|---|---|---|---|
| TGE | Work function | 4.7 | eV |
| TGI | Physical thickness | 7 | nm |
| | EOT | 5.1 | nm |
| S/D electrode | Work function | 4.5 | eV |
| BGI | Physical thickness | 40 | nm |
| | EOT | 25 | nm |
| BGE | Work function | 5.0 | eV |
| CAAC-OS | Electron affinity | 4.7 | eV |
| | Bandgap (300K) | 3.2 | eV |
| | Relative permittivity | 15 | |
| | Electron mobility | 6 | cm²/Vs |
| | Hole mobility | 0.01 | cm²/Vs |
| | Density of states in conduction | 5.0 × 10¹⁸ | cm⁻³ |
| | band (300K) | | |
| | Density of states in valence band | 5.0 × 10¹⁸ | cm⁻³ |
| | (300K) | | |
| | Thickness | 25 | nm |
| | Donor concentration | 1.0 × 10¹⁶ | cm⁻³ |
| | (channel formation region) | | |
| | Donor concentration | 1.0 × 10²⁰ | cm⁻³ |
| | (S/D region) | | |

The device simulation is performed using the above transistor and parameters to calculate capacitance (Cg)-top gate voltage (Vg) characteristics and Id-Vg characteristics. Note that the Cg-Vg characteristics are calculated with Vs−Vd=Vbg=0 V. In addition, the Id-Vg characteristics are calculated with Vs=Vbg=0 V.

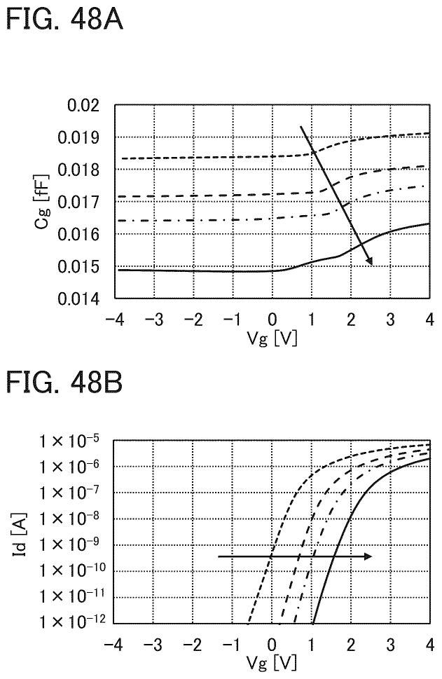

FIG. 48A and FIG. 48B show the results of the device simulation. FIG. 48A shows the calculated Cg-Vg characteristics, and FIG. 48B shows the calculated Id-Vg characteristics. In FIG. 48A, the vertical axis represents the capacitance Cg [fF] between the top gate electrode and the drain electrode, and the horizontal axis represents the top gate voltage Vg [V]. In FIG. 48B, the vertical axis represents the drain current Id [A], and the horizontal axis represents the top gate voltage Vg [V].

Dotted lines shown in FIG. 48A and FIG. 48B are results obtained by using the transistor with the first oxide having a length of 0 nm in the channel length direction. Dashed lines shown in FIG. 48A and FIG. 48B are results obtained by using the transistor with the first oxide having a length of 3 nm in the channel length direction. Dashed-dotted lines shown in FIG. 48A and FIG. 48B are results obtained by using the transistor with the first oxide having a length of 5 nm in the channel length direction. Solid lines shown in FIG. 48A and FIG. 48B are results obtained by using the transistor with the first oxide having a length of 10 nm in the channel length direction.

FIG. 48A confirms that parasitic capacitance is decreased when the first oxide and the second oxide are provided. Meanwhile, no change in capacitance contributing to an electric field for a channel indicates that parasitic capacitance is relatively reduced. Thus, the transistor of one embodiment of the present invention can operate at high speed and achieves low power consumption.

FIG. 48B confirms that the threshold voltage Vth shifts in the positive direction when the first oxide and the second oxide are provided. This is presumably because the intensity of a vertical electric field is relatively increased and a short-channel effect is inhibited when the first oxide and the second oxide are provided.

Accordingly, parasitic capacitance between the top gate electrode and the drain electrode can be reduced by increasing the length of each of the insulator 244a and the insulator 244b described in the above embodiment in the channel length direction. In addition, a short-channel effect can be inhibited.

According to the above results, the length of the insulator 244a described in the above embodiment in the channel length direction (the length D1) is preferably greater than or equal to 1 nm, greater than or equal to 3 nm, or greater than or equal to 5 nm and less than or equal to 20 nm, less than or equal to 15 nm, or less than or equal to 10 nm.

Next, an effect of the length of an oxide semiconductor in the channel width direction on the electrical characteristics of a transistor with a small channel length (a short-channel transistor) is evaluated.

In the transistor used for this device simulation, the length of each of the first oxide and the second oxide in the channel length direction is 3 nm. A gate length is 6.5 nm. A distance between the side surface of the first oxide and the side surface of the second oxide is 20.5 nm. The length of the oxide semiconductor in the channel width direction (channel width) is set to 26.9 nm, 45 nm, or 60 nm.

Parameters other than those described above, which are set for the device simulation, are the same as the parameters shown in Table 2.

The device simulation is performed using the above transistor and parameters to calculate Id-Vg characteristics. Note that the Id-Vg characteristics are calculated with Vs=Vbg=0 V and Vd=1.2 V.

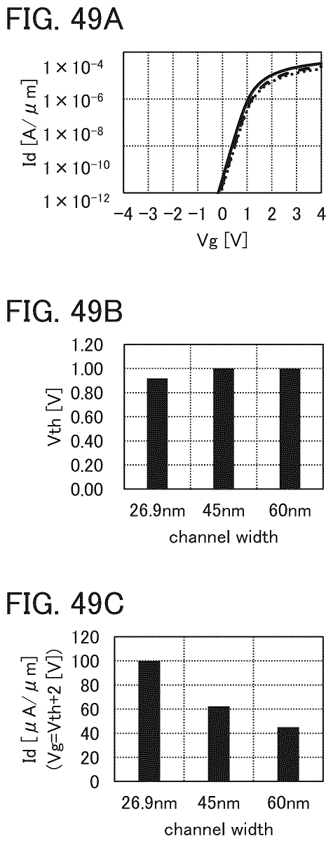

FIG. 49A to FIG. 49C show the results of the device simulation. FIG. 49A shows the calculated Id-Vg characteristics. In FIG. 49A, the vertical axis represents the drain current Id per micrometer of channel width [A/μm], and the horizontal axis represents the top gate voltage Vg [V]. A solid line shown in FIG. 49A is a result obtained by using the transistor with the oxide semiconductor having a length of 26.9 nm in the channel width direction. A dashed line shown in FIG. 49A is a result obtained by using the transistor with the oxide semiconductor having a length of 45 nm in the channel width direction. A dotted line shown in FIG. 49A is a result obtained by using the transistor with the oxide semiconductor having a length of 60 nm in the channel width direction.

FIG. 49B shows the results of the threshold voltage Vth estimated from the calculated Id-Vg characteristics, and FIG. 49C shows the results of the drain current Id per micrometer of channel width [μA/μm] at the top gate voltage Vg=Vth+2 [V].

FIG. 49B reveals that a change in the threshold voltage Vth is small even when the length of the oxide semiconductor in the channel width direction is changed. FIG. 49C reveals that the drain current increases as the length of the oxide semiconductor in the channel width direction decreases under the condition of a high top gate voltage (Vg=Vth+2 [V]). This is presumably because the intensity of an electric field per unit channel is increased when the length of the oxide semiconductor in the channel width direction is decreased.

Note that it is known that the drain current of a MOSFET represented by gradual channel approximation (GCA) is proportional to the channel width of a semiconductor layer; however, the above results suggest that characteristics consistent with GCA cannot be obtained with a minute transistor owing to the effect of an electric field in the channel length direction.

Accordingly, it can be seen that a device that can maintain drive capability can be manufactured using a transistor with an oxide semiconductor having a small length in the channel length direction (a transistor with a small channel length) when the length of the oxide semiconductor in the channel width direction is decreased.

This example can be used in an appropriate combination with any of the structures, configurations, methods, and the like described in the embodiments and other examples.

### Example 3

In this example, a sample including a plurality of transistors was fabricated, and the structure of the transistors, the crystallinity of a metal oxide included in the transistors, and the electrical characteristics of the transistors were evaluated.

### [Fabrication of Sample]

The transistors included in the sample correspond to the transistor illustrated in FIG. 22A to FIG. 22D. Thus, FIG. 22A to FIG. 22D can be referred to for the cross-sectional structure of the transistors included in the sample. Note that the designed channel length and channel width values of the transistors included in the sample were 20 nm and 20 nm, respectively.

A fabrication method of the sample is described below. Note that Embodiment 1 can be referred to for details of the fabrication method.

As the insulator 212, 60-nm-thick silicon nitride was used. The insulator 212 was deposited by a pulsed DC sputtering method using a silicon target.

As the insulator 214, 40-nm-thick aluminum oxide was used. The insulator 214 was deposited by a pulsed DC sputtering method using an aluminum target.

As the insulator 216, 130-nm-thick silicon oxide was used. The insulator 216 was deposited by a pulsed DC sputtering method using a silicon target.

Note that the insulator 212, the insulator 214, and the insulator 216 were successively deposited without exposure to the air using a multi-chamber sputtering apparatus.

The conductor 205a was formed using a titanium nitride film deposited by a metal CVD method. The conductor 205b was formed using a tungsten film deposited by a metal CVD method.

As the insulator 222, 20-nm-thick hafnium oxide deposited by an ALD method was used. The insulator 224 was formed using a 20-nm-thick silicon oxide film deposited by a sputtering method.

The oxide 230a was formed using a 10-nm-thick oxide film deposited by a DC sputtering method. Note that the oxide film to be the oxide 230a was deposited using an oxide target with In:Ga:Zn=1:3:4 [atomic ratio].

The oxide 230b was formed using a 15-nm-thick oxide film deposited by an RF sputtering method. Note that the oxide film to be the oxide 230b was deposited using an oxide target with In:Ga:Zn=1:1:1.2 [atomic ratio].

The conductor 242a and the conductor 242b were formed using a 20-nm-thick tantalum nitride film deposited by a sputtering method. Note that the conductive film to be the conductor 242a and the conductor 242b was deposited using a metal tantalum target under an atmosphere containing nitrogen.

The insulator 271a1 and the insulator 271b1 were formed using a 5-nm-thick silicon nitride film. The insulator 271a2 and the insulator 271b2 were formed using a silicon oxide film. Note that the silicon nitride film and the silicon oxide film were successively deposited without exposure to the air using a multi-chamber sputtering apparatus.

As the insulator 275, 5-nm-thick silicon nitride deposited by an ALD method was used.

As the insulator 280, silicon oxide deposited by a sputtering method was used.

The insulator 252 was formed using a 1-nm-thick aluminum oxide film deposited by an ALD method. The insulator 250 was formed using a 3-nm-thick silicon oxide film deposited by an ALD method. The insulator 254 was formed using a 3-nm-thick silicon nitride film deposited by an ALD method.

The conductor 260a was formed using a 5-nm-thick titanium nitride film deposited by a metal CVD method. The conductor 260b was formed using a tungsten film deposited by a metal CVD method.

As the insulator 282, aluminum oxide was used. The insulator 282 was deposited by a pulsed DC sputtering method using an aluminum target.

As the insulator 283a, 20-nm-thick silicon nitride deposited by a sputtering method was used. As the insulator 283b, 5-nm-thick silicon nitride deposited by an ALD method was used.

As the insulator 274, silicon oxynitride deposited by a CVD method was used. As the insulator 285, 50-nm-thick silicon oxide deposited by a sputtering method was used.

As each of the insulator 241a and the insulator 241b, a stack of a first insulator and a second insulator was used. The first insulator was formed using an aluminum oxide film deposited by an ALD method, and the second insulator was formed using a silicon nitride film deposited by an ALD method.

Each of the conductor 240a and the conductor 240b was formed using a stacked film of a titanium nitride film and a tungsten film over the titanium nitride film. Note that the titanium nitride film and the tungsten film were deposited by a CVD method.

The sample including the transistors was fabricated in the above manner. In the transistors included in the fabricated sample, the EOT of a top gate insulating film (the insulator 252, the insulator 250, and the insulator 254) is 5.1 nm.

### [Cross-Sectional Observation Image]

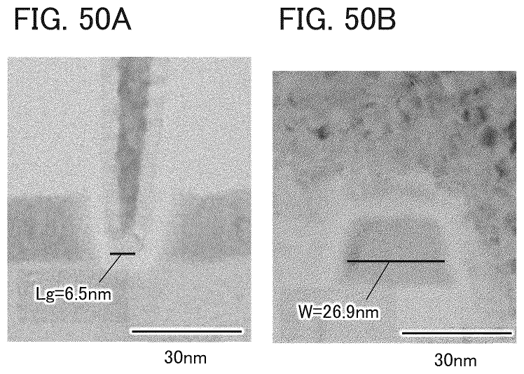

Cross-sectional STEM images of the fabricated sample were taken with “HD-2700” produced by Hitachi High-Technologies Corporation. FIG. 50A shows a cross-sectional STEM image of the fabricated sample in the channel length direction, and FIG. 50B shows a cross-sectional STEM image of the fabricated sample in the channel width direction.

Note that in FIG. 50A and FIG. 50B, the length of each component was measured on the basis of the observation results of the cross-sectional STEM images. As the result of the measurement using FIG. 50A, the gate length in the channel length direction of the transistor included in the sample (the width Lg illustrated in FIG. 50A) is 6.5 nm. As the result of the measurement using FIG. 50B, the length of the interface between the oxide 230a and the oxide 230b in the channel width direction of the transistor included in the sample (W illustrated in FIG. 50B) is 26.9 nm.

### [Electrical Characteristics Evaluation]

The electrical characteristics of the transistors included in the fabricated sample were evaluated. Here, Id-Vg characteristics were measured as the electrical characteristics. The measurement of the Id-Vg characteristics was performed under the conditions where the drain voltage Vd was 0.1 V or 1.2 V; the source voltage Vs and the back gate voltage Vbg were 0 V; and the top gate voltage Vg was swept from −4 V to +4 V in increments of 0.1 V. The measurement was performed in an environment at room temperature.

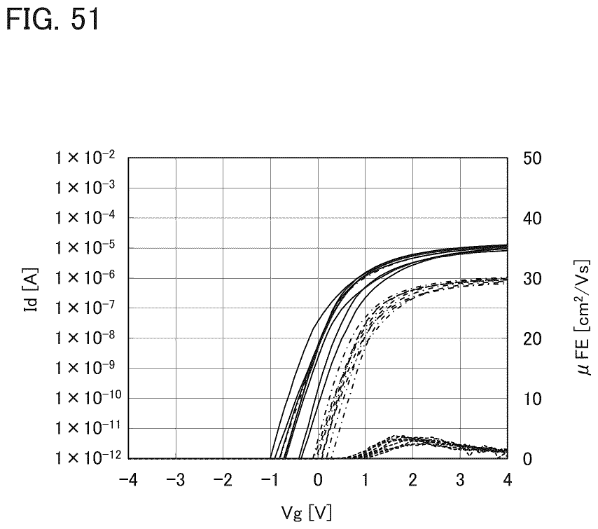

FIG. 51 shows the Id-Vg characteristics of nine transistors included in the fabricated sample. In FIG. 51, the first vertical axis represents the drain current Id [A], the second vertical axis represents the field-effect mobility μFE [cm²/Vs], and the horizontal axis represents the top gate voltage Vg [V]. In FIG. 51, Id with the drain voltage Vd of 1.2 V is shown by solid lines, Id with the drain voltage Vd of 0.1 V is shown by dashed-dotted lines, and the field-effect mobility is shown by dashed lines. Note that the field-effect mobility was calculated from the value measured at the drain voltage Vd set to 1.2 V.

FIG. 51 confirms that the transistors included in the fabricated sample have favorable electrical characteristics. The transistors have an EOT of 5.1 nm, which is relatively large with respect to the gate length. However, as shown in FIG. 51, it can be seen that there is less DIBL (drain induced barrier lowering), which is an index of a short-channel effect.

Next, the Id-Vg characteristics of 36 transistors in the fabricated sample were measured, and variations of Vth were evaluated. Note that the conditions of the Id-Vg characteristics measurement are similar to those described above.

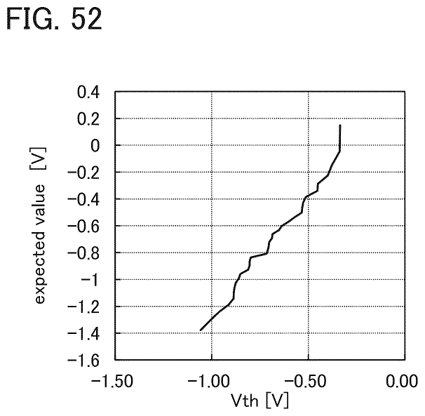

FIG. 52 shows the normal probability plot diagram of Vth. In FIG. 52, the horizontal axis represents the Vth [V], and the vertical axis represents the expected value [V] in the case where Vth follows a normal distribution. That is, the normal probability plot of Vth shown in FIG. 52 is a normal Q-Q plot.

According to FIG. 52, the median value of the threshold voltages Vth is-0.43 V, and the standard deviation (o) of the threshold voltages Vth is 0.22 V.

### [Cutoff Frequency]

The cutoff frequency of the transistor included in the fabricated sample was measured. Specifically, the cutoff frequency of the transistor with respect to the channel length was measured. In the measurement of the cutoff frequency, the drain voltage Vd was set to 2.5 V and the top gate voltage Vg was set to 1.5 V. The measurement was performed in an environment at room temperature (here, in an environment at 27° C.). For the measurement, 1000 transistors were connected in parallel. The gate length of the transistor in the channel length direction is 6.5 nm.

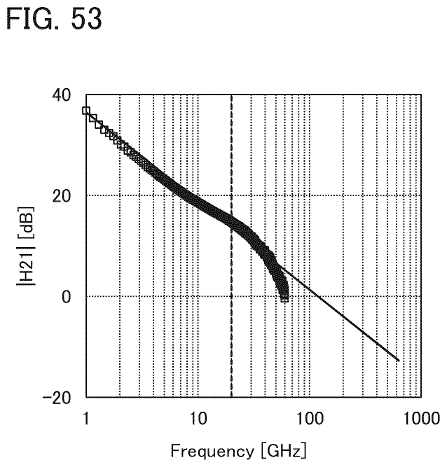

FIG. 53 shows the measurement result of the cutoff frequency. In FIG. 53, the vertical axis represents the current gain (|H21|) [dB], and the horizontal axis represents the frequency [GHz]. In addition, squares shown in FIG. 53 represent actual measurement of the current gain with respect to the frequency, and a solid line shown in FIG. 53 represents extrapolation of the actual measurement of the current gain with respect to the frequency. The frequency at which the current amplification rate was 1, i.e., the current gain |H21| was 0 dB, was obtained by extrapolation to obtain the cutoff frequency fᵣ.

As the result of the measurement, the cutoff frequency fᵣ of the transistor is estimated to be 118 GHz.

Accordingly, it can be confirmed that the transistors included in the fabricated sample are minute and have favorable electrical characteristics. It is also shown that the transistors have excellent frequency characteristics.

The structure, configuration, method, or the like described in this example can be used in an appropriate combination with any of the structures, configurations, methods, and the like described in the embodiments and the like.

### Example 4

In this example, the barrier property of a silicon nitride film against oxygen and hydrogen, the sheet resistance of a stack of a conductor and a metal oxide, the structure of a transistor, and the electrical characteristics of the transistor were evaluated.

### <Barrier Property of Silicon Nitride Film Against Oxygen and Hydrogen>

In this section, the oxygen barrier property and hydrogen barrier property of a silicon nitride film were evaluated. Specifically, samples (Sample 5A to Sample 5D) each including a stacked-layer film including a silicon nitride film were fabricated and analyzed by SIMS.

### [Sample Fabrication 1]

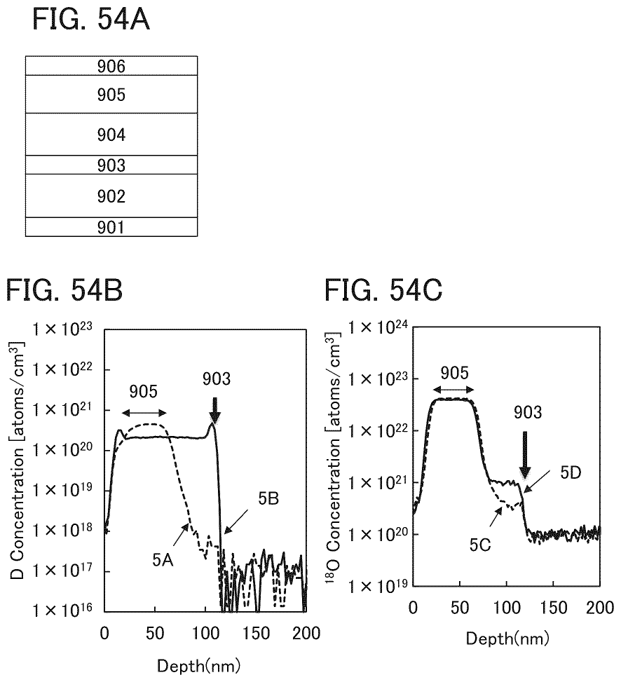

FIG. 54A illustrates the stacked-layer structure of the fabricated stacked-layer film. As illustrated in FIG. 54A, the stacked-layer film includes a layer 901, a layer 902 over the layer 901, a layer 903 over the layer 902, a layer 904 over the layer 903, a layer 905 over the layer 904, and a layer 906 over the layer 905.

A silicon substrate was prepared as the layer 901 for all of Sample 5A to Sample 5D. A stacked-layer structure of a 100-nm-thick silicon oxide film formed using thermal oxidation treatment and a 100-nm-thick silicon oxynitride film deposited over the silicon oxide film by a PECVD method was used as the layer 902.

In Sample 5A and Sample 5B, a 3.3-nm-thick silicon nitride film deposited by an ALD method was used as the layer 903. In Sample 5C and Sample 5D, a 1.4-nm-thick silicon nitride film deposited by an ALD method was used as the layer 903.

In all of Sample 5A to Sample 5D, a 50-nm-thick silicon oxynitride film deposited by a PECVD method was used as the layer 904.

In Sample 5A and Sample 5B, a 50-nm-thick silicon oxynitride film deposited by a PECVD method was used as the layer 905. Here, the silicon oxynitride film was deposited using a deuterium (D₂) gas at 200 sccm, a SiH₄ gas at 2.0 sccm, and an N₂O gas at 800 sccm as deposition gases. In Sample 5C and Sample 5D, a 50-nm-thick silicon oxide film containing 180 deposited by a sputtering method was used as the layer 905.

In all of Sample 5A to Sample 5D, a 20-nm-thick silicon nitride film deposited by a sputtering method was used as the layer 906.

Then, heat treatment was performed on Sample 5B and Sample 5D at 400° C. for eight hours in a nitrogen atmosphere. Note that Sample 5A and Sample 5C were not subjected to the heat treatment. The oxygen (¹⁸O) concentration distributions in Sample 5C and Sample 5D can be compared with each other to evaluate the oxygen barrier property of the silicon nitride film used as the layer 903 (how much oxygen passes through the layer 903 by thermal diffusion). In addition, the deuterium (D) concentration distributions in Sample 5A and Sample 5B can be compared with each other to evaluate the hydrogen barrier property of the silicon nitride film used as the layer 903 (how much hydrogen passes through the layer 903 by thermal diffusion). In the above manner, Sample 5A to Sample 5D each including the stacked-layer film were fabricated.

### [Evaluation of Hydrogen Concentration and Oxygen Concentration]

Sample 5A to Sample 5D were analyzed by SIMS. Note that the analysis direction of the SIMS analysis is a direction from the substrate toward the layer 906. By the SIMS analysis, the deuterium (D) profiles of Sample 5A and Sample 5B were obtained, and the oxygen (¹⁸O) profiles of Sample 5C and Sample 5D were obtained.

FIG. 54B shows the results of the deuterium (D) profiles of Sample 5A and Sample 5B. In FIG. 54B, the horizontal axis represents the depth in the thickness direction (Depth) [nm], and the vertical axis represents the concentration of deuterium (D concentration) [atoms/cm³]. A dotted line shown in FIG. 54B is the deuterium (D) profile of Sample 5A, and a solid line shown in FIG. 54B is the deuterium (D) profile of Sample 5B.

FIG. 54B reveals that deuterium (D) contained in the layer 905 of Sample 5B subjected to the above heat treatment is not diffused into the silicon oxynitride film used as the layer 902. Thus, it can be seen that thermal diffusion of deuterium (D) contained in the layer 905 is inhibited by the silicon nitride film used as the layer 903.

FIG. 54C shows the results of the oxygen (¹⁸O) profiles of Sample 5C and Sample 5D. In FIG. 54C, the horizontal axis represents the depth in the thickness direction (Depth) [nm], and the vertical axis represents the concentration of 180 (¹⁸O concentration) [atoms/cm³]. A dotted line shown in FIG. 54C is the oxygen (¹⁸O) profile of Sample 5C, and a solid line shown in FIG. 54C is the oxygen (¹⁸O) profile of Sample 5D.

FIG. 54C reveals that oxygen (¹⁸O) contained in the layer 905 of Sample 5D subjected to the above heat treatment is not diffused into the silicon oxynitride film used as the layer 902. Thus, it can be seen that thermal diffusion of oxygen (¹⁸O) contained in the layer 905 is inhibited by the silicon nitride film used as the layer 903.

Accordingly, it can be seen that the silicon nitride film has a barrier property against oxygen and hydrogen. Thus, the use of a silicon nitride film having an oxygen barrier property for the insulator 275 illustrated in FIG. 1 and the like can inhibit oxidation of the conductor 242a and the conductor 242b that are covered with the insulator 275 and function as a source electrode and a drain electrode. The conductivity of the oxide 230 in a region covered with the insulator 275 can also be maintained. Furthermore, the use of a silicon nitride film having a hydrogen barrier property for the insulator 275 can inhibit diffusion of hydrogen into the channel formation region in the oxide 230 and can keep a low donor concentration in the channel formation region.

### <Evaluation of Transistor>

As described above, it can be seen that a silicon nitride film has a barrier property against oxygen and hydrogen. In this section, samples (Sample 5E to Sample 5G) including transistors were fabricated, and the sheet resistances and the electrical characteristics of the transistors were evaluated. Note that the transistors included in Sample 5E to Sample 5G correspond to the transistor illustrated in FIG. 22A to FIG. 22D. Thus, FIG. 22A to FIG. 22D can be referred to for the cross-sectional structure of the transistors included in Sample 5E to Sample 5G.

### [Sample Fabrication 2]

Fabrication methods of Sample 5E and Sample 5F are described below. Note that differences from the samples fabricated in Example 3 are mainly described. The fabrication methods of Sample 5E and Sample 5F are the same except for the insulator 275. Embodiment 1 can be referred to for details of the fabrication methods. As the design values of the transistors included in Sample 5E and Sample 5F, the channel length was set to 30 nm, and the channel width was set to 30 nm.

The insulator 275 was not provided in Sample 5E. Meanwhile, in Sample 5F, 5-nm-thick silicon nitride deposited by an ALD method was used as the insulator 275. That is, the transistor included in Sample 5E does not include a silicon nitride film over the source electrode and the drain electrode, and the transistor included in Sample 5F includes a silicon nitride film over the source electrode and the drain electrode.

In Sample 5E and Sample 5F, the insulator 252 was formed using a 1-nm-thick aluminum oxide film deposited by an ALD method. The insulator 250 was formed using a stacked-layer film of a 5-nm-thick silicon oxynitride film deposited by a CVD method and a 1.5-nm-thick hafnium oxide film deposited over the silicon oxynitride film by an ALD method. The insulator 254 was formed using a 1-nm-thick silicon nitride film deposited by an ALD method.

In Sample 5E and Sample 5F, as the insulator 283a, 25-nm-thick silicon nitride deposited by a sputtering method was used. As the insulator 283b, 5-nm-thick silicon nitride deposited by an ALD method was used.

Sample 5E and Sample 5F including the transistors were fabricated in the above manner. In the transistors included in Sample 5E and Sample 5F, the gate length in the channel length direction (the width Lg illustrated in FIG. 3A) is 18 nm, and the length of the interface between the oxide 230a and the oxide 230b in the channel width direction is 48 nm.

Note that in Sample 5E and Sample 5F, test elements were fabricated through a process that is partly in common with the fabrication process of the transistors. Specifically, a fabrication method of the test elements is the same as the fabrication method of the transistors except that the step of forming the opening reaching the oxide 230b is not performed. More specifically, the test elements were fabricated by forming a stack of the insulator 224, the oxide 230a, the oxide 230b, the conductive layer 242B, and the insulating layer 271B, forming the insulator 275, the insulator 280, the insulator 282, and the like over the stack, forming two openings reaching the conductive layer 242B in the insulating layer 271B, the insulator 275, the insulator 280, the insulator 282, and the like, forming the conductor 240a and the conductor 240b individually in the two openings, and forming the conductor 246a and the conductor 246b over the conductor 240a and the conductor 240b, respectively.

The test elements included in Sample 5E and Sample 5F were fabricated such that the length of a transistor in the channel length direction was 40000 nm and the length of the transistor in the channel width direction was 30 nm.

### [Sheet Resistance]

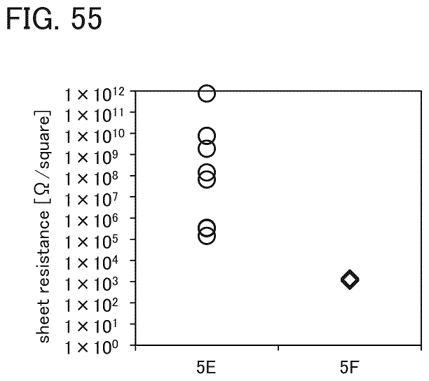

Sheet resistance measurement was performed using the test elements included in Sample 5E and Sample 5F. FIG. 55 shows the result of the sheet resistance measurement. In FIG. 55, the vertical axis represents the sheet resistance [Ω/square]. Note that a plot shown on the left side in FIG. 55 is the result of the test elements included in Sample 5E, and a plot shown on the right side in FIG. 55 is the result of the test elements included in Sample 5F.

FIG. 55 confirms that a variation of the sheet resistance values of Sample 5F is suppressed to a low resistance side as compared with Sample 5E. Thus, it can be seen that the conductivity of the oxide 230b positioned below the conductor 242a or the conductor 242b can be maintained when the insulator 275 using silicon nitride is provided.

### [Electrical Characteristics Evaluation 1]

The electrical characteristics of the transistors included in fabricated Sample 5E and Sample 5F were evaluated. Here, Id-Vg characteristics were measured as the electrical characteristics. The measurement of the Id-Vg characteristics was performed under the conditions where the drain voltage Vd was 0.1 V or 1.2 V; the source voltage Vs and the back gate voltage Vbg were 0 V; and the top gate voltage Vg was swept from −4 V to +4 V in increments of 0.1 V. The measurement was performed in an environment at room temperature. Note that transistors having a gate length of 18 nm in the channel length direction in Sample 5E and Sample 5F were used for the evaluation of the electrical characteristics.

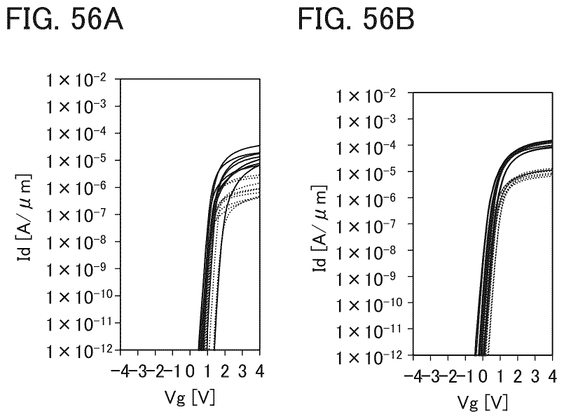

FIG. 56A shows the Id-Vg characteristics of nine transistors included in Sample 5E, and FIG. 56B shows the Id-Vg characteristics of nine transistors included in Sample 5F. In FIG. 56A and FIG. 56B, the vertical axis represents the drain current per micrometer of channel width (Id [A/μm]), and the horizontal axis represents the gate-source voltage (Vg [V]). In FIG. 56A and FIG. 56B, Id with the drain voltage Vd of 1.2 V is shown by solid lines, and Id with the drain voltage Vd of 0.1 V is shown by dotted lines.

FIG. 56A and FIG. 56B confirm that the transistors included in Sample 5F show a smaller variation in threshold voltage and a higher on-state current than the transistors included in Sample 5E. Thus, it can be seen that a variation in the electrical characteristics of transistors can be reduced when the insulator 275 using silicon nitride is provided.

[Sample fabrication 3]

A fabrication method of Sample 5G is described below. Note that differences from Sample 5F are mainly described. Embodiment 1 can be referred to for details of the fabrication method. As the design values of transistors included in Sample 5G, the channel length was set to 20 nm, and the channel width was set to 20 nm.

In Sample 5G, the insulator 252 was formed using a 1-nm-thick aluminum oxide film deposited by an ALD method. The insulator 250 was formed using a 3-nm-thick silicon oxide film deposited by an ALD method. The insulator 254 was formed using a 3-nm-thick silicon nitride film deposited by an ALD method. The insulator 252, the insulator 250, and the insulator 254 function as a top gate insulating film. This means that the top gate insulating film is formed to have a physical thickness of 7.0 nm (EOT=5.1 nm).

In Sample 5G, 20-nm-thick silicon nitride deposited by a sputtering method was used as the insulator 283a. As the insulator 283b, 5-nm-thick silicon nitride deposited by an ALD method was used.

Sample 5G including the transistors was fabricated in the above manner.

### [Cross-Sectional Observation Image]

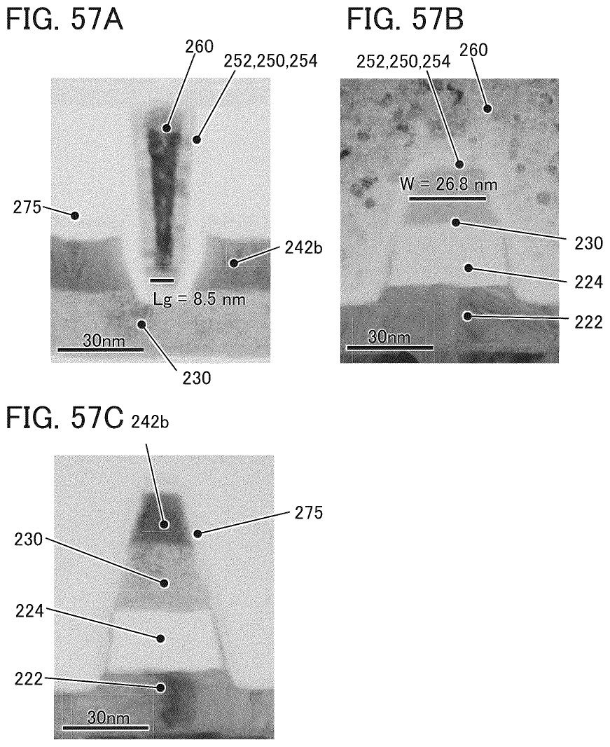

Cross-sectional STEM images of fabricated Sample 5G were taken with “HD-2700” produced by Hitachi High-Technologies Corporation. FIG. 57A shows a cross-sectional STEM image in the channel length direction of the transistor included in Sample 5G, FIG. 57B shows a cross-sectional STEM image in the channel width direction of the transistor included in fabricated Sample 5G, and FIG. 57C shows a cross-sectional STEM image in the channel width direction of a region where the oxide 230 of the transistor included in fabricated Sample 5G overlaps with the source electrode or the drain electrode. Note that in FIG. 57A to FIG. 57C, some components (e.g., the insulator 271) are not denoted by reference numerals.

Note that in FIG. 57A and FIG. 57B, the length of each component was measured on the basis of the observation results of the cross-sectional STEM images. As the result of the measurement using FIG. 57A, the gate length in the channel length direction of the transistor included in Sample 5G (the width Lg illustrated in FIG. 3A) is 8.5 nm. As the result of the measurement using FIG. 57B, the length in the channel width direction of the interface between the oxide 230a and the oxide 230b included in Sample 5G is 26.8 nm.

FIG. 57C reveals that the insulator 275 can be deposited by an ALD method to have good coverage of the conductor 242 and the oxide 230. This confirms that the insulator 275 has sufficient coverage for use as a protective film and an etch stopper film.

### [Electrical Characteristics Evaluation 2]

The electrical characteristics of the transistors included in fabricated Sample 5G were evaluated. Here, Id-Vg characteristics were measured as the electrical characteristics. The measurement of the Id-Vg characteristics was performed under the conditions where the drain voltage Vd was 0.1 V or 1.2 V; the source voltage Vs and the back gate voltage Vbg were 0 V; and the top gate voltage Vg was swept from −4 V to +4 V in increments of 0.1 V. The measurement was performed in an environment at room temperature.

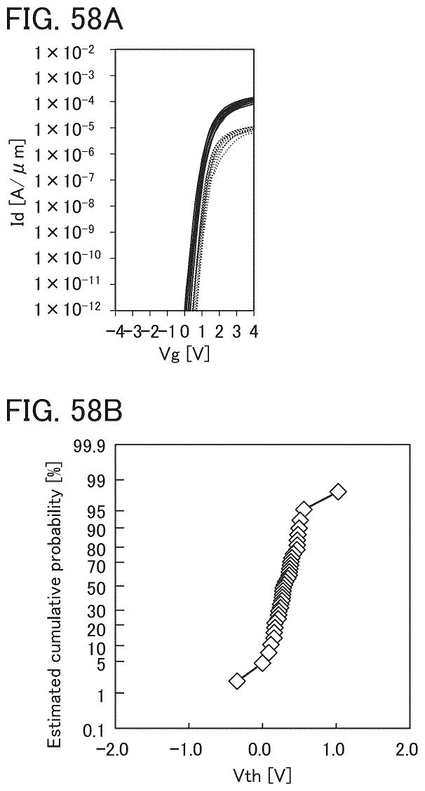

FIG. 58A shows the Id-Vg characteristics of nine transistors included in Sample 5G. In FIG. 58A, the vertical axis represents the drain current per micrometer of channel width (Id [A/μm]), and the horizontal axis represents the gate-source voltage (Vg [V]). In FIG. 58A, Id with the drain voltage Vd of 1.2 V is shown by solid lines, and Id with the drain voltage Vd of 0.1 V is shown by dotted lines.

FIG. 58A confirms that the transistors included in Sample 5G have normally-off characteristics and switching characteristics. Specifically, when the drain voltage Vd is 1.2 V, Vth is 0.28 V, and SS is 172 mV/dec. Note that in this example, Vth is defined as the gate-source voltage Vg for the drain current Id to be 1 pA. Furthermore, SS is a subthreshold slope.

Next, the Id-Vg characteristics of 36 transistors in Sample 5G in the range of 100 mm² were measured, and variations of Vth were evaluated.

FIG. 58B shows the normal probability plot diagram of Vth. In FIG. 58B, the horizontal axis represents the Vth [V], and the vertical axis represents the estimated cumulative probability [%]. Note that examples of methods for calculating estimated cumulative probability (also referred to as cumulative relative frequency) include a median ranking method, an average ranking method, a symmetric sample cumulative distribution method, and a Kaplan-Meier method, and an appropriate method may be selected. In this example, the estimated cumulative probability was calculated using a median ranking method.

According to FIG. 58B, the standard deviation (o) of Vth of the 36 transistors is approximately 134 mV.

The structure, configuration, method, or the like described in this example can be used in an appropriate combination with any of the structures, configurations, methods, and the like described in the embodiments and the like.

### Example 5

In this example, the fundamental physical properties of a metal oxide were evaluated. Specifically, the relationship between the Hall mobility and the carrier concentration of the metal oxide was evaluated. Samples each including a transistor including a metal oxide in its channel formation region were fabricated, and the electrical characteristics of the transistors were evaluated.

### <Relationship Between Hall Mobility and Carrier Concentration of Metal Oxide>

In this section, the result of evaluating the relationship between the Hall mobility and the carrier concentration of the metal oxide is described. Specifically, Hall effect measurement was performed on samples each including the metal oxide, and the result was used to calculate the carrier concentration in the metal oxide.

Here, the Hall effect measurement is a method in which electrical characteristics such as carrier concentration, mobility, and resistivity are measured with the use of the Hall effect, which is a phenomenon where, when a magnetic field is applied to an object through which a current flows in a direction perpendicular to the direction of the current, an electromotive force is produced in directions perpendicular to both the current and the magnetic field. Here, the Hall effect measurement using the Van der Pauw method was performed.

Fabrication methods of the samples used for the Hall effect measurement are described.

First, Sample 60A to Sample 60D were fabricated. Note that the fabrication methods of Sample 60A to Sample 60D are the same except for the composition of a target used for depositing the metal oxide.

A quartz substrate was prepared, and a 35-nm-thick metal oxide was deposited over the quartz substrate by a sputtering method. Note that the composition of an oxide target used for depositing the metal oxide is In:Ga:Zn=5:1:3 [atomic ratio] for Sample 60A, In:Ga:Zn=1:1:2 [atomic ratio] for Sample 60B, In:Ga:Zn=1:1:5 [atomic ratio] for Sample 60C, and In:Ga:Zn=1:1:8 [atomic ratio] for Sample 60D.

After the metal oxide was deposited, treatment was performed at 450° C. for one hour in an atmospheric pressure environment with a flow rate ratio of a nitrogen gas to an oxygen gas being 4:1. This treatment is referred to as first treatment. The first treatment can decrease the carrier concentration in the metal oxide.

After the first treatment was performed, the substrate of each of Sample 60A to Sample 60D was divided, whereby Sample 61A to Sample 68A were fabricated from Sample 60A, Sample 61B to Sample 68B were fabricated from Sample 60B, Sample 61C to Sample 68C were fabricated from Sample 60C, and Sample 61D to Sample 68D were fabricated from Sample 60D.

Next, treatment was performed for one hour under reduced pressure (in a vacuum). This treatment is referred to as second treatment. The temperature of the second treatment differs from sample to sample. Specifically, the temperature of the second treatment was set to 100° C. for Samples 62A, 62B, 62C, and 62D, 150° C. for Samples 63A, 63B, 63C, and 63D, 200° C. for Samples 64A, 64B, 64C, and 64D, 250° C. for Samples 65A, 65B, 65C, and 65D, 300° C. for Samples 66A, 66B, 66C, and 66D, 350° C. for Samples 67A, 67B, 67C, and 67D, and 400° C. for Samples 68A, 68B, 68C, and 68D. Note that Samples 61A, 61B, 61C, and 61D were not subjected to the second treatment. When the temperature of the second treatment differs from sample to sample, the carrier concentration in the metal oxide can be varied.

In the above manner, the samples used for the Hall effect measurement (Sample 61A to Sample 68A, Sample 61B to Sample 68B, Sample 61C to Sample 68C, and Sample 61D to Sample 68D) were fabricated. Note that Sample 61A to Sample 68A are hereinafter referred to as Sample Group 6A, Sample 61B to Sample 68B as Sample Group 6B, Sample 61C to Sample 68C as Sample Group 6C, and Sample 61D to Sample 68D as Sample Group 6D in some cases.

Note that a 200-nm-thick titanium-aluminum alloy film was deposited over each sample by a sputtering method in order to perform the Hall effect measurement. Note that a metal mask was used to form the titanium-aluminum alloy film at each of the four corners of the sample.

For the Hall effect measurement, “ResiTest 8400” produced by TOYO Corporation was used.

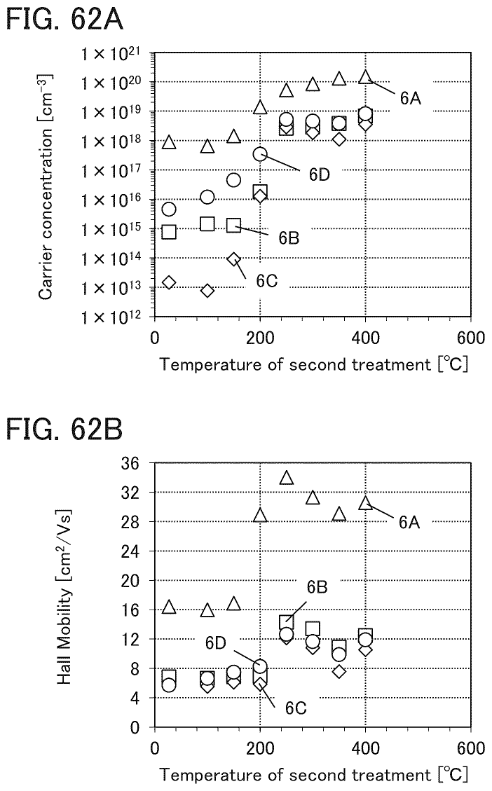

FIG. 62A shows the results of the Hall effect measurement. FIG. 62A is a diagram showing the temperature dependence of the carrier concentration in the metal oxide. In FIG. 62A, the vertical axis represents the carrier concentration in the metal oxide (Carrier concentration) [cm⁻³], and the horizontal axis represents the temperature of the second treatment [C]. Triangles shown in FIG. 62A indicate the results of Sample Group 6A, squares shown in FIG. 62A indicate the results of Sample Group 6B, rhombuses shown in FIG. 62A indicate the results of Sample Group 6C, and circles shown in FIG. 62A indicate the results of Sample Group 6D.

FIG. 62A confirms that the carrier concentration in each of Sample Group 6A to Sample Group 6D tends to increase as the temperature of the second treatment increases.

FIG. 62B shows the results of the Hall effect measurement. FIG. 62B is a diagram showing the temperature dependence of the Hall mobility of the metal oxide. In FIG. 62B, the vertical axis represents the Hall mobility of the metal oxide (Hall Mobility) [cm²/Vs], and the horizontal axis represents the temperature of the second treatment [° C.]. Triangles shown in FIG. 62B indicate the results of Sample Group 6A, squares shown in FIG. 62B indicate the results of Sample Group 6B, rhombuses shown in FIG. 62B indicate the results of Sample Group 6C, and circles shown in FIG. 62B indicate the results of Sample Group 6D.

According to FIG. 62B, the Hall mobility of each of Sample Group 6A to Sample Group 6D is a maximum when the temperature of the second treatment is 250° C. Among the metal oxides with high proportions of Zn (e.g., the metal oxides included in Sample Group 6B, Sample Group 6C, and Sample Group 6D), the Hall mobility of Sample Group 6B is high. It can also be confirmed that the Hall mobility tends to slightly decrease when the proportion of Zn is increased.

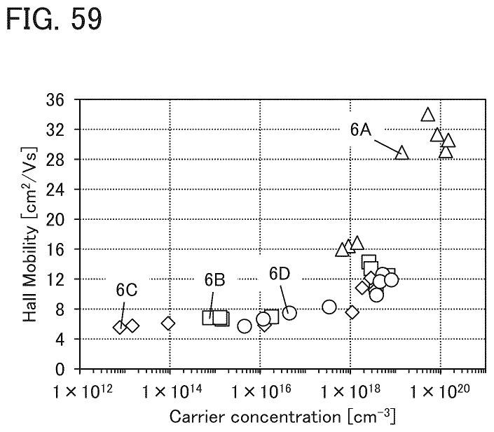

FIG. 59 shows the results of the Hall effect measurement. FIG. 59 is a diagram showing the relationship between the Hall mobility and the carrier concentration of the metal oxide. In FIG. 59, the vertical axis represents the Hall mobility of the metal oxide (Hall Mobility) [cm²/Vs], and the horizontal axis represents the carrier concentration in the metal oxide (Carrier concentration) [cm⁻³]. Triangles shown in FIG. 59 indicate the results of Sample Group 6A, squares shown in FIG. 59 indicate the results of Sample Group 6B, rhombuses shown in FIG. 59 indicate the results of Sample Group 6C, and circles shown in FIG. 59 indicate the results of Sample Group 6D.

FIG. 59 confirms that a metal oxide with a high proportion of Zn (e.g., the metal oxide included in Sample Group 6B, Sample Group 6C, or Sample Group 6D) tends to have a low Hall mobility and a low carrier concentration. It can also be confirmed that a metal oxide with a high proportion of In (e.g., the metal oxide included in Sample Group 6A) tends to have a high Hall mobility and a high carrier concentration. Specifically, in Sample Group 6A, the maximum value of the Hall mobility is 34.0 cm²/Vs, and the minimum value of the carrier concentration is 9.1×10¹⁷ cm⁻³.

Furthermore, the Hall mobility of each of Sample Group 6A to Sample Group 6D tends to increase as the carrier concentration increases. That is, it can be seen that there is a trade-off between the carrier concentration and the Hall mobility of the metal oxide. Thus, it can be seen that an optimum composition and an allowable Hall mobility range can be inferred by specifying a desired carrier concentration.

### <Electrical Characteristics of Transistor>

In this section, samples including a plurality of transistors illustrated in FIG. 22A to FIG. 22D were fabricated, and the electrical characteristics of the transistors were evaluated.

In this section, Sample 69A to Sample 69D were fabricated. FIG. 22A to FIG. 22D can be referred to for the cross-sectional structure of the transistors included in Sample 69A to Sample 69D. Note that in this section, the step of processing part of the insulator 282, part of the insulator 280, part of the insulator 275, part of the insulator 222, and part of the insulator 216 until the top surface of the insulator 214 is exposed (see FIG. 15A to FIG. 15D) was not performed.

As the design values of the transistors included in Sample 69A to Sample 69D, the channel length was set to 60 nm, and the channel width was set to 60 nm. Note that in this example, the design value of the channel width refers to the design value of an apparent channel width. Thus, the design value of the channel width can be rephrased as the design value of the gate width.

Fabrication methods of Sample 69A to Sample 69D are described below. Note that the fabrication methods of Sample 69A to Sample 69D are the same except for the composition of a target used for depositing the oxide 230b. Embodiment 1 can be referred to for details of the fabrication methods.

As the insulator 212, 60-nm-thick silicon nitride was used. The insulator 212 was deposited by a pulsed DC sputtering method using a silicon target.

As the insulator 214, 40-nm-thick aluminum oxide was used. The insulator 214 was deposited by a pulsed DC sputtering method using an aluminum target.

As the insulator 216, 130-nm-thick silicon oxide was used. The insulator 216 was deposited by a pulsed DC sputtering method using a silicon target.

Note that the insulator 212, the insulator 214, and the insulator 216 were successively deposited without exposure to the air using a multi-chamber sputtering apparatus.

The conductor 205a was formed using a titanium nitride film deposited by a metal CVD method. The conductor 205b was formed using a tungsten film deposited by a metal CVD method.

As the insulator 222, 20-nm-thick hafnium oxide deposited by an ALD method was used.

The insulator 224 was formed using 10-nm-thick silicon oxide deposited by a sputtering method.

The oxide 230a was formed using a 10-nm-thick oxide film deposited by an RF sputtering method. Note that the oxide film to be the oxide 230a was deposited using an oxide target with In:Ga:Zn=1:3:2 [atomic ratio]. An In—Ga—Zn oxide deposited by such a method has an oxygen-blocking property. That is, the oxide 230a functions as a buffer layer. Thus, providing the oxide 230a can inhibit oxygen implantation into the oxide 230b from below the oxide 230a.

For the oxide 230b, a 15-nm-thick oxide film deposited by a DC sputtering method was used. Note that the oxide film to be the oxide 230b was deposited using an oxide target with In:Ga:Zn=5:1:3 [atomic ratio] for Sample 69A, an oxide target with In:Ga:Zn=1:1:2 [atomic ratio] for Sample 69B, an oxide target with In:Ga:Zn=1:1:5 [atomic ratio] for Sample 69C, and an oxide target with In:Ga:Zn=1:1:8 [atomic ratio] for Sample 69D.

The conductor 242a and the conductor 242b were formed using a 20-nm-thick tantalum nitride film deposited by a sputtering method. Note that the conductive film to be the conductor 242a and the conductor 242b was deposited using a metal tantalum target under an atmosphere containing nitrogen.

The insulator 271a1 and the insulator 271b1 were formed using a 5-nm-thick silicon nitride film. The insulator 271a2 and the insulator 271b2 were formed using a silicon oxide film. Note that the silicon nitride film and the silicon oxide film were successively deposited without exposure to the air using a multi-chamber sputtering apparatus.

As the insulator 275, 5-nm-thick silicon nitride deposited by an ALD method was used.

As the insulator 280, silicon oxide deposited by a sputtering method was used.

The insulator 252 was formed using a 1-nm-thick aluminum oxide film deposited by an ALD method. The insulator 250 was formed using a stacked-layer film of a 1-nm-thick silicon oxide film deposited by an ALD method and a 4-nm-thick hafnium oxide film deposited over the silicon oxide film by an ALD method. The insulator 254 was formed using a 1-nm-thick silicon nitride film deposited by an ALD method.

The conductor 260a was formed using a 5-nm-thick titanium nitride film deposited by a metal CVD method. The conductor 260b was formed using a tungsten film deposited by a metal CVD method.

As the insulator 282, aluminum oxide was used. The insulator 282 was deposited by a pulsed DC sputtering method using an aluminum target.

As the insulator 283, 20-nm-thick silicon nitride was used. The insulator 283 was deposited by a pulsed DC sputtering method using a silicon target. In this manner, silicon nitride having a hydrogen barrier property was provided over and under the insulator 280 functioning as an interlayer film.

By the above methods, Sample 69A to Sample 69D including the transistors were fabricated.

Next, the electrical characteristics of the transistors included in fabricated Sample 69A to Sample 69D were evaluated. Here, drain current (Id)-top gate voltage (Vg) characteristics were measured as the electrical characteristics. The measurement of the Id-Vg characteristics was performed under the conditions where the drain-source voltage Vds was 0.1 V or 1.2 V; the back gate voltage Vbg was 0 V; and the top gate voltage Vg was swept from −4 V to +4 V in increments of 0.1 V. The measurement was performed in an environment at room temperature (27° C.) in dry air under atmospheric pressure.

For evaluation of the electrical characteristics, a semi-automatic prober produced by Hi-SOL, Inc. was used. As a measuring instrument, B1500A produced by Keysight Technologies, Inc. was used.

Threshold voltage (Vth) and field-effect mobility in a linear region (μ_{FE} (lin.)) were calculated from the obtained Id-Vg characteristics. Here, the threshold voltage (Vth) is defined as the gate voltage Vg for the drain current to be 1 pA.

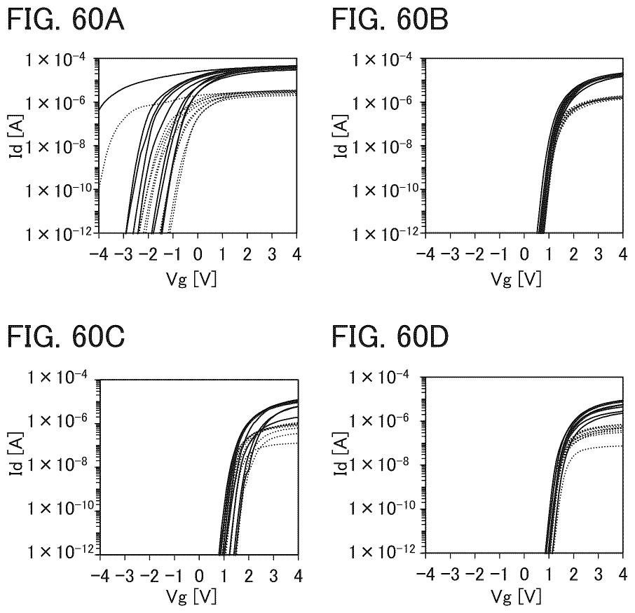

FIG. 60A to FIG. 60D show the Id-Vg characteristics of the transistors included in the fabricated samples. FIG. 60A shows the Id-Vg characteristics of nine transistors included in Sample 69A, FIG. 60B shows the Id-Vg characteristics of nine transistors included in Sample 69B, FIG. 60C shows the Id-Vg characteristics of nine transistors included in Sample 69C, and FIG. 60D shows the Id-Vg characteristics of nine transistors included in Sample 69D. In FIG. 60A to FIG. 60D, the vertical axis represents the drain current Id [A], and the horizontal axis represents the top gate voltage Vg [V]. In FIG. 60A to FIG. 60D, the drain current Id with the drain-source voltage Vds of 1.2 V is shown by solid lines, and the drain current Id with the drain-source voltage Vds of 0.1 V is shown by dotted lines.

FIG. 60A to FIG. 60D show the result that all the transistors included in each sample mostly have switching characteristics. Specifically, with the drain-source voltage Vds of 1.2 V, Sample 69A shows a Vth of −2.42 V (σ=1.70 V) and a LIFE (lin.) of 13.5 cm²/Vs, Sample 69B shows a Vth of 0.62 V (σ=0.08 V) and a LIFE (lin.) of 5.5 cm²/Vs, Sample 69C shows a Vth of 1.02 V (0=0.24 V) and a LIFE (lin.) of 3.2 cm²/Vs, and Sample 69D shows a Vth of 1.00 V (σ=0.08 V) and a μ_{FE} (lin.) of 1.7 cm²/Vs. Note that the above values are each a median value of characteristic values obtained from the nine transistors, and o is a standard deviation.

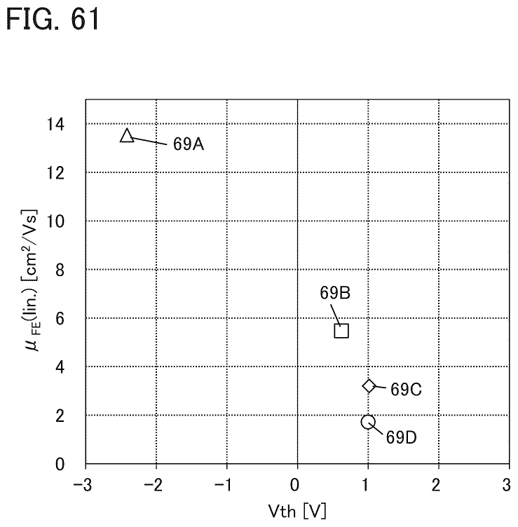

FIG. 61 shows the result of plotting the calculated median values of Vth and the calculated median values of FE (lin.). In FIG. 61, the vertical axis represents the field-effect mobility in a linear region (LIFE (lin.)) [cm²/Vs], and the horizontal axis represents the threshold voltage Vth [V]. A triangle shown in FIG. 61 indicates the result of the transistors included in Sample 69A, a square shown in FIG. 61 indicates the result of the transistors included in Sample 69B, a rhombus shown in FIG. 61 indicates the result of the transistors included in Sample 69C, and a circle shown in FIG. 61 indicates the result of the transistors included in Sample 69D.

FIG. 61 confirms a tendency of a transistor including a metal oxide with a high proportion of In (e.g., the metal oxide used for the oxide 230b of Sample 69A) in a channel formation region to achieve a high field-effect mobility but have a negative Vth. FIG. 61 also confirms a tendency of a transistor including a metal oxide with a high proportion of Zn (e.g., the metal oxide used for the oxide 230b of Sample 69B, Sample 69C, or Sample 69D) in a channel formation region to have a low field-effect mobility but have a positive Vth. This suggests a trade-off between the field-effect mobility and the threshold voltage. For example, a metal oxide with a high proportion of In is preferably included in a channel formation region in order to obtain a transistor having a high field-effect mobility. A metal oxide with a high proportion of Zn is preferably included in a channel formation region in order to obtain a transistor having normally-off characteristics.

FIG. 61 reveals that an In—Ga—Zn oxide deposited using an oxide target with In:Ga:Zn=1:1:2 [atomic ratio] is preferably used for the oxide 230b in order to obtain normally-off characteristics while maintaining high mobility. That is, it can be confirmed that a transistor having normally-off characteristics with favorable controllability can be obtained by depositing a metal oxide including a channel formation region under a condition for a composition with a high proportion of Zn.

The structure, configuration, method, or the like described in this example can be used in an appropriate combination with any of the structures, configurations, methods, and the like described in the other embodiments and the like.

### REFERENCE NUMERALS

101: wiring, 102: wiring, 103: wiring, 104: wiring, 110a: light-emitting element, 110B: light-emitting element, 110b: light-emitting element, 110c: light-emitting element, 110G: light-emitting element, 110R: light-emitting element, 110: light-emitting element, 111B: pixel electrode, 111C: connection electrode, 111G: pixel electrode, 111R: pixel electrode, 111: pixel electrode, 112B: organic layer, 112G: organic layer, 112R: organic layer, 112: organic layer, 113: common electrode, 114: common layer, 121: protective layer, 124a: pixel, 124b: pixel, 125: insulating layer, 126: resin layer, 128: layer, 140: connection portion, 150: pixel, 170: substrate, 171: adhesive layer, 200A: transistor, 200B: transistor, 200: transistor, 205a: conductor, 205b: conductor, 205: conductor, 212: insulator, 214: insulator, 216: insulator, 222: insulator, 224A: insulating film, 224: insulator, 230a: oxide, 230A: oxide film, 230b: oxide, 230B: oxide film, 230ba: region, 230bb: region, 230bc: region, 230bd: region, 230be: region, 230: oxide, 240a: conductor, 240b: conductor, 240): capacitor, 241a: insulator, 241b: insulator, 242a: conductor, 242A: conductive film, 242b: conductor, 242B: conductive layer, 242: conductor, 243a: oxide, 243b: oxide, 243: oxide, 244a: insulator, 244b: insulator, 245: conductive layer, 246a: conductor, 246b: conductor, 250a: insulator, 250A: insulating film, 250b: insulator, 250: insulator, 251: conductive layer, 252A: insulating film, 252: insulator, 254A: insulating film, 254: insulator, 255a: insulating layer, 255b: insulating layer, 255c: insulating layer, 256: insulator, 260a: conductor, 260b: conductor, 260: conductor, 261: insulating layer, 262: insulating layer, 263: insulating layer, 264: insulating layer, 265: sealing portion, 271a: insulator, 271A: insulating film, 271b: insulator, 271B: insulating layer, 271: insulator, 274: insulator, 275: insulator, 280): insulator, 282a: insulator, 282b: insulator, 282: insulator, 283a: insulator, 283b: insulator, 283: insulator, 285: insulator, 295: opening region, 301: substrate, 310): transistor, 311: conductive layer, 312: low-resistance region, 313: insulating layer, 314: insulating layer, 315: element isolation layer, 329: insulating layer, 331: substrate, 332: insulating layer, 341: conductive layer, 343: insulating layer, 352: conductive layer, 354: insulating layer, 356: plug, 365: insulating layer, 371: plug, 374a: conductive layer, 374b: conductive layer, 374: plug, 390: display module, 400A: display device, 400B: display device, 400C: display device, 400D: display device, 400: display device, 401: substrate, 431: display portion, 432: circuit portion, 433a: pixel circuit, 433: pixel circuit portion, 434a: pixel, 434: pixel portion, 435: terminal portion, 436: wiring portion, 440: FPC, 441: substrate, 442: substrate, 500: semiconductor device, 700A: electronic device, 700B: electronic device, 721: housing, 723: wearing portion, 727: earphone portion, 750: earphone, 751: display panel, 753: optical member, 756: display region, 757: frame, 758: nose pad, 761: lower electrode, 762: upper electrode, 763a: light-emitting unit, 763b: light-emitting unit. 763c: light-emitting unit, 763: EL layer, 764: layer, 771a: light-emitting layer, 771b: light-emitting layer, 771c: light-emitting layer, 771: light-emitting layer, 772a: light-emitting layer, 772b: light-emitting layer, 772c: light-emitting layer, 772: light-emitting layer, 773: light-emitting layer, 780a: layer, 780b: layer, 780c: layer, 780: layer, 781: layer, 782: layer, 785: charge-generation layer, 790a: layer, 790b: layer, 790c: layer, 790: layer, 791: layer, 792: layer, 800A: electronic device, 800B: electronic device, 820: display portion, 821: housing, 822: communication portion, 823: wearing portion, 824: control portion, 825: image capturing portion, 827: earphone portion, 832: lens, 901: layer, 902: layer, 903: layer, 904: layer, 905: layer, 906: layer, 1400: storage device, 1411: peripheral circuit, 1420: row circuit, 1430: column circuit, 1440); output circuit, 1460): control logic circuit, 1470: memory cell array, 1471: memory cell, 1472: memory cell, 1473: memory cell, 1474: memory cell, 1475: memory cell, 1476: memory cell, 1477: memory cell, 1478: memory cell, 2700): manufacturing apparatus, 2701: atmosphere-side substrate supply chamber, 2702: atmosphere-side substrate transfer chamber, 270) 3a: load lock chamber, 2703b: unload lock chamber, 2704: transfer chamber, 270) 6a: chamber, 2706b: chamber, 2706c: chamber, 2706d: chamber, 2761: cassette port, 2762: alignment port, 2763a: transfer robot, 2763b: transfer robot, 2801: gas supply source, 2802: valve, 2803: high-frequency generator, 2804: waveguide, 2805: mode converter, 2806: gas pipe, 2807: waveguide, 2808: slot antenna plate, 2809: dielectric plate, 2810: high-density plasma, 2811_1: substrate, 2811_2: substrate, 2811_3: substrate, 2811_n: substrate, 2811: substrate, 2812: substrate holder, 2813: heating mechanism, 2815: matching box, 2816: high-frequency power source, 2817: vacuum pump, 2818: valve, 2819: exhaust port, 2820: lamp, 2821: gas supply source, 2822: valve, 2823: gas inlet, 2824: substrate, 2825: substrate holder, 2826: heating mechanism, 2828: vacuum pump, 2829: valve, 2830: exhaust port, 2900: microwave treatment apparatus, 2901: quartz tube, 2902: substrate holder, 2903: heating means, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote control, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information. 9055: hinge. 9101: portable information terminal. 9102: portable information terminal. 9103: tablet terminal. 9200: portable information terminal. 9201: portable information terminal

1. A semiconductor device comprising:
a metal oxide comprising a channel formation region of a transistor;
a first conductor and a second conductor over the metal oxide;
a first insulator positioned over the metal oxide and between the first conductor and the second conductor;
a second insulator over the first insulator;
a third insulator over the second insulator;
a third conductor over the third insulator;
a fourth insulator positioned between the first conductor and the first insulator;
a fifth insulator positioned between the second conductor and the first insulator; and
a sixth insulator positioned above the first conductor and the second conductor,
wherein the sixth insulator comprises an opening,
wherein the opening comprises a region that is between the first conductor and the second conductor and that overlaps with the metal oxide,
wherein the first insulator, the second insulator, the third insulator, and the third conductor are placed in the opening,
wherein the first insulator comprises a region in contact with a top surface of the metal oxide, a region in contact with a side surface of the metal oxide, and a region in contact with a sidewall of the opening,
wherein the first insulator is a material through which oxygen is less likely to pass than the second insulator,
wherein the first insulator comprises a region having a thickness of greater than or equal to 1.0 nm and less than 3.0 nm,
wherein the first conductor and the second conductor each comprise a metal element,
wherein the fourth insulator and the fifth insulator comprise the metal element, and
wherein a distance from the first conductor to the first insulator is greater than or equal to a thickness of the first insulator and is less than or equal to a distance from the third conductor to the metal oxide in a cross-sectional view of the transistor in a channel length direction.

2. The semiconductor device according to claim 1,
wherein the first insulator is a material through which oxygen and hydrogen are less likely to pass than the second insulator,
wherein the third insulator is a material through which hydrogen is less likely to pass than the second insulator,
wherein the first insulator and the second insulator each comprise oxygen,
wherein the second insulator and the third insulator each comprise silicon, and
wherein the third insulator and the third conductor each comprise nitrogen.

3. The semiconductor device according to claim 1,
wherein the first insulator comprises aluminum.

4. The semiconductor device according to claim 3,
wherein the metal oxide has a concentration gradient with an increasing concentration of aluminum from a bottom surface of the metal oxide toward the top surface of the metal oxide.

5. The semiconductor device according to claim 4,
wherein the metal oxide comprises at least indium, aluminum, and zinc.

6. The semiconductor device according to claim 1,
wherein the metal element is tantalum or titanium.

7. A method for manufacturing a semiconductor device comprising a metal oxide, a first conductor to a third conductor, a first insulator to a fourth insulator, a fifth insulator positioned between the first conductor and the second insulator, and a sixth insulator positioned between the second conductor and the second insulator, the method comprising:
a first step of sequentially forming a metal oxide film and a conductive film;
a second step of processing the metal oxide film and the conductive film into an island shape to form the metal oxide and a conductive layer;
a third step of forming the first insulator;
a fourth step of processing part of the first insulator and part of the conductive layer to form the first conductor, the second conductor, and an opening reaching the metal oxide;
a fifth step of forming a first insulating film in the opening;
a sixth step of forming a second insulating film over the first insulating film;
a seventh step of performing microwave treatment in an atmosphere comprising oxygen;
an eighth step of sequentially forming a third insulating film and a second conductive film; and
a ninth step of forming the second insulator, the third insulator, the fourth insulator, and the third conductor by CMP treatment,
wherein the fifth insulator and the sixth insulator are formed when any one of the fourth step, the fifth step, the sixth step, and the seventh step is performed.
